(19) United States
(12) Patent Application Publication
(10) Pub. No.: US 2026/0206488 A1
(43) Pub. Date: Jul. 16, 2026

(54) LIGHT-EMITTING DEVICE INCLUDING CONDENSED CYCLIC COMPOUND, ELECTRONIC APPARATUS INCLUDING THE LIGHT-EMITTING DEVICE, AND THE CONDENSED CYCLIC COMPOUND

(71) Applicant: Samsung Display Co., Ltd., Yongin-si (KR)

(72) Inventors: Munki Sim, Yongin-si (KR); Sunyoung Pak, Yongin-si (KR); Kyoung Sunwoo, Yongin-si (KR); Minjae Sung, Yongin-si (KR); Chihyun Ryoo, Yongin-si (KR); Seonhyoung Hur, Yongin-si (KR)

(21) Appl. No.: 19/447,817

(22) Filed: Jan. 13, 2026

(30) Foreign Application Priority Data
Jan. 14, 2025 (KR) 10-2025-0005598

(51) Int. Cl. H10K 85/60; C07F 5/02; C09K 11/06; H10K 50/12

(52) U.S. Cl. CPC H10K 85/658; C07F 5/027; C09K 11/06; H10K 85/6572; H10K 85/6574; C09K 2211/1007; C09K 2211/1018; H10K 50/12

(57) ABSTRACT

A light-emitting device includes a first electrode; a second electrode facing the first electrode; an interlayer between the first electrode and the second electrode and comprising an emission layer; and a condensed cyclic compound represented by Formula 1. Also provided are an electronic apparatus including the light-emitting device, and the condensed cyclic compound represented by Formula 1:

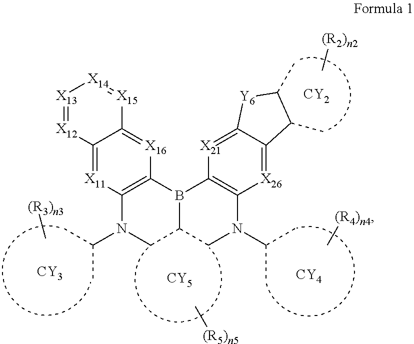

wherein a detailed description of Formula 1 is provided herein.

### CROSS-REFERENCE TO RELATED APPLICATION

This application claims priority to and the benefit of Korean Patent Application No. 10-2025-0005598, filed on Jan. 14, 2025, in the Korean Intellectual Property Office, the disclosure of which is incorporated by reference herein in its entirety.

### BACKGROUND

### 1. Field

One or more aspects of embodiments of the present disclosure are directed toward a light-emitting device including a condensed cyclic compound, an electronic apparatus including the light-emitting device, and the condensed cyclic compound.

### 2. Description of the Related Art

Among light-emitting devices, self-emissive devices have wide viewing angles, suitably high contrast ratios, short response times, and excellent or suitable characteristics in terms of luminance, driving voltage, and/or response speed.

In a light-emitting device, a first electrode is arranged on a substrate, and a hole transport region, an emission layer, an electron transport region, and a second electrode are sequentially arranged on the first electrode. Holes provided from the first electrode move toward the emission layer through the hole transport region, and electrons provided from the second electrode move toward the emission layer through the electron transport region. Carriers, such as the holes and electrons, recombine in the emission layer to produce excitons. The excitons transition from an excited state to a ground state, thereby generating light.

### SUMMARY

One or more aspects of embodiments of the present disclosure are directed towards a light-emitting device including a condensed cyclic compound, an electronic apparatus including the light-emitting device, and the condensed cyclic compound.

Additional aspects will be set forth in part in the description which follows and, in part, will be apparent from the description, or may be learned by practice of the presented embodiments of the disclosure.

According to one or more embodiments, a light-emitting device includes:
a first electrode,
a second electrode facing the first electrode,
an interlayer arranged between the first electrode and the second electrode and including an emission layer, and
a condensed cyclic compound represented by Formula 1:

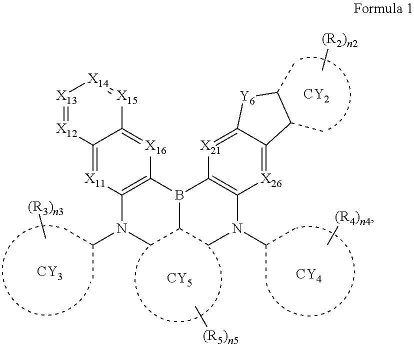

wherein, in Formula 1,
CY₂ to CY₅ may each independently be a C₃-C₆₀ carbocyclic group or a C₁-C₆₀ heterocyclic group,
Y₆ may be C(R₆₁)(R₆₂), N(R₆₁), O, Si(R₆₁)(R₆₂), P(R₆₁), or S,
X₁₁ may be N or C(R₁₁), X₁₂ may be N or C(R₁₂), X₁₃ may be N or C(R₁₃), X₁₄ may be N or C(R₁₄), X₁₅ may be N or C(R₁₅), and X₁₆ may be N or C(R₁₆),
X₂₁ may be N or C(R₂₁), and X₂₆ may be N or C(R₂₆),
n2 to n5 may each independently be an integer from 0 to 10,
when n2 is 2 or more, R₂ in the number of n2 may be identical to or different from each other,
when n3 is 2 or more, R₃ in the number of n3 may be identical to or different from each other,
when n4 is 2 or more, R₄ in the number of n4 may be identical to or different from each other,
when n5 is 2 or more, R₅ in the number of n5 may be identical to or different from each other,
R₁ to R₁₆, R₂, R₂₁, R₂₆, R₃, R₄, R₅, R₆₁, and R₆₂ may each independently be hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂),
neighboring two or more selected from among R₁₁ to R₁₆, R₂, R₂₁, R₂₆, R₃, R₄, R₅, R₆₁, R₆₂, and Q₁ to Q₃ may optionally be bonded to each other to form a C₅-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ may be:
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be hydrogen; deuterium; —F; —C₁; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

According to one or more embodiments, an electronic apparatus and electronic equipment include the light-emitting device.

According to one or more embodiments, provided is the condensed cyclic compound represented by Formula 1.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view of a structure of a light-emitting device according to one or more embodiments;

FIG. 2 is a schematic view of a structure of an electronic apparatus according to one or more embodiments;

FIG. 3 is a schematic view of a structure of an electronic apparatus according to one or more embodiments;

FIG. 4 is a block diagram of electronic equipment according to one or more embodiments;

FIG. 5 shows schematic views of electronic equipment according to one or more embodiments;

FIG. 6 is a schematic perspective view of electronic equipment including a light-emitting device according to one or more embodiments;

FIG. 7 is a schematic view of an exterior of a vehicle as electronic equipment including a light-emitting device according to one or more embodiments; and

FIGS. 8A-8C are each a schematic view of an interior of a vehicle according to one or more embodiments.

### DETAILED DESCRIPTION

Reference will now be made in more detail to one or more embodiments, examples of which are illustrated in the accompanying drawings, wherein like reference numerals refer to like elements throughout the specification, and duplicative descriptions thereof may not be provided. In this regard, the present embodiments may have different forms and should not be construed as being limited to the descriptions set forth herein. Accordingly, one or more embodiments are merely described in more detail herein below, by referring to the drawings, to explain aspects of the present description. As used herein, the term “and/or” includes any and all combinations of one or more of the associated listed items.

As used herein, expressions such as “at least one of”, “one of”, and “selected from”, when preceding a list of elements, modify the entire list of elements and do not modify the individual elements of the list. For example, throughout the disclosure, the expressions “at least one selected from among a, b and c”, “at least one of a, b or c”, and “at least one of a, b and/or c” indicate only a, only b, only c, both (e.g., simultaneously) a and b, both (e.g., simultaneously) a and c, both (e.g., simultaneously) b and c, all of a, b, and c, or variations thereof.

It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “use,” “using,” and “used” may be considered synonymous with the terms “utilize,” “utilizing,” and “utilized,” respectively.

Further, the use of “may” when describing embodiments of the present disclosure refers to “one or more embodiments of the present disclosure”.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to” another element, there are no intervening elements present.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A light-emitting device (e.g., an organic light-emitting device) according to one or more embodiments may include: a first electrode; a second electrode facing the first electrode; an interlayer arranged between the first electrode and the second electrode and including an emission layer; and a condensed cyclic compound represented by Formula 1.

First, the condensed cyclic compound will be described.

The condensed cyclic compound may be represented by Formula 1:

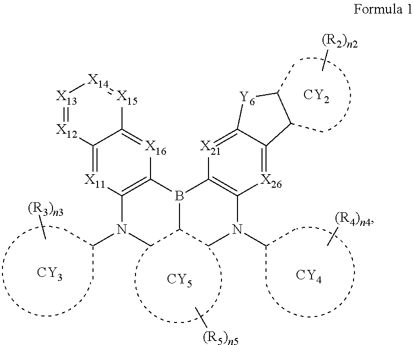

wherein, in Formula 1, CY₂ to CY₅ may each independently be a C₃-C₆₀ carbocyclic group or a C₁-C₆₀ heterocyclic group.

In one or more embodiments, CY₂ to CY₅ in Formula 1 may each independently be a benzene group, a naphthalene group, an anthracene group a phenanthrene group, a fluoranthene group, a triphenylene group, a pyrene group, a chrysene group, an indene group, a fluorene group, a spiro-bifluorene group, a benzofluorene group, a dibenzofluorene group, an indole group, a pyridine group, a pyrimidine group, a carbazole group, a benzocarbazole group, a dibenzocarbazole group, a furan group, a benzofuran group, a dibenzofuran group, a naphthofuran group, a benzonaphthofuran group, a dinaphthofuran group, a thiophene group, a benzothiophene group, a dibenzothiophene group, a naphthothiophene group, a benzonaphthothiophene group, or a dinaphthothiophene group.

In one or more embodiments, the condensed cyclic compound represented by Formula 1 may be a compound represented by Formula 1-1:

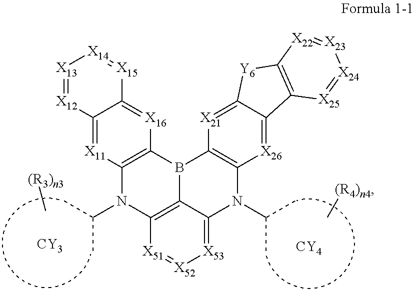

wherein, in Formula 1-1,
CY₃, CY₄, Y₆, X₁₁ to X₁₆, X₂₁, X₂₆, n3, n4, R₃, and R₄ are each as respectively described herein,
X₂₂ may be N or C(R₂₂), X₂₃ may be N or C(R₂₃), X₂₄ may be N or C(R₂₄), and X₂₅ may be N or C(R₂₅),
X₅₁ may be N or C(R₅₁), X₅₂ may be N or C(R₅₂), and X₅₃ may be N or C(R₅₃),
R₂₂ to R₂₅ may each independently be as described in connection with R₂, and
R₅₁ to R₅₃ may each independently be as described in connection with R₅.

In Formula 1, X₁₁ may be N or C(R₁₁), X₁₂ may be N or C(R₁₂), X₁₃ may be N or C(R₁₃), X₁₄ may be N or C(R₁₄), X₁₅ may be N or C(R₁₅), and X₁₆ may be N or C(R₁₆).

In Formula 1, X₂₁ may be N or C(R₂₁), and X₂₆ may be N or C(R₂₆).

In one or more embodiments, the condensed cyclic compound represented by Formula 1 may be a compound represented by Formula 1-2:

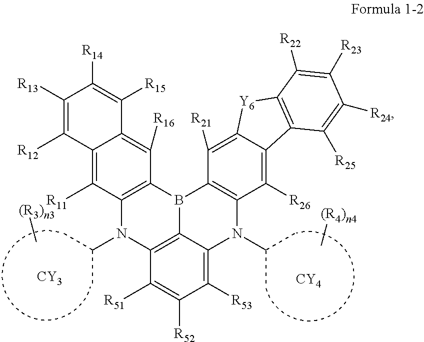

wherein, in Formula 1-2,
CY₃, CY₄, Y₆, n3, n4, R₁₁ to R₁₆, R₂₁, R₂₆, R₃, and R₄ are each as respectively described herein,
R₂₂ to R₂₅ may each independently be as described in connection with R₂, and
R₅₁ to R₅₃ may each independently be as described in connection with R₅.

In one or more embodiments, a group represented by

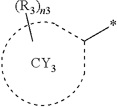

in Formula 1 may be a group represented by Formula 3:

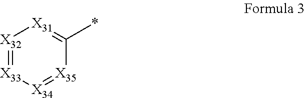

wherein, in Formula 3,
X₃₁ may be N or C(R₃₁), X₃₂ may be N or C(R₃₂), X₃₃ may be N or C(R₃₃), X₃₄ may be N or C(R₃₄), and X₃₅ may be N or C(R₃₅),
R₃₁ to R₃₅ may each independently be as described in connection with R₃, and
* indicates a binding site to a neighboring nitrogen atom.

In one or more embodiments, in Formula 3, X₃₁ may be C(R₃₁), X₃₂ may be C(R₃₂), X₃₃ may be C(R₃₃), X₃₄ may be C(R₃₄), and X₃₅ may be C(R₃₅).

In one or more embodiments, at least one selected from among R₃₁ and R₃₅ in Formula 3 may be a C₆-C₆₀ aryl group unsubstituted or substituted with at least one R₁₀ₐ or a C₁-C₆₀ heteroaryl group unsubstituted or substituted with at least one R₁₀ₐ.

In one or more embodiments, at least one selected from among R₃₁ and R₃₅ in Formula 3 may be a phenyl group unsubstituted or substituted with at least one R₁₀ₐ.

In one or more embodiments, a group represented by

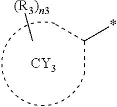

in Formula 1 may be a group represented by one selected from among Formulae 3A to 3E:

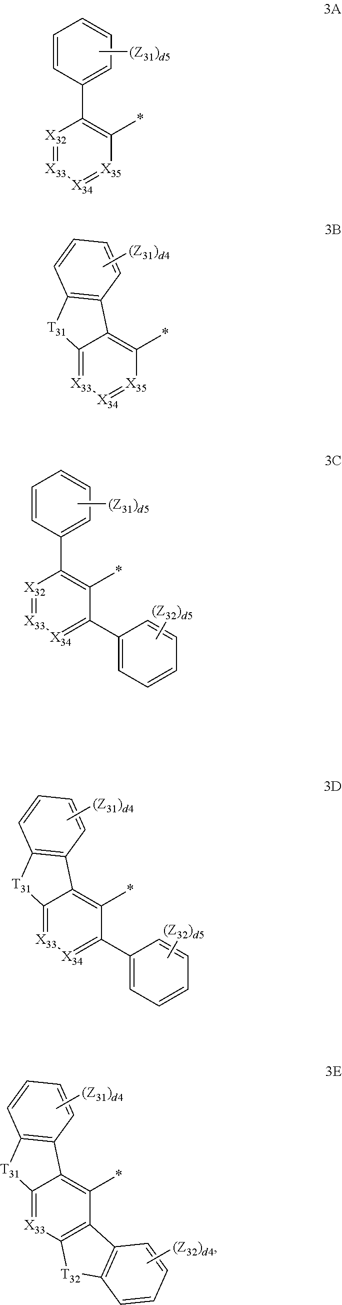

wherein, in Formulae 3A to 3E,
T₃₁ and T₃₂ may each independently be C(Z₃₃)(Z₃₄), N(Z₃₃), O, Si(Z₃₃)(Z₃₄), P(Z₃₃), or S,
X₃₂ may be N or C(R₃₂), X₃₃ may be N or C(R₃₃), X₃₄ may be N or C(R₃₄), and X₃₅ may be N or C(R₃₅),
R₃₂ to R₃₅ may each independently be as described in connection with R₃,
Z₃₁ to Z₃₄ may each independently be as described in connection with R₁₀ₐ,
d4 may be an integer from 0 to 4,
d5 may be an integer from 0 to 5, and
* indicates a binding site to a neighboring nitrogen atom.

In one or more embodiments, a group represented by

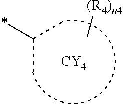

in Formula 1 may be a group represented by Formula 4:

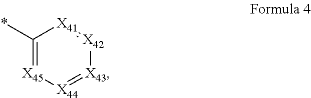

wherein, in Formula 4,
X₄₁ may be N or C(R₄₁), X₄₂ may be N or C(R₄₂), X₄₃ may be N or C(R₄₃), X₄₄ may be N or C(R₄₄), and X₄₅ may be N or C(R₄₅),
R₄₁ to R₄₅ may each independently be as described in connection with R₄, and
* indicates a binding site to a neighboring nitrogen atom.

In one or more embodiments, in Formula 4, X₄₁ may be C(R₄₁), X₄₂ may be C(R₄₂), X₄₃ may be C(R₄₃), X₄₄ may be C(R₄₄), and X₄₅ may be C(R₄₅).

In one or more embodiments, at least one selected from among R₄₁ and R₄₅ in Formula 4 may be a C₆-C₆₀ aryl group unsubstituted or substituted with at least one R₁₀ₐ or a C₁-C₆₀ heteroaryl group unsubstituted or substituted with at least one R₁₀ₐ.

In one or more embodiments, at least one selected from among R₄₁ and R₄₅ in Formula 4 may be a phenyl group unsubstituted or substituted with at least one R₁₀ₐ.

In one or more embodiments, a group represented by

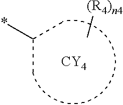

in Formula 1 may be a group represented by one selected from among Formulae 4A to 4E:

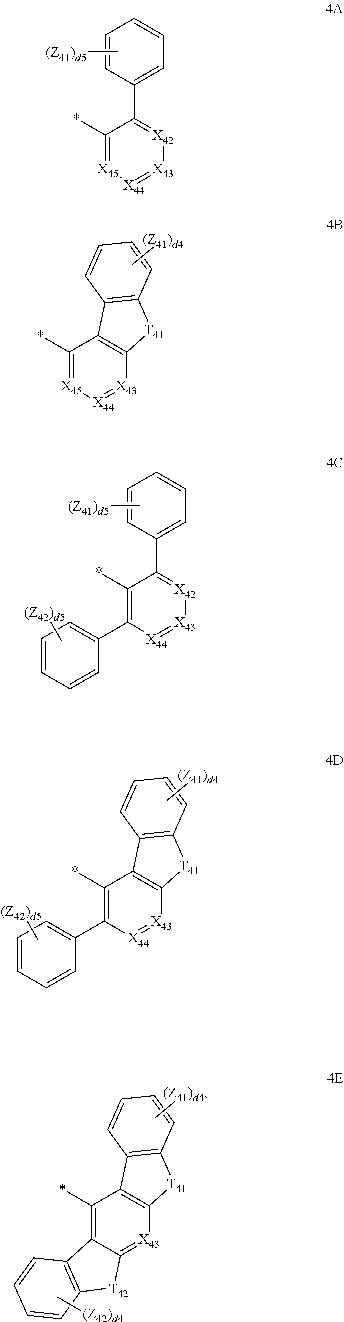

wherein, in Formulae 4A to 4E,
T₄₁ and T₄₂ may each independently be C(Z₄₃)(Z₄₄), N(Z₄₃), O, Si(Z₄₃)(Z₄₄), P(Z₄₃), or S,
X₄₂ may be N or C(R₄₂), X₄₃ may be N or C(R₄₃), X₄₄ may be N or C(R₄₄), and X₄₅ may be N or C(R₄₅),
R₄₂ to R₄₅ may each independently be as described in connection with R₄,
Z₄₁ to Z₄₄ may each independently be as described in connection with R₁₀ₐ,
d4 may be an integer from 0 to 4,
d5 may be an integer from 0 to 5, and
* indicates a binding site to a neighboring nitrogen atom.

Y₆ in Formula 1 may be C(R₆₁)(R₆₂), N(R₆₁), O, Si(R₆₁)(R₆₂), P(R₆₁), or S. In one or more embodiments, Y₆ in Formula 1 may be N(R₆₁), O, or S.

n2 to n5 in Formula 1 indicate the numbers of R₂ to R₅, respectively, and may each independently be an integer from 0 to 10. When n2 is 2 or more, R₂ in the number of n2 may be substantially identical to or different from each other, when n3 is 2 or more, R₃ in the number of n3 may be substantially identical to or different from each other, when n4 is 2 or more, R₄ in the number of n4 may be substantially identical to or different from each other, and when n5 is 2 or more, R₅ in the number of n5 may be substantially identical to or different from each other.

R₁₁ to R₁₆, R₂, R₂₁, R₂₆, R₃, R₄, R₅, R₆₁, and R₆₂ in Formula 1 may each independently be hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂). In some embodiments, neighboring two or more selected from among R₁₁ to R₁₆, R₂, R₂₁, R₂₆, R₃, R₄, R₅, R₆₁, R₆₂, and Q₁ to Q₃ may optionally be bonded to each other to form a C₅-C₆₀ carbocyclic group unsubstituted or substituted with at least one R₁₀ₐ or a C₁-C₆₀ heterocyclic group unsubstituted or substituted with at least one R₁₀ₐ.

In one or more embodiments, neighboring two of R₂ may be bonded to each other to form a benzene group unsubstituted or substituted with at least one R₁₀ₐ or a carbazole group unsubstituted or substituted with at least one R₁₀ₐ.

In one or more embodiments, neighboring R₁₂ and R₁₃ may be bonded to each other to form a benzene group unsubstituted or substituted with at least one R₁₀ₐ or a carbazole group unsubstituted or substituted with at least one R₁₀ₐ.

In one or more embodiments, neighboring two of R₃ may be bonded to each other to form a benzene group unsubstituted or substituted with at least one R₁₀ₐ or a dibenzofuran group unsubstituted or substituted with at least one R₁₀ₐ.

In one or more embodiments, neighboring Q₁ and Q₂ may be bonded to each other to form a phenoxazine group unsubstituted or substituted with at least one R₁₀ₐ or a dihydroacridine group unsubstituted or substituted with at least one R₁₀ₐ.

In one or more embodiments, R₁₁ to R₁₆, R₂, R₂₁, R₂₆, R₃, R₄, R₅, R₆₁, and R₆₂ in Formula 1 may each independently be:

hydrogen, deuterium, —F, a hydroxyl group, a cyano group, a C₁-C₂₀ alkyl group, or a C₁-C₂₀ alkoxy group,
a C₁-C₂₀ alkyl group or a C₁-C₂₀ alkoxy group, each substituted with deuterium, —F, —CD₃, —CD₂H, —CDH₂, —CF₃, —CF₂H, —CFH₂, a hydroxyl group, a cyano group, or any combination thereof,
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a C₁-C₂₀ alkylphenyl group, a naphthyl group, a fluorenyl group, a phenanthrenyl group, an anthracenyl group, a thiophenyl group, a furanyl group, an indenyl group, an isoindolyl group, an indolyl group, a carbazolyl group, a benzofuranyl group, a benzothiophenyl group, a benzosilolyl group, a dibenzofuranyl group, a dibenzothiophenyl group, a dibenzosilolyl group, a benzofluorenyl group, a benzocarbazolyl group, a naphthobenzofuranyl group, a naphthobenzothiophenyl group, a naphthobenzosilolyl group, a dibenzofluorenyl group, a dibenzocarbazolyl group, a dinaphthofuranyl group, a dinaphthothiophenyl group, a dinaphthosilolyl group, an indenocarbazolyl group, an indolocarbazolyl group, a benzofuranocarbazolyl group, a benzothienocarbazolyl group, or a benzosilolocarbazolyl group, each unsubstituted or substituted with deuterium, —F, —CD₃, —CD₂H, —CDH₂, —CF₃, —CF₂H, —CFH₂, a hydroxyl group, a cyano group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a C₁-C₂₀ alkylphenyl group, a naphthyl group, a fluorenyl group, a phenanthrenyl group, an anthracenyl group, a thiophenyl group, a furanyl group, an indenyl group, an isoindolyl group, an indolyl group, a carbazolyl group, a benzofuranyl group, a benzothiophenyl group, a benzosilolyl group, a dibenzofuranyl group, a dibenzothiophenyl group, a dibenzosilolyl group, a benzofluorenyl group, a benzocarbazolyl group, a naphthobenzofuranyl group, a naphthobenzothiophenyl group, a naphthobenzosilolyl group, a dibenzofluorenyl group, a dibenzocarbazolyl group, a dinaphthofuranyl group, a dinaphthothiophenyl group, a dinaphthosilolyl group, an indenocarbazolyl group, an indolocarbazolyl group, a benzofuranocarbazolyl group, a benzothienocarbazolyl group, a benzosilolocarbazolyl group, —N(Q₃₁)(Q₃₂), —B(Q₃₁)(Q₃₂), or any combination thereof; or
—Si(Q₁)(Q₂)(Q₃), —B(Q₁)(Q₂), or —N(Q₁)(Q₂).

R₁₀ₐ as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

The condensed cyclic compound represented by Formula 1 may be, for example, one of Compounds 1 to 144:

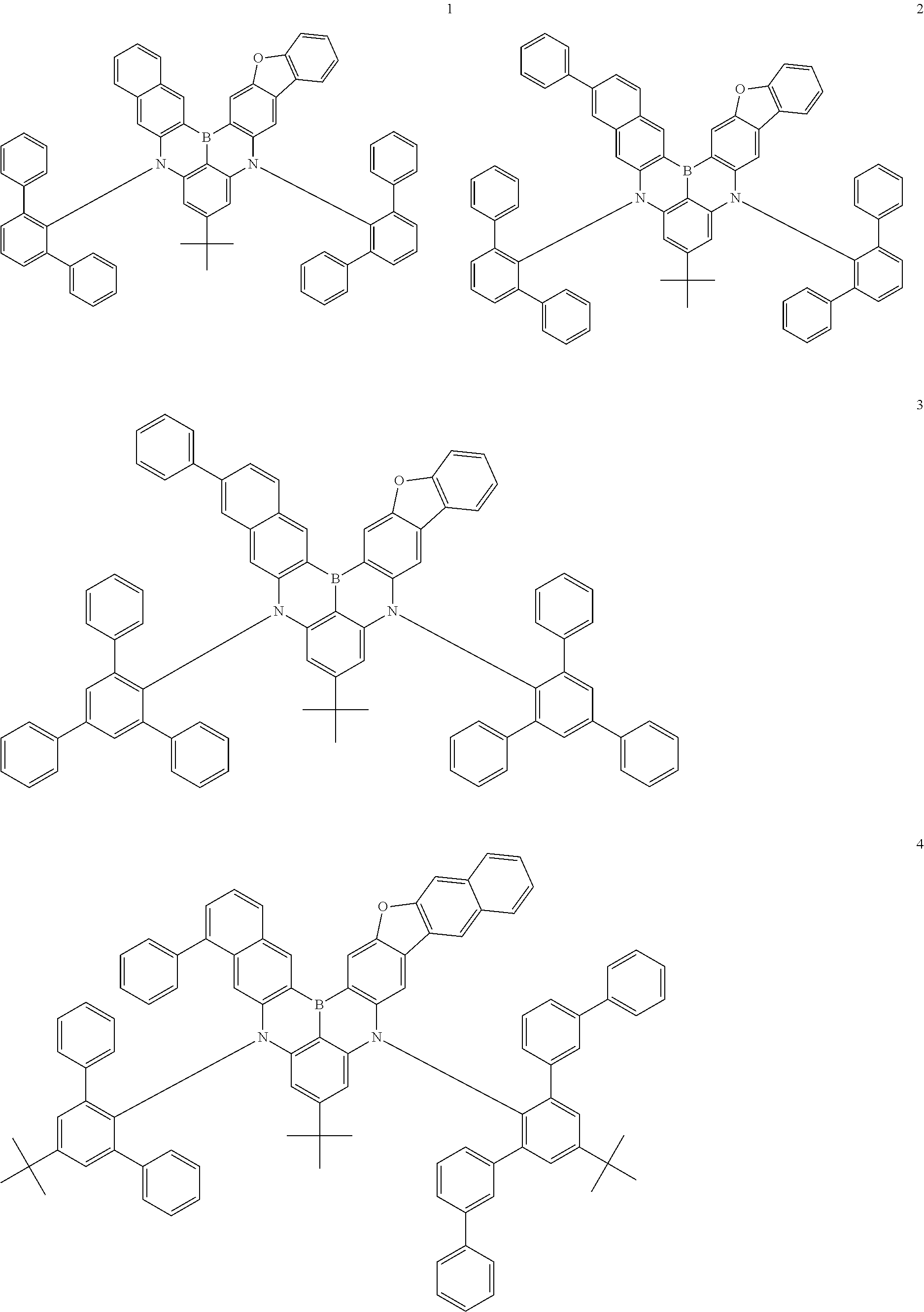

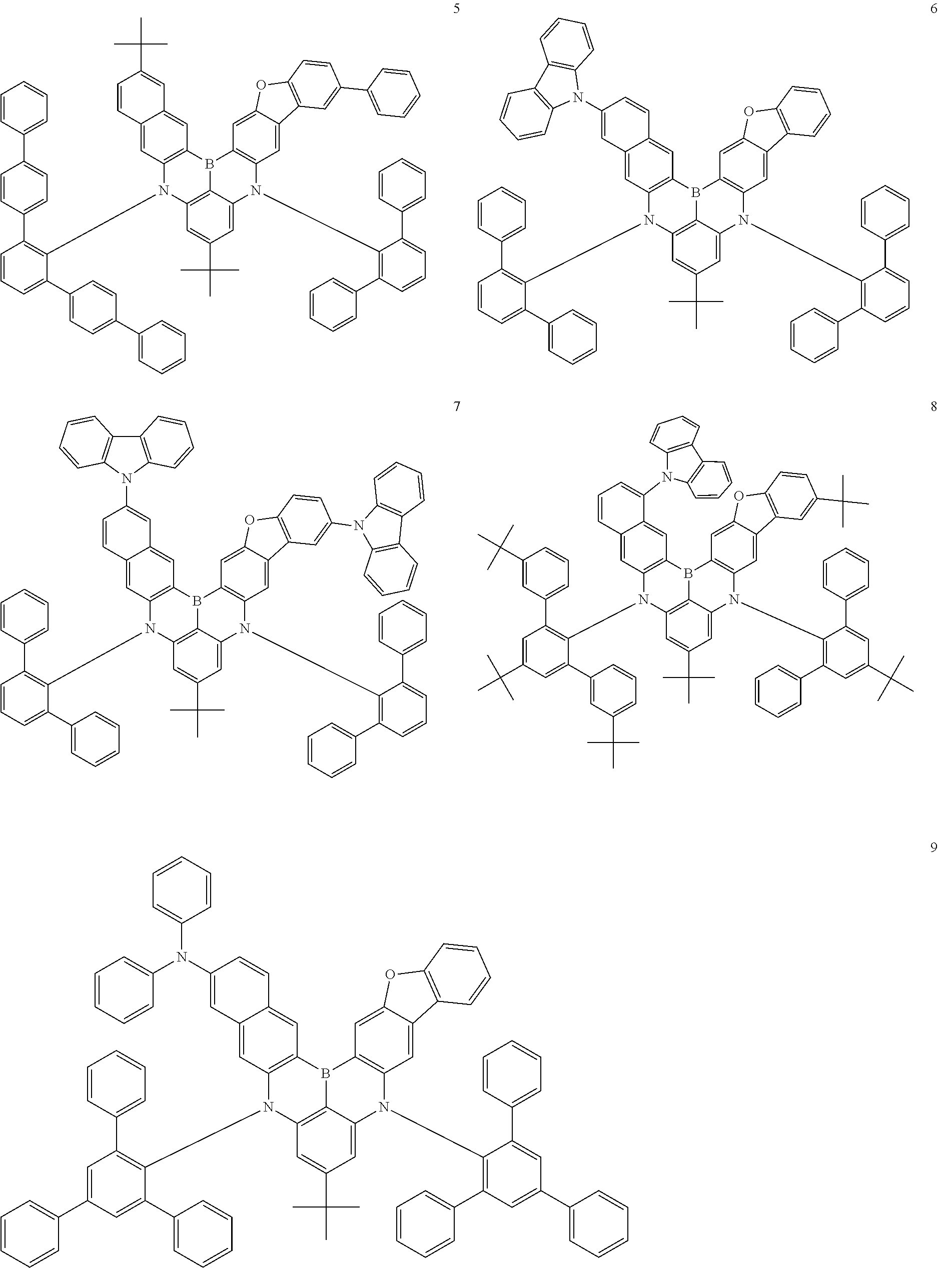

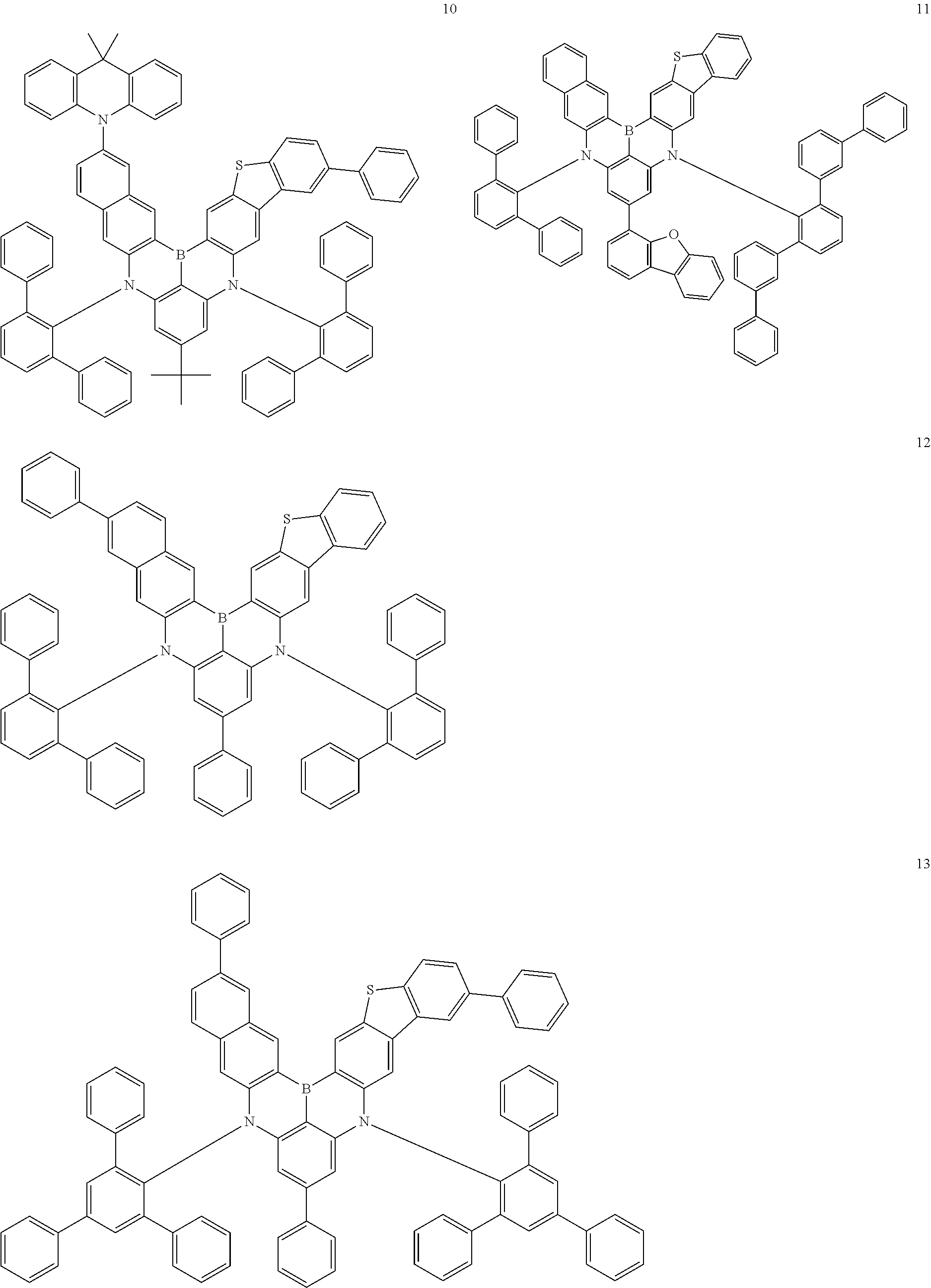

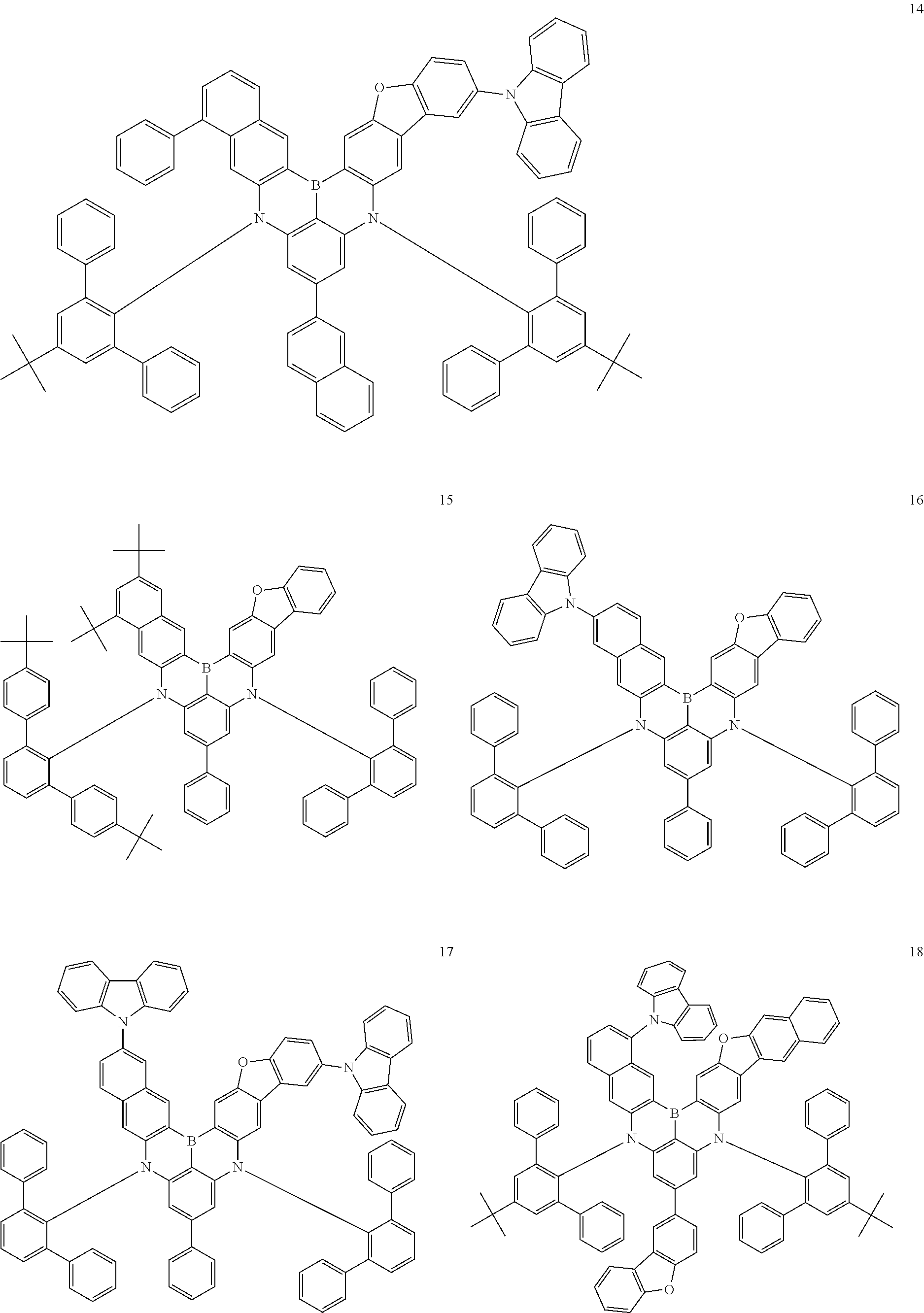

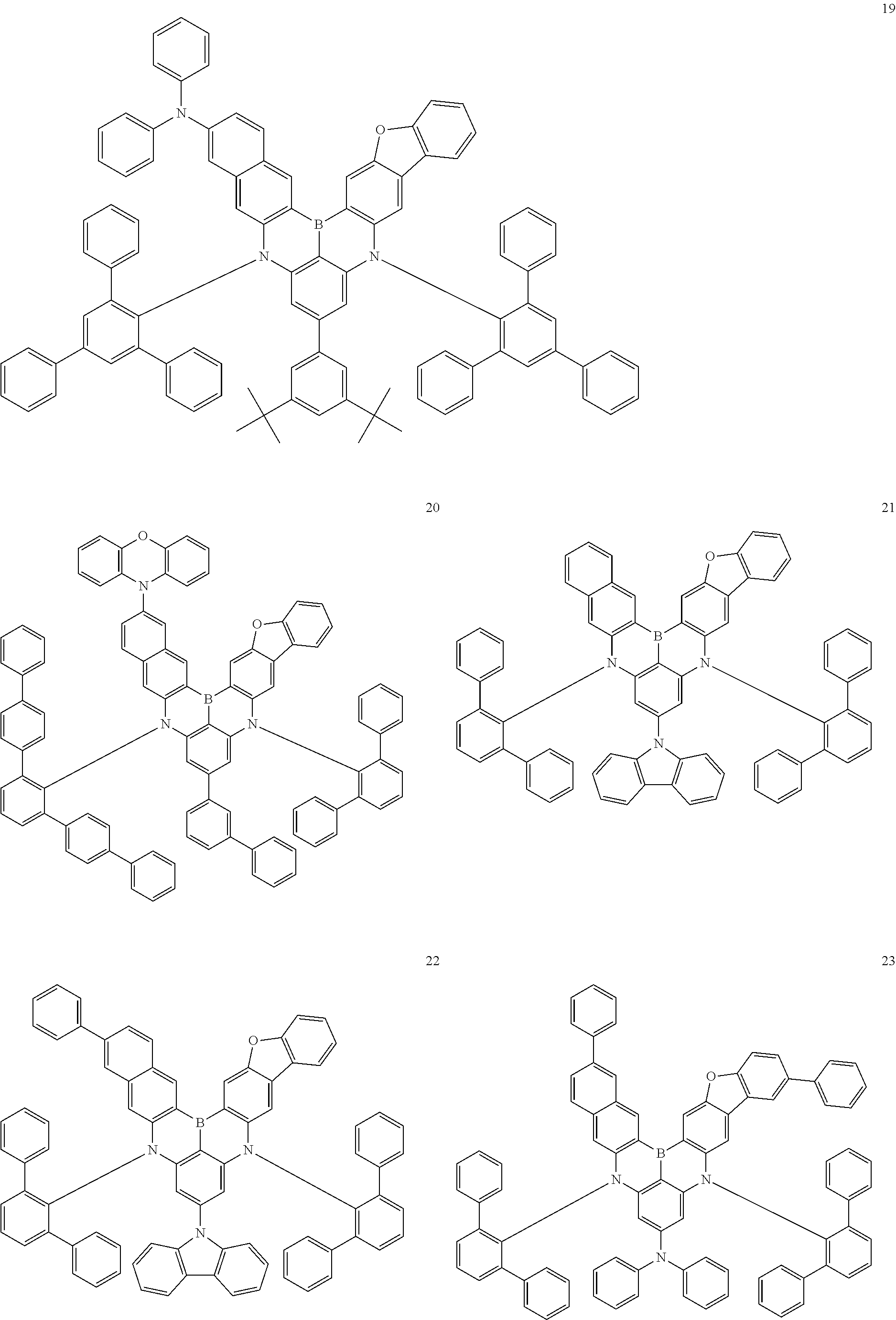

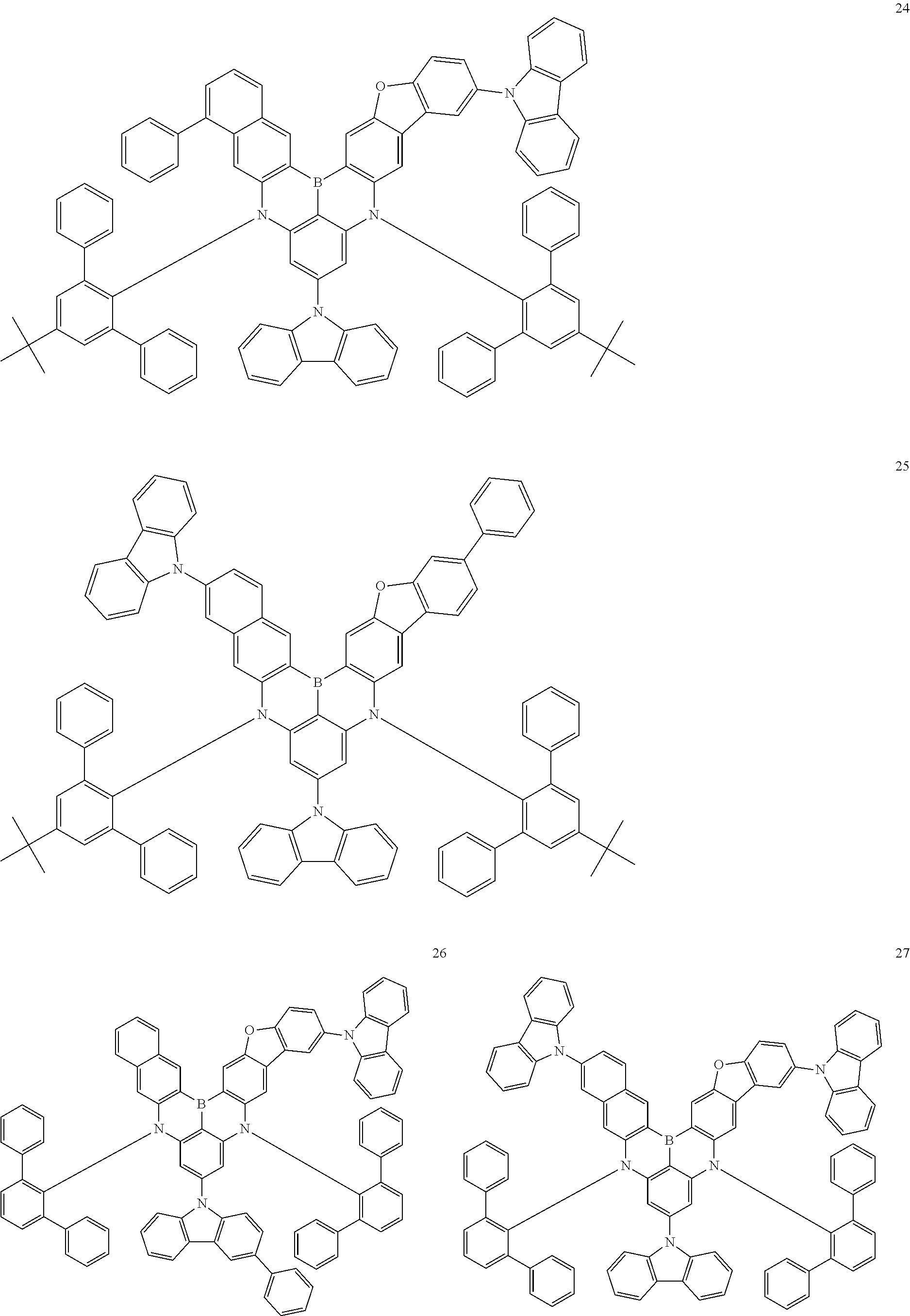

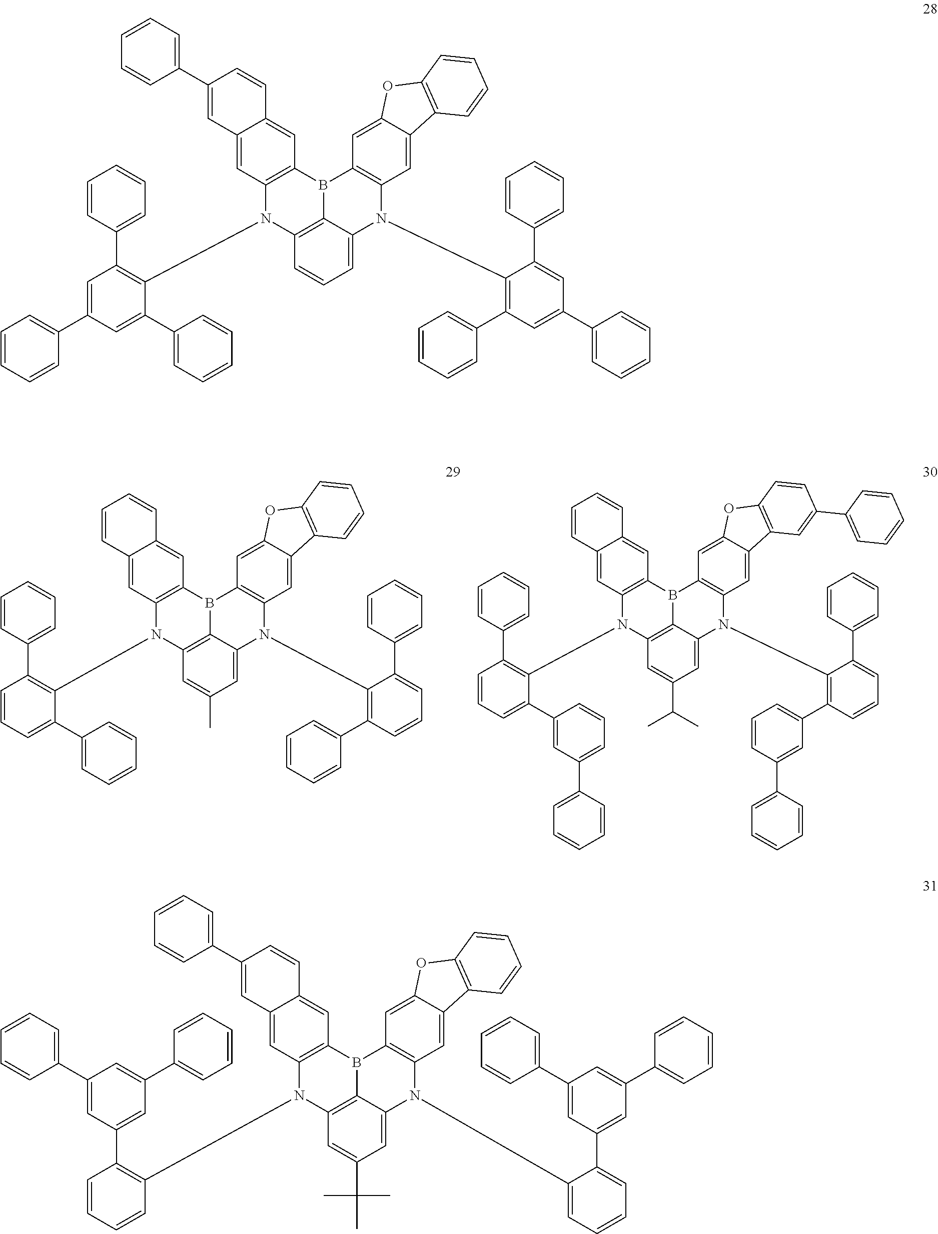

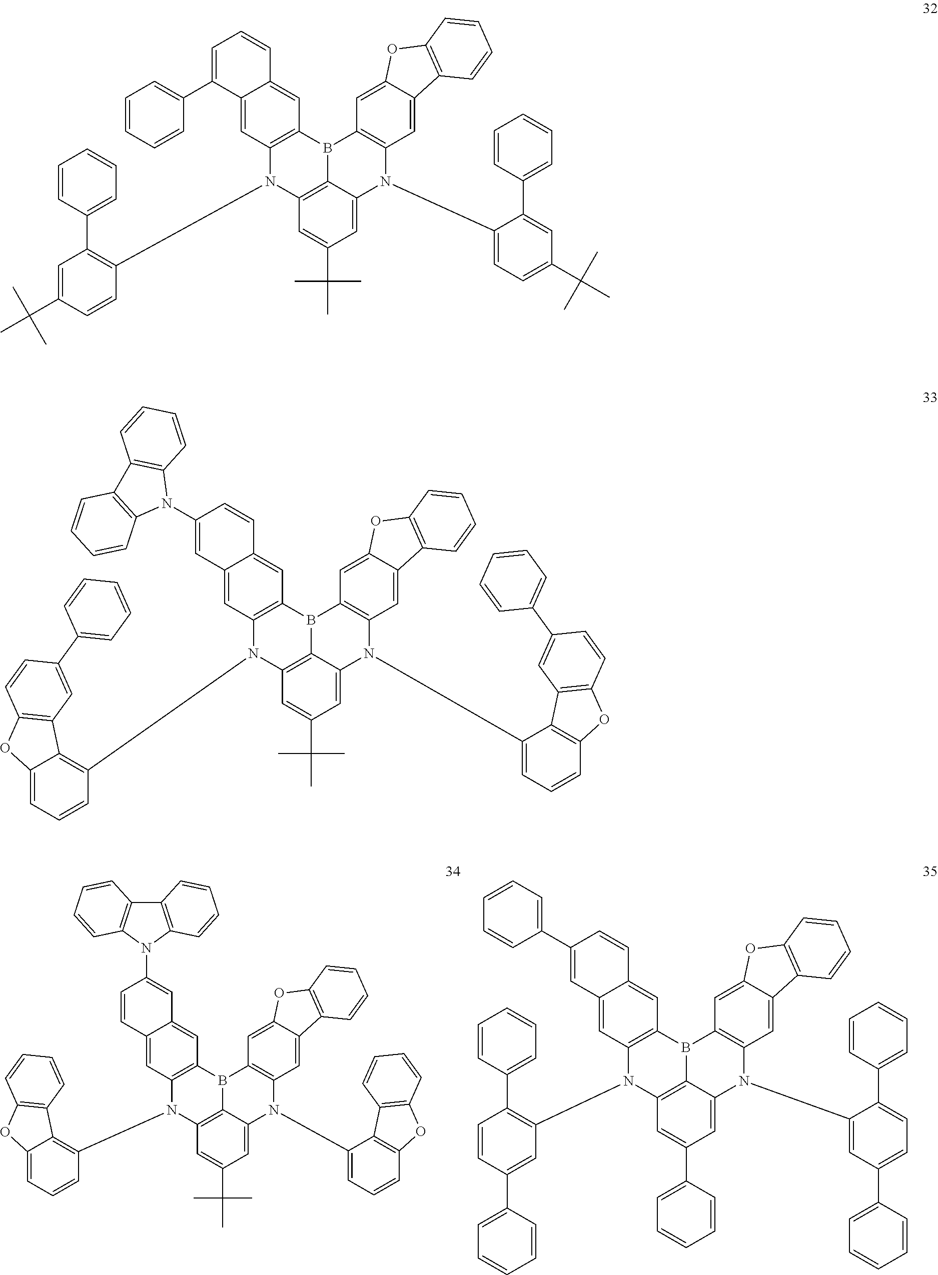

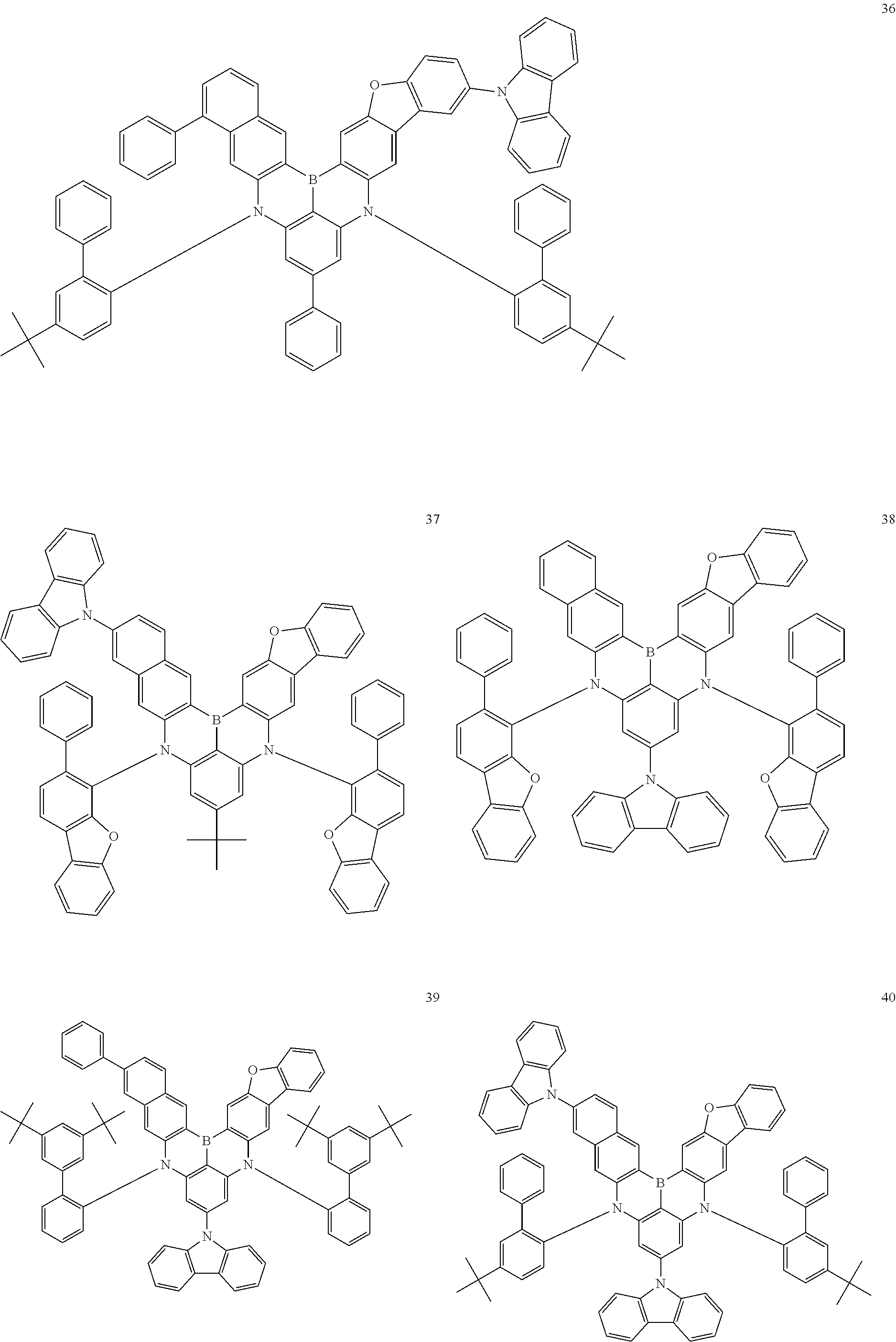

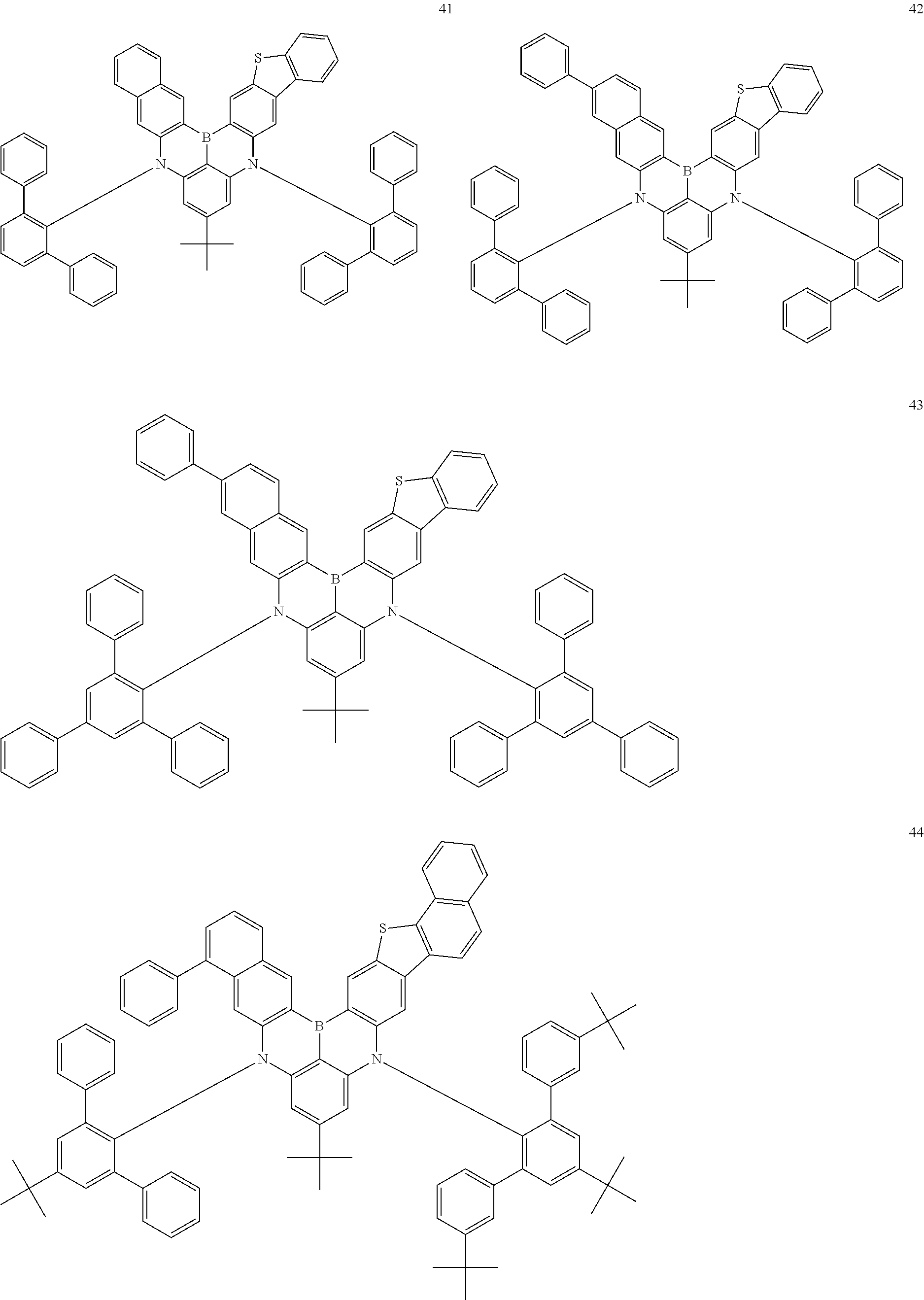

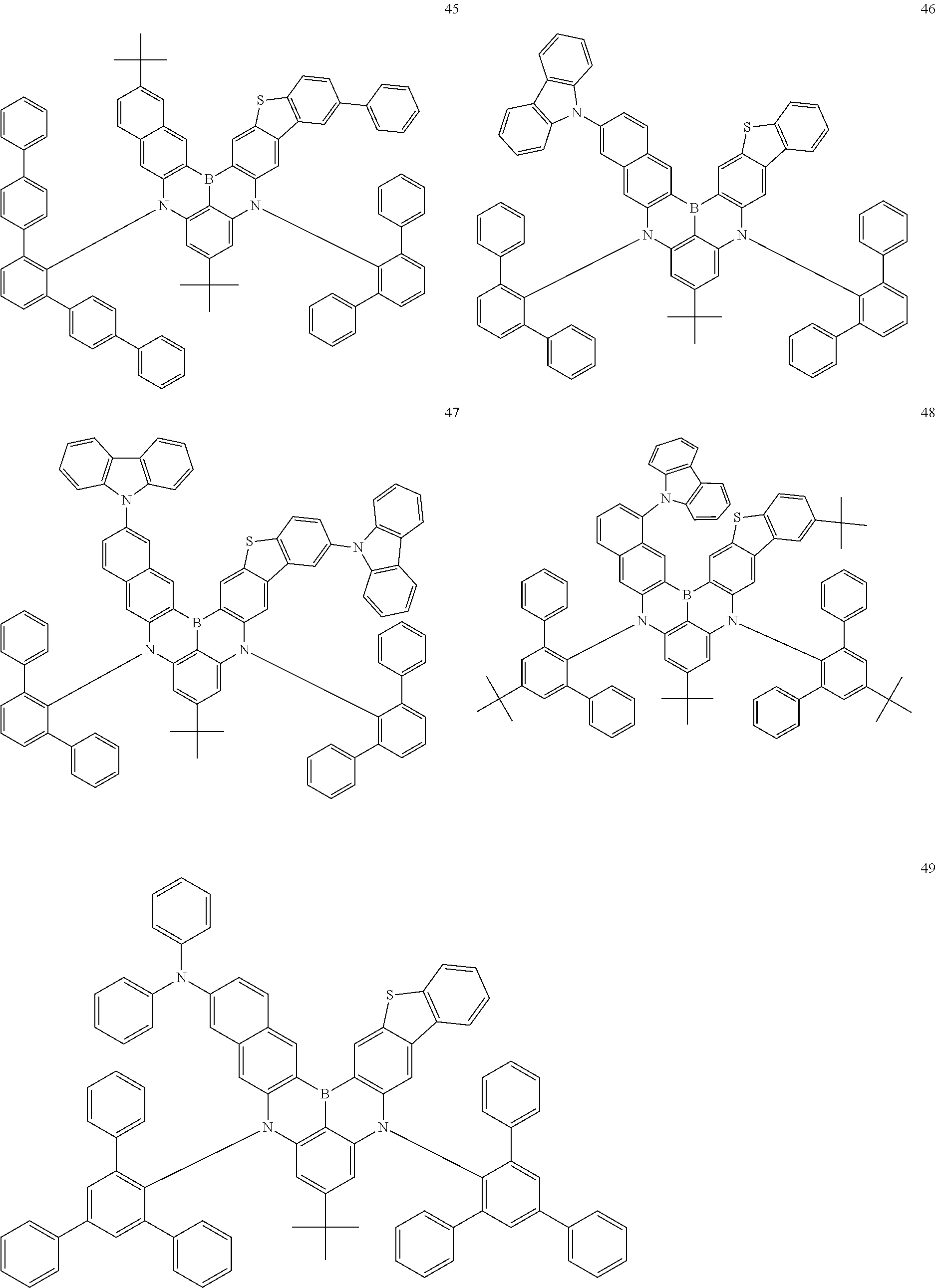

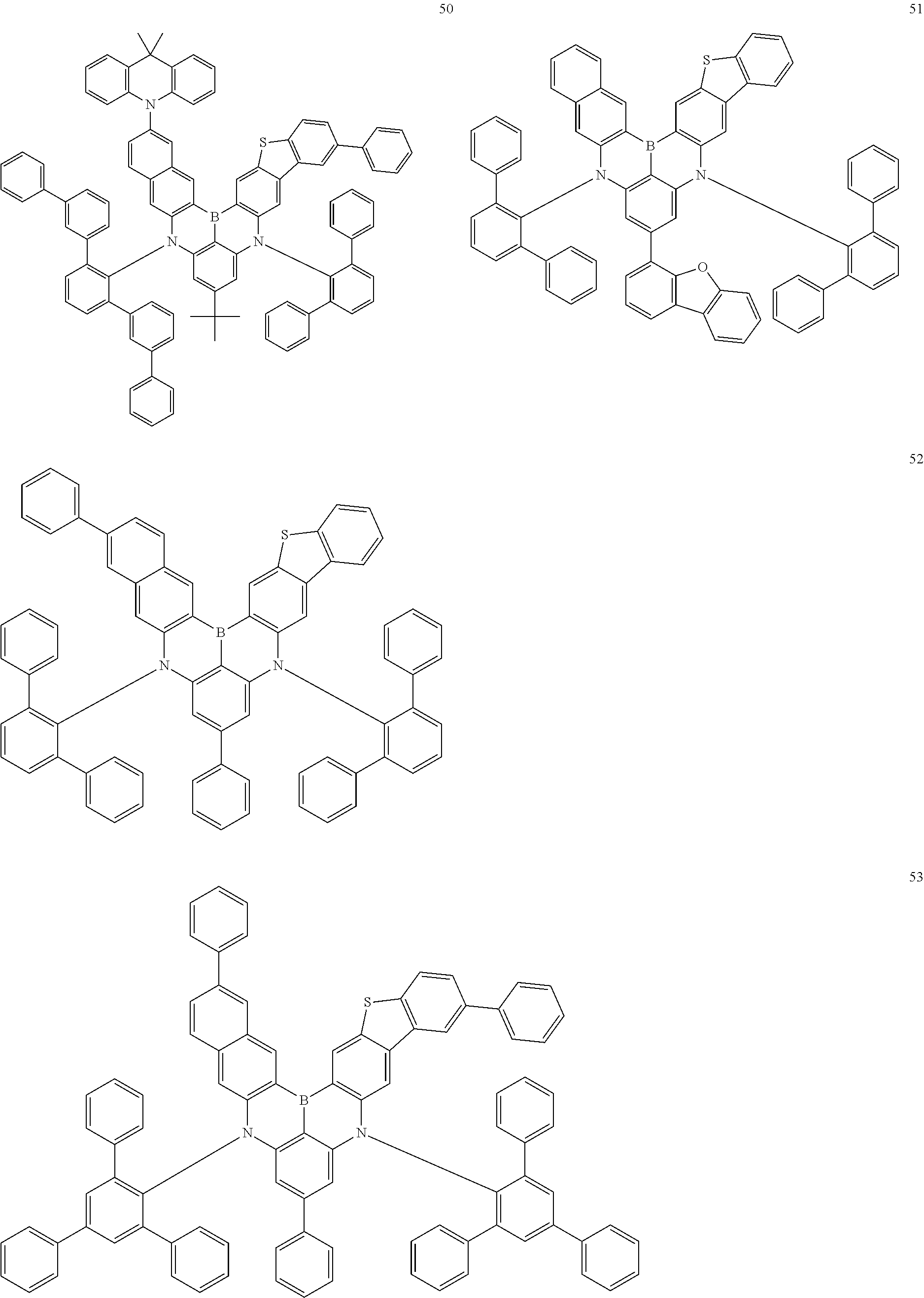

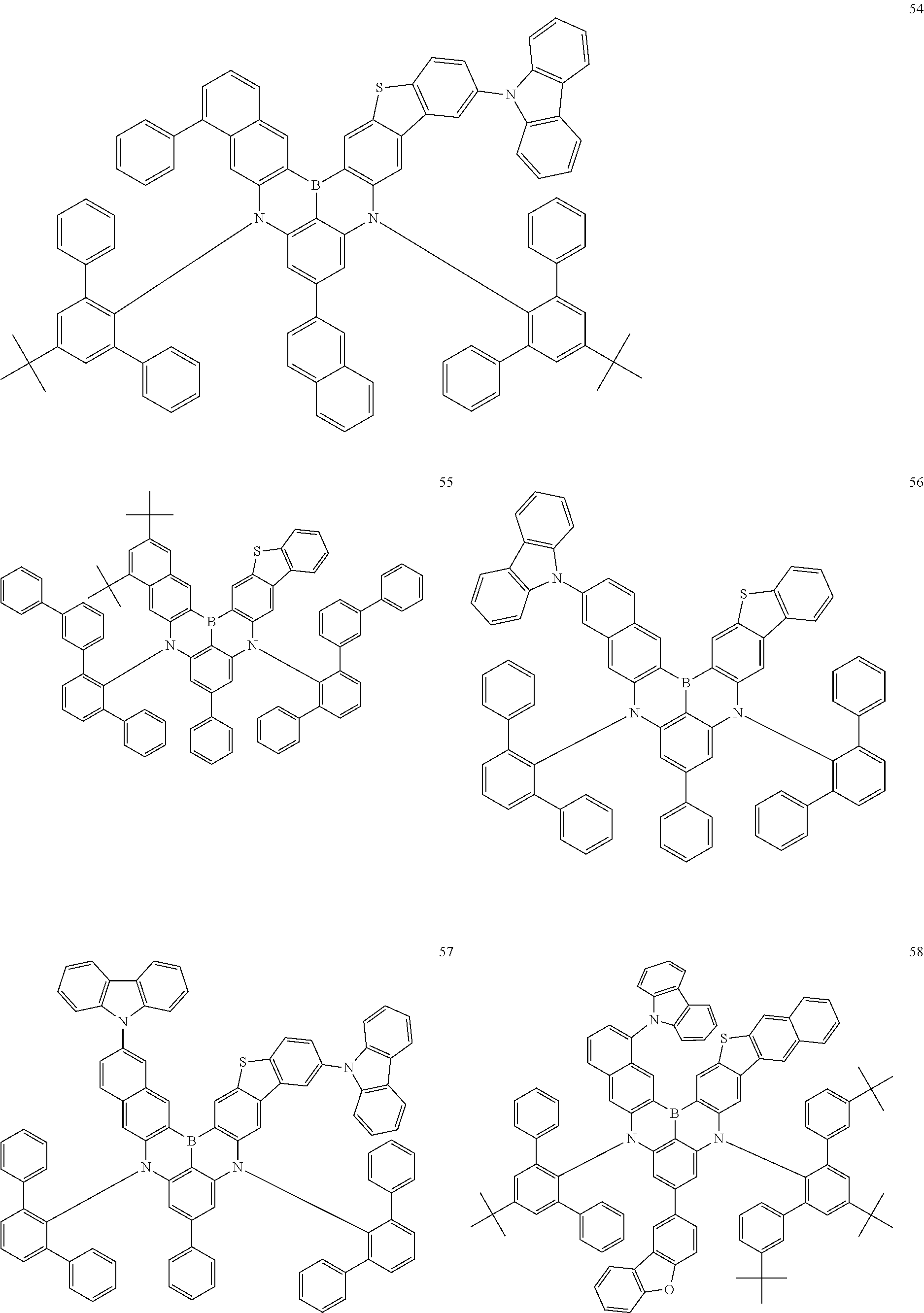

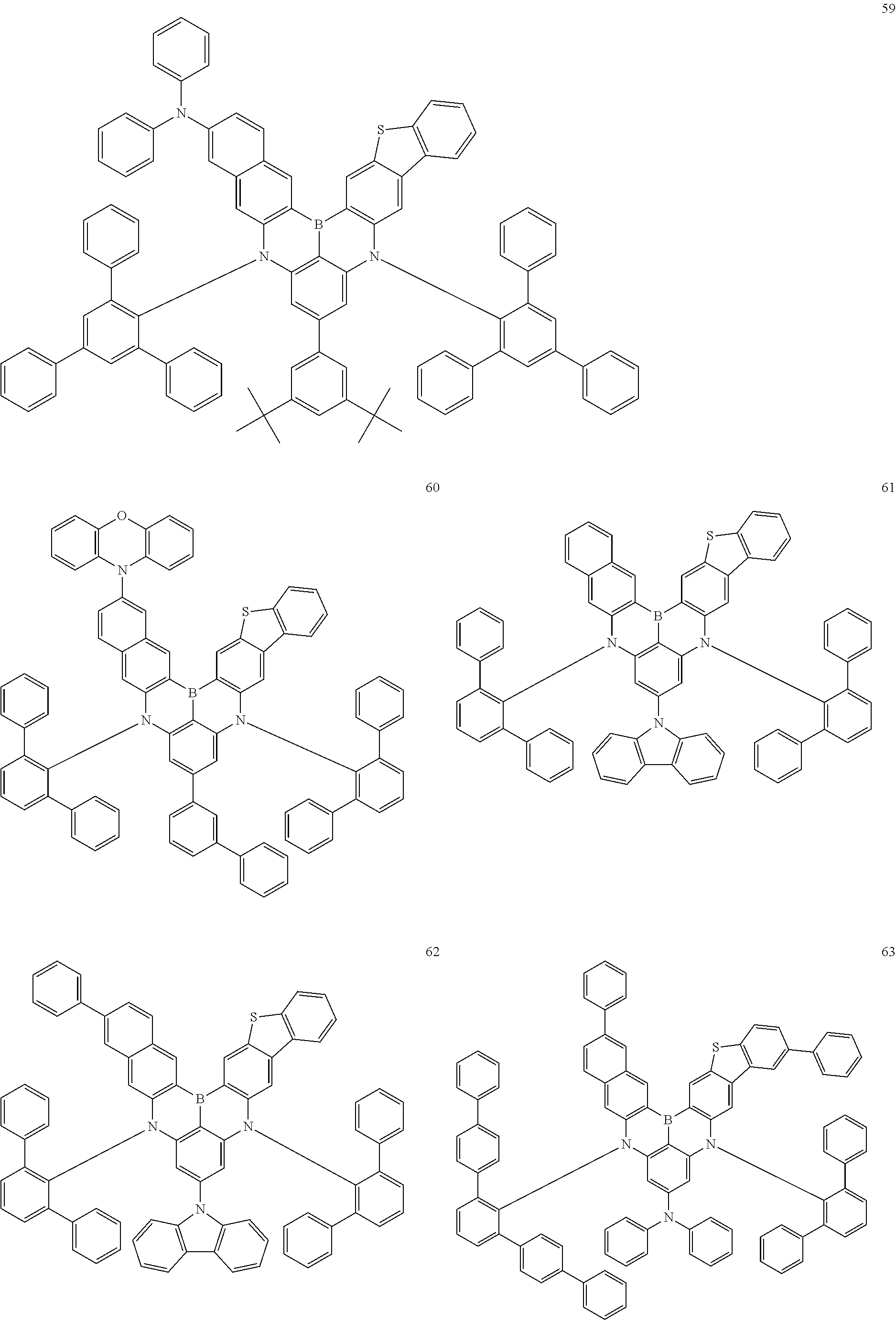

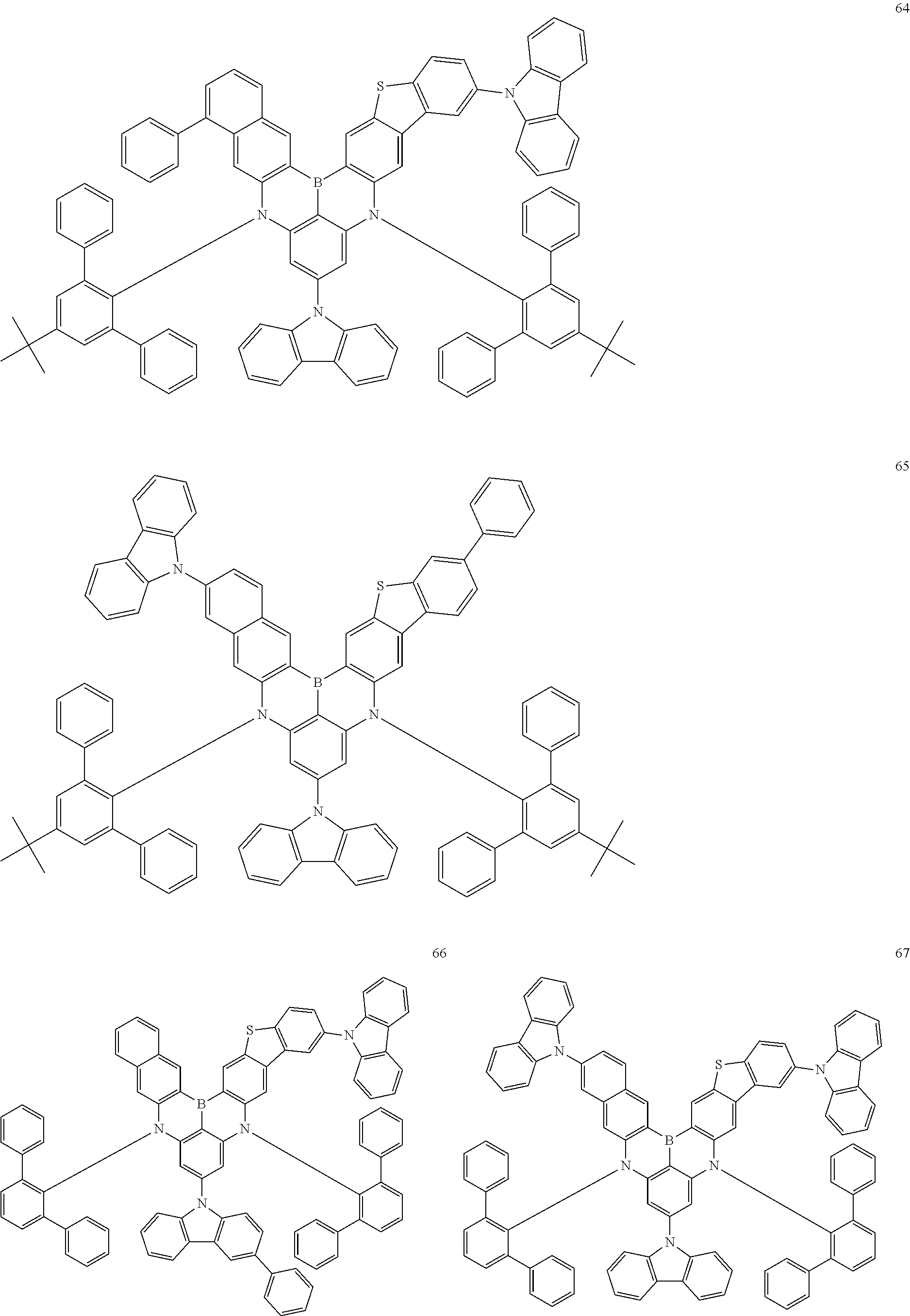

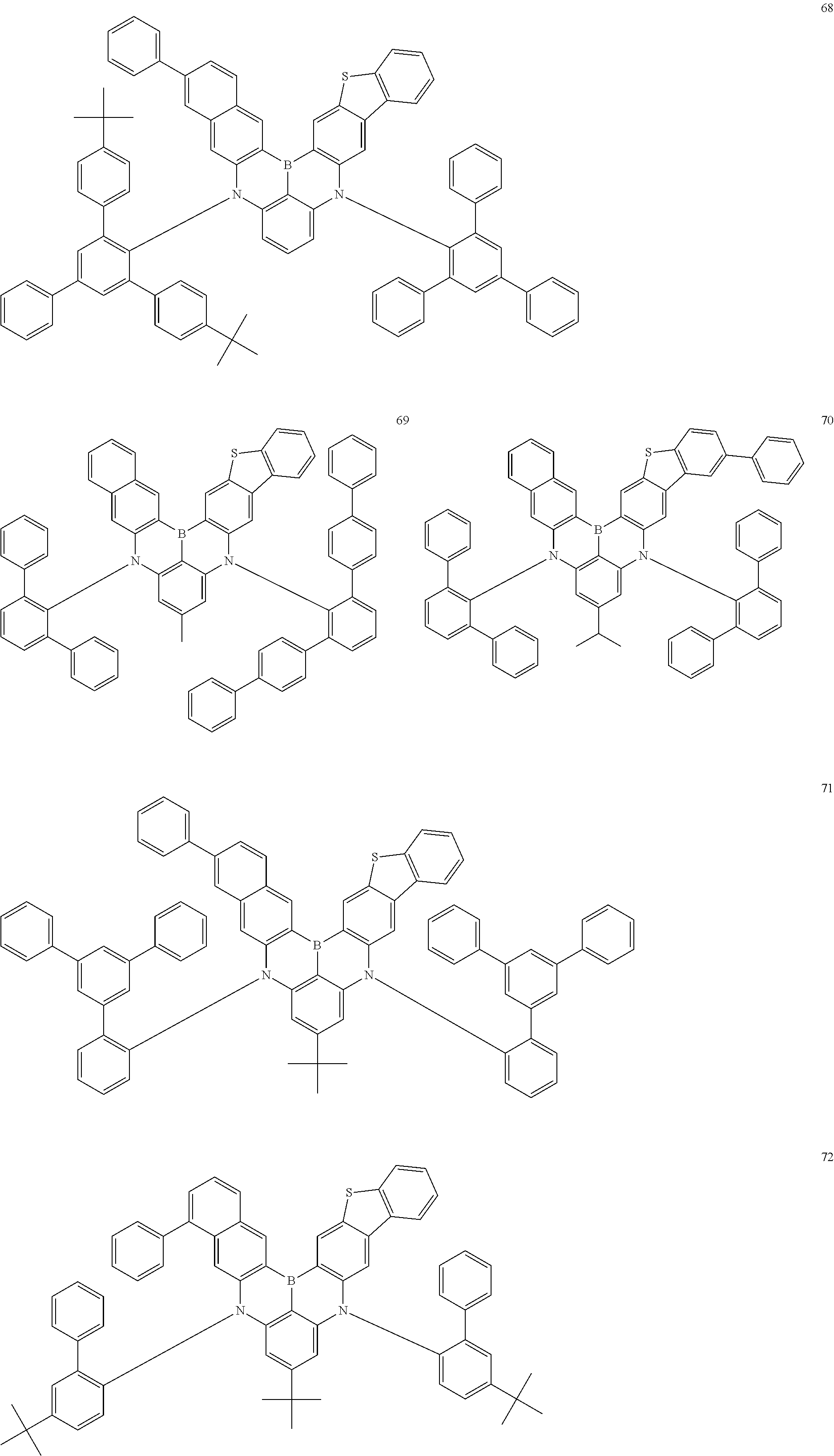

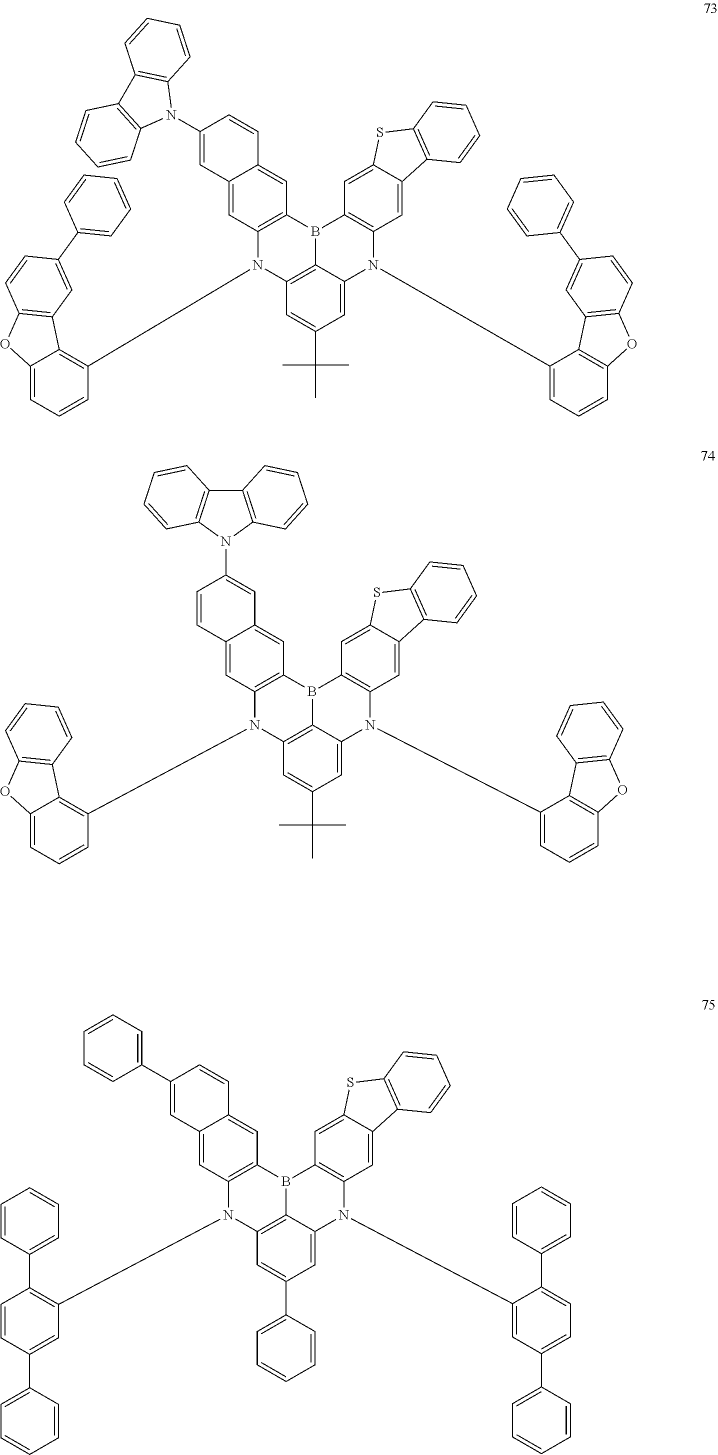 [SMILES: CC(C)(C)c1cc2c3c(c1)N(c1cccc4oc5ccc(-c6ccccc6)cc5c14)c1cc4c(cc1B3c1cc3ccc(-n5c6ccccc6c6ccccc65)cc3cc1N2c1cccc2oc3ccc(-c5ccccc5)cc3c12)sc1ccccc14 ; CC(C)(C)c1cc2c3c(c1)N(c1cccc4oc5ccccc5c14)c1cc4c(cc1B3c1cc3cc(-n5c6ccccc6c6ccccc65)ccc3cc1N2c1cccc2oc3ccccc3c12)sc1ccccc14 ; c1ccc(-c2ccc(-c3ccccc3)c(N3c4cc5cc(-c6ccccc6)ccc5cc4B4c5cc6sc7ccccc7c6cc5N(c5cc(-c6ccccc6)ccc5-c5ccccc5)c5cc(-c6ccccc6)cc3c54)c2)cc1]

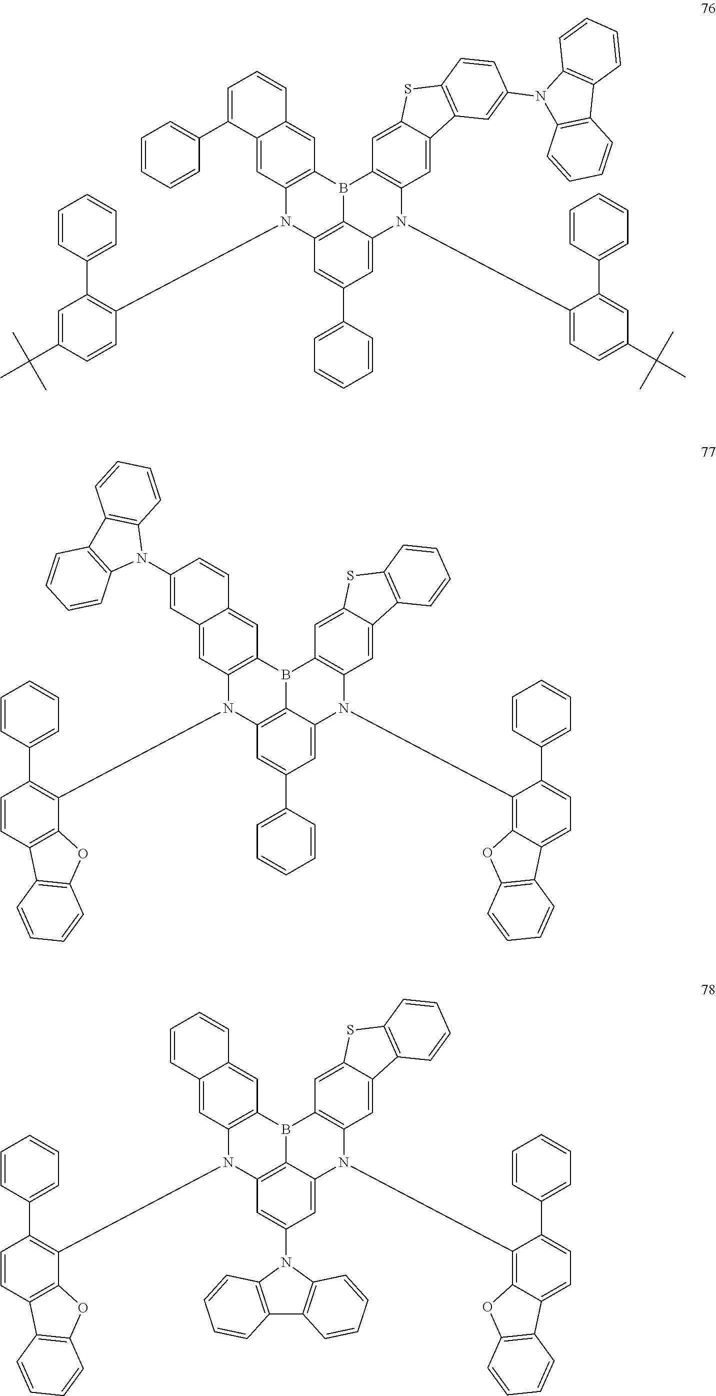 [SMILES: CC(C)(C)c1ccc(N2c3cc4c(-c5ccccc5)cccc4cc3B3c4cc5sc6ccc(-n7c8ccccc8c8ccccc87)cc6c5cc4N(c4ccc(C(C)(C)C)cc4-c4ccccc4)c4cc(-c5ccccc5)cc2c43)c(-c2ccccc2)c1 ; c1ccc(-c2cc3c4c(c2)N(c2c(-c5ccccc5)ccc5c2oc2ccccc25)c2cc5c(cc2B4c2cc4ccc(-n6c7ccccc7c7ccccc76)cc4cc2N3c2c(-c3ccccc3)ccc3c2oc2ccccc23)sc2ccccc25)cc1 ; c1ccc(-c2ccc3c(oc4ccccc43)c2N2c3cc4ccccc4cc3B3c4cc5sc6ccccc6c5cc4N(c4c(-c5ccccc5)ccc5c4oc4ccccc45)c4cc(-n5c6ccccc6c6ccccc65)cc2c43)cc1]

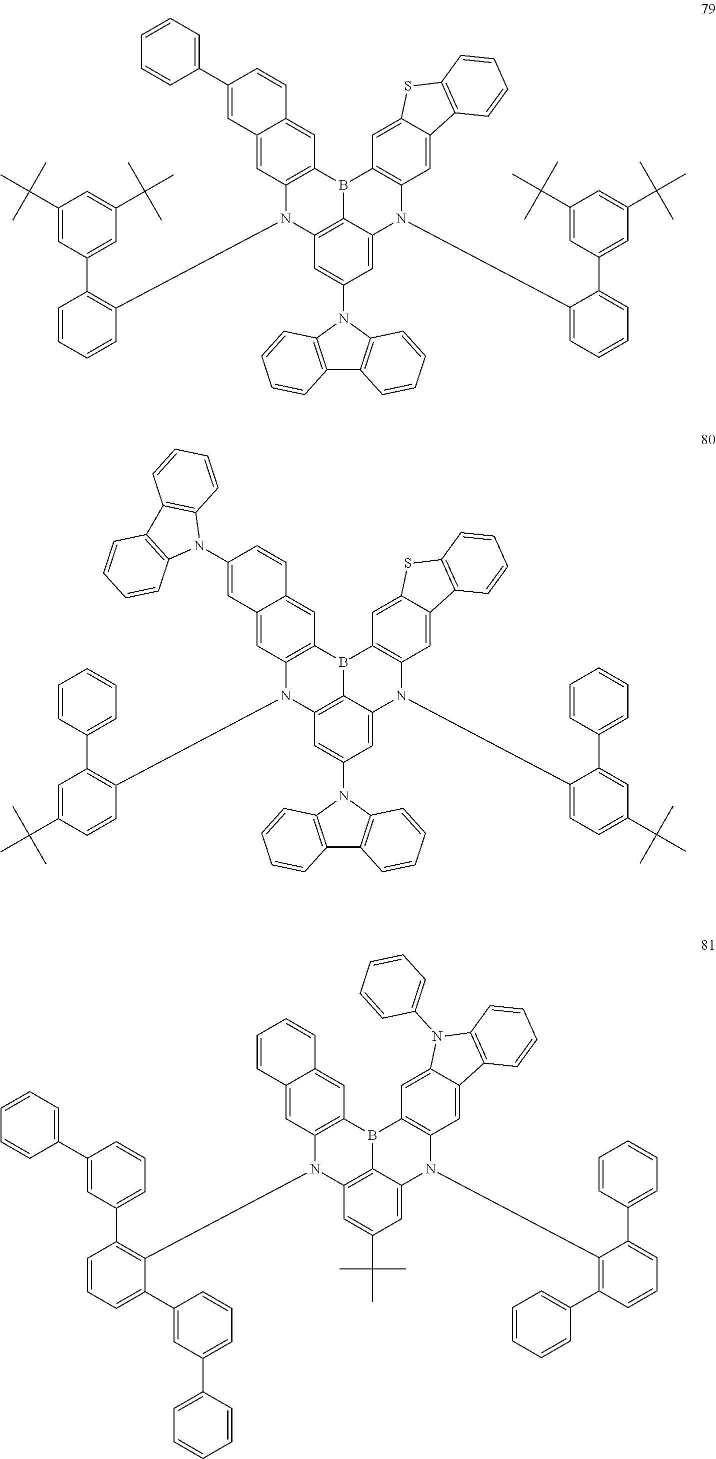

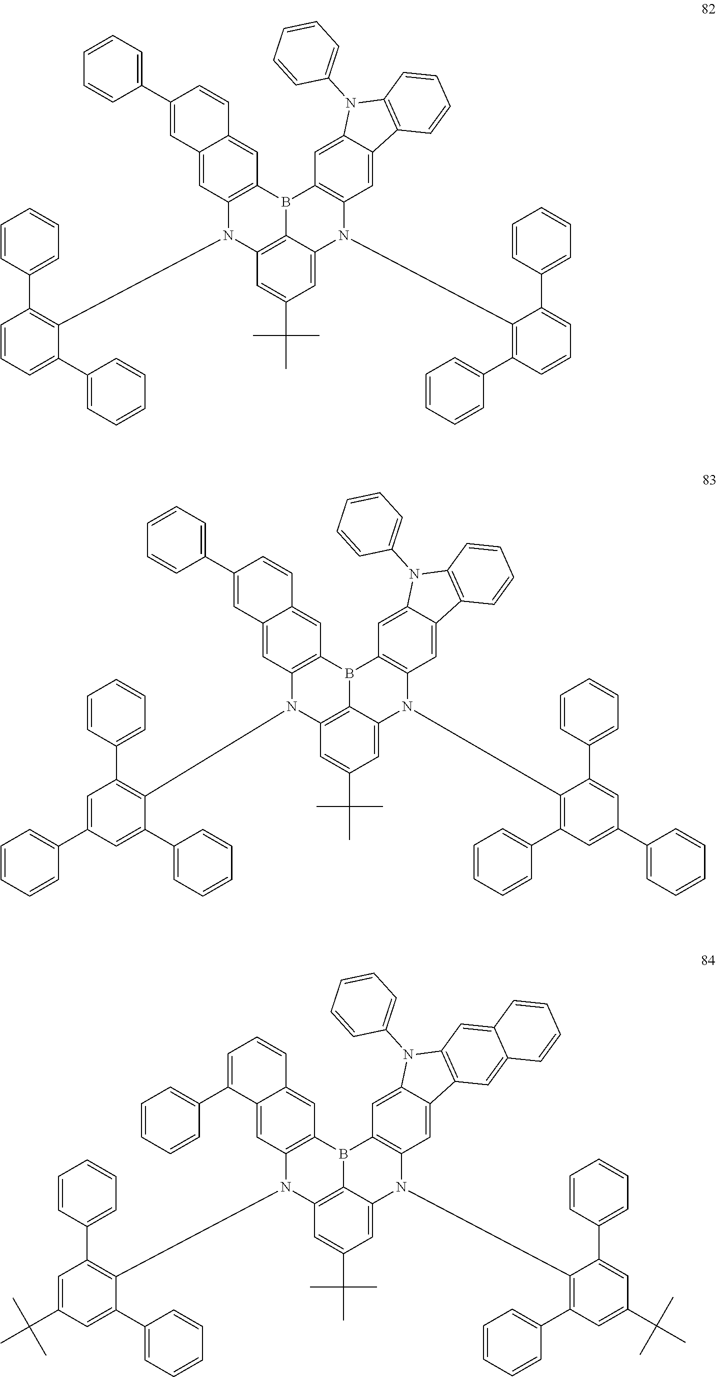 [SMILES: CC(C)(C)c1cc2c3c(c1)N(c1c(-c4ccccc4)cccc1-c1ccccc1)c1cc4c5ccccc5n(-c5ccccc5)c4cc1B3c1cc3ccc(-c4ccccc4)cc3cc1N2c1c(-c2ccccc2)cccc1-c1ccccc1 ; CC(C)(C)c1cc2c3c(c1)N(c1c(-c4ccccc4)cc(-c4ccccc4)cc1-c1ccccc1)c1cc4c5ccccc5n(-c5ccccc5)c4cc1B3c1cc3ccc(-c4ccccc4)cc3cc1N2c1c(-c2ccccc2)cc(-c2ccccc2)cc1-c1ccccc1 ; CC(C)(C)c1cc(-c2ccccc2)c(N2c3cc4c(-c5ccccc5)cccc4cc3B3c4cc5c(cc4N(c4c(-c6ccccc6)cc(C(C)(C)C)cc4-c4ccccc4)c4cc(C(C)(C)C)cc2c43)c2cc3ccccc3cc2n5-c2ccccc2)c(-c2ccccc2)c1]

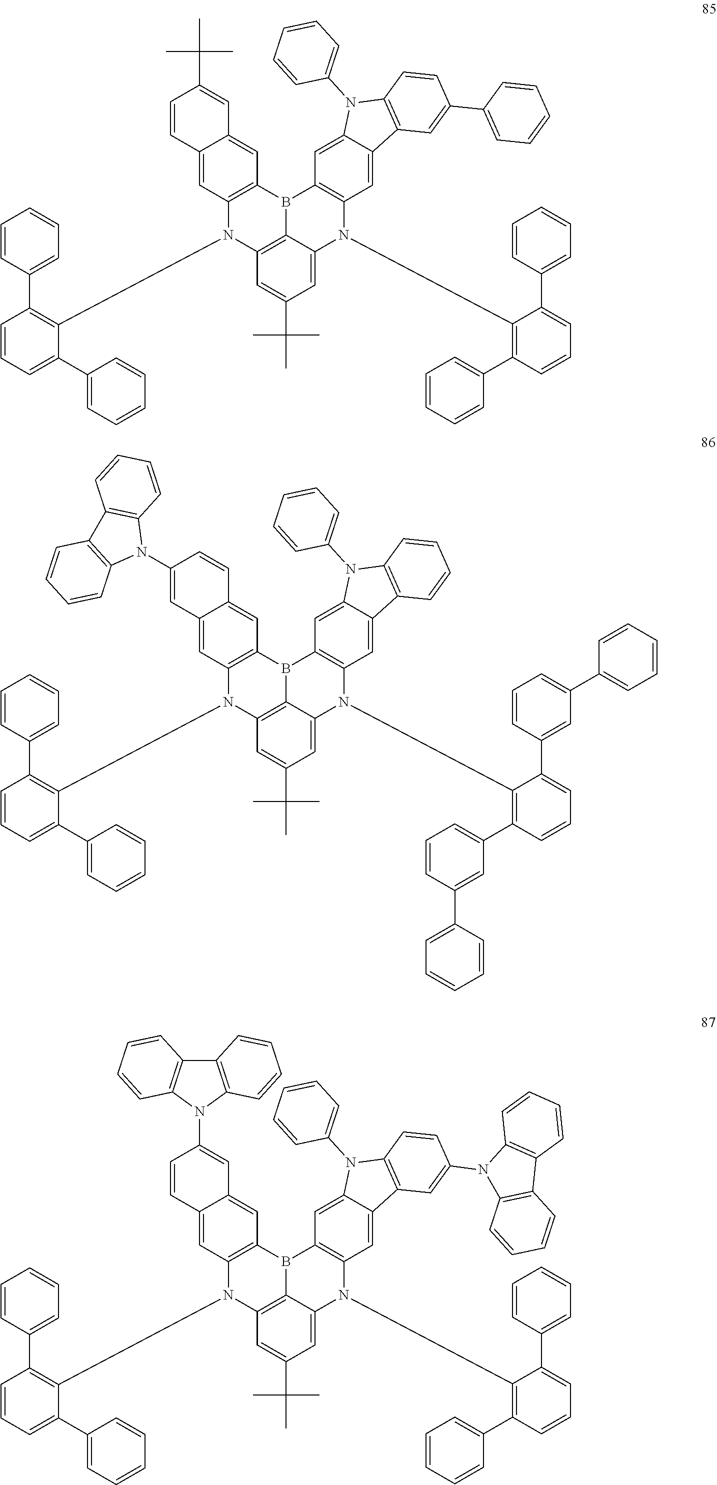

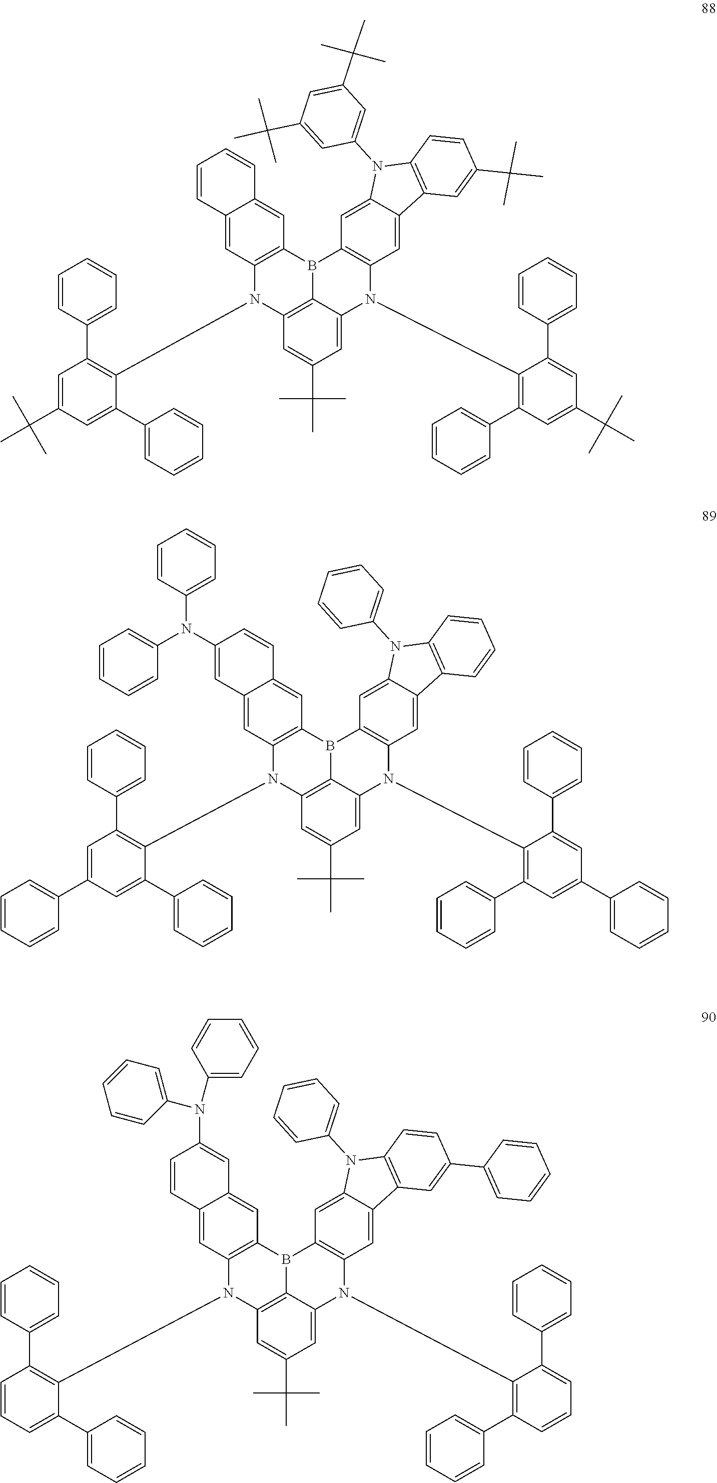

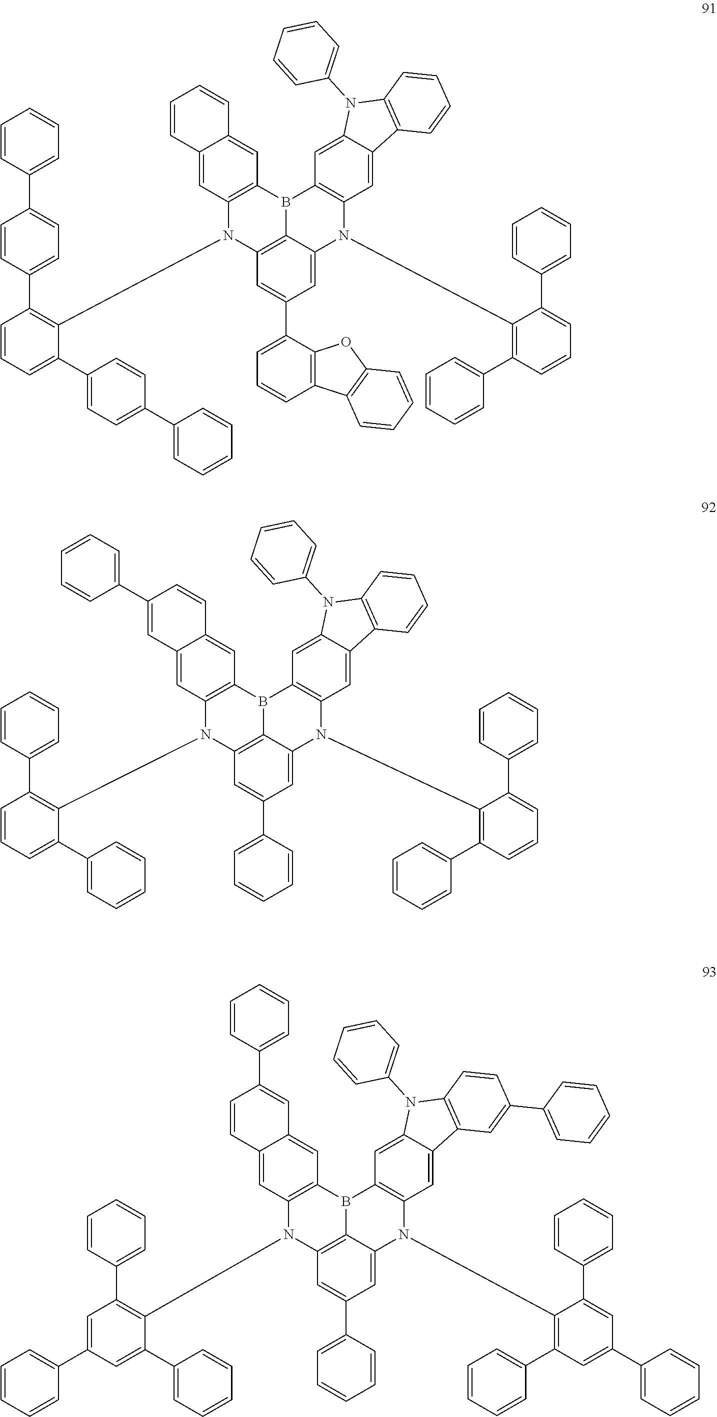 [SMILES: c1ccc(-c2ccc(-c3cccc(-c4ccc(-c5ccccc5)cc4)c3N3c4cc5ccccc5cc4B4c5cc6c(cc5N(c5c(-c7ccccc7)cccc5-c5ccccc5)c5cc(-c7cccc8c7oc7ccccc78)cc3c54)c3ccccc3n6-c3ccccc3)cc2)cc1 ; c1ccc(-c2cc3c4c(c2)N(c2c(-c5ccccc5)cccc2-c2ccccc2)c2cc5c6ccccc6n(-c6ccccc6)c5cc2B4c2cc4ccc(-c5ccccc5)cc4cc2N3c2c(-c3ccccc3)cccc2-c2ccccc2)cc1 ; c1ccc(-c2cc(-c3ccccc3)c(N3c4cc5ccc(-c6ccccc6)cc5cc4B4c5cc6c(cc5N(c5c(-c7ccccc7)cc(-c7ccccc7)cc5-c5ccccc5)c5cc(-c7ccccc7)cc3c54)c3cc(-c4ccccc4)ccc3n6-c3ccccc3)c(-c3ccccc3)c2)cc1]

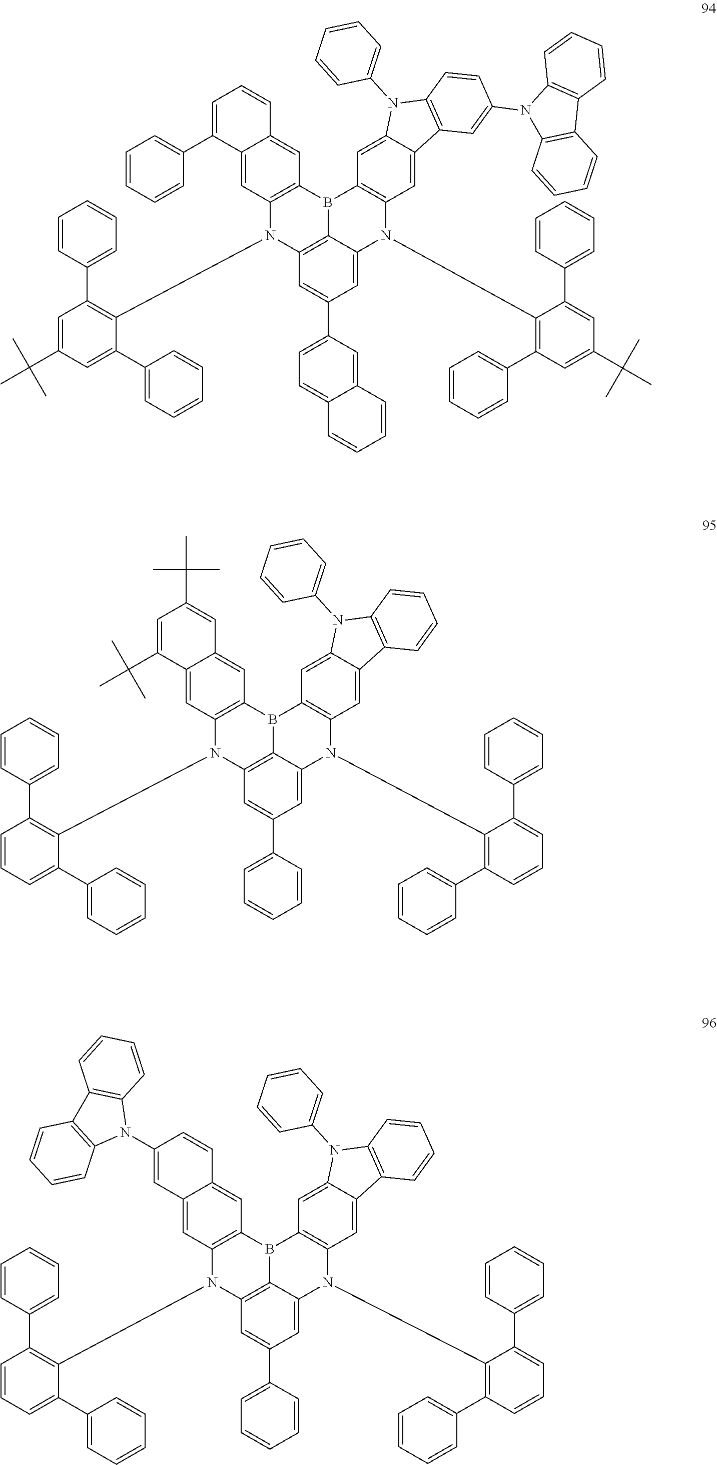 [SMILES: CC(C)(C)c1cc(-c2ccccc2)c(N2c3cc4c(-c5ccccc5)cccc4cc3B3c4cc5c(cc4N(c4c(-c6ccccc6)cc(C(C)(C)C)cc4-c4ccccc4)c4cc(-c6ccc7ccccc7c6)cc2c43)c2cc(-n3c4ccccc4c4ccccc43)ccc2n5-c2ccccc2)c(-c2ccccc2)c1 ; CC(C)(C)c1cc(C(C)(C)C)c2cc3c(cc2c1)B1c2cc4c(cc2N(c2c(-c5ccccc5)cccc2-c2ccccc2)c2cc(-c5ccccc5)cc(c21)N3c1c(-c2ccccc2)cccc1-c1ccccc1)c1ccccc1n4-c1ccccc1 ; c1ccc(-c2cc3c4c(c2)N(c2c(-c5ccccc5)cccc2-c2ccccc2)c2cc5c6ccccc6n(-c6ccccc6)c5cc2B4c2cc4ccc(-n5c6ccccc6c6ccccc65)cc4cc2N3c2c(-c3ccccc3)cccc2-c2ccccc2)cc1]

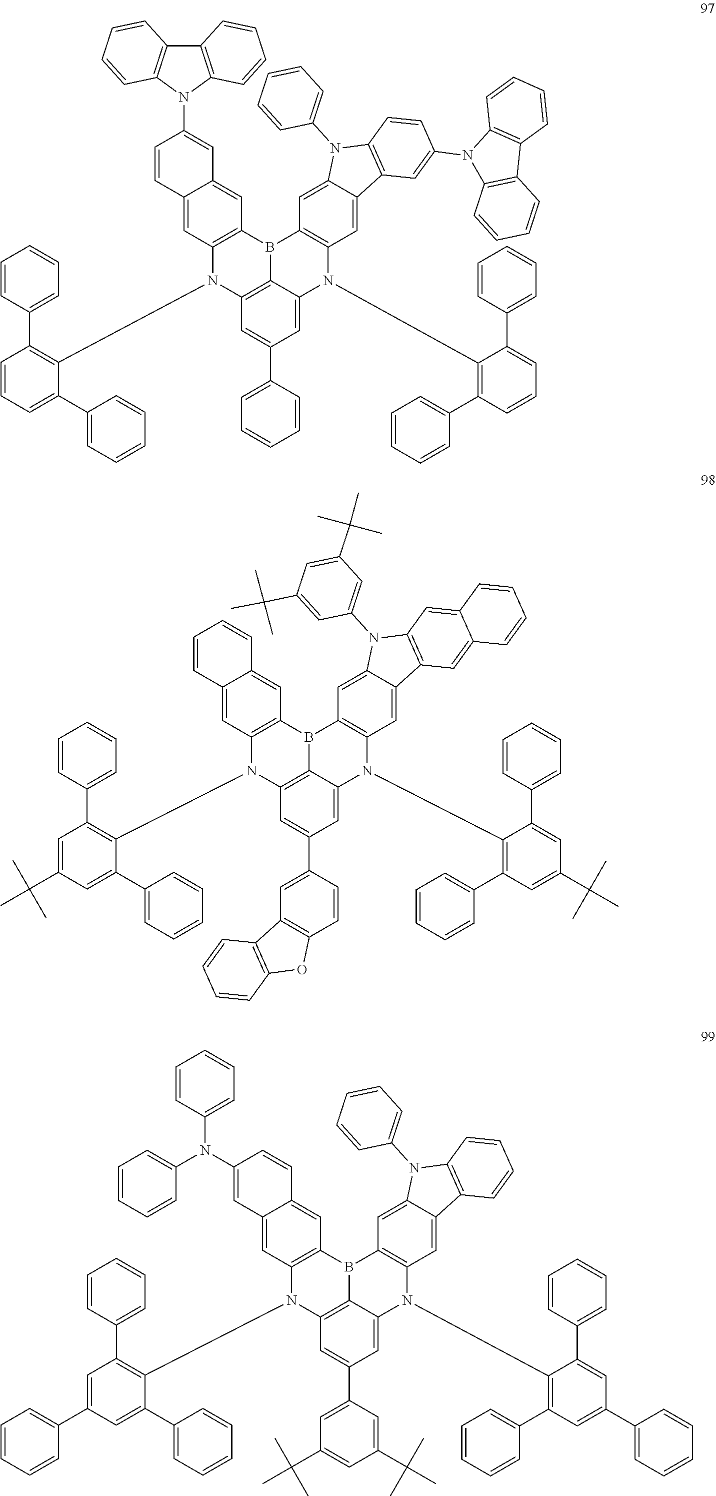

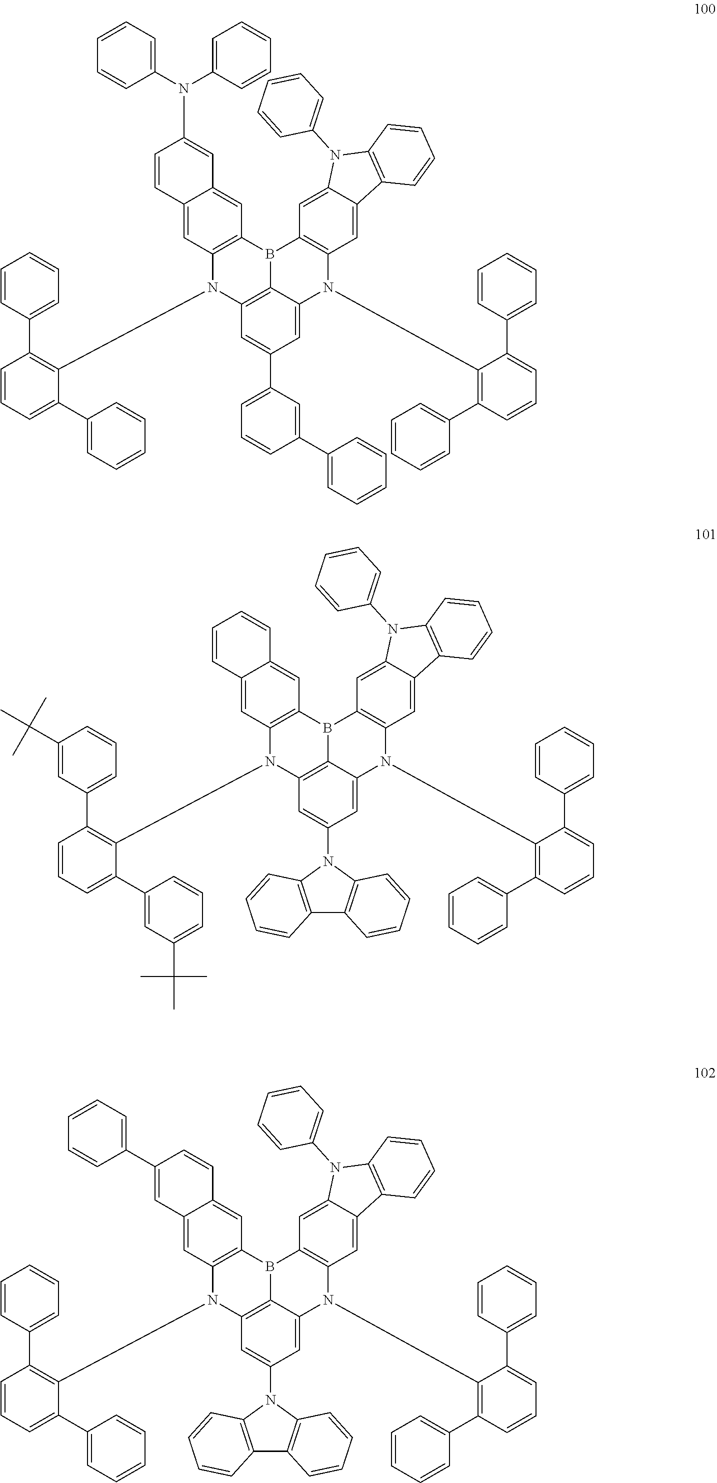

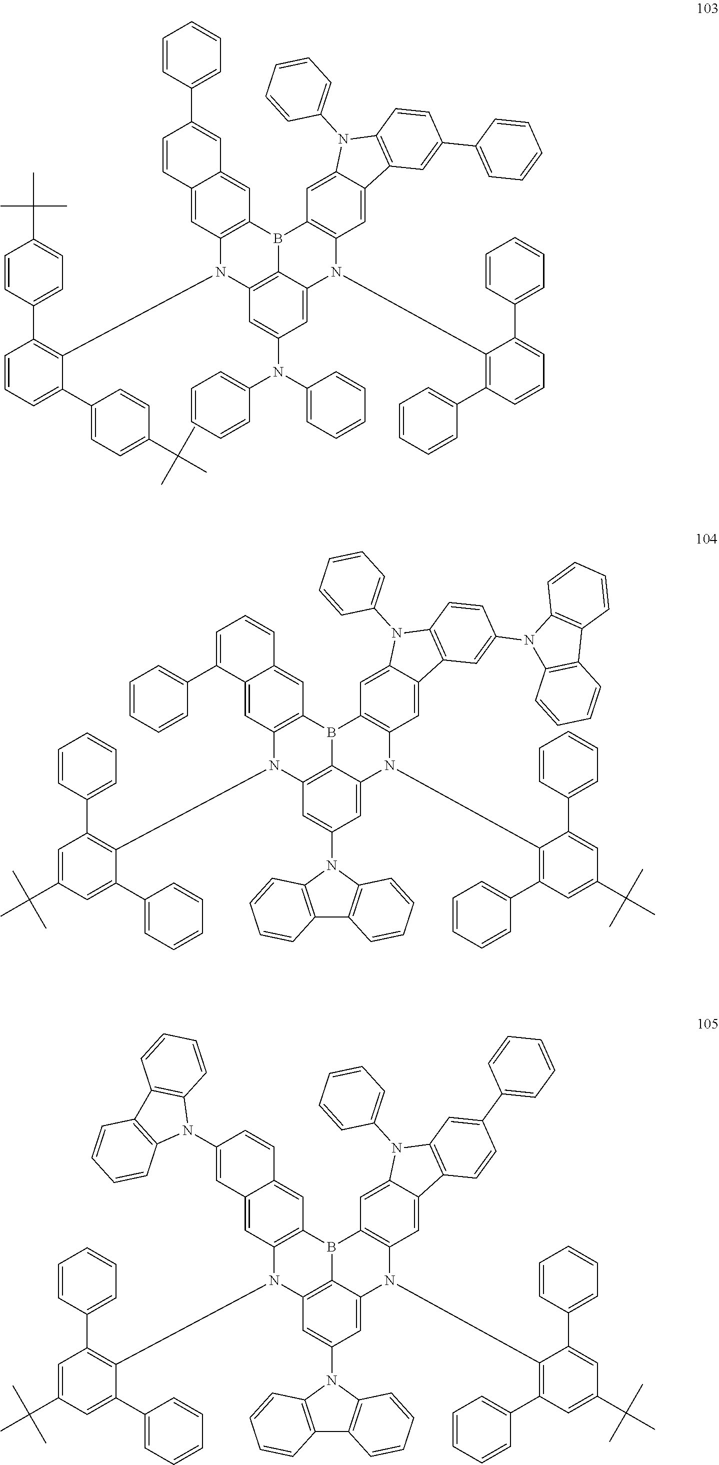

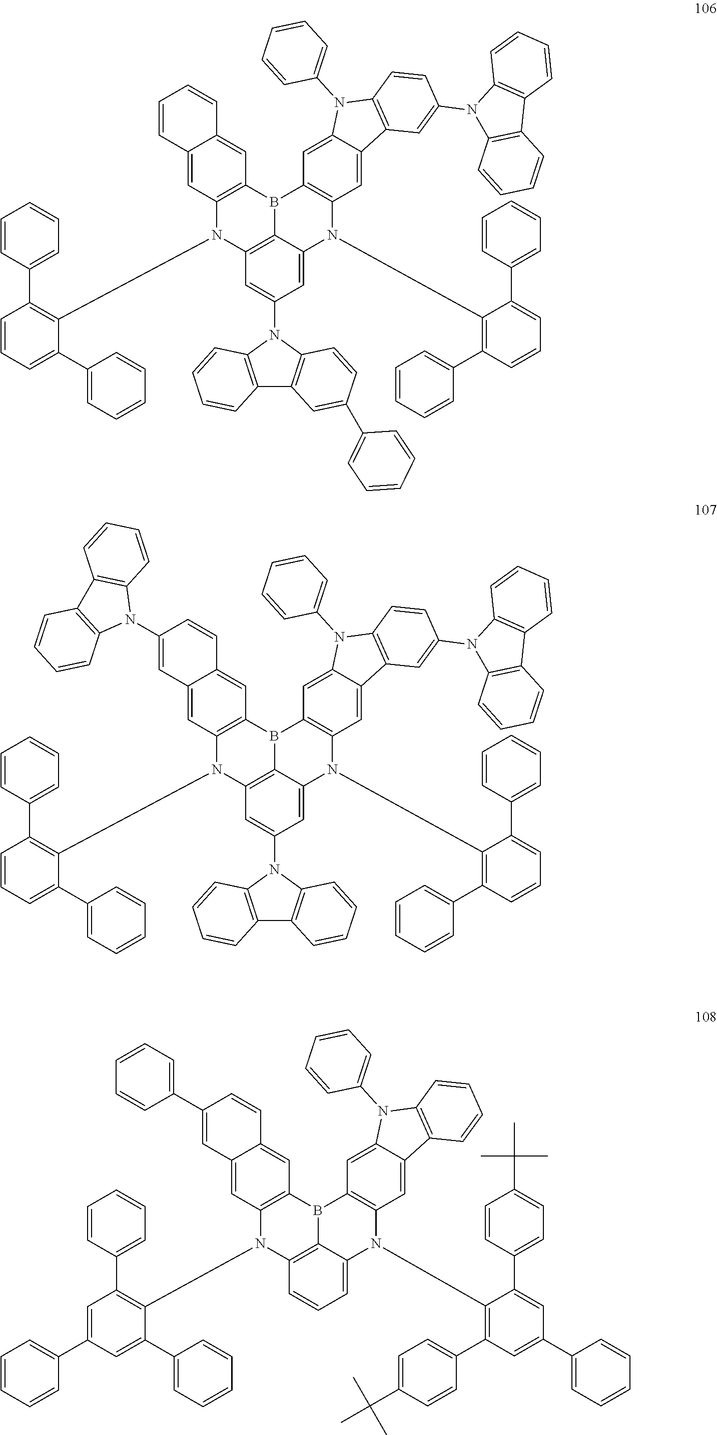

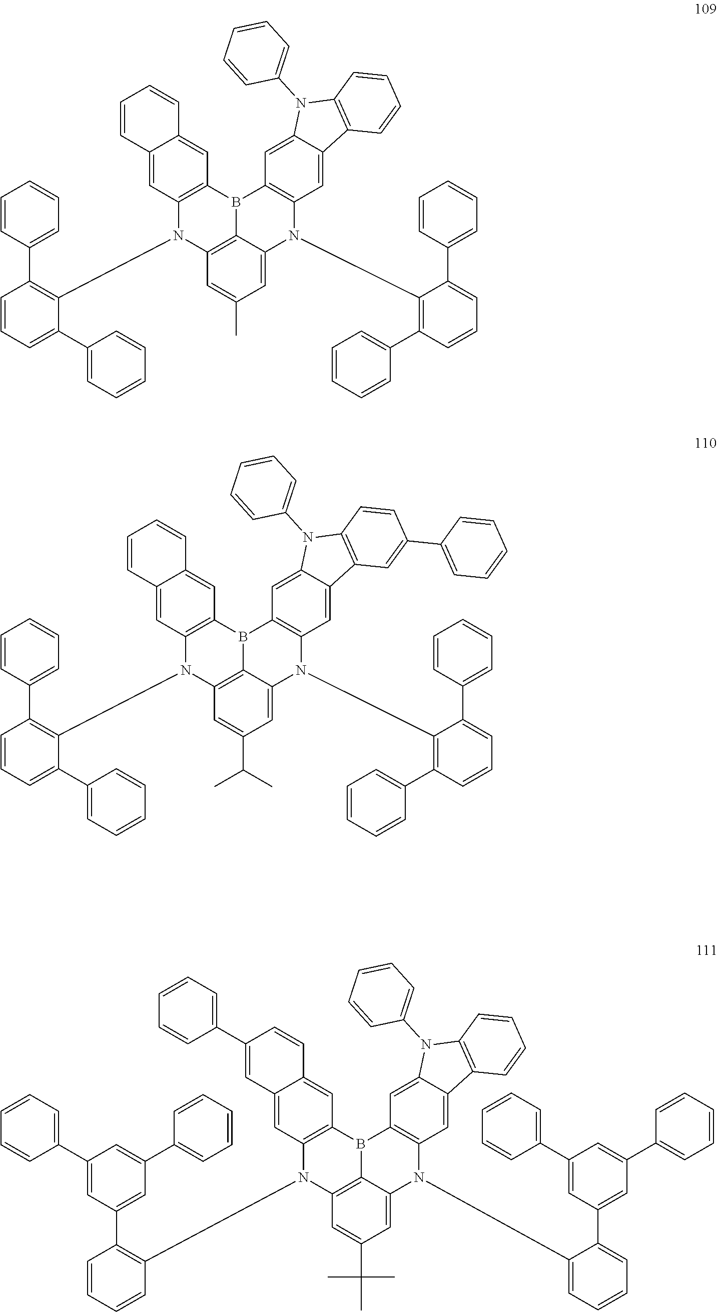 [SMILES: Cc1cc2c3c(c1)N(c1c(-c4ccccc4)cccc1-c1ccccc1)c1cc4c5ccccc5n(-c5ccccc5)c4cc1B3c1cc3ccccc3cc1N2c1c(-c2ccccc2)cccc1-c1ccccc1 ; CC(C)c1cc2c3c(c1)N(c1c(-c4ccccc4)cccc1-c1ccccc1)c1cc4c5cc(-c6ccccc6)ccc5n(-c5ccccc5)c4cc1B3c1cc3ccccc3cc1N2c1c(-c2ccccc2)cccc1-c1ccccc1 ; CC(C)(C)c1cc2c3c(c1)N(c1ccccc1-c1cc(-c4ccccc4)cc(-c4ccccc4)c1)c1cc4c5ccccc5n(-c5ccccc5)c4cc1B3c1cc3ccc(-c4ccccc4)cc3cc1N2c1ccccc1-c1cc(-c2ccccc2)cc(-c2ccccc2)c1]

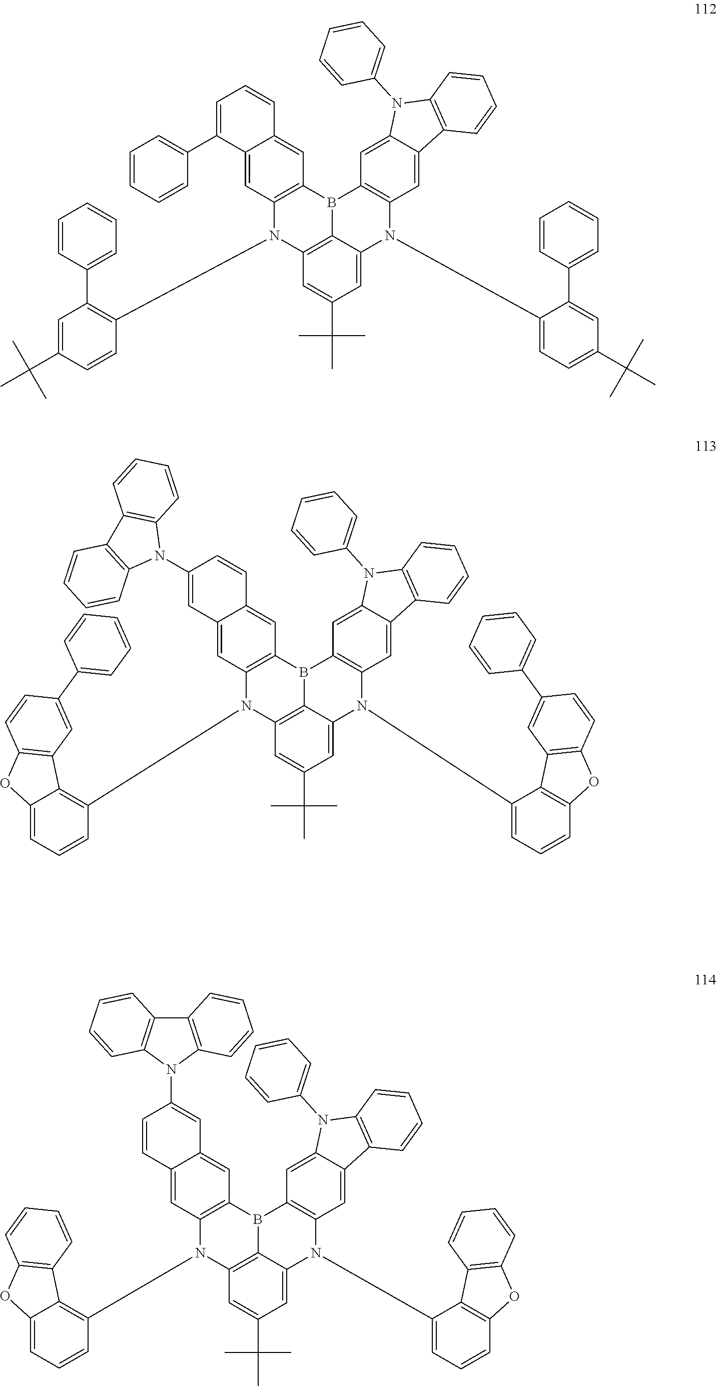 [SMILES: CC(C)(C)c1ccc(N2c3cc4c(-c5ccccc5)cccc4cc3B3c4cc5c(cc4N(c4ccc(C(C)(C)C)cc4-c4ccccc4)c4cc(C(C)(C)C)cc2c43)c2ccccc2n5-c2ccccc2)c(-c2ccccc2)c1 ; CC(C)(C)c1cc2c3c(c1)N(c1cccc4oc5ccc(-c6ccccc6)cc5c14)c1cc4c5ccccc5n(-c5ccccc5)c4cc1B3c1cc3ccc(-n4c5ccccc5c5ccccc54)cc3cc1N2c1cccc2oc3ccc(-c4ccccc4)cc3c12 ; CC(C)(C)c1cc2c3c(c1)N(c1cccc4oc5ccccc5c14)c1cc4c5ccccc5n(-c5ccccc5)c4cc1B3c1cc3cc(-n4c5ccccc5c5ccccc54)ccc3cc1N2c1cccc2oc3ccccc3c12]

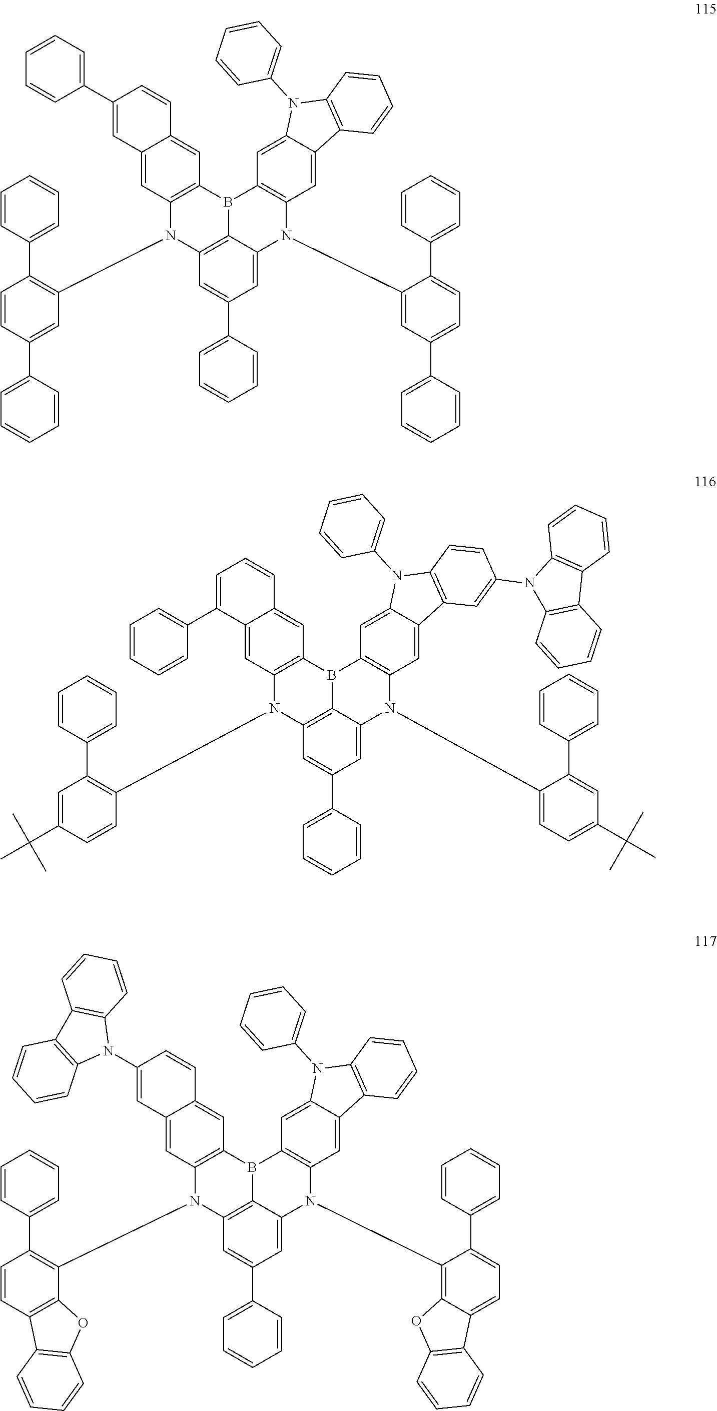 [SMILES: c1ccc(-c2ccc(-c3ccccc3)c(N3c4cc5cc(-c6ccccc6)ccc5cc4B4c5cc6c(cc5N(c5cc(-c7ccccc7)ccc5-c5ccccc5)c5cc(-c7ccccc7)cc3c54)c3ccccc3n6-c3ccccc3)c2)cc1 ; CC(C)(C)c1ccc(N2c3cc4c(-c5ccccc5)cccc4cc3B3c4cc5c(cc4N(c4ccc(C(C)(C)C)cc4-c4ccccc4)c4cc(-c6ccccc6)cc2c43)c2cc(-n3c4ccccc4c4ccccc43)ccc2n5-c2ccccc2)c(-c2ccccc2)c1 ; c1ccc(-c2cc3c4c(c2)N(c2c(-c5ccccc5)ccc5c2oc2ccccc25)c2cc5c6ccccc6n(-c6ccccc6)c5cc2B4c2cc4ccc(-n5c6ccccc6c6ccccc65)cc4cc2N3c2c(-c3ccccc3)ccc3c2oc2ccccc23)cc1]

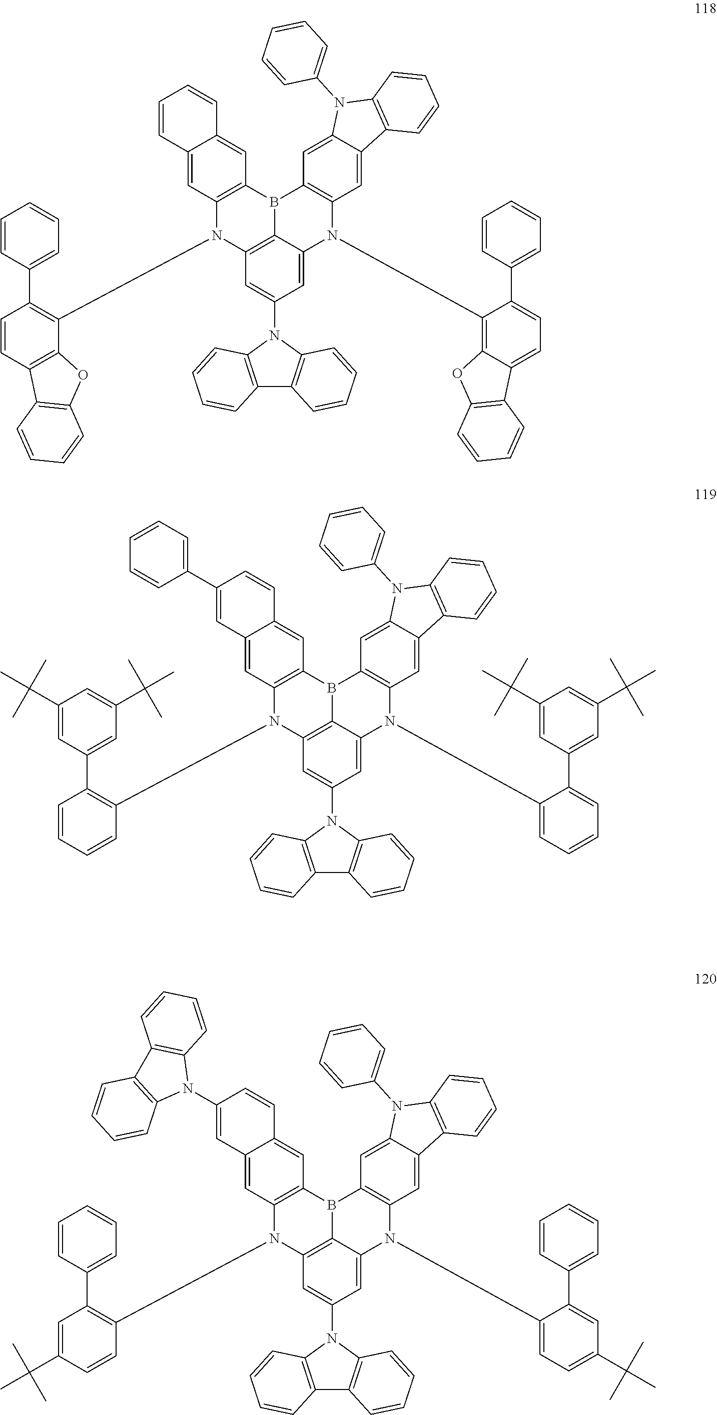

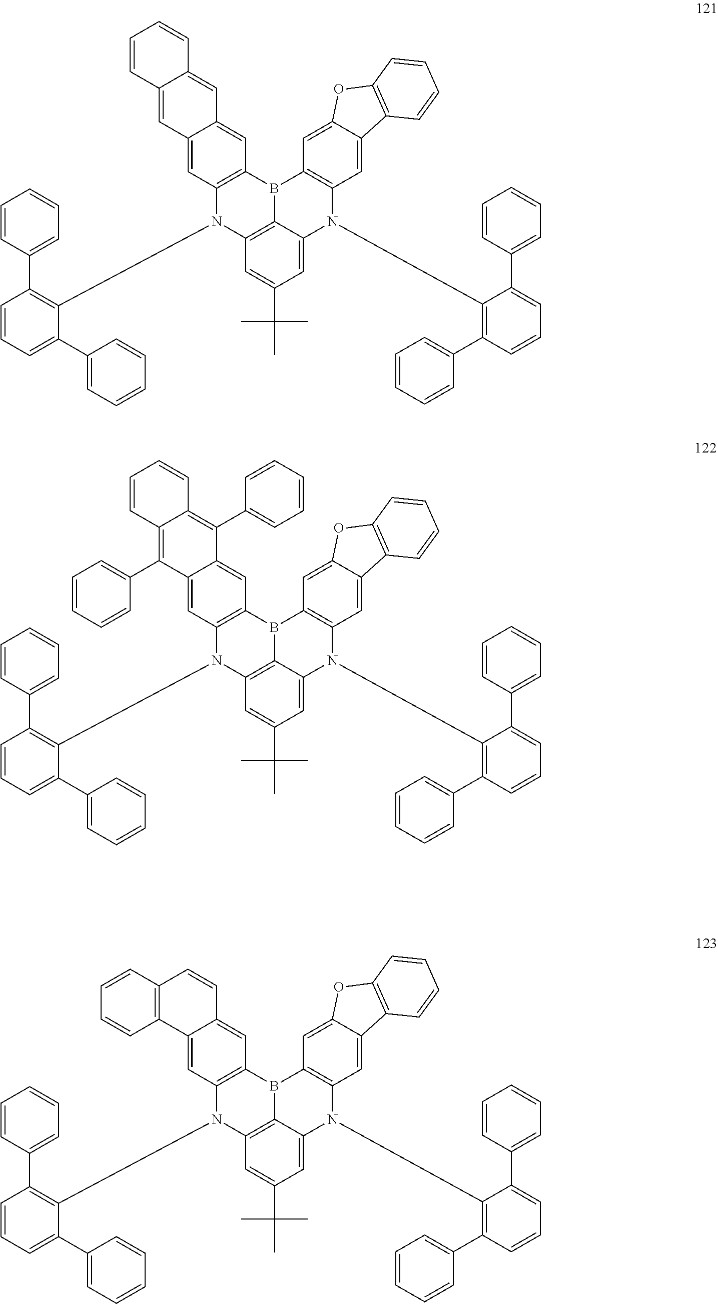 [SMILES: CC(C)(C)c1cc2c3c(c1)N(c1c(-c4ccccc4)cccc1-c1ccccc1)c1cc4c(cc1B3c1cc3cc5ccccc5cc3cc1N2c1c(-c2ccccc2)cccc1-c1ccccc1)oc1ccccc14 ; CC(C)(C)c1cc2c3c(c1)N(c1c(-c4ccccc4)cccc1-c1ccccc1)c1cc4c(cc1B3c1cc3c(-c5ccccc5)c5ccccc5c(-c5ccccc5)c3cc1N2c1c(-c2ccccc2)cccc1-c1ccccc1)oc1ccccc14 ; CC(C)(C)c1cc2c3c(c1)N(c1c(-c4ccccc4)cccc1-c1ccccc1)c1cc4c(cc1B3c1cc3ccc5ccccc5c3cc1N2c1c(-c2ccccc2)cccc1-c1ccccc1)oc1ccccc14]

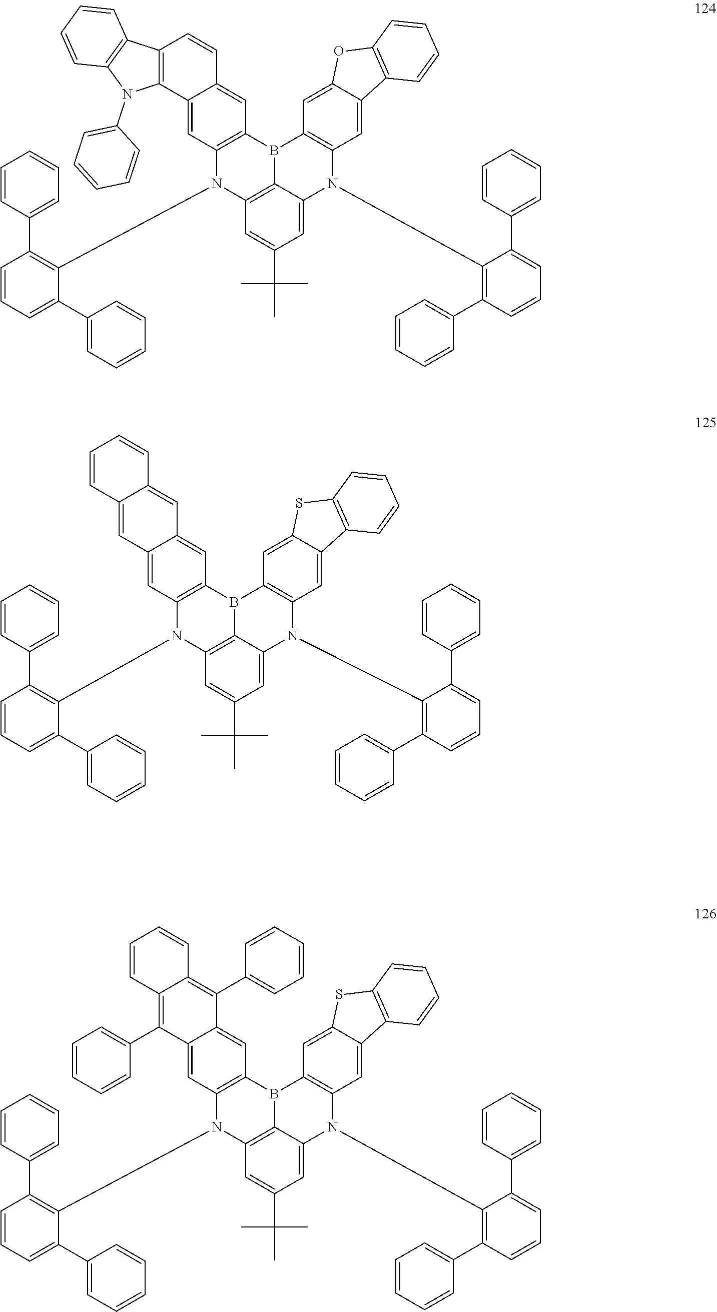 [SMILES: CC(C)(C)c1cc2c3c(c1)N(c1c(-c4ccccc4)cccc1-c1ccccc1)c1cc4c(ccc5c6ccccc6n(-c6ccccc6)c45)cc1B3c1cc3oc4ccccc4c3cc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1cc3cc5ccccc5cc3cc1N2c1c(-c2ccccc2)cccc1-c1ccccc1)sc1ccccc14 ; CC(C)(C)c1cc2c3c(c1)N(c1c(-c4ccccc4)cccc1-c1ccccc1)c1cc4c(cc1B3c1cc3c(-c5ccccc5)c5ccccc5c(-c5ccccc5)c3cc1N2c1c(-c2ccccc2)cccc1-c1ccccc1)sc1ccccc14]

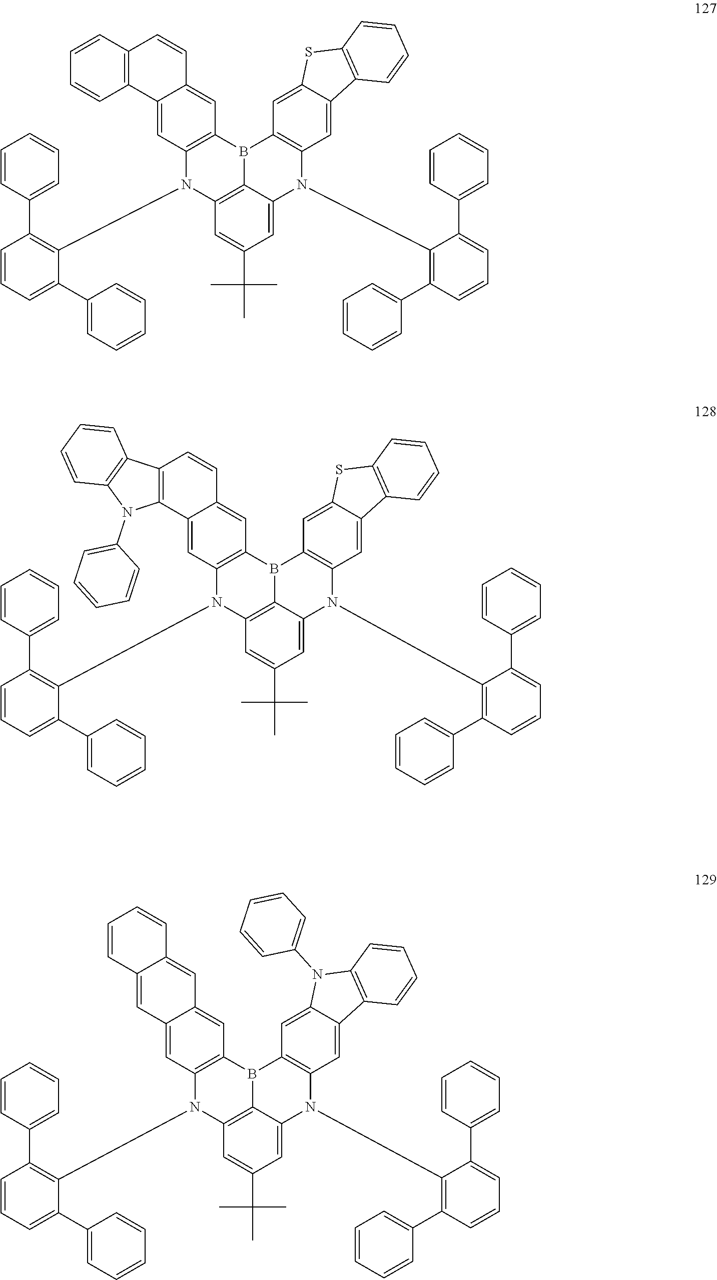 [SMILES: CC(C)(C)c1cc2c3c(c1)N(c1c(-c4ccccc4)cccc1-c1ccccc1)c1cc4c(cc1B3c1cc3ccc5ccccc5c3cc1N2c1c(-c2ccccc2)cccc1-c1ccccc1)sc1ccccc14 ; CC(C)(C)c1cc2c3c(c1)N(c1c(-c4ccccc4)cccc1-c1ccccc1)c1cc4c(ccc5c6ccccc6n(-c6ccccc6)c45)cc1B3c1cc3sc4ccccc4c3cc1N2c1c(-c2ccccc2)cccc1-c1ccccc1 ; CC(C)(C)c1cc2c3c(c1)N(c1c(-c4ccccc4)cccc1-c1ccccc1)c1cc4c5ccccc5n(-c5ccccc5)c4cc1B3c1cc3cc4ccccc4cc3cc1N2c1c(-c2ccccc2)cccc1-c1ccccc1]

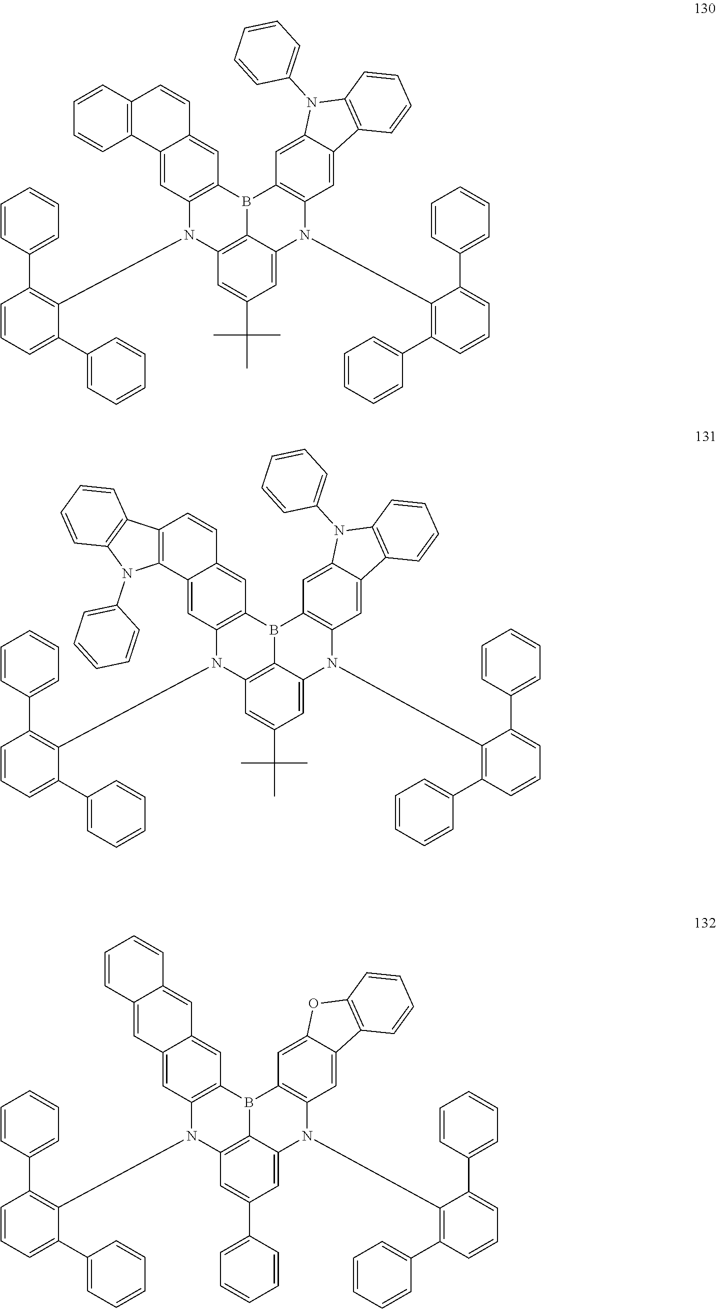 [SMILES: CC(C)(C)c1cc2c3c(c1)N(c1c(-c4ccccc4)cccc1-c1ccccc1)c1cc4c5ccccc5n(-c5ccccc5)c4cc1B3c1cc3ccc4ccccc4c3cc1N2c1c(-c2ccccc2)cccc1-c1ccccc1 ; CC(C)(C)c1cc2c3c(c1)N(c1c(-c4ccccc4)cccc1-c1ccccc1)c1cc4c(ccc5c6ccccc6n(-c6ccccc6)c45)cc1B3c1cc3c(cc1N2c1c(-c2ccccc2)cccc1-c1ccccc1)c1ccccc1n3-c1ccccc1 ; c1ccc(-c2cc3c4c(c2)N(c2c(-c5ccccc5)cccc2-c2ccccc2)c2cc5c(cc2B4c2cc4cc6ccccc6cc4cc2N3c2c(-c3ccccc3)cccc2-c2ccccc2)oc2ccccc25)cc1]

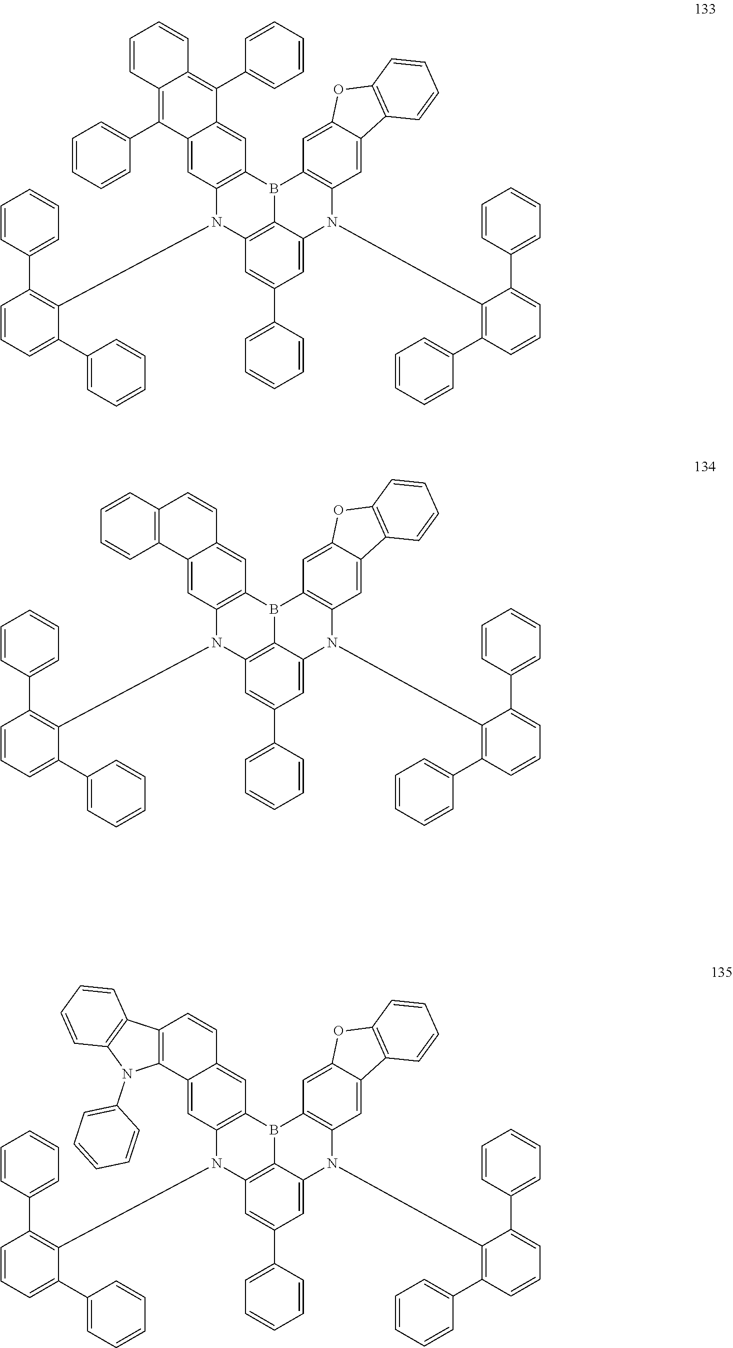 [SMILES: c1ccc(-c2cc3c4c(c2)N(c2c(-c5ccccc5)cccc2-c2ccccc2)c2cc5c(cc2B4c2cc4c(-c6ccccc6)c6ccccc6c(-c6ccccc6)c4cc2N3c2c(-c3ccccc3)cccc2-c2ccccc2)oc2ccccc25)cc1 ; c1ccc(-c2cc3c4c(c2)N(c2c(-c5ccccc5)cccc2-c2ccccc2)c2cc5c(cc2B4c2cc4ccc6ccccc6c4cc2N3c2c(-c3ccccc3)cccc2-c2ccccc2)oc2ccccc25)cc1 ; c1ccc(-c2cc3c4c(c2)N(c2c(-c5ccccc5)cccc2-c2ccccc2)c2cc5c(ccc6c7ccccc7n(-c7ccccc7)c56)cc2B4c2cc4oc5ccccc5c4cc2N3c2c(-c3ccccc3)cccc2-c2ccccc2)cc1]

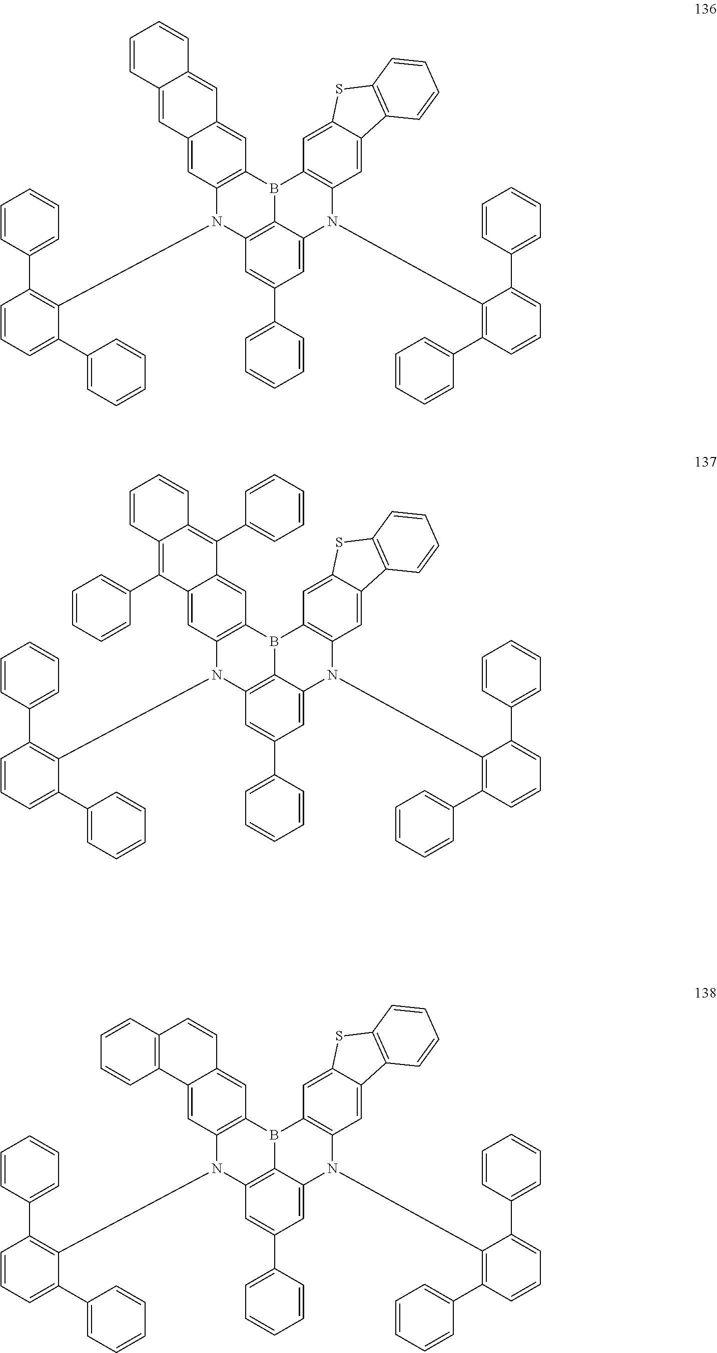 [SMILES: c1ccc(-c2cc3c4c(c2)N(c2c(-c5ccccc5)cccc2-c2ccccc2)c2cc5c(cc2B4c2cc4cc6ccccc6cc4cc2N3c2c(-c3ccccc3)cccc2-c2ccccc2)sc2ccccc25)cc1 ; c1ccc(-c2cc3c4c(c2)N(c2c(-c5ccccc5)cccc2-c2ccccc2)c2cc5c(cc2B4c2cc4c(-c6ccccc6)c6ccccc6c(-c6ccccc6)c4cc2N3c2c(-c3ccccc3)cccc2-c2ccccc2)sc2ccccc25)cc1 ; c1ccc(-c2cc3c4c(c2)N(c2c(-c5ccccc5)cccc2-c2ccccc2)c2cc5c(cc2B4c2cc4ccc6ccccc6c4cc2N3c2c(-c3ccccc3)cccc2-c2ccccc2)sc2ccccc25)cc1]

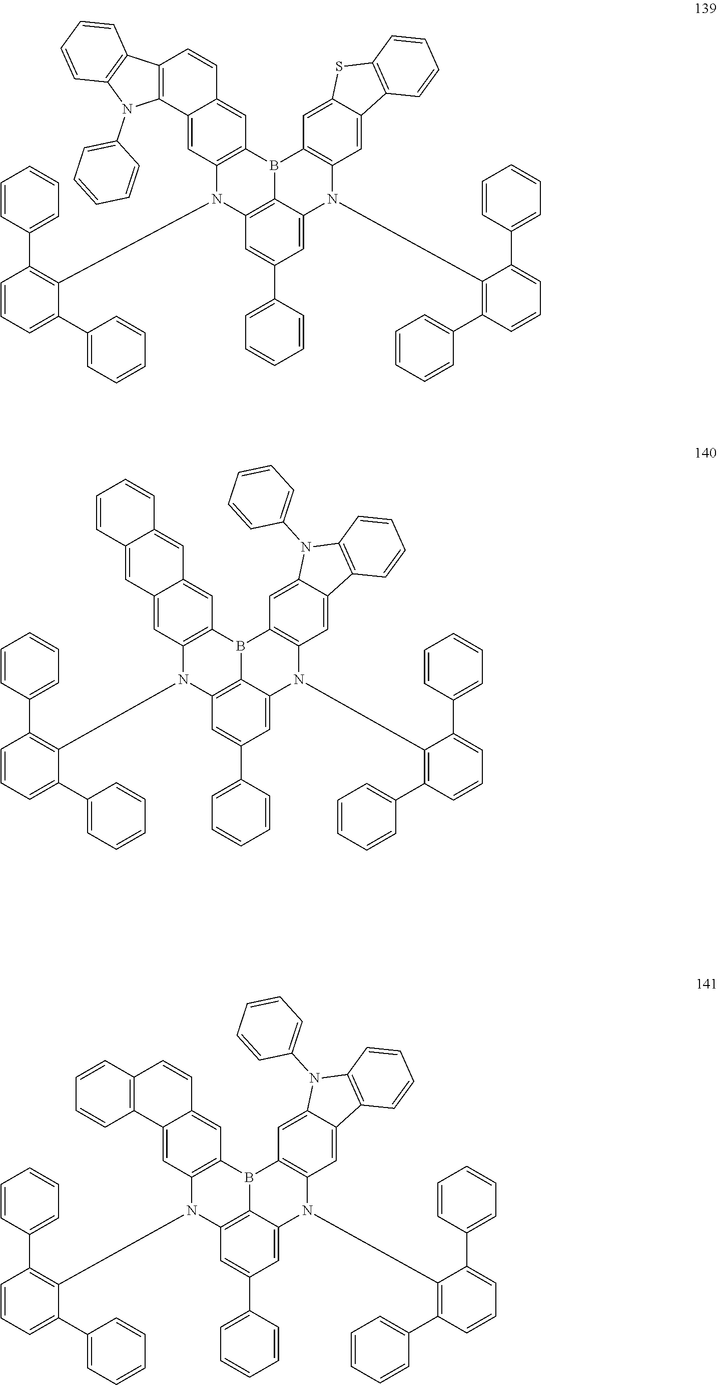 [SMILES: c1ccc(-c2cc3c4c(c2)N(c2c(-c5ccccc5)cccc2-c2ccccc2)c2cc5c(ccc6c7ccccc7n(-c7ccccc7)c56)cc2B4c2cc4sc5ccccc5c4cc2N3c2c(-c3ccccc3)cccc2-c2ccccc2)cc1 ; c1ccc(-c2cc3c4c(c2)N(c2c(-c5ccccc5)cccc2-c2ccccc2)c2cc5c6ccccc6n(-c6ccccc6)c5cc2B4c2cc4cc5ccccc5cc4cc2N3c2c(-c3ccccc3)cccc2-c2ccccc2)cc1 ; c1ccc(-c2cc3c4c(c2)N(c2c(-c5ccccc5)cccc2-c2ccccc2)c2cc5c6ccccc6n(-c6ccccc6)c5cc2B4c2cc4ccc5ccccc5c4cc2N3c2c(-c3ccccc3)cccc2-c2ccccc2)cc1]

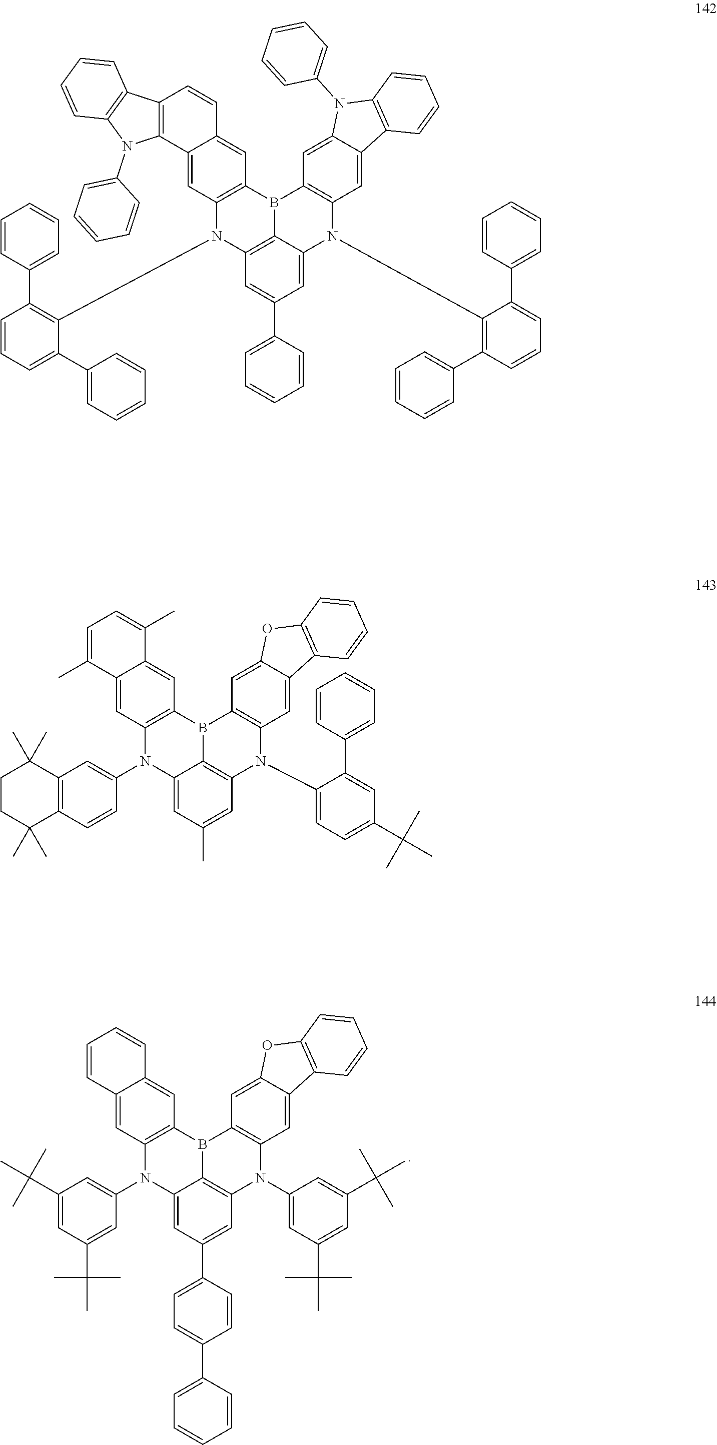

In one or more embodiments, the condensed cyclic compound represented by Formula 1 may be to emit green light.

Although not limited to a specific theory, if (e.g., when) rings in a condensed cyclic compound are further fused together to broaden conjugation, thereby inducing a wavelength shift from blue light to green light with a longer wavelength, intramolecular planarity may increase so that intermolecular aggregation may easily or more suitably occur, and the fused core may expand so that it becomes difficult to introduce a substituent for protecting a boron (B) atom. Thus, due to bonding between the empty p orbital of the B atom and a nucleophile, the structure of the condensed cyclic compound may be easily or suitably transformed. Accordingly, when a longer wavelength is induced by the above method, the optical characteristics of a light-emitting device may deteriorate.

Although not limited to a specific theory, the condensed cyclic compound according to the disclosure has a structure represented by Formula 1, wherein, in Formula 1, each ‘atom indicated by a star’ corresponds to a ‘highest occupied molecular orbital (HOMO) atom having the highest electron density in a condensed ring (an area indicated by an ellipse) including the atom.’

### Formula 1 (Annotated)

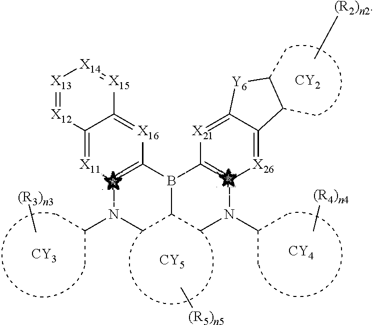

As shown in the above annotated Formula 1, when each ‘atom indicated by a star,’ which corresponds to a HOMO atom in each condensed ring indicated by an ellipse, is arranged adjacent to a ‘nitrogen (N) atom’ that is a HOMO atom of a multiple resonance core, there may be a section where HOMOs are adjacent to each other between the ‘atom indicated by a star’ and the ‘N atom.’ Because the section where HOMOs are adjacent to each other is a conjugation region and has a bonding orbital characteristic, the multiple resonance rule, which is a phenomenon of charge transfer (CT) between atoms that occurs when a HOMO and a lowest unoccupied molecular orbital (LUMO) are alternately arranged between neighboring atoms, may be partially broken, and thus, the emission of the condensed cyclic compound may be shifted from blue light to green light with a longer wavelength. For example, by arranging ‘naphthalene 2-carbon’ and ‘dibenzofuran 2-carbon,’ which have the highest electron density in a naphthalene structure and a dibenzofuran structure, respectively, adjacent to the N atom, green light emission may be realized.

Accordingly, a light-emitting device including the condensed cyclic compound represented by Formula 1 may be to emit green light.

In the condensed cyclic compound represented by Formula 1, unlike the method of further fusing rings in a condensed cyclic compound to broaden conjugation, a substituent that plays the roles of ‘relaxing intramolecular planarity’ and ‘protecting a B atom’ may be easily introduced. For example, by having the structure of Formula 1, the condensed cyclic compound according to the disclosure may have an improved degree of freedom in structural improvement. Accordingly, by using the condensed cyclic compound represented by Formula 1, a light-emitting device having excellent or suitable optical characteristics may be provided. For example, a light-emitting device including the condensed cyclic compound represented by Formula 1 may have suitably high efficiency and long lifespan characteristics.

Methods of synthesizing the condensed cyclic compound represented by Formula 1 may be easily understood to those of ordinary skill in the art by referring to Synthesis Examples and Examples described herein.

In one or more embodiments,
the first electrode of the light-emitting device may be an anode,
the second electrode of the light-emitting device may be a cathode,
the interlayer may further include a hole transport region arranged between the first electrode and the emission layer, and an electron transport region arranged between the emission layer and the second electrode,
the hole transport region may include a hole injection layer, a hole transport layer, an emission auxiliary layer, an electron-blocking layer, or any combination thereof, and
the electron transport region may include a buffer layer, a hole-blocking layer, an electron control layer, an electron transport layer, an electron injection layer, or any combination thereof.

In one or more embodiments, the condensed cyclic compound represented by Formula 1 may be included between the first electrode and the second electrode of the light-emitting device. Accordingly, the condensed cyclic compound represented by Formula 1 may be included in the interlayer of the light-emitting device, for example, in the emission layer of the interlayer. The emission layer may be to emit red light, green light, blue light, and/or white light. For example, the emission layer may be to emit green light.

In one or more embodiments, the emission layer may include a host and a dopant, and the dopant may include the condensed cyclic compound represented by Formula 1. In this regard, the amount of the host may be greater than the amount of the condensed cyclic compound represented by Formula 1.

In one or more embodiments, the light-emitting device may further include a capping layer arranged outside the first electrode and/or outside the second electrode.

In one or more embodiments, the light-emitting device may further include at least one selected from among a first capping layer arranged outside the first electrode and a second capping layer arranged outside the second electrode, wherein at least one selected from among the first capping layer and the second capping layer may include the condensed cyclic compound represented by Formula 1. A more detailed description of the first capping layer and/or the second capping layer is provided herein.

In one or more embodiments, the light-emitting device may further include a first capping layer arranged outside the first electrode. For example, the first capping layer may include the condensed cyclic compound represented by Formula 1.

In one or more embodiments, the light-emitting device may further include a second capping layer arranged outside the second electrode. For example, the second capping layer may include the condensed cyclic compound represented by Formula 1.

In one or more embodiments, the light-emitting device may further include a first capping layer arranged outside the first electrode and a second capping layer arranged outside the second electrode. For example, at least one selected from among the first capping layer and the second capping layer may include the condensed cyclic compound represented by Formula 1.

The wording “(interlayer and/or capping layer) includes a condensed cyclic compound” as used herein may be understood as “(interlayer and/or capping layer) may include one kind of condensed cyclic compound represented by Formula 1 or two or more different kinds of condensed cyclic compounds, each represented by Formula 1.”

In one or more embodiments, the interlayer and/or the capping layer may include Compound 1 only as the condensed cyclic compound. In this regard, Compound 1 may be present in the emission layer of the light-emitting device. In one or more embodiments, the interlayer may include, as the condensed cyclic compound, Compound 1 and Compound 2. In this regard, Compound 1 and Compound 2 may be present in substantially the same layer (e.g., both (e.g., simultaneously) Compound 1 and Compound 2 may be present in the emission layer), or may be present in different layers (e.g., Compound 1 may be present in the emission layer, and Compound 2 may be present in the electron transport region).

The term “interlayer” as used herein refers to a single layer and/or all of multiple layers arranged between the first electrode and the second electrode of the light-emitting device.

One or more embodiments provide an electronic apparatus including the light-emitting device. The electronic apparatus may further include a thin-film transistor. For example, the electronic apparatus may further include a thin-film transistor including a source electrode and a drain electrode, wherein the first electrode of the light-emitting device may be electrically connected (e.g., electrically coupled) to the source electrode or the drain electrode. In one or more embodiments, the electronic apparatus may further include a color filter, a color conversion layer, a touch screen layer, a polarizing layer, or any combination thereof. A more detailed description of the electronic apparatus is provided herein.

One or more embodiments provide electronic equipment including the light-emitting device. The electronic equipment may be one selected from among a flat panel display, a curved display, a computer monitor, a medical monitor, a television (TV), a billboard, an indoor light, an outdoor light, a signal light, a head-up display (HUD), a fully and/or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including multiple displays tiled together, a theater screen, a stadium screen, a phototherapy device, and a signboard.

One or more embodiments provide the condensed cyclic compound represented by Formula 1. A more detailed description of Formula 1 is provided herein.

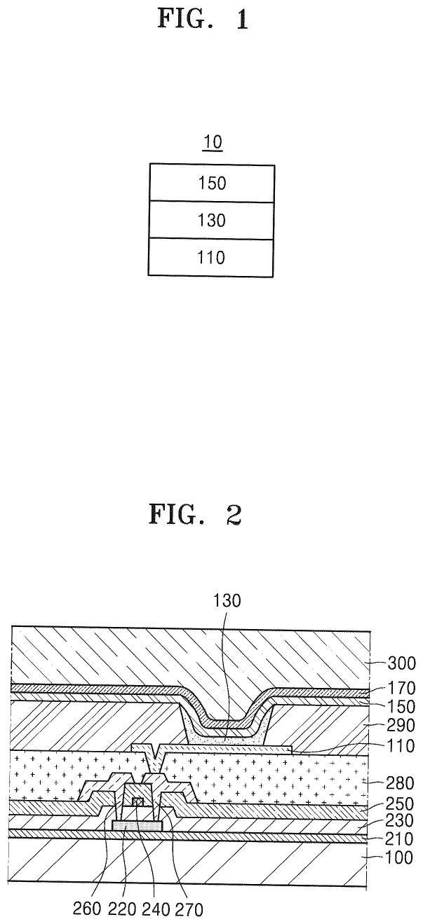

### Description of FIG. 1

FIG. 1 is a schematic cross-sectional view of a light-emitting device 10 according to one or more embodiments. The light-emitting device 10 includes a first electrode 110, an interlayer 130, and a second electrode 150.

Hereinafter, the structure of the light-emitting device 10 according to one or more embodiments and a method of manufacturing the light-emitting device 10 will be described with reference to FIG. 1.

### First Electrode 110

In FIG. 1, a substrate may be additionally arranged under the first electrode 110 or on the second electrode 150. As the substrate, a glass substrate or a plastic substrate may be used. In one or more embodiments, the substrate may be a flexible substrate, and may include plastics with excellent or suitable heat resistance and/or durability, such as polyimide, polyethylene terephthalate (PET), polycarbonate, polyethylene naphthalate, polyarylate (PAR), polyetherimide, or any combination thereof.

The first electrode 110 may be formed by, for example, depositing and/or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a transflective electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a transflective electrode or a reflective electrode, a material for forming the first electrode 110 may include magnesium (Mg), silver (Ag), aluminum (AI), aluminum-lithium (Al—Li), calcium (Ca), magnesium-indium (Mg—In), magnesium-silver (Mg—Ag), or any combination thereof.

The first electrode 110 may have a single-layer structure including (e.g., consisting of) a single layer or a multi-layer structure including multiple layers. For example, the first electrode 110 may have a three-layer structure of ITO/Ag/ITO.

### Interlayer 130

The interlayer 130 is arranged on the first electrode 110. The interlayer 130 includes an emission layer.

The interlayer 130 may further include a hole transport region arranged between the first electrode 110 and the emission layer, and an electron transport region arranged between the emission layer and the second electrode 150.

The interlayer 130 may further include, in addition to one or more suitable organic materials, a metal-containing compound such as an organometallic compound, an inorganic material such as quantum dots, and/or the like.

In one or more embodiments, the interlayer 130 may include i) two or more emitting units sequentially stacked between the first electrode 110 and the second electrode 150 and ii) a charge generation layer between the two or more emitting units. When the interlayer 130 includes the two or more light-emitting units and the charge generation layer, the light-emitting device 10 may be a tandem light-emitting device.

### Hole Transport Region in Interlayer 130

The hole transport region may have i) a single-layer structure including (e.g., consisting of) a single layer including (e.g., consisting of) a single material, ii) a single-layer structure including (e.g., consisting of) a single layer including multiple different materials, or iii) a multi-layer structure including multiple layers including multiple different materials.

The hole transport region may include a hole injection layer, a hole transport layer, an emission auxiliary layer, an electron-blocking layer, or any combination thereof.

In one or more embodiments, the hole transport region may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein constituent layers of each structure are stacked sequentially from the first electrode 110.

The hole transport region may include a compound represented by Formula 201, a compound represented by Formula 202, or any combination thereof:

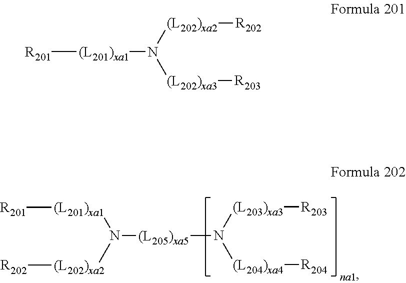

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, and/or a C₂-C₅ alkenylene group unsubstituted or substituted with at least one R₁₀ₐ, to form a C₈-C₆₀ polycyclic group (e.g., a carbazole group, and/or the like) unsubstituted or substituted with at least one R₁₀ₐ (e.g., Compound HT16, and/or the like),
R₂₀₃ and R₂₀₄ may optionally be linked to each other via a single bond, a C₁-C₅ alkylene group unsubstituted or substituted with at least one R₁₀ₐ, and/or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In one or more embodiments, each of Formulae 201 and 202 may include at least one selected from among groups represented by Formulae CY201 to CY217:

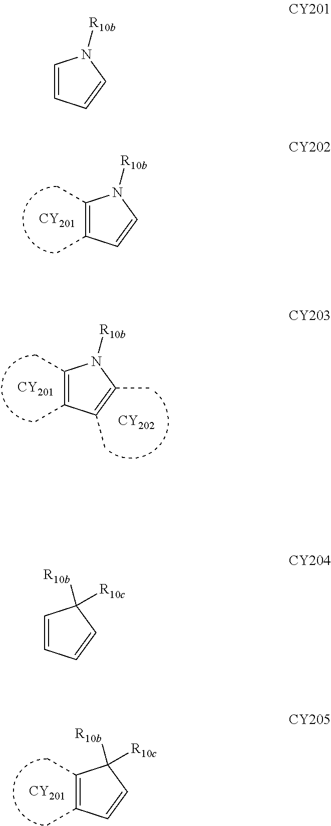

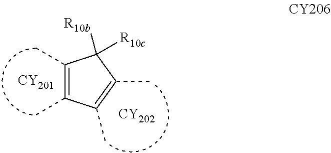

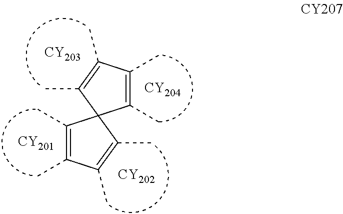

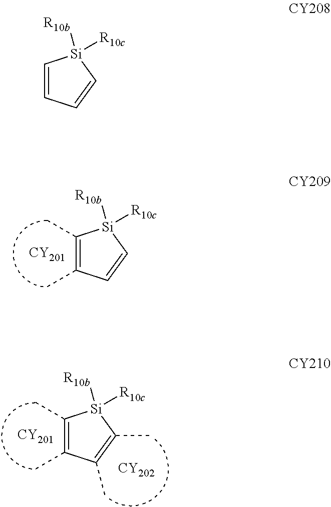

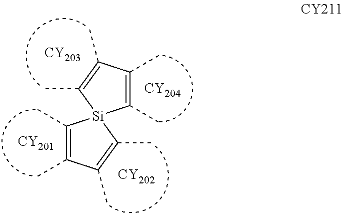

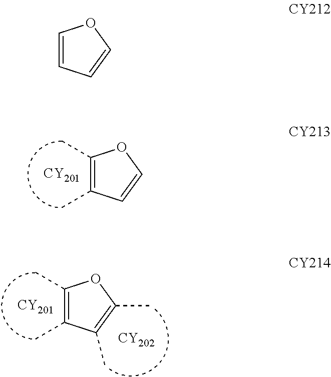

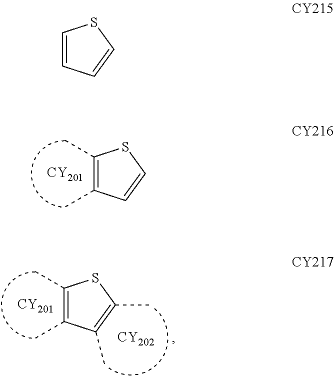

wherein, in Formulae CY201 to CY217, R_{10b} and R_{10c} are each independently as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In one or more embodiments, ring CY₂₀₁ to ring CY₂₀₄ in Formulae CY201 to CY217 may each independently be a benzene group, a naphthalene group, a phenanthrene group, or an anthracene group.

In one or more embodiments, each of Formulae 201 and 202 may include at least one selected from among groups represented by Formulae CY201 to CY203.

In one or more embodiments, Formula 201 may include at least one selected from among groups represented by Formulae CY201 to CY203 and at least one selected from among groups represented by Formulae CY204 to CY₂₁₇.

In one or more embodiments, in Formula 201, xa1 may be 1, R₂₀₁ may be a group represented by one selected from among Formulae CY201 to CY203, xa2 may be 0, and R₂₀₂ may be a group represented by one selected from among Formulae CY204 to CY207.

In one or more embodiments, each of Formulae 201 and 202 may not include (e.g., may exclude) groups represented by Formulae CY201 to CY203.

In one or more embodiments, each of Formulae 201 and 202 may not include (e.g., may exclude) groups represented by Formulae CY201 to CY203, and may include at least one selected from among groups represented by Formulae CY204 to CY217.

In one or more embodiments, each of Formulae 201 and 202 may not include (e.g., may exclude) groups represented by Formulae CY201 to CY217.

In one or more embodiments, the hole transport region may include one selected from among Compounds HT1 to HT47, m-MTDATA, TDATA, 2-TNATA, NPB(NPD), β-NPB, TPD, Spiro-TPD, Spiro-NPB, methylated-NPB, TAPC, HMTPD, CzSi, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

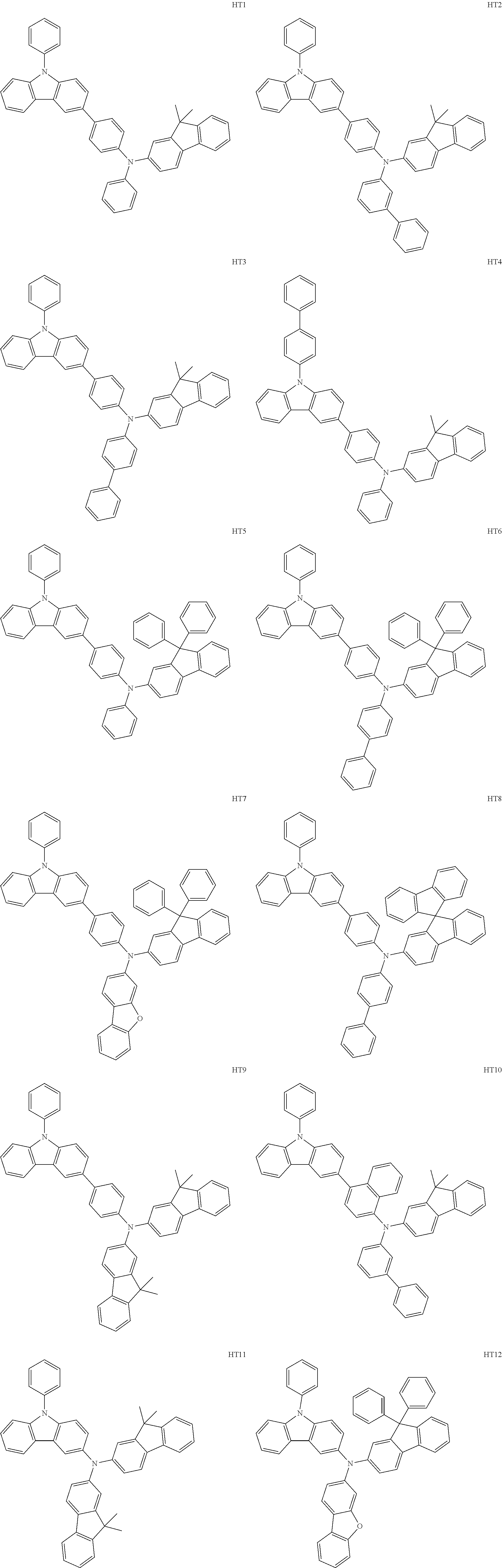

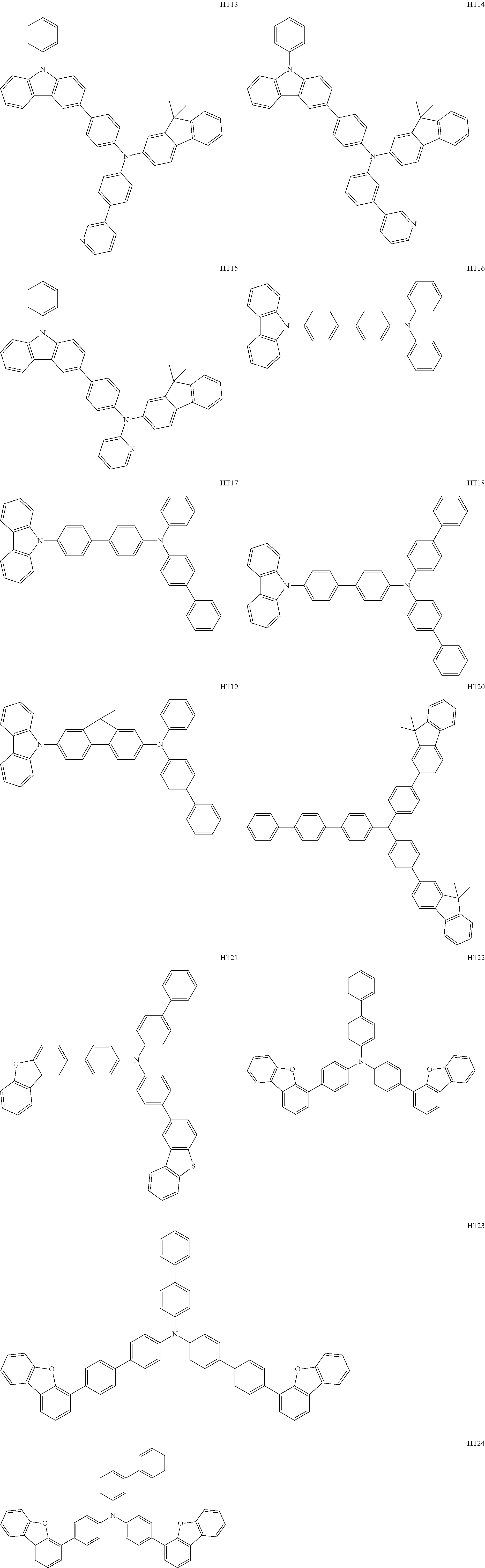

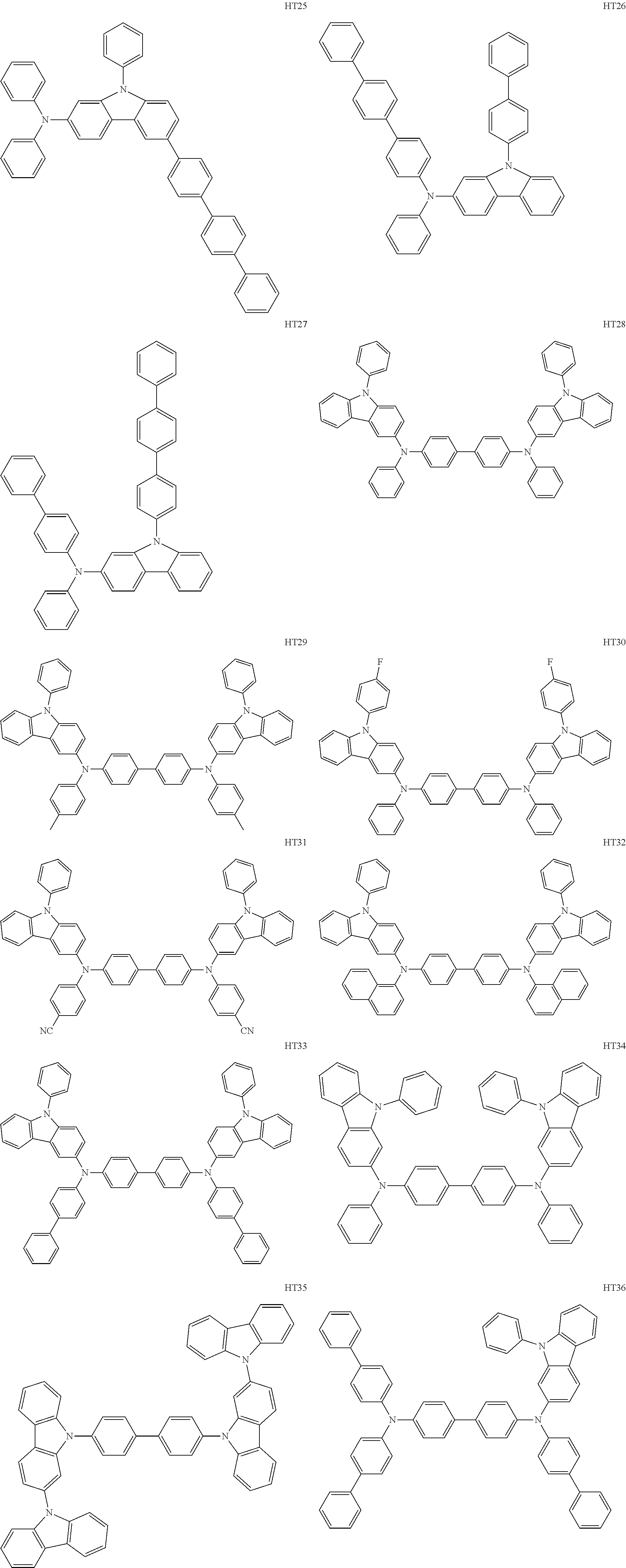

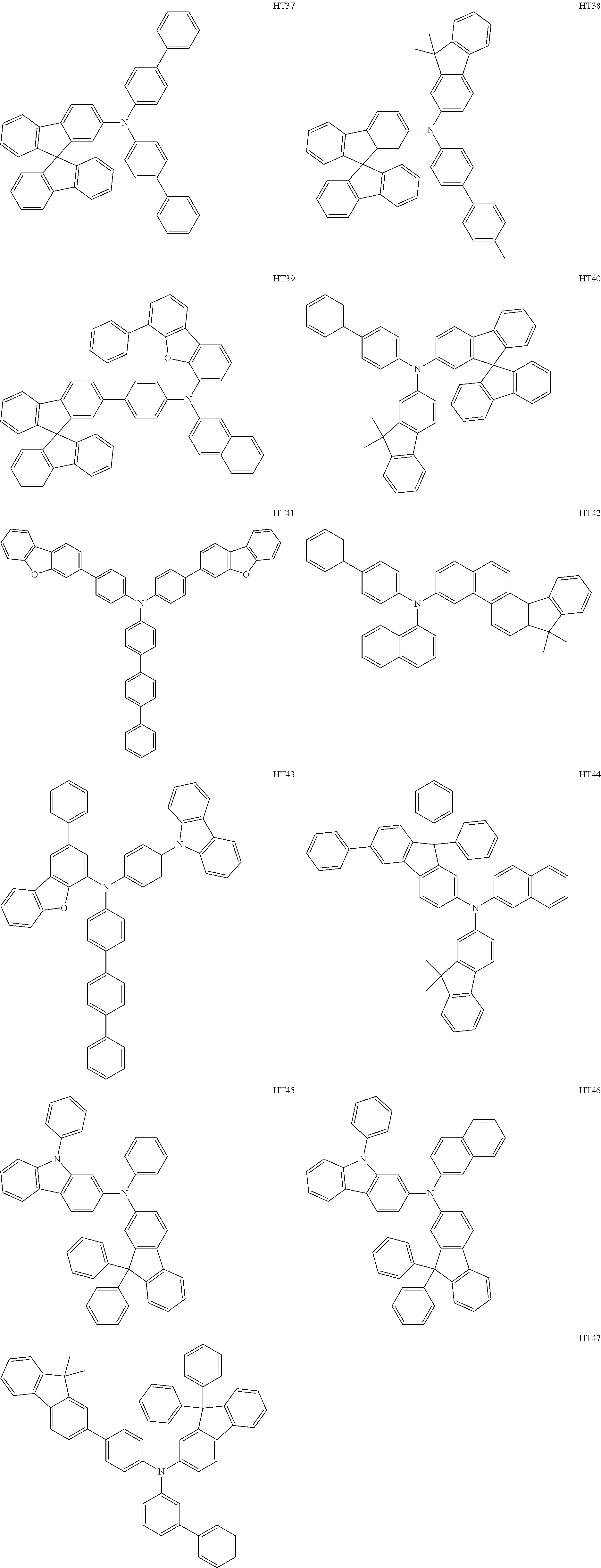

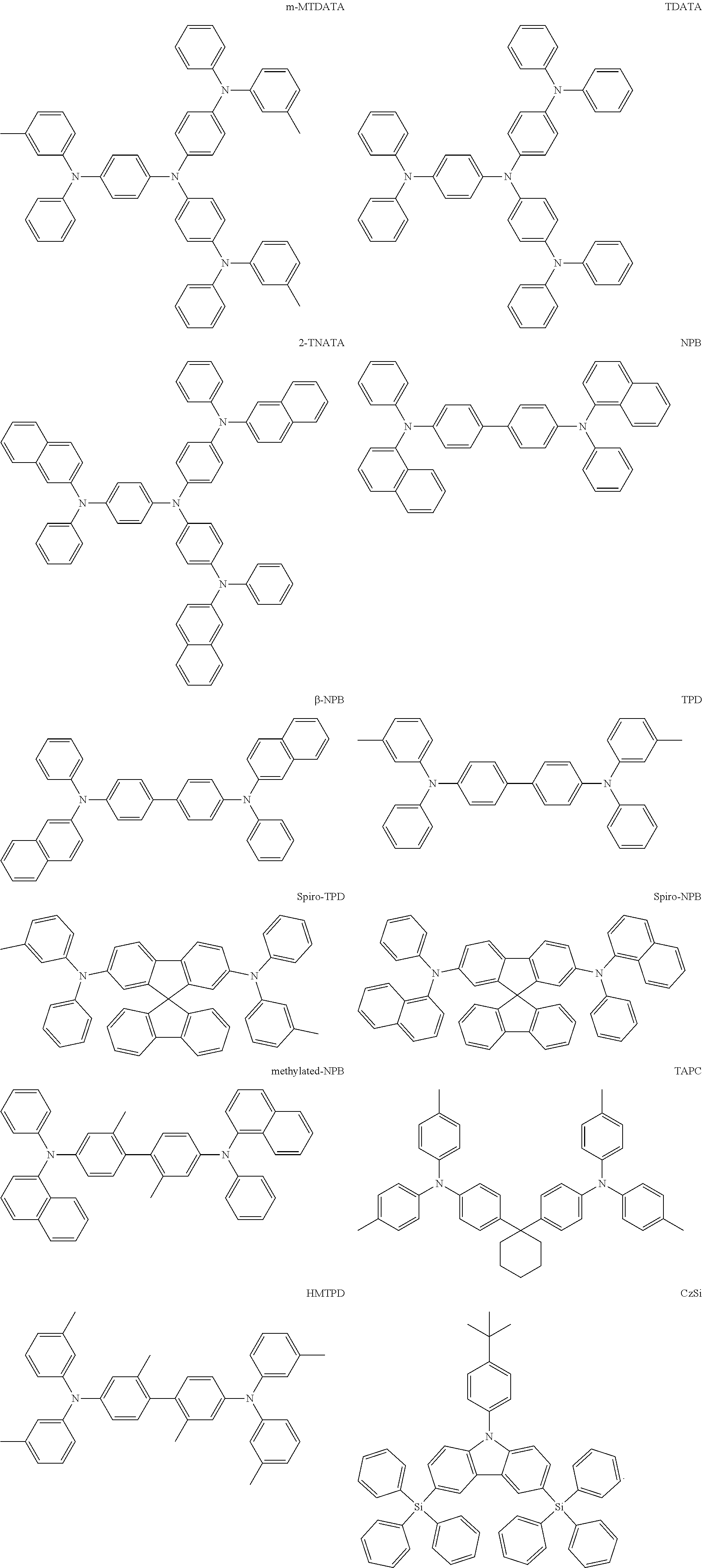

The thickness of the hole transport region may be in a range of about 50 Å to about 10,000 Å, for example, about 100 Å to about 4,000 Å. When the hole transport region includes a hole injection layer, a hole transport layer, or any combination thereof, the thickness of the hole injection layer may be in a range of about 100 Å to about 9,000 Å, for example, about 100 Å to about 1,000 Å, and the thickness of the hole transport layer may be in a range of about 50 Å to about 2,000 Å, for example, about 100 Å to about 1,500 Å. When the thicknesses of the hole transport region, the hole injection layer, and/or the hole transport layer are within their respective ranges described above, satisfactory or suitable hole-transporting characteristics may be obtained without a substantial increase in driving voltage.

The emission auxiliary layer may increase light emission efficiency by compensating for an optical resonance distance according to the wavelength of light emitted by the emission layer, and the electron-blocking layer may block or reduce the leakage of electrons from the emission layer to the hole transport region. Any of the materials that may be included in the hole transport region may be included in the emission auxiliary layer and the electron-blocking layer.

p-Dopant

The hole transport region may include, in addition to the materials described above, a charge generation material for the improvement of conductive properties. The charge generation material may be uniformly (e.g., substantially uniformly) or non-uniformly (e.g., substantially non-uniformly) dispersed in the hole transport region (e.g., in the form of a single layer including (e.g., consisting of) the charge generation material).

The charge generation material may be, for example, a p-dopant.

In one or more embodiments, the p-dopant may have a LUMO energy level of −3.5 eV or less.

In one or more embodiments, the p-dopant may include a quinone derivative, a cyano group-containing compound, a compound including an element EL1 and an element EL2, or any combination thereof.

Examples of the quinone derivative may include TCNQ, F4-TCNQ, and/or the like.

Examples of the cyano group-containing compound may include HAT-CN, a compound represented by Formula 221, and/or the like:

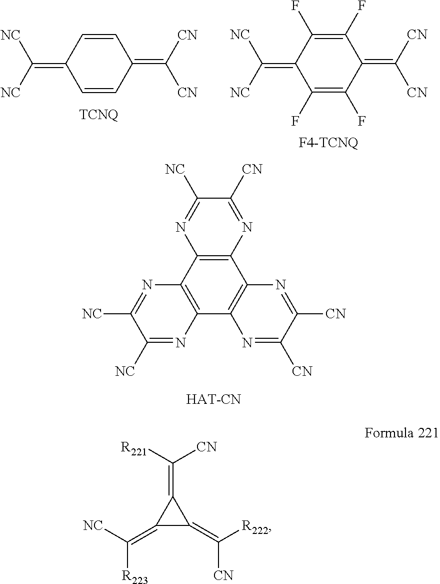

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including the element EL1 and the element EL2, the element EL1 may be a metal, a metalloid, or any suitable combination thereof, and the element EL2 may be a non-metal, a metalloid, or any suitable combination thereof.

Examples of the metal may include: an alkali metal (e.g., lithium (Li), sodium (Na), potassium (K), rubidium (Rb), cesium (Cs), and/or the like); an alkaline earth metal (e.g., beryllium (Be), magnesium (Mg), calcium (Ca), strontium (Sr), barium (Ba), and/or the like); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (e.g., zinc (Zn), indium (In), tin (Sn), and/or the like); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and/or the like.

Examples of the metalloid may include silicon (Si), antimony (Sb), tellurium (Te), and/or the like.

Examples of the non-metal may include oxygen (O), a halogen (e.g., F, Cl, Br, I, and/or the like), and/or the like.

Examples of the compound including the element EL1 and the element EL2 may include a metal oxide, a metal halide (e.g., a metal fluoride, a metal chloride, a metal bromide, a metal iodide, and/or the like), a metalloid halide (e.g., a metalloid fluoride, a metalloid chloride, a metalloid bromide, a metalloid iodide, and/or the like), a metal telluride, or any combination thereof.

Examples of the metal oxide may include a tungsten oxide (e.g., WO, W₂O₃, WO₂, WO₃, W₂O₅, and/or the like), a vanadium oxide (e.g., VO, V₂O₃, VO₂, V₂O₅, and/or the like), a molybdenum oxide (e.g., MoO, Mo₂O₃, MoO₂, MoO₃, Mo₂O₅, and/or the like), a rhenium oxide (e.g., ReO₃, and/or the like), and/or the like.

Examples of the metal halide may include an alkali metal halide, an alkaline earth metal halide, a transition metal halide, a post-transition metal halide, a lanthanide metal halide, and/or the like.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and/or the like.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, Mg₁₂, CaI₂, SrI₂, BaI₂, and/or the like.

Examples of the transition metal halide may include a titanium halide (e.g., TiF₄, TiCl₄, TiBr₄, TiI₄, and/or the like), a zirconium halide (e.g., ZrF₄, ZrCl₄, ZrBr₄, ZrI₄, and/or the like), a hafnium halide (e.g., HfF₄, HfC₁₄, HfBr₄, HfI₄, and/or the like), a vanadium halide (e.g., VF₃, VCl₃, VBr₃, VI₃, and/or the like), a niobium halide (e.g., NbF₃, NbCl₃, NbBr₃, NbI₃, and/or the like), a tantalum halide (e.g., TaF₃, TaCl₃, TaBr₃, TaI₃, and/or the like), a chromium halide (e.g., CrF₃, CrCl₃, CrBr₃, CrI₃, and/or the like), a molybdenum halide (e.g., MoF₃, MoCl₃, MoBr₃, MoI₃, and/or the like), a tungsten halide (e.g., WF₃, WCl₃, WBr₃, WI₃, and/or the like), a manganese halide (e.g., MnF₂, MnCl₂, MnBr₂, MnI₂, and/or the like), a technetium halide (e.g., TcF₂, TcCl₂, TcBr₂, TcI₂, and/or the like), a rhenium halide (e.g., ReF₂, ReCl₂, ReBr₂, ReI₂, and/or the like), an iron halide (e.g., FeF₂, FeCl₂, FeBr₂, FeI₂, and/or the like), a ruthenium halide (e.g., RuF₂, RuCl₂, RuBr₂, RuI₂, and/or the like), an osmium halide (e.g., OsF₂, OsCl₂, OsBr₂, OsI₂, and/or the like), a cobalt halide (e.g., CoF₂, CoCl₂, CoBr₂, CoI₂, and/or the like), a rhodium halide (e.g., RhF₂, RhCl₂, RhBr₂, RhI₂, and/or the like), an iridium halide (e.g., IrF₂, IrCl₂, IrBr₂, IrI₂, and/or the like), a nickel halide (e.g., NiF₂, NiCl₂, NiBr₂, NiI₂, and/or the like), a palladium halide (e.g., PdF₂, PdCl₂, PdBr₂, PdI₂, and/or the like), a platinum halide (e.g., PtF₂, PtCl₂, PtBr₂, PtI₂, and/or the like), a copper halide (e.g., CuF, CuCl, CuBr, CuI, and/or the like), a silver halide (e.g., AgF, AgCl, AgBr, AgI, and/or the like), a gold halide (e.g., AuF, AuCl, AuBr, AuI, and/or the like), and/or the like.

Examples of the post-transition metal halide may include a zinc halide (e.g., ZnF₂, ZnCl₂, ZnBr₂, Zn₁₂, and/or the like), an indium halide (e.g., InI₃, and/or the like), a tin halide (e.g., SnI₂, and/or the like), and/or the like.

Examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and/or the like.

Examples of the metalloid halide may include an antimony halide (e.g., SbCl₅, and/or the like) and/or the like.

Examples of the metal telluride may include an alkali metal telluride (e.g., Li₂Te, Na₂Te, K₂Te, Rb₂Te, Cs₂Te, and/or the like), an alkaline earth metal telluride (e.g., BeTe, MgTe, CaTe, SrTe, BaTe, and/or the like), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), a post-transition metal telluride (e.g., ZnTe, and/or the like), a lanthanide metal telluride (e.g., LaTe, CeTe, PrTe, NdTe, PmTe, EuTe, GdTe, TbTe, DyTe, HoTe, ErTe, TmTe, YbTe, LuTe, and/or the like), and/or the like.

### Emission Layer in Interlayer 130

When the light-emitting device 10 is a full-color light-emitting device, the emission layer may be patterned into a red emission layer, a green emission layer, and/or a blue emission layer, according to a subpixel. In one or more embodiments, the emission layer may have a stacked structure of two or more layers of a red emission layer, a green emission layer, and a blue emission layer, in which the two or more layers contact each other or are separated from each other, to emit white light. In one or more embodiments, the emission layer may include two or more materials of a red light-emitting material, a green light-emitting material, and a blue light-emitting material, in which the two or more materials are mixed with each other in a single layer, to emit white light. For example, the emission layer may be to emit green light.

In one or more embodiments, the emission layer may include the condensed cyclic compound represented by Formula 1 as described herein.

The emission layer may include a host and a dopant.

In one or more embodiments, the dopant may include the condensed cyclic compound represented by Formula 1 as described herein. In this regard, the dopant may include, in addition to the condensed cyclic compound represented by Formula 1, a phosphorescent dopant, a fluorescent dopant, or any combination thereof. More detailed descriptions of the phosphorescent dopant, the fluorescent dopant, and/or the like, which may be included in the emission layer in addition to the condensed cyclic compound represented by Formula 1, are provided herein below.

The amount of the dopant in the emission layer may be in a range of about 0.01 parts by weight to about 15 parts by weight based on 100 parts by weight of the host.

In one or more embodiments, the emission layer may include quantum dots.

In one or more embodiments, the emission layer may include a delayed fluorescence material. The delayed fluorescence material may act as a host or a dopant in the emission layer.

The thickness of the emission layer may be in a range of about 100 Å to about 1,000 Å, for example, about 200 Å to about 600 Å. When the thickness of the emission layer is within any of the ranges described above, excellent or suitable luminescence characteristics may be obtained without a substantial increase in driving voltage.

### Host

The host may include, for example, a carbazole-containing compound, an anthracene-containing compound, or any combination thereof.

In one or more embodiments, the host may include a compound represented by Formula 301:

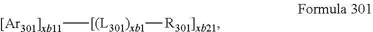

wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ are each independently as described in connection with Q₁.

In one or more embodiments, when xb11 in Formula 301 is 2 or more, two or more of Ar₃₀₁ may be linked to each other via a single bond.

In one or more embodiments, the host may include a compound represented by Formula 301-1, a compound represented by Formula 301-2, or any combination thereof:

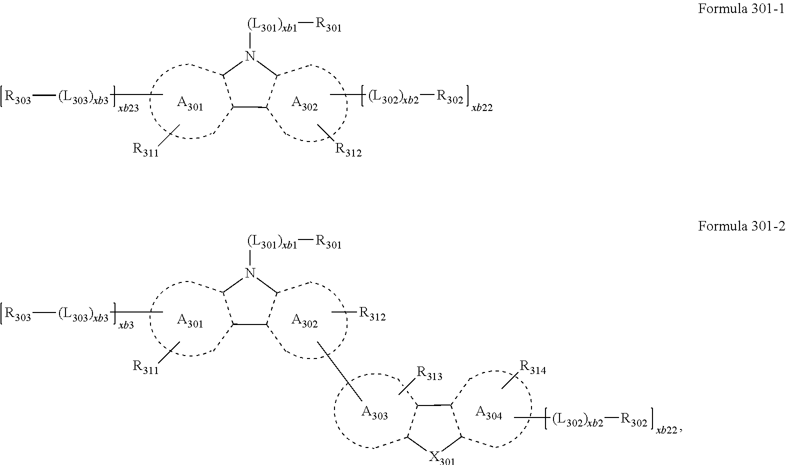

wherein, in Formulae 301-1 and 301-2,
ring A₃₀₁ to ring A₃₀₄ may each independently be a C₃-C₆₀ carbocyclic group or a C₁-C₆₀ heterocyclic group,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ are each as respectively described herein,
L₃₀₂ to L₃₀₄ may each independently be as described in connection with L₃₀₁,
xb2 to xb4 may each independently be as described in connection with xb1, and
R₃₀₂ to R₃₀₅ and R₃₁₁ to R₃₁₄ are each independently as described in connection with R₃₀₁.

In one or more embodiments, the host may include an alkali earth metal complex, a post-transition metal complex, or any combination thereof. For example, the host may include a Be complex (e.g., Compound H55), a Mg complex, a Zn complex, or any combination thereof.

In one or more embodiments, the host may include one selected from among Compounds H1 to H128, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-(9-carbazolyl)benzene (mCP), 1,3,5-tri(carbazol-9-yl)benzene (TCP), or any combination thereof:

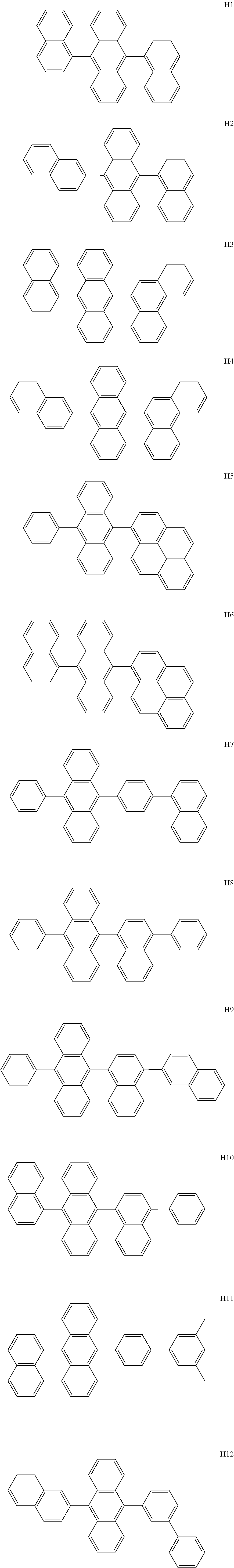

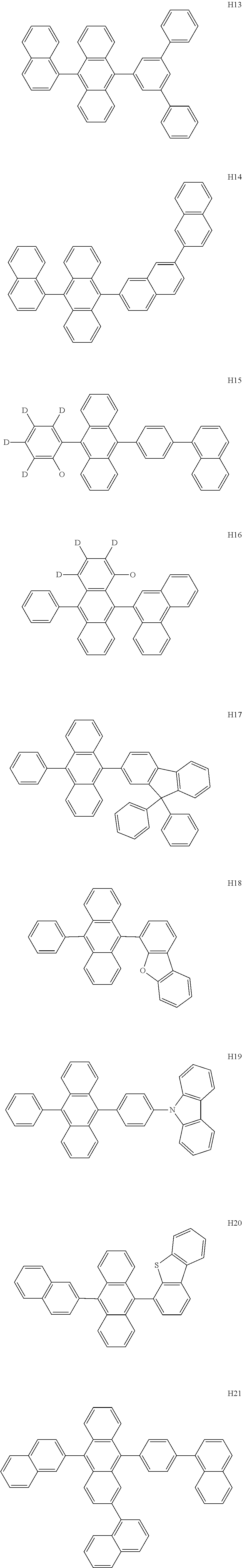

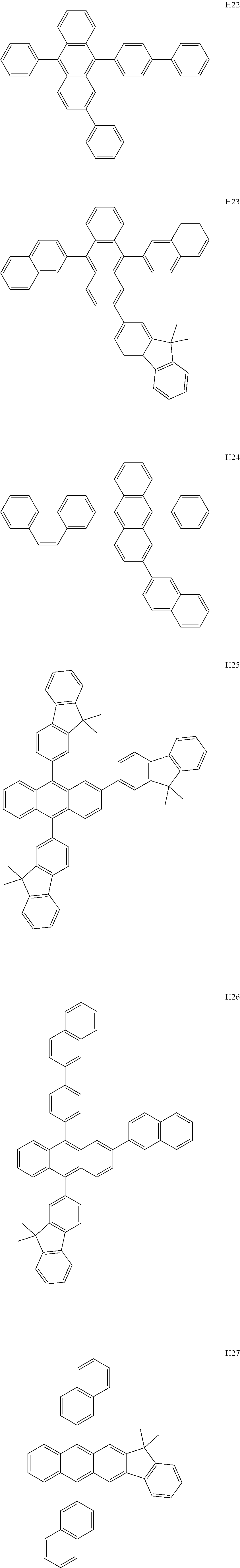

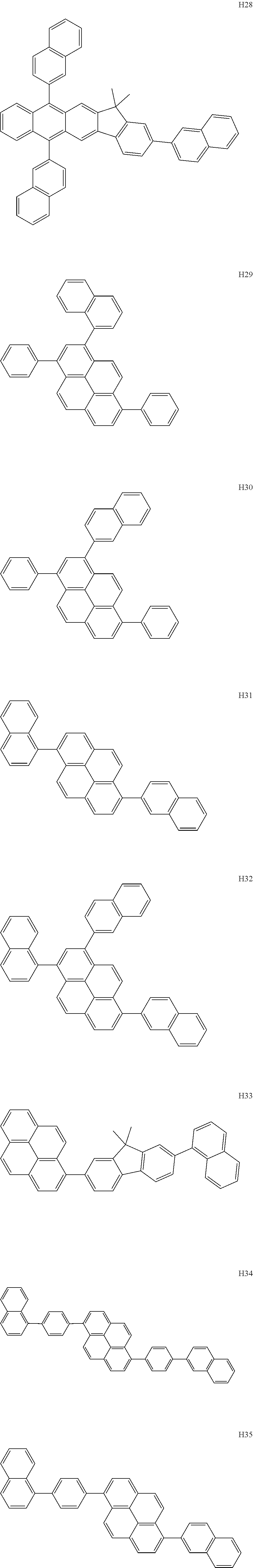

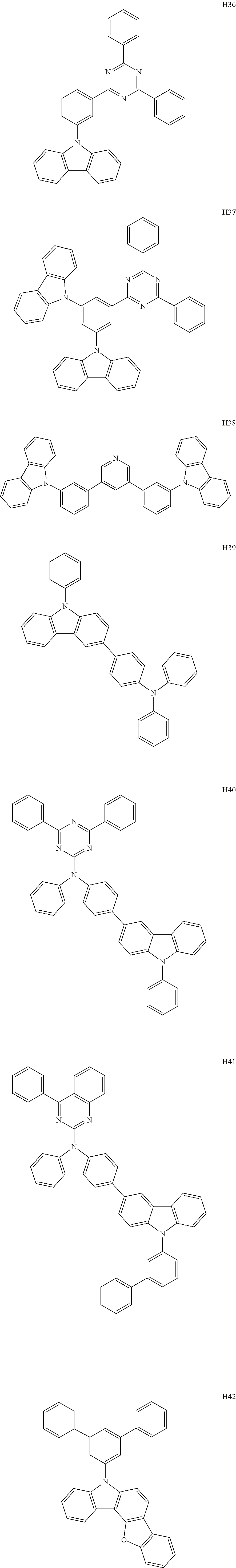

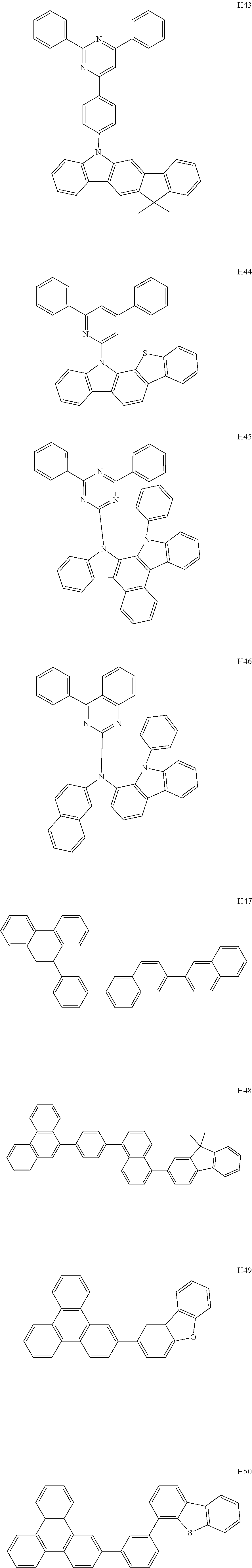

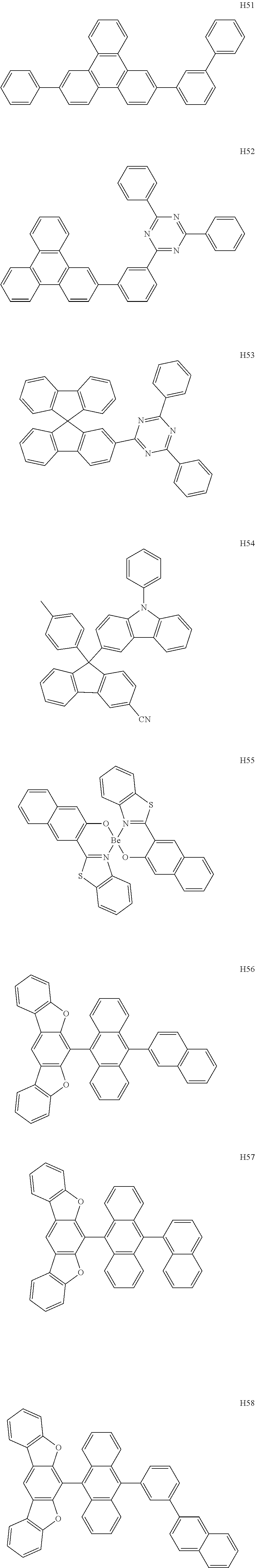

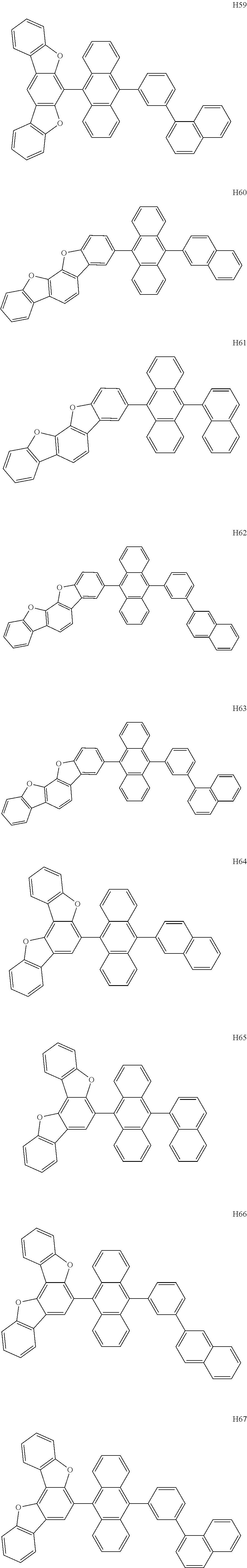

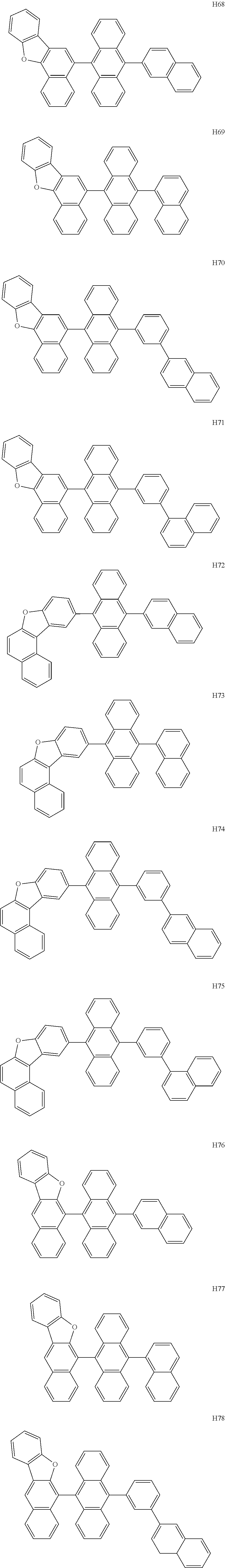

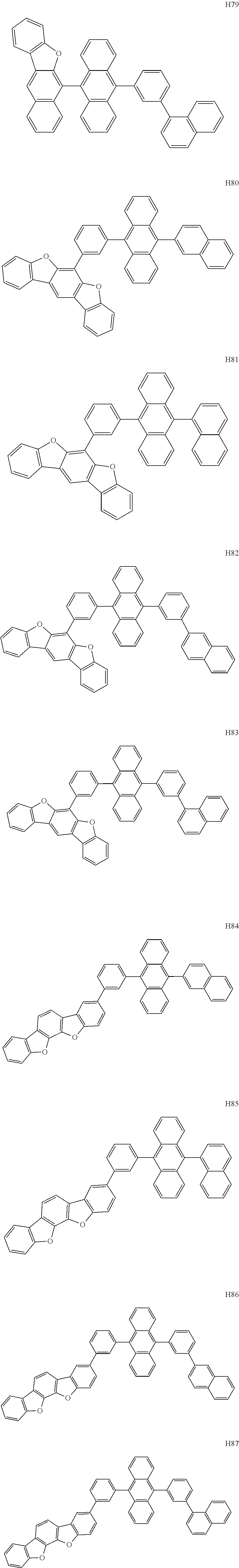

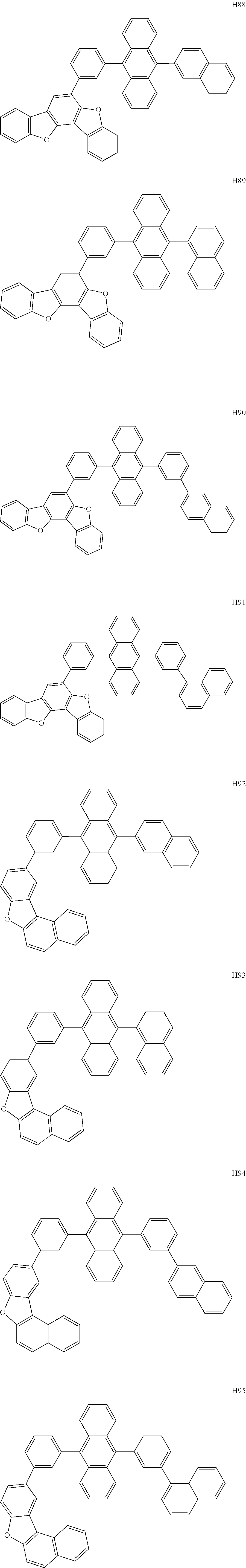

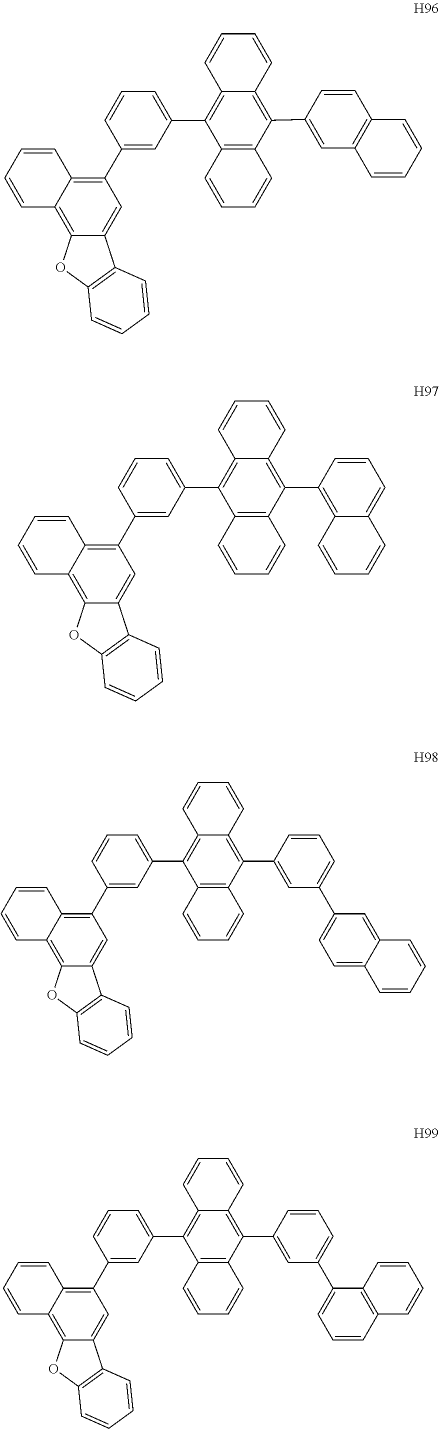 [SMILES: c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

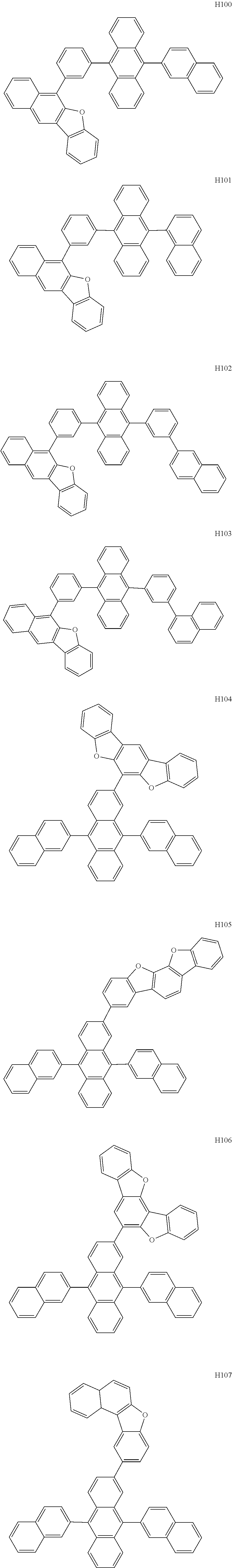

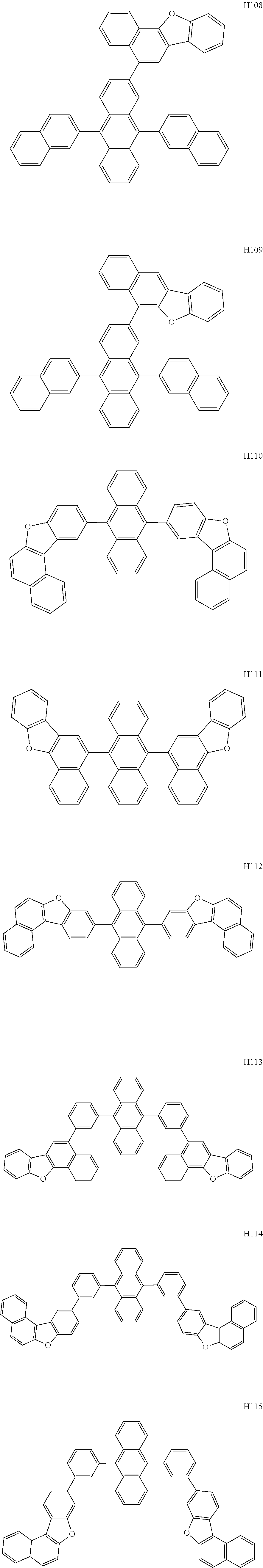

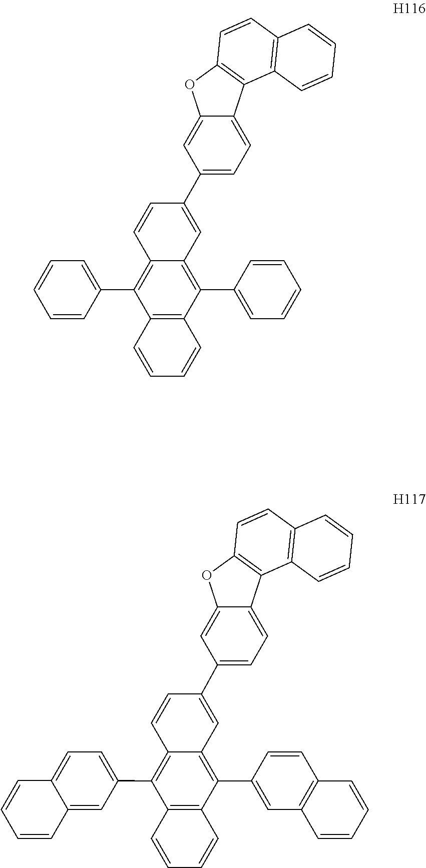 [SMILES: c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

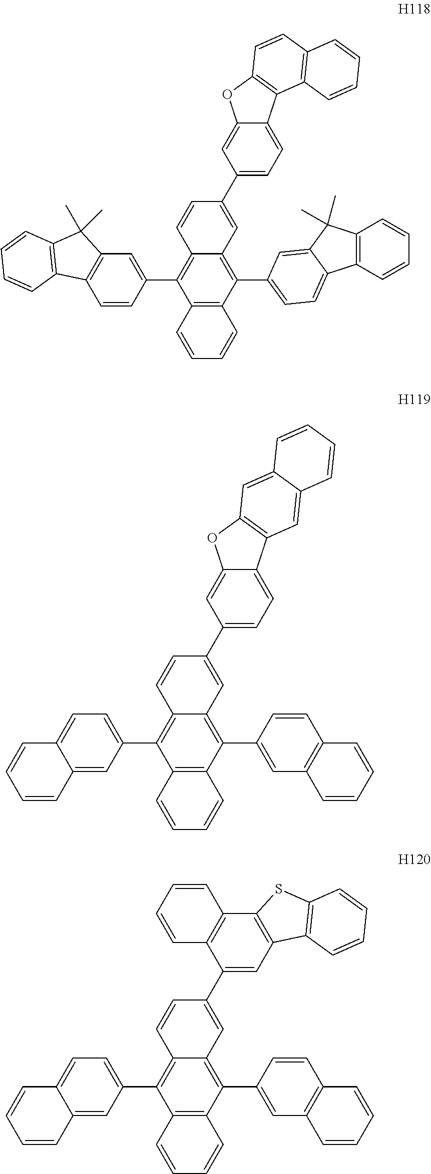 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

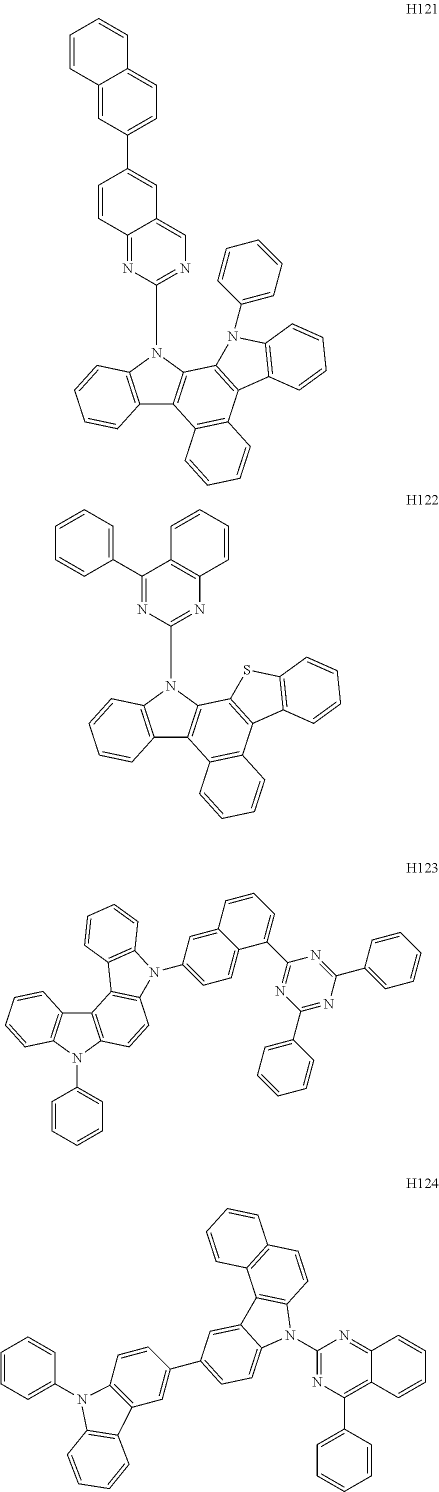

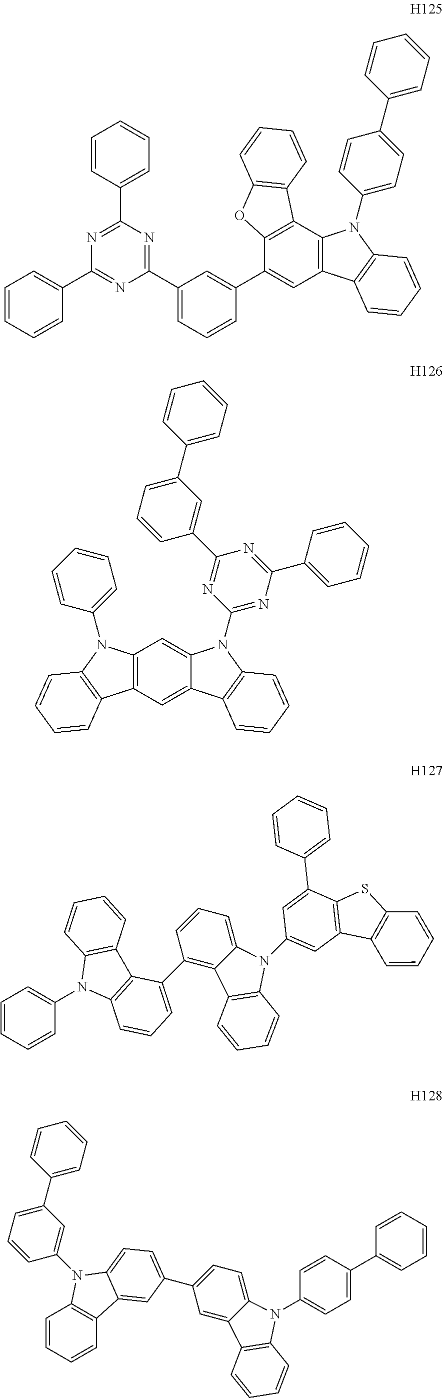

In one or more embodiments, the host may include a first host compound and a second host compound.

In one or more embodiments, the first host compound may be a hole-transporting host.

In one or more embodiments, the second host compound may be an electron-transporting host.

In one or more embodiments, the term “hole-transporting host” as used herein refers to a compound including a hole-transporting moiety.

In one or more embodiments, the term “electron-transporting host” as used herein refers to not only a compound including an electron-transporting moiety, but also a compound having bipolar properties.

The terms “hole-transporting host” and “electron-transporting host” as used herein may each be understood according to the relative difference between the hole mobility and electron mobility in the hole-transporting host and the electron-transporting host. For example, even if (e.g., when) the electron-transporting host does not include an electron-transporting moiety, a bipolar compound exhibiting relatively higher electron mobility than the hole-transporting host may be also understood as the electron-transporting host.

In one or more embodiments, the hole-transporting host may be represented by one selected from among Formulae 311-1 to 311-6, and the electron-transporting host may be represented by one selected from among Formulae 312-1 to 312-4 and 313:

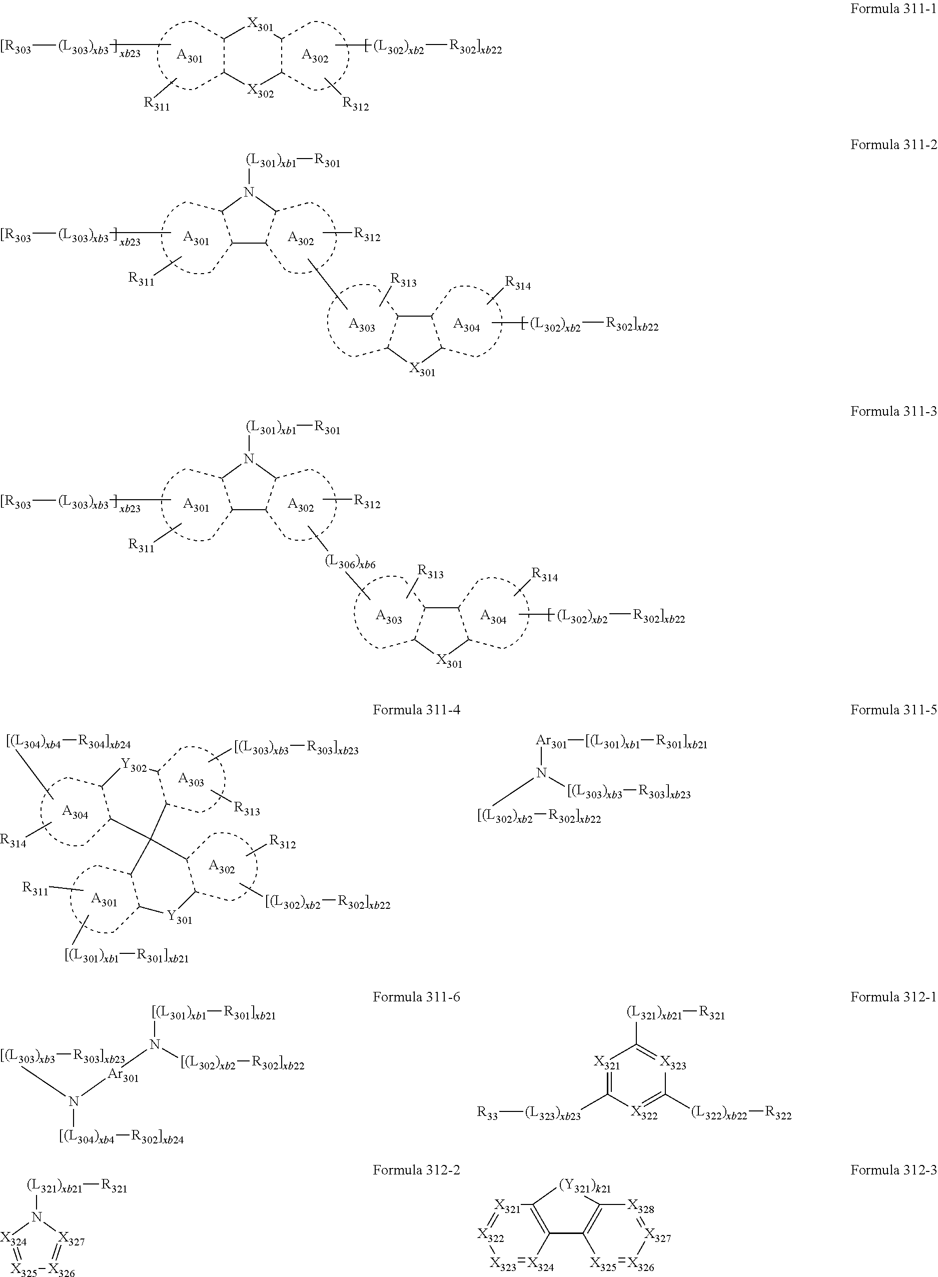

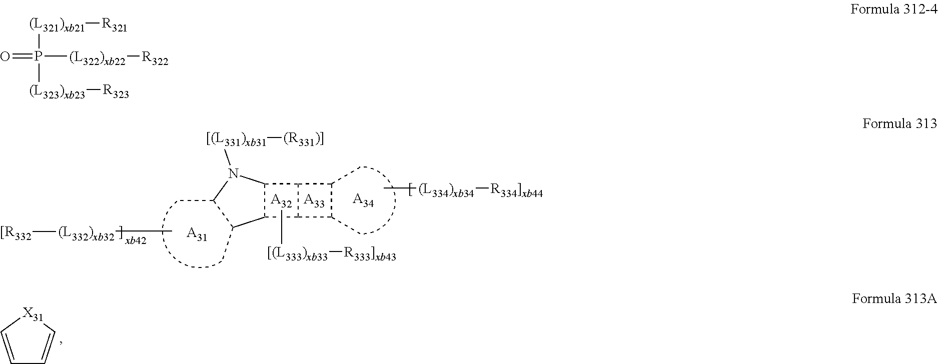

wherein, in Formulae 311-1 to 311-6, 312-1 to 312-4, 313, and 313A,
Ar₃₀₁ may be a C₃-C₆₀ carbocyclic group unsubstituted or substituted with at least one R₁₀ₐ or a C₁-C₆₀ heterocyclic group unsubstituted or substituted with at least one R₁₀ₐ,
A₃₀₁ to A₃₀₄ may each independently be a C₃-C₆₀ carbocyclic group or a C₁-C₆₀ heterocyclic group,
X₃₀₁ may be O, S, N[(L₃₀₄)_{xb4}-R₃₀₄], C[(L₃₀₄)_{xb4}-R₃₀₄][(L₃₀₅)_{xb5}-R₃₀₅], or Si[(L₃₀₄)_{xb4}-R₃₀₄][(L₃₀₅)_{xb5}-R₃₀₅],
X₃₀₂, Y₃₀₁, and Y₃₀₂ may each independently be a single bond, O, S, N[(L₃₀₅)_{xb5}-R₃₀₅], C[(L₃₀₄)_{xb4}-R₃₀₄][(L₃₀₅)_{xb5}-R₃₀₅], Si[(L₃₀₄)_{xb4}-R₃₀₄][(L₃₀₅)_{xb5}-R₃₀₅], or S(═O)₂,
xb1 to xb5 may each independently be 0, 1, 2, 3, 4, or 5,
xb6 may be 1, 2, 3, 4, or 5,
X₃₂₁ to X₃₂₈ may each independently be N or C[(L₃₂₄)_{xb24}-R₃₂₄],
Y₃₂₁ may be *—O—*′, *—S—*′, *—N[(L₃₂₅)_{xb25}-R₃₂₅]—*′, *—C[(L₃₂₅)_{xb25}-R₃₂₅][(L₃₂₆)_{xb26}-R₃₂₆]—*′, *—C[(L₃₂₅)_{xb25}-R₃₂₅]═C[(L₃₂₆)_{xb26}-R₃₂₆]—*′, *—C[(L₃₂₅)_{xb25}-R₃₂₅]═N—*′, or *—N═C[(L₃₂₆)_{xb26}-R₃₂₆]—*′,
k21 may be 0, 1, or 2, wherein, if (e.g., when) k21 is 0, Y₃₂₁ may not be present,
xb21 to xb26 may each independently be 0, 1, 2, 3, 4, or 5,
A₃₁, A₃₂, and A₃₄ may each independently be a C₃-C₆₀ carbocyclic group or a C₁-C₃₀ heterocyclic group,
A₃₃ may be a group represented by Formula 313 Å,
X₃₁ may be N[(L₃₃₅)_{xb35}-(R₃₃₅)], O, S, Se, C[(L₃₃₅)_{xb35}-(R₃₃₅)][(L₃₃₆)_{xb36}-(R₃₃₆)], or Si[(L₃₃₅)_{xb35}-(R₃₃₅)][(L₃₃₆)_{xb36}-(R₃₃₆)],
xb31 to xb36 may each independently be 0, 1, 2, 3, 4, or 5,
xb42 to xb44 may each independently be 0, 1, 2, 3, 4, 5, 6, 7, 8, 9, or 10,
L₃₀₁ to L₃₀₆, L₃₂₁ to L₃₂₆, and L₃₃₁ to L₃₃₆ may each independently be a single bond, a C₁-C₂₀ alkylene group unsubstituted or substituted with at least one R₁₀ₐ, a C₂-C₂₀ alkenylene group unsubstituted or substituted with at least one R₁₀ₐ, a C₂-C₂₀ alkynylene group unsubstituted or substituted with at least one R₁₀ₐ, a C₃-C₁₀ cycloalkylene group unsubstituted or substituted with at least one R₁₀ₐ, a C₁-C₁₀ heterocycloalkylene group unsubstituted or substituted with at least one R₁₀ₐ, a C₃-C₁₀ cycloalkenylene group unsubstituted or substituted with at least one R₁₀ₐ, a C₁-C₁₀ heterocycloalkenylene group unsubstituted or substituted with at least one R₁₀ₐ, a C₆-C₆₀ arylene group unsubstituted or substituted with at least one R₁₀ₐ, a C₁-C₆₀ heteroarylene group unsubstituted or substituted with at least one R₁₀ₐ, a divalent non-aromatic condensed polycyclic group unsubstituted or substituted with at least one R₁₀ₐ, or a divalent non-aromatic condensed heteropolycyclic group unsubstituted or substituted with at least one R₁₀ₐ,
R₃₀₁ to R₃₀₅, R₃₁₁ to R₃₁₄, R₃₂₁ to R₃₂₆, and R₃₃₁ to R₃₃₆ may each independently be hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂),
neighboring two or more selected from among R₃₂₁ to R₃₂₄ may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

In one or more embodiments, the first host compound and the second host compound may form an exciplex.

### Phosphorescent Dopant

The emission layer may further include a phosphorescent dopant.

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In one or more embodiments, the phosphorescent dopant may include an organometallic compound represented by Formula 401:

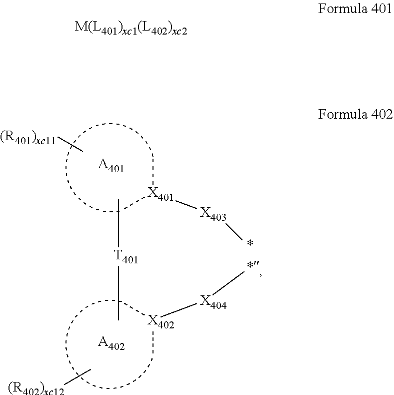

wherein, in Formulae 401 and 402,
M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, when xc1 is 2 or more, two or more of L₄₀₁ may be identical to or different from each other,
L₄₀₂ may be an organic ligand, and xc2 may be 0, 1, 2, 3, or 4, wherein, when xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)═*′, or *═C═*′,
X₄₀₃ and X₄₀₄ may each independently be a chemical bond (e.g., a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ are each independently as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ are each independently as described in connection with Q₁,
xc11 and xc12 may each independently be an integer from 0 to 10, and
* and *′ in Formula 402 each indicate a binding site to M in Formula 401.

In one or more embodiments, in Formula 402, i) X₄₀₁ may be nitrogen, and X₄₀₂ may be carbon, or ii) each of X₄₀₁ and X₄₀₂ may be nitrogen.

In one or more embodiments, when xc1 in Formula 401 is 2 or more, two rings A₄₀₁ among two or more of L₄₀₁ may optionally be linked to each other via T₄₀₂, which is a linking group, and/or two rings A₄₀₂ among two or more of L₄₀₁ may optionally be linked to each other via T₄₀₃, which is a linking group (see e.g., Compounds PD1 to PD4 and PD7). T₄₀₂ and T₄₀₃ are each independently as described in connection with T₄₀₁.

L₄₀₂ in Formula 401 may be an organic ligand. For example, L₄₀₂ may include a halogen group, a diketone group (e.g., an acetylacetonate group), a carboxylic acid group (e.g., a picolinate group), —C(═O), an isonitrile group, a —CN group, a phosphorus-containing group (e.g., a phosphine group, a phosphite group, and/or the like), or any combination thereof.

The phosphorescent dopant may include, for example, one selected from among Compounds PD1 to PD40, or any combination thereof:

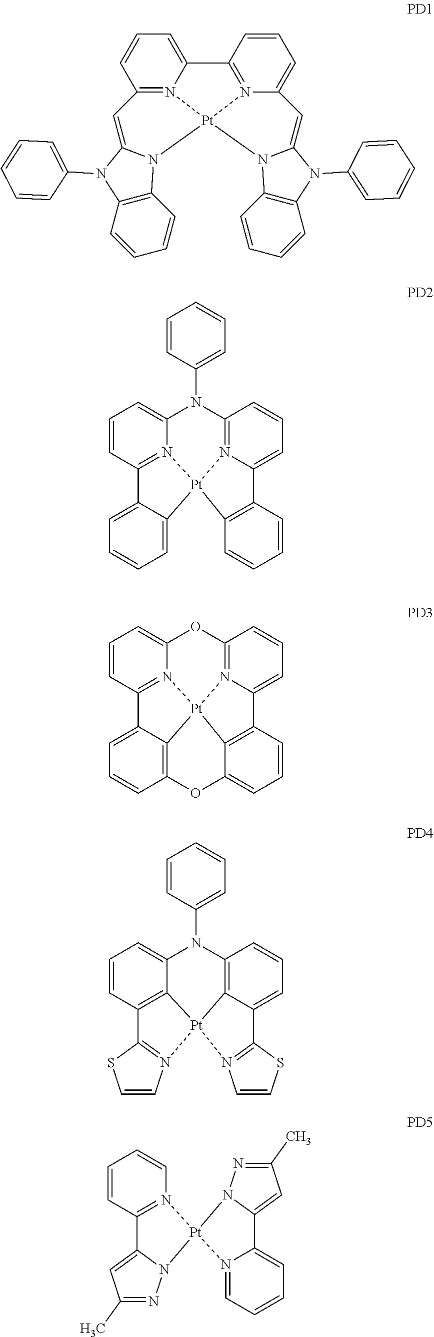

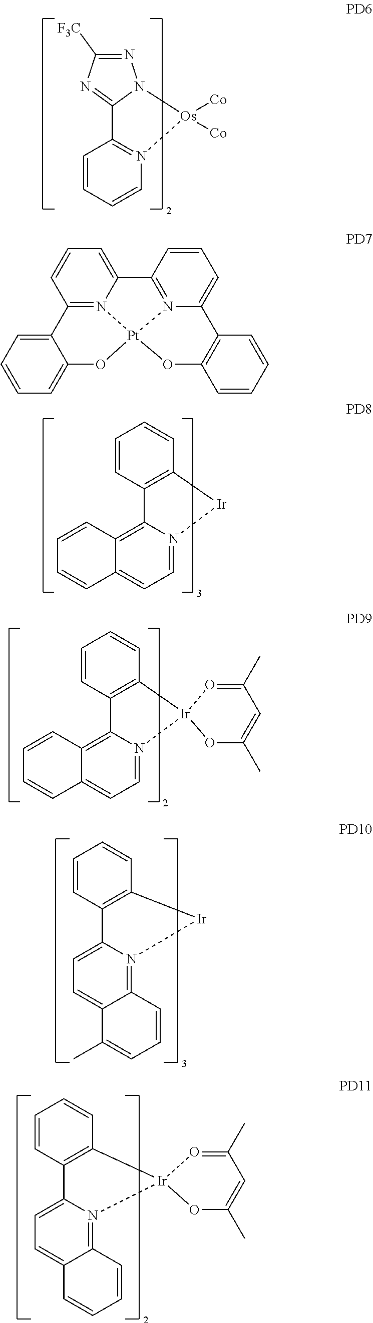

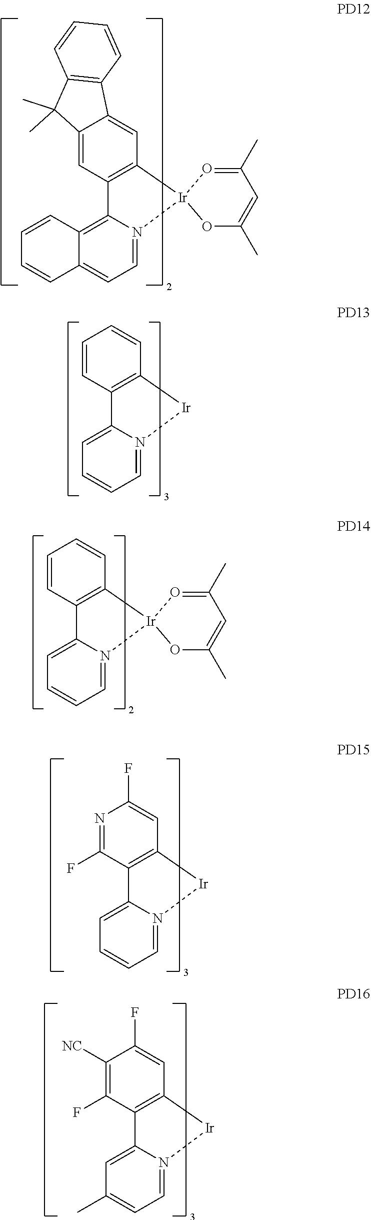

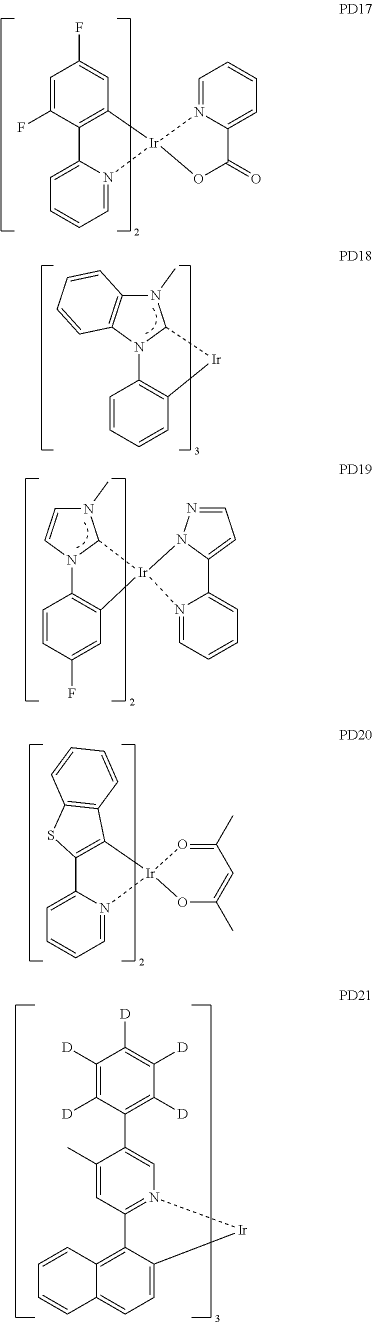

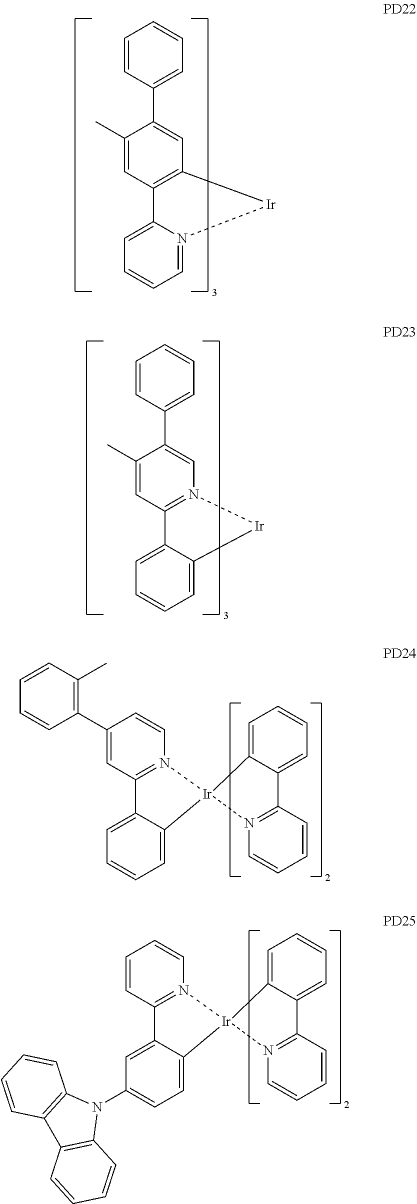

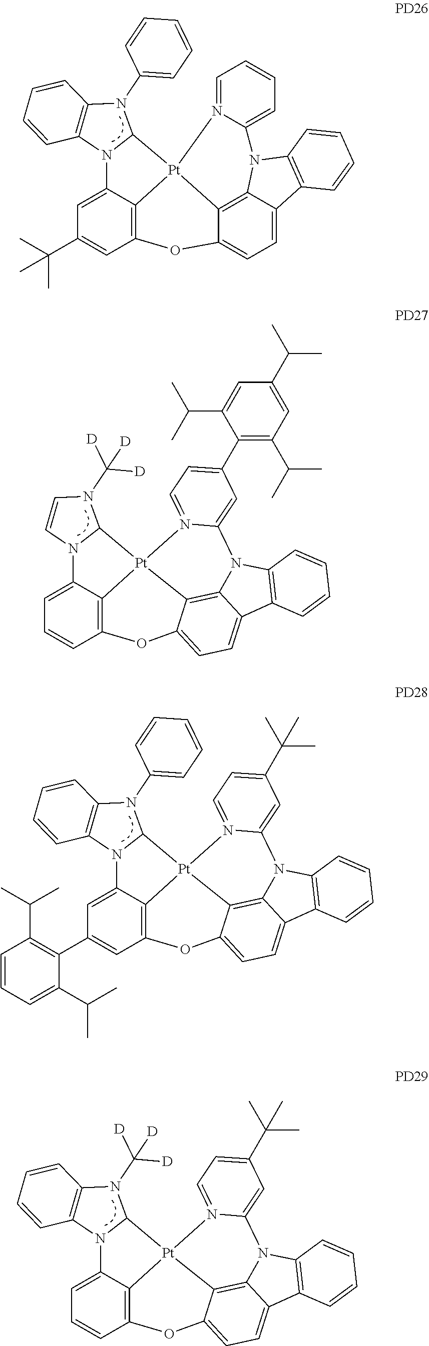

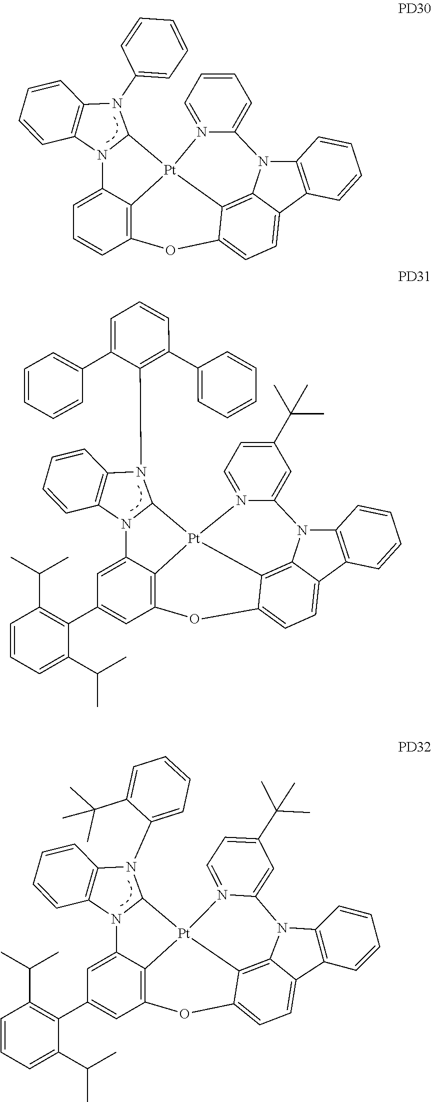

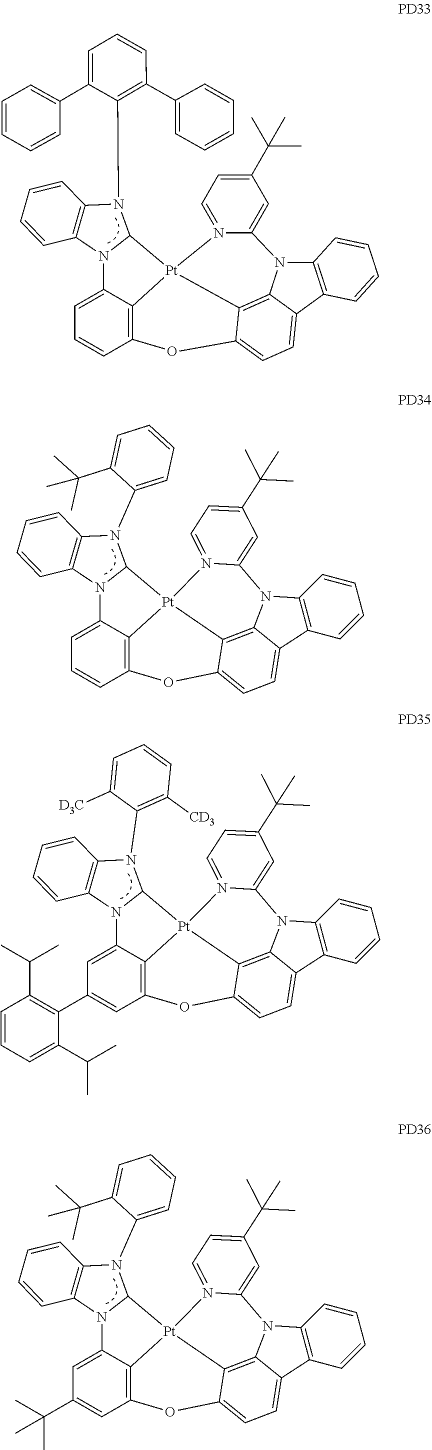

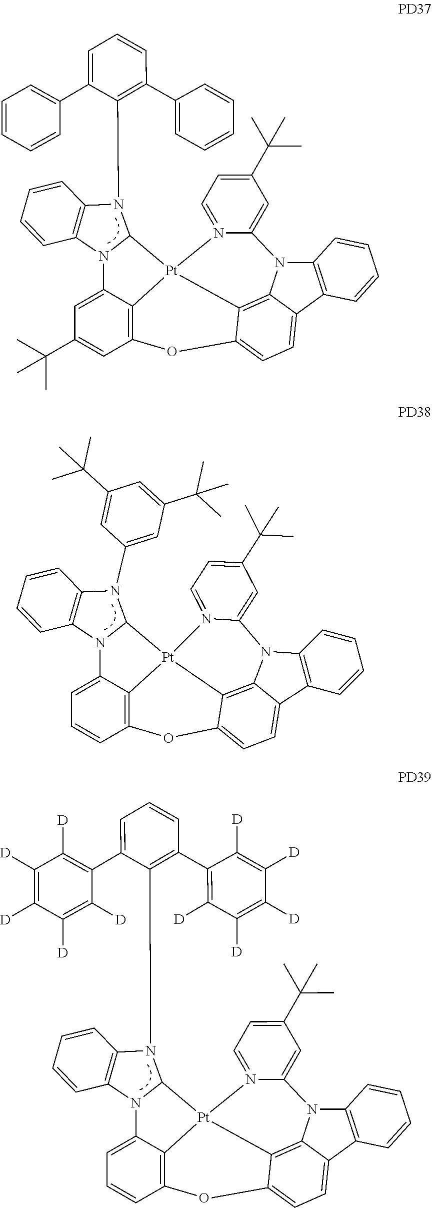

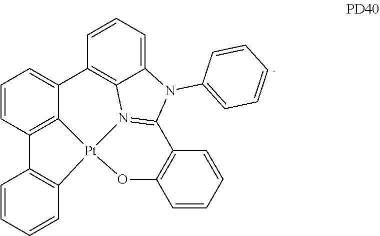

### Fluorescent Dopant

The emission layer may further include a fluorescent dopant.

The fluorescent dopant may include an amine group-containing compound, a styryl group-containing compound, or any combination thereof.

In one or more embodiments, the fluorescent dopant may include a compound represented by Formula 501:

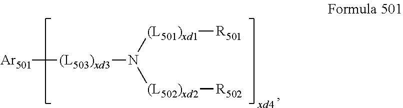

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In one or more embodiments, Ar₅₀₁ in Formula 501 may be a condensed cyclic group (e.g., an anthracene group, a chrysene group, a pyrene group, and/or the like) in which three or more monocyclic groups are condensed with each other.

In one or more embodiments, xd4 in Formula 501 may be 2.

In one or more embodiments, the fluorescent dopant may include one selected from among Compounds FD1 to FD36, DPVBi, DPAVBi, or any combination thereof:

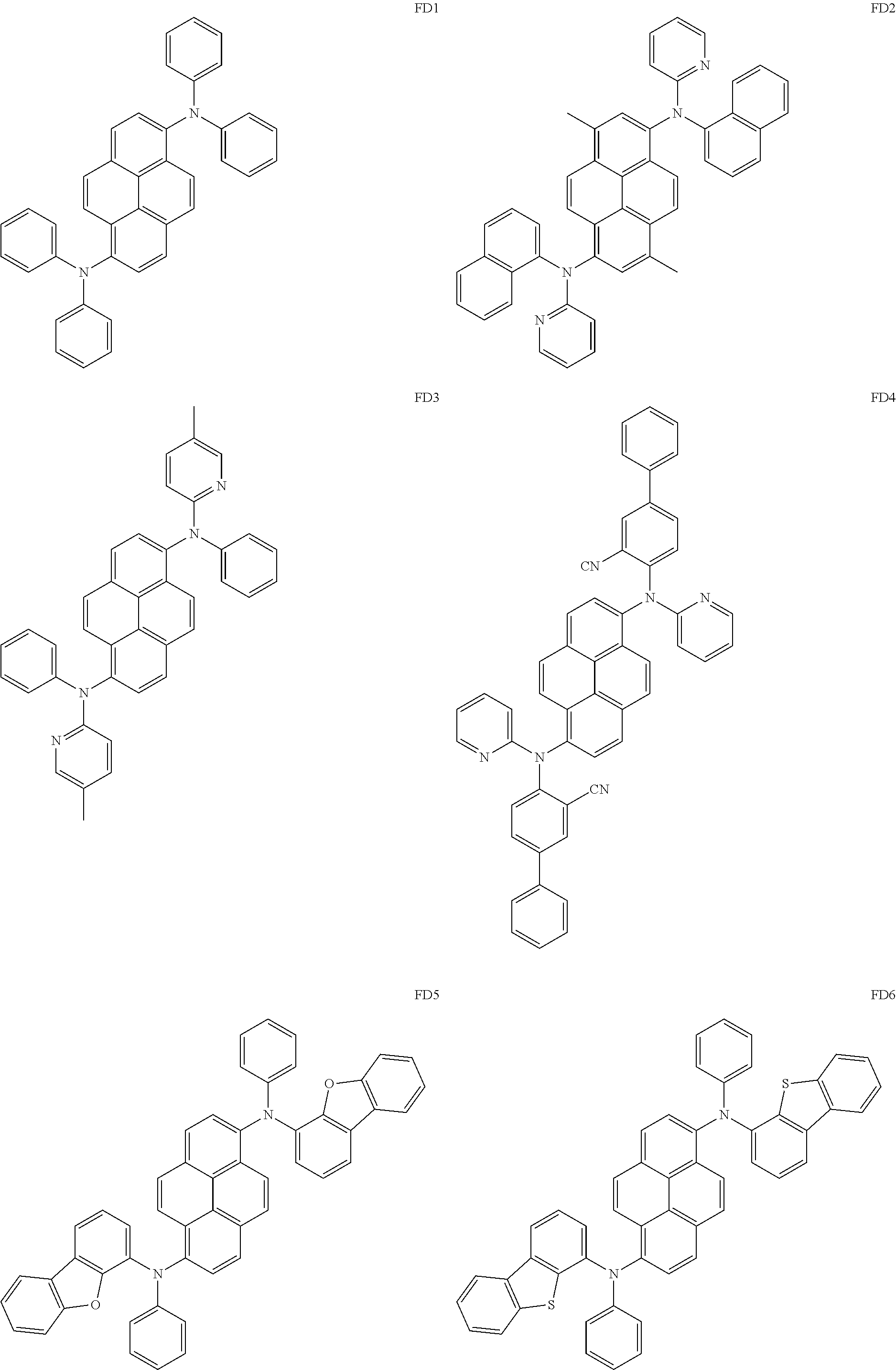

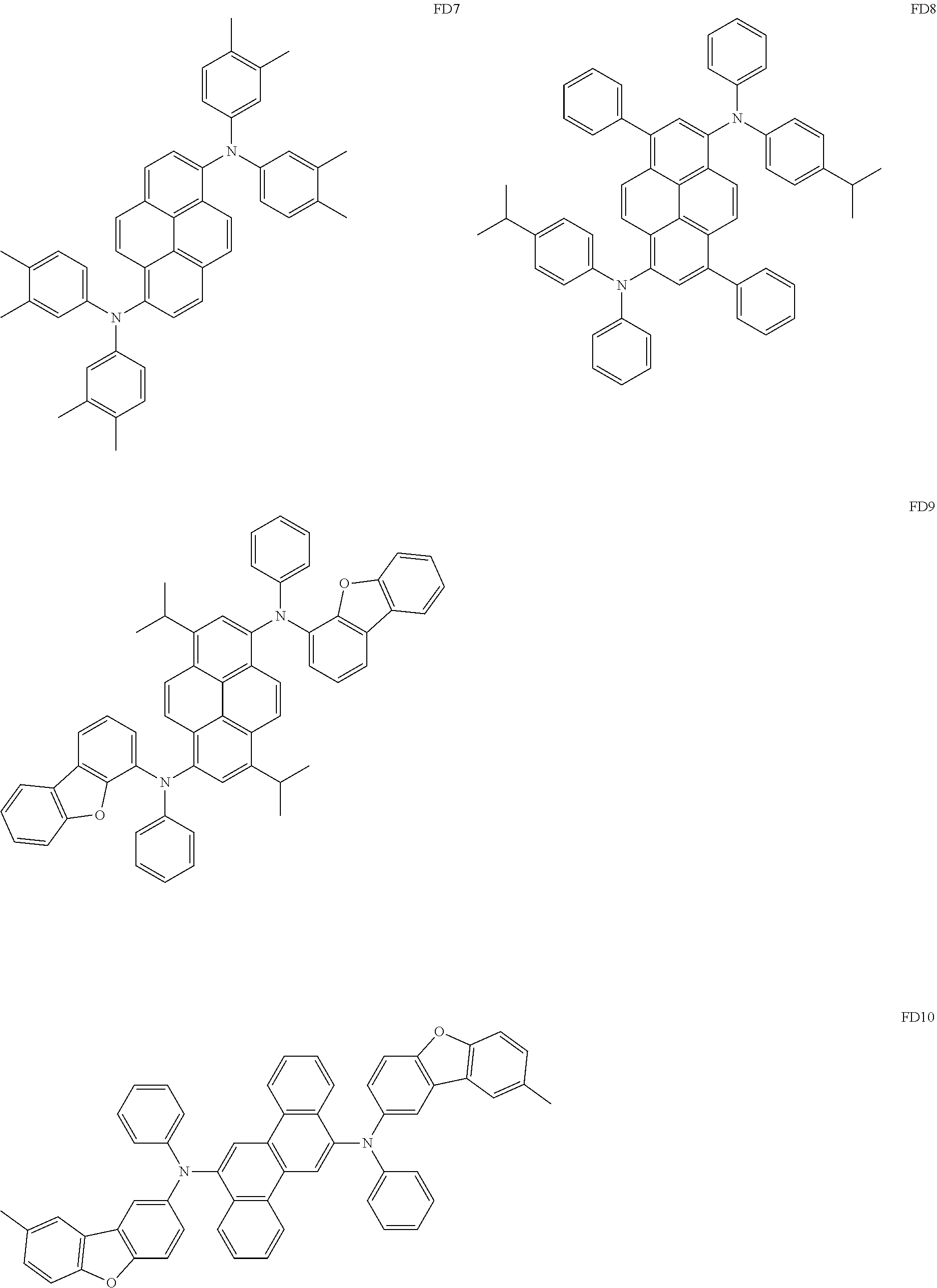

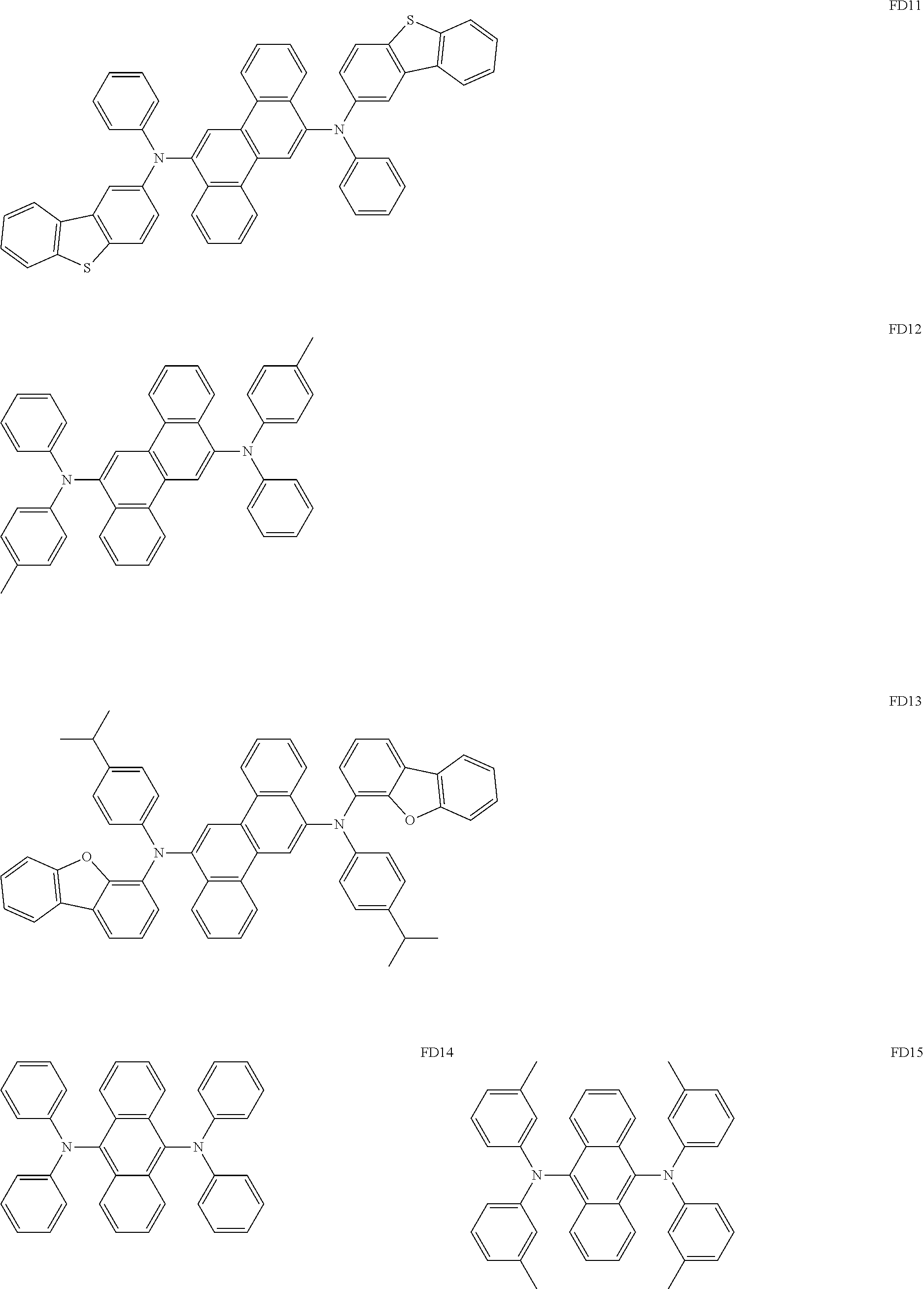

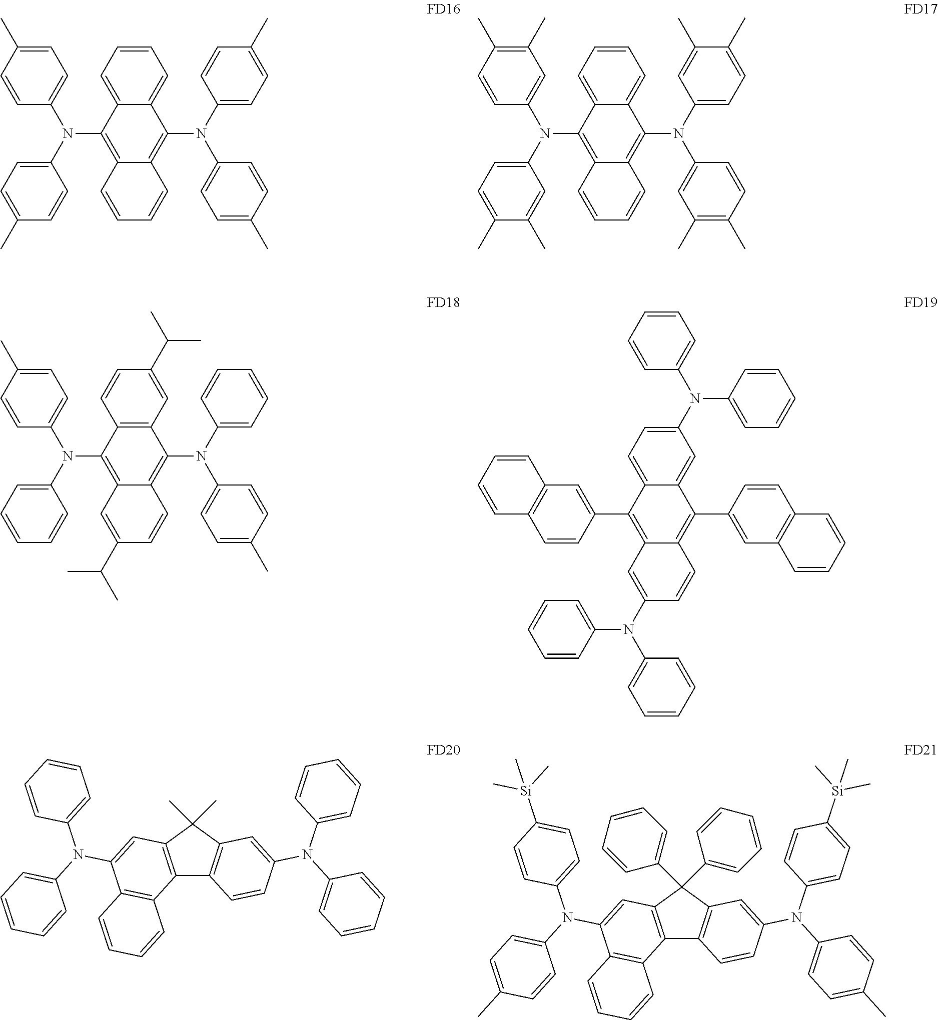

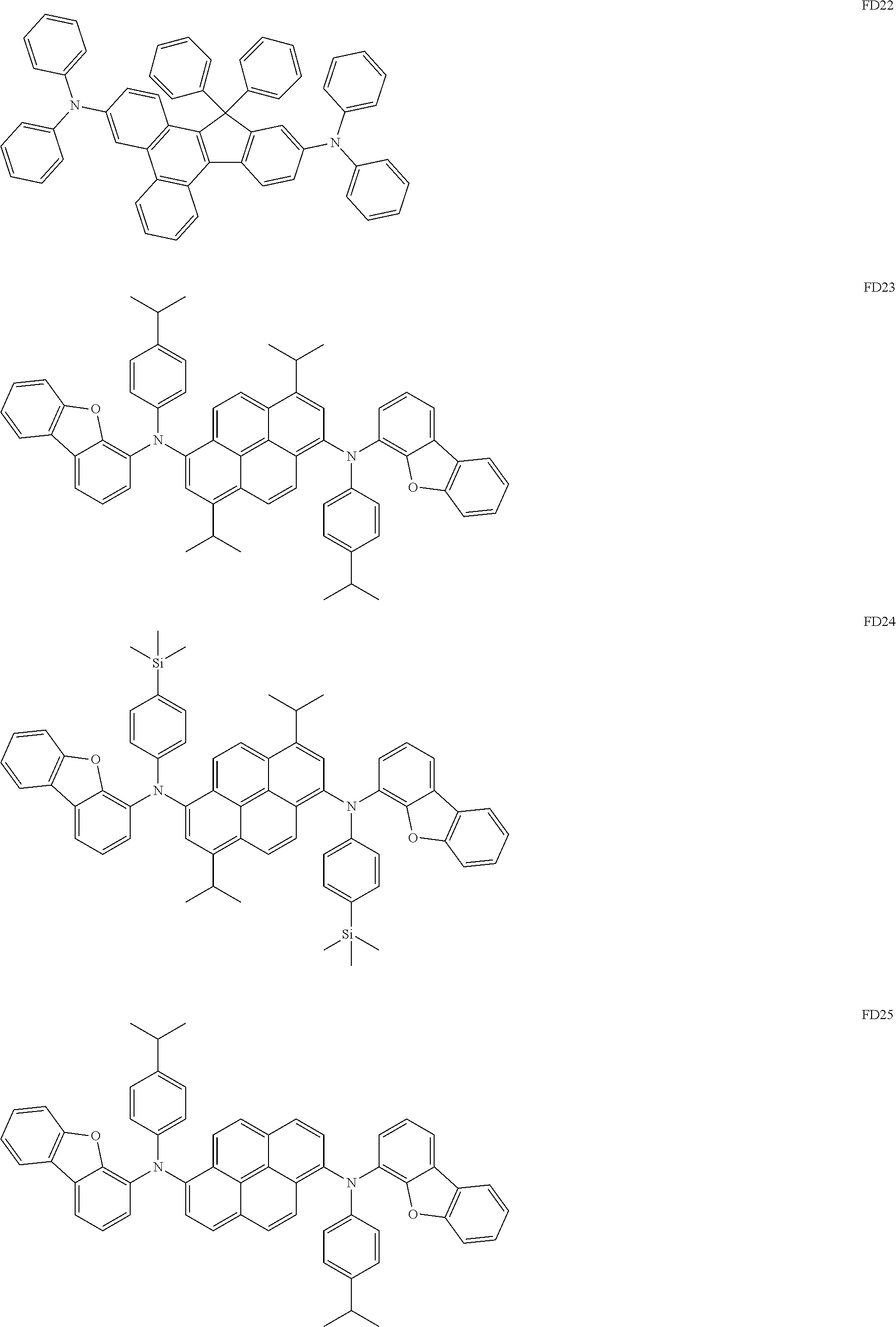

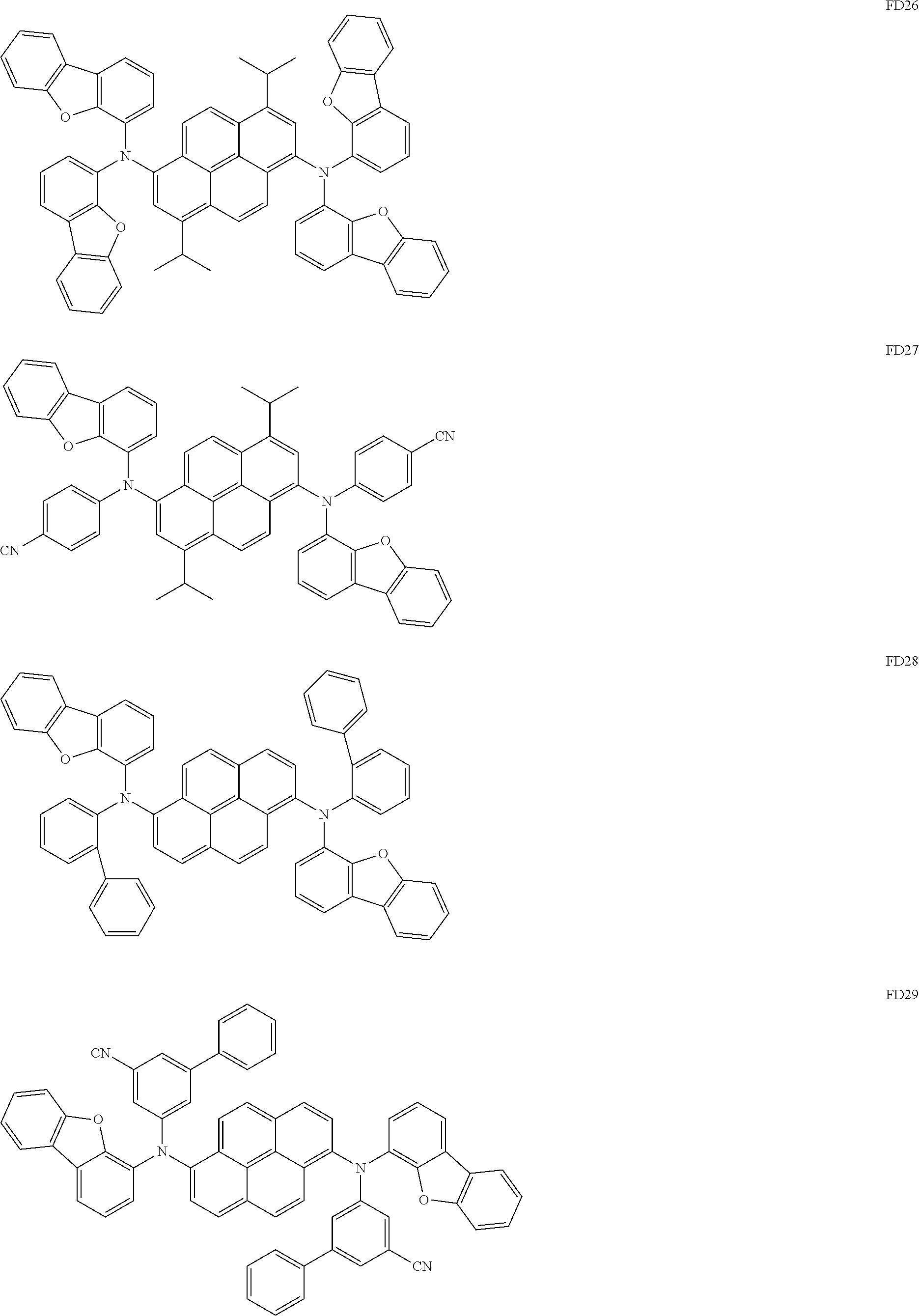

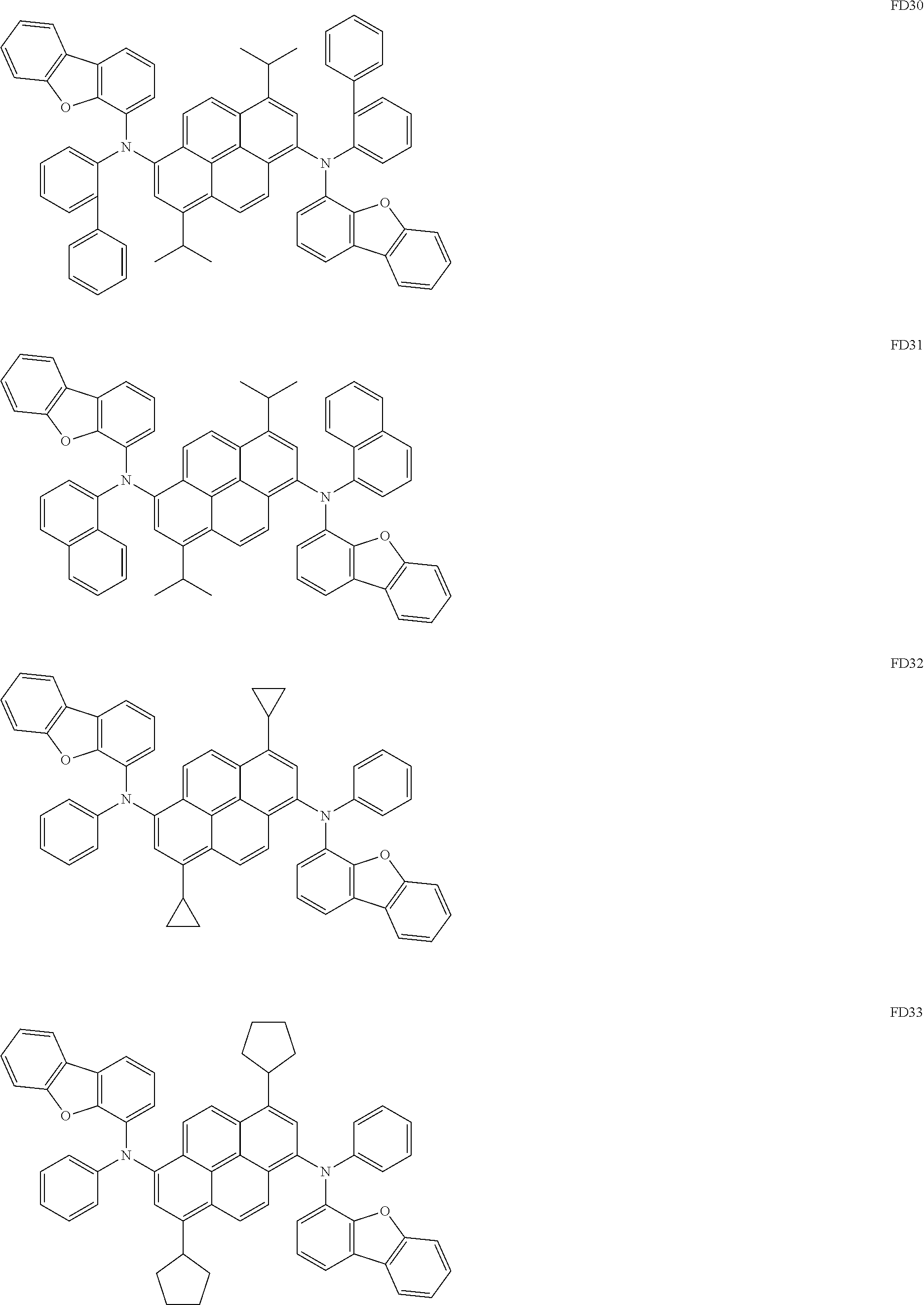

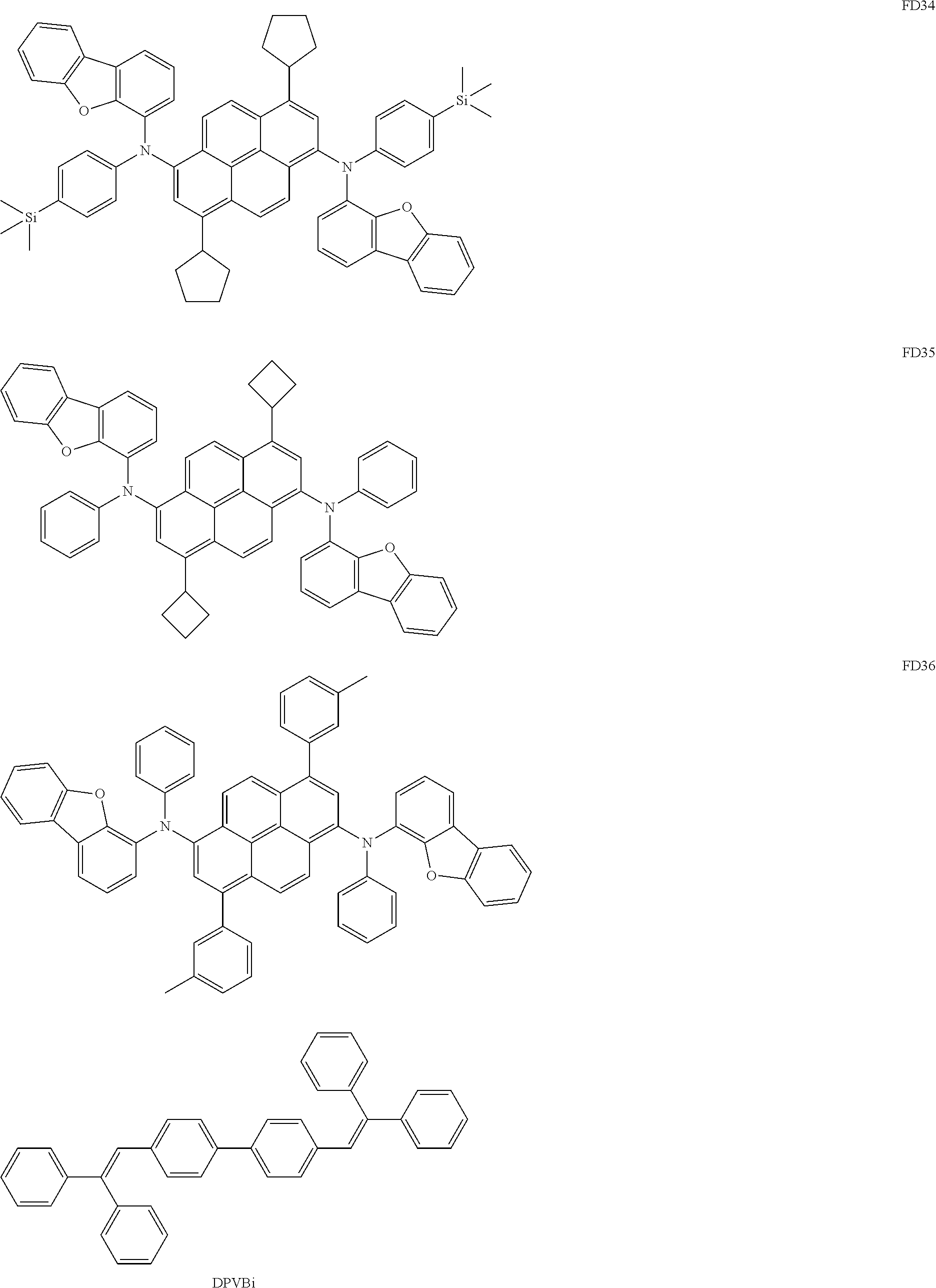

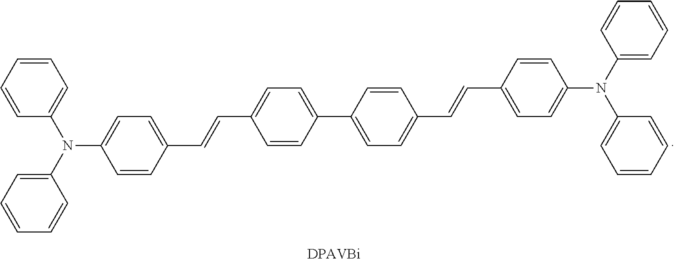 [SMILES: C(=C\c1ccc(N(c2ccccc2)c2ccccc2)cc1)/c1ccc(-c2ccc(/C=C/c3ccc(N(c4ccccc4)c4ccccc4)cc3)cc2)cc1]

### Delayed Fluorescence Material

The emission layer may include a delayed fluorescence material.

In one or more embodiments, the condensed cyclic compound represented by Formula 1 may be a delayed fluorescence material.

The delayed fluorescence material described herein may be selected from among compounds capable of emitting delayed fluorescence based on a delayed fluorescence emission mechanism.

The delayed fluorescence material included in the emission layer may act as a host or a dopant depending on the type or kind of other materials included in the emission layer.

In one or more embodiments, a difference between a triplet energy level (eV) of the delayed fluorescence material and a singlet energy level (eV) of the delayed fluorescence material may be in a range of 0 eV to about 0.5 eV. When the difference between the triplet energy level (eV) of the delayed fluorescence material and the singlet energy level (eV) of the delayed fluorescence material is within the range described above, up-conversion from the triplet state to the singlet state of the delayed fluorescence material may effectively or suitably occur, and thus, the light-emitting device 10 may have improved luminescence efficiency.

In one or more embodiments, the delayed fluorescence material may include i) a material including at least one electron donor (e.g., a π electron-rich C₃-C₆₀ cyclic group such as a carbazole group, and/or the like) and at least one electron acceptor (e.g., a sulfoxide group, a cyano group, a π electron-deficient nitrogen-containing C₁-C₆₀ cyclic group, and/or the like), ii) a material including a C₈-C₆₀ polycyclic group in which two or more cyclic groups are condensed while sharing boron (B), and/or the like.

In one or more embodiments, the delayed fluorescence material may include at least one selected from among Compounds DF1 to DF14:

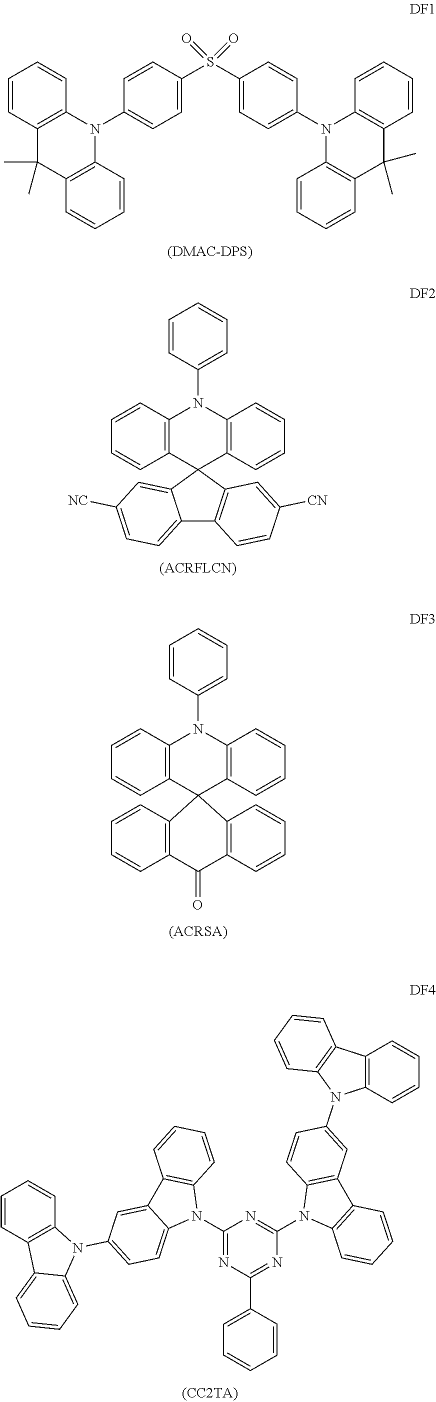

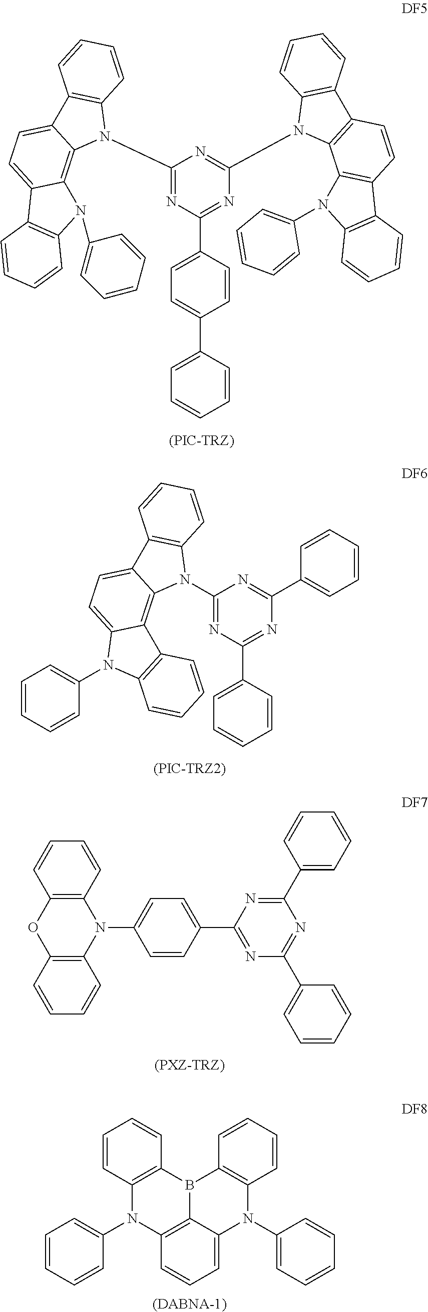

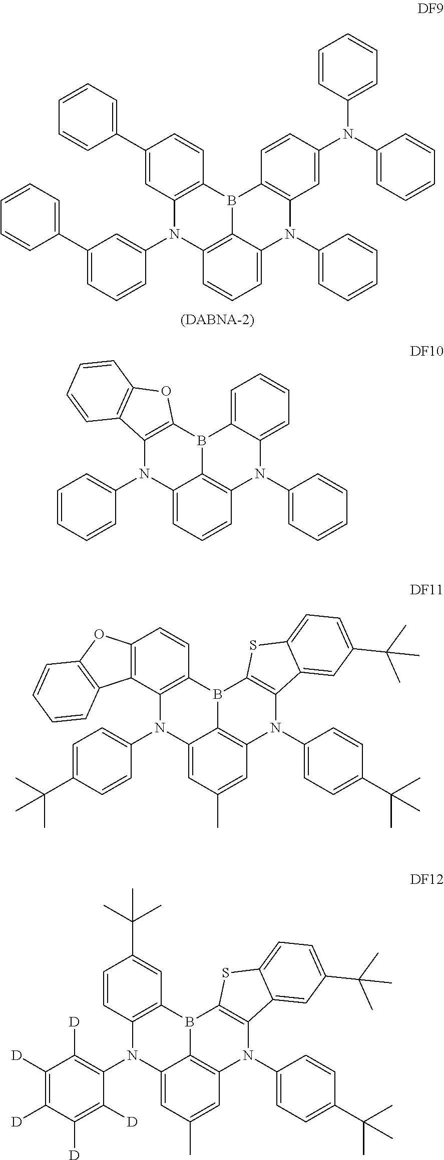

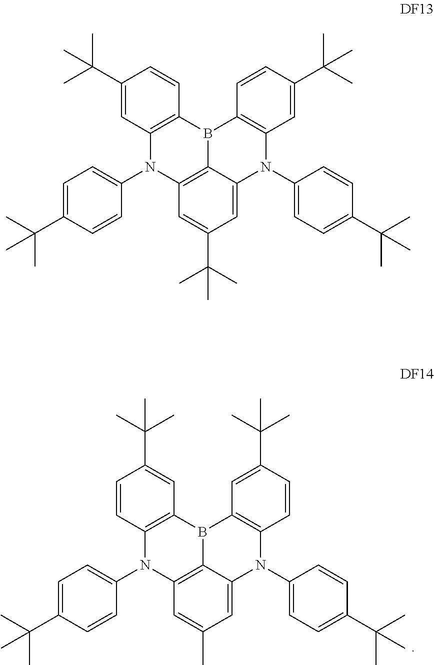

### Quantum Dots

The emission layer may include quantum dots.

The term “quantum dot” as used herein may refer to a crystal of a semiconductor compound. Quantum dots may be to emit light of one or more suitable emission wavelengths depending on the size of crystals. Quantum dots may be to emit light of one or more suitable emission wavelengths by adjusting the ratio of elements in the quantum dot compound.

The diameter of the quantum dots may be, for example, in a range of about 1 nm to about 10 nm.

The quantum dots may be synthesized by a wet chemical process, a metal organic chemical vapor deposition (MOCVD) process, a molecular beam epitaxy (MBE) process, or any suitable process similar thereto.

The wet chemical process is a method including mixing a precursor material with an organic solvent and then growing quantum dot particle crystals. When the quantum dot particle crystals grow, the organic solvent may naturally act as a dispersant coordinated on the surface of the quantum dot particle crystals, and may control the growth of the quantum dot particle crystals. Accordingly, in the wet chemical process, the growth of quantum dot particle crystals may be controlled or selected through a process which costs lower and is easier than a vapor deposition method, such as metal organic chemical vapor deposition (MOCVD) or molecular beam epitaxy (MBE).

The quantum dots may include: a Group II-VI semiconductor compound; a Group III-V semiconductor compound; a Group III-VI semiconductor compound; a Group I-III-VI semiconductor compound; a Group IV-VI semiconductor compound; a Group IV element and/or compound; or any combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound, such as CdZnSeS, CdZnSeTe, CdZnSTe, CdHgSeS, CdHgSeTe, CdHgSTe, HgZnSeS, HgZnSeTe, and/or HgZnSTe; or any combination thereof.

Examples of the Group III-V semiconductor compound may include: a binary compound, such as GaN, GaP, GaAs, GaSb, AlN, AlP, AlAs, AISb, InN, InP, InAs, and/or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb; a quaternary compound, such as GaAINP, GaAINAs, GaAINSb, GaAlPAs, GaAlPSb, GaInNP, GaInNAs, GaInNSb, GaInPAs, GaInPSb, InAlNP, InAlNAs, InAlNSb, InAlPAs, and/or InAlPSb; or any combination thereof. In one or more embodiments, the Group III-V semiconductor compound may further include a Group II element. Examples of the Group III-V semiconductor compound further including a Group II element may include InZnP, InGaZnP, InAlZnP, and/or the like.

Examples of the Group III-VI semiconductor compound may include: a binary compound, such as GaS, Ga₂S₃, GaSe, Ga₂Se₃, GaTe, InS, InSe, In₂Se₃, and/or InTe; a ternary compound, such as InGaS₃ and/or InGaSe₃; or any combination thereof.

Examples of the Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and/or AgAlO₂; a quaternary compound, such as AgInGaS, AgInGaS₂, AgInGaSe, AgInGaSe₂, CuInGaS and/or AgInGaSe₂; or any combination thereof.

Examples of the Group IV-VI semiconductor compound may include: a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, and/or SnPbTe; a quaternary compound, such as SnPbSSe, SnPbSeTe, and/or SnPbSTe; or any combination thereof.

The Group IV element and/or compound may include: a single element, such as Si and/or Ge; a binary compound, such as SiC and/or SiGe; or any combination thereof.

Each element included in a multi-element compound, such as the binary compound, the ternary compound, and/or the quaternary compound, may be present at a substantially uniform concentration or a substantially non-uniform concentration in a particle. For example, the formulae above refer to the types (kinds) of elements included in the compound, wherein the ratio of elements in the compound may suitably vary. For example, AgInGaS₂ may refer to AgInₓGa₁₋ₓS₂ (wherein x is a real number between 0 and 1).

In one or more embodiments, the quantum dots may have a single structure in which the concentration of each element in the quantum dots is substantially uniform, or a core-shell dual structure. For example, a material included in the core and a material included in the shell may be different from each other.

The shell of the quantum dots may act as a protective layer that prevents or reduces chemical degeneration of the core to maintain semiconductor characteristics, and/or as a charging layer that imparts electrophoretic characteristics to the quantum dots. The shell may be a single layer or a multi-layer. The interface between the core and the shell may have a concentration gradient in which the concentration of an element existing in the shell decreases toward the center of the core.

Examples of the shell of the quantum dots may include an oxide of a metal, an oxide of a non-metal, a semiconductor compound, and/or any suitable combination thereof. Examples of the oxide of a metal and the oxide of a non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound, such as MgAl₂O₄, CoFe₂O₄, NiFe₂O₄, and/or CoMn₂O₄; or any combination thereof. Examples of the semiconductor compound may include: a Group III-VI semiconductor compound; a Group II-VI semiconductor compound; a Group III-V semiconductor compound; a Group III-VI semiconductor compound; a Group I-III-VI semiconductor compound; a Group IV-VI semiconductor compound; or any combination thereof, as described herein. For example, the semiconductor compound may include CdS, CdSe, CdTe, ZnS, ZnSe, ZnTe, ZnSeS, ZnSTe, GaAs, GaP, GaS, GaSe, AgGaS, AgGaS₂, GaSb, HgS, HgSe, HgTe, InAs, InP, InGaP, InSb, AlAs, AlP, AISb, or any combination thereof.

Each element included in a multi-element compound, such as the binary compound and/or the ternary compound, may be present at a substantially uniform concentration or a substantially non-uniform concentration in a particle. For example, the formulae above may refer to the types (kinds) of elements included in the compound, wherein the ratio of elements in the compound may suitably vary.

The quantum dots may have a full width at half maximum (FWHM) of an emission wavelength spectrum of about 45 nm or less, about 40 nm or less, or for example, about 30 nm or less. When the FWHM of an emission wavelength spectrum of the quantum dots is within any of these ranges, the quantum dots may have improved color purity and/or improved color reproducibility. In one or more embodiments, because light emitted through the quantum dots is emitted in all directions, the wide viewing angle may be improved.

In one or more embodiments, the quantum dots may be in the form of a spherical nanoparticle, a pyramidal nanoparticle, a multi-arm nanoparticle, a cubic nanoparticle, a nanotube, a nanowire, a nanofiber, a nanoplate, and/or the like.

Because the energy band gap may be controlled or selected by adjusting the size of the quantum dots and/or the ratio of elements in the quantum dot compound, light of one or more suitable wavelengths may be obtained from the quantum dot-containing emission layer. Accordingly, by using the quantum dots as described above (e.g., by using quantum dots of different sizes and/or by varying the ratio of elements in the quantum dot compound), a light-emitting device that emits light of one or more suitable wavelengths may be realized. For example, the control of the size of the quantum dots and/or the ratio of elements in the quantum dot compound may be selected to emit red light, green light, and/or blue light. In one or more embodiments, the size of the quantum dots may be configured to emit white light by combination of light of one or more suitable colors.

### Electron Transport Region in Interlayer 130

The electron transport region may have i) a single-layer structure including (e.g., consisting of) a single layer including (e.g., consisting of) a single material, ii) a single-layer structure including (e.g., consisting of) a single layer including multiple different materials, or iii) a multi-layer structure including multiple layers including multiple different materials.

The electron transport region may include a buffer layer, a hole-blocking layer, an electron control layer, an electron transport layer, an electron injection layer, or any combination thereof.

In one or more embodiments, the electron transport region may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, wherein constituent layers of each structure are sequentially stacked from the emission layer.

The electron transport region (e.g., the buffer layer, the hole-blocking layer, the electron control layer, and/or the electron transport layer in the electron transport region) may include a metal-free compound including at least one π electron-deficient nitrogen-containing C₁-C₆₀ cyclic group.

In one or more embodiments, the electron transport region may include a compound represented by Formula 601:

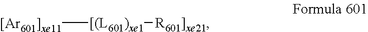

wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ are each independently as described in connection with Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ cyclic group unsubstituted or substituted with at least one R₁₀ₐ.

In one or more embodiments, when xe11 in Formula 601 is 2 or more, two or more of Ar₆₀₁ may be linked to each other via a single bond.

In one or more embodiments, Ar₆₀₁ in Formula 601 may be an anthracene group unsubstituted or substituted with at least one R₁₀ₐ.

In one or more embodiments, the electron transport region may include a compound represented by Formula 601-1:

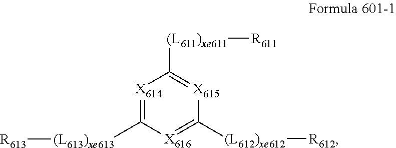

wherein, in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ are each independently as described in connection with L₆₀₁,
xe611 to xe613 are each independently as described in connection with xe1,
R₆₁₁ to R₆₁₃ are each independently as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In one or more embodiments, xe1 and xe611 to xe613 in Formulae 601 and 601-1 may each independently be 0, 1, or 2.

The electron transport region may include one selected from among Compounds ET1 to ET47, 2,9-dimethyl-4,7-diphenyl-1,10-phenanthroline (BCP), 4,7-diphenyl-1,10-phenanthroline (Bphen), Alq₃, BAlq, TAZ, NTAZ, TSPO1, TPBI, or any combination thereof:

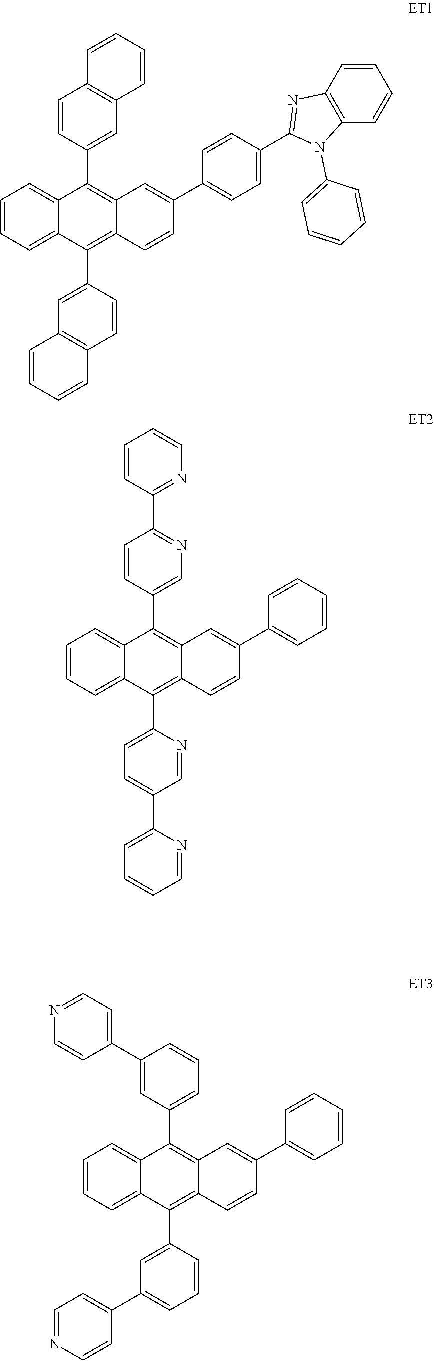 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)cn4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

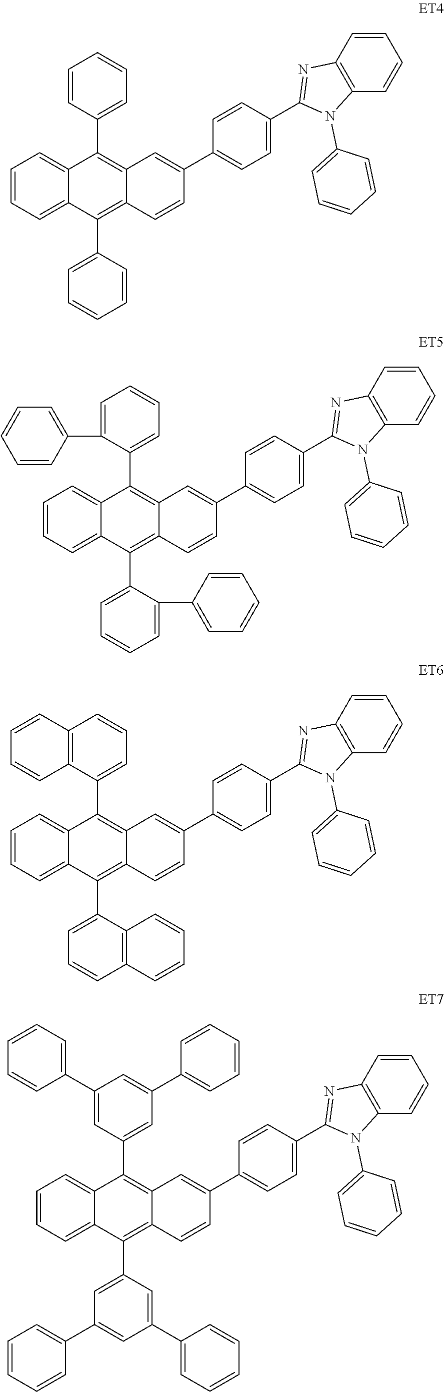 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

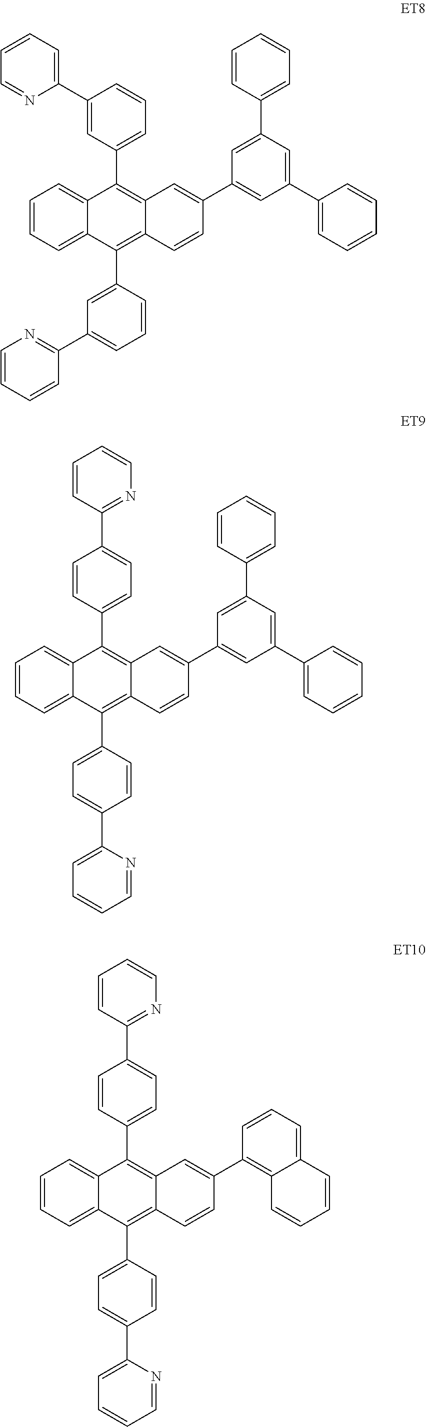 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

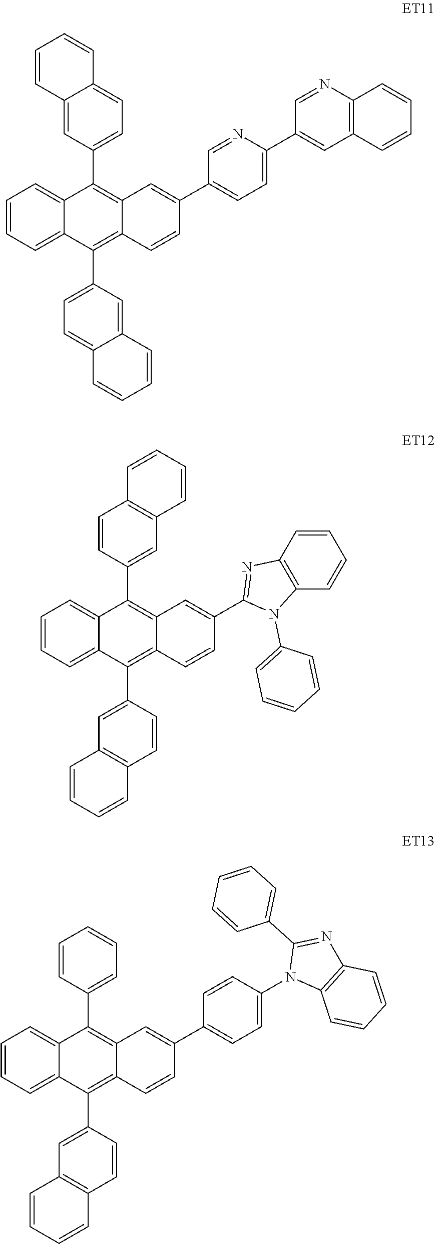 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

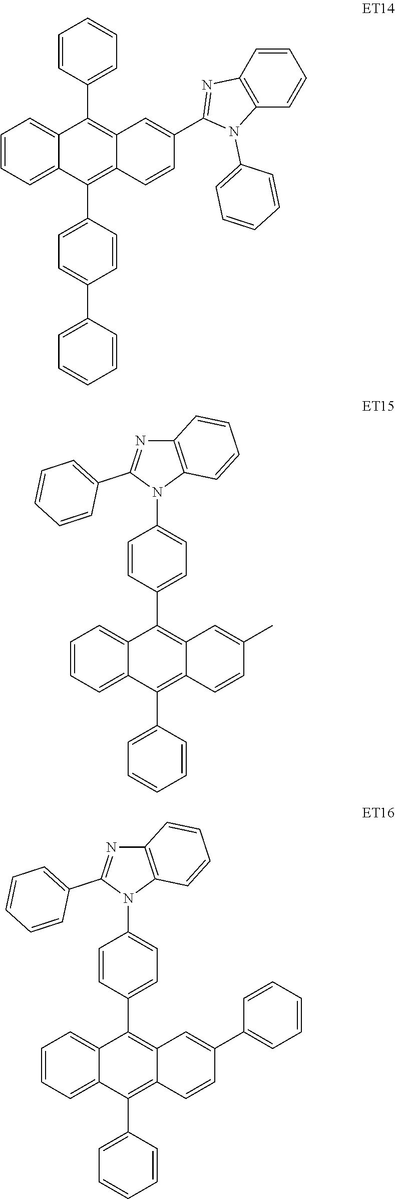

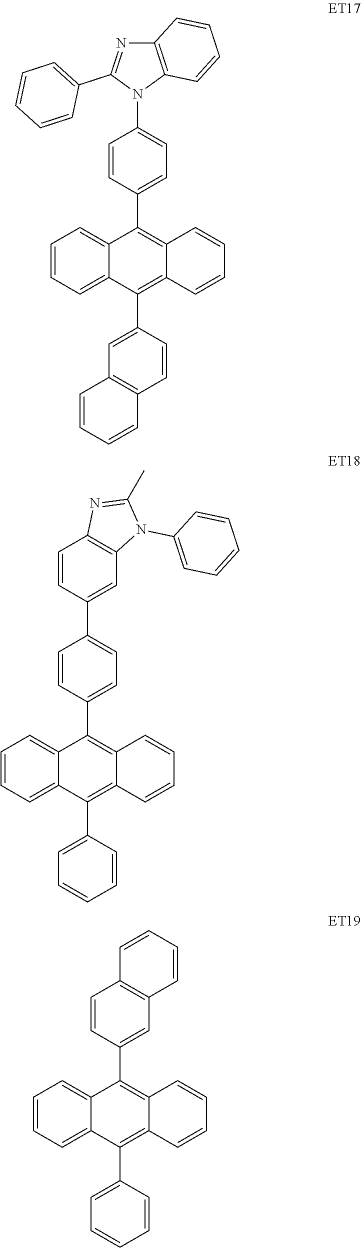

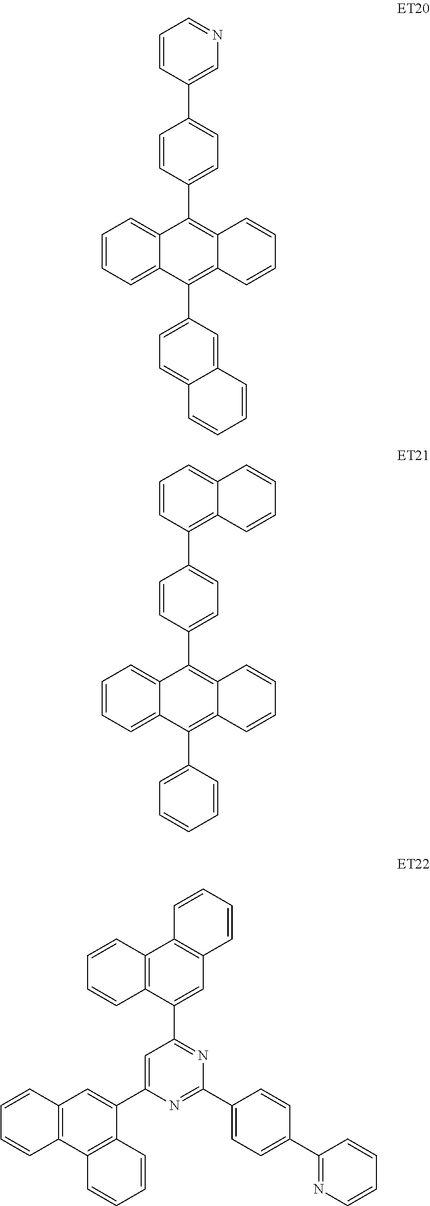

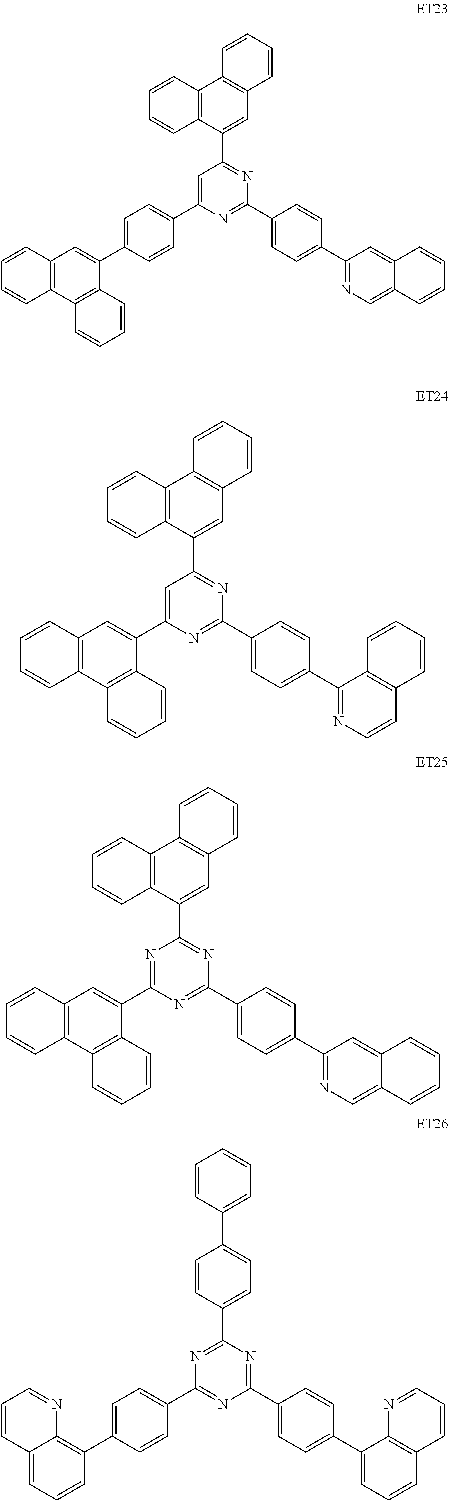 [SMILES: c1ccc2cc(-c3ccc(-c4nc(-c5ccc(-c6cc7ccccc7c7ccccc67)cc5)cc(-c5cc6ccccc6c6ccccc56)n4)cc3)ncc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2cc(-c3ccc(-c4nc(-c5cc6ccccc6c6ccccc56)nc(-c5cc6ccccc6c6ccccc56)n4)cc3)ncc2c1 ; c1ccc(-c2ccc(-c3nc(-c4ccc(-c5cccc6cccnc56)cc4)nc(-c4ccc(-c5cccc6cccnc56)cc4)n3)cc2)cc1]

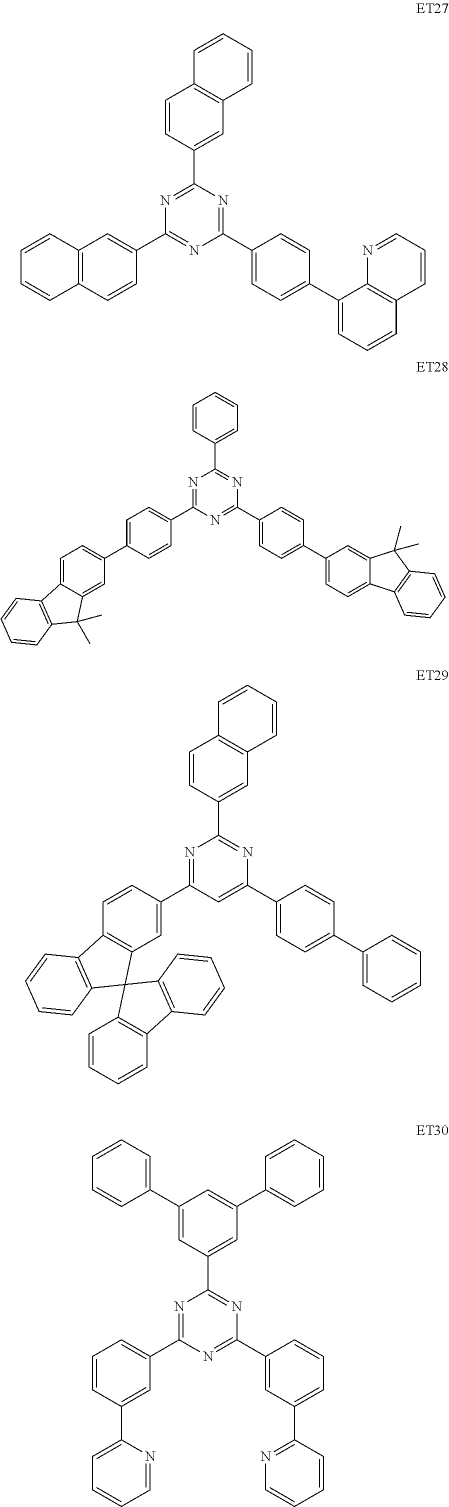 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

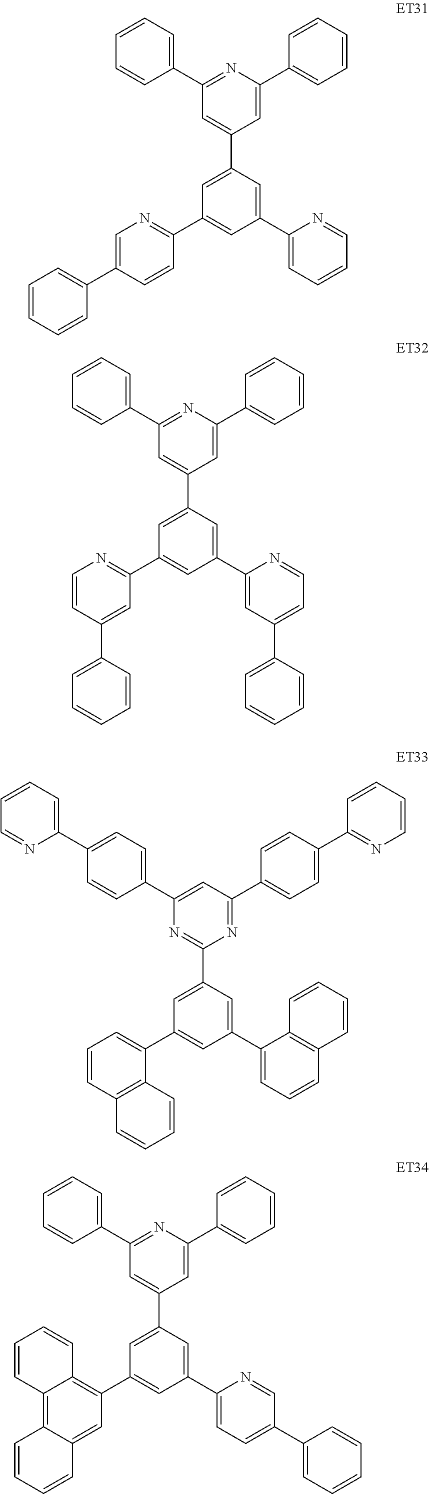

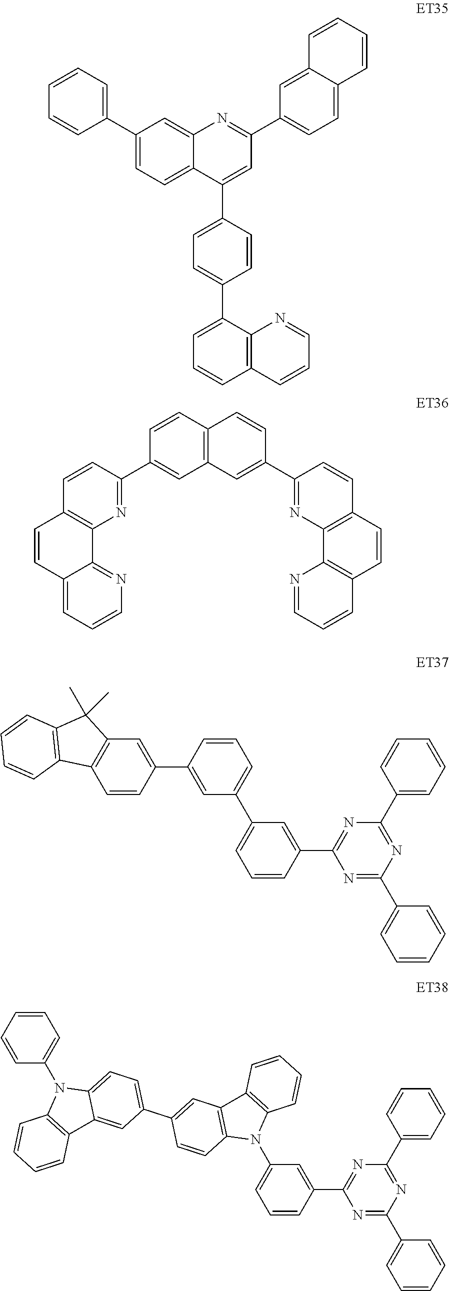

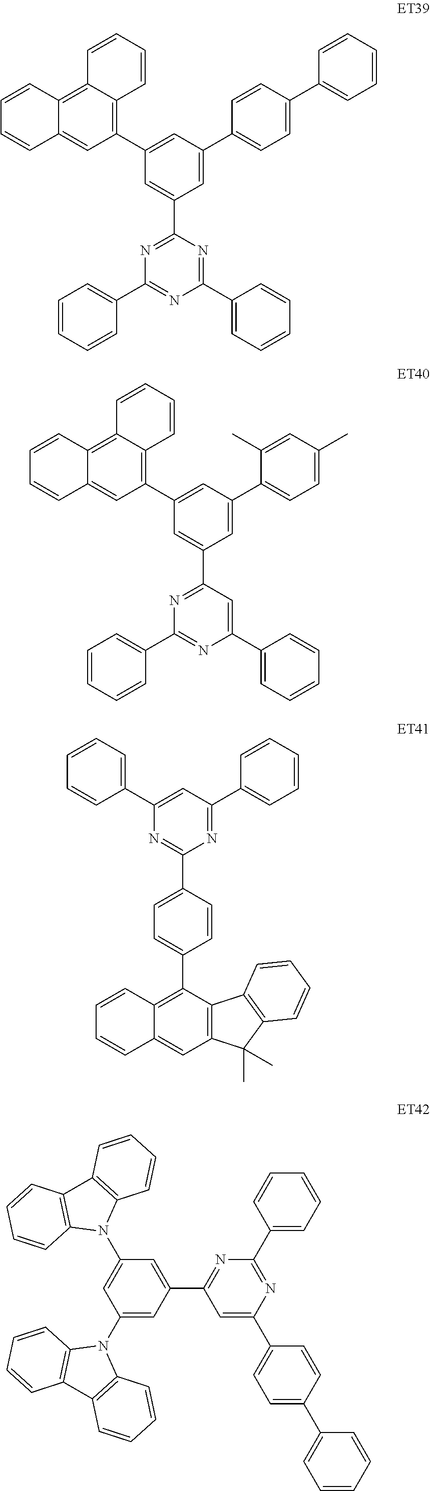

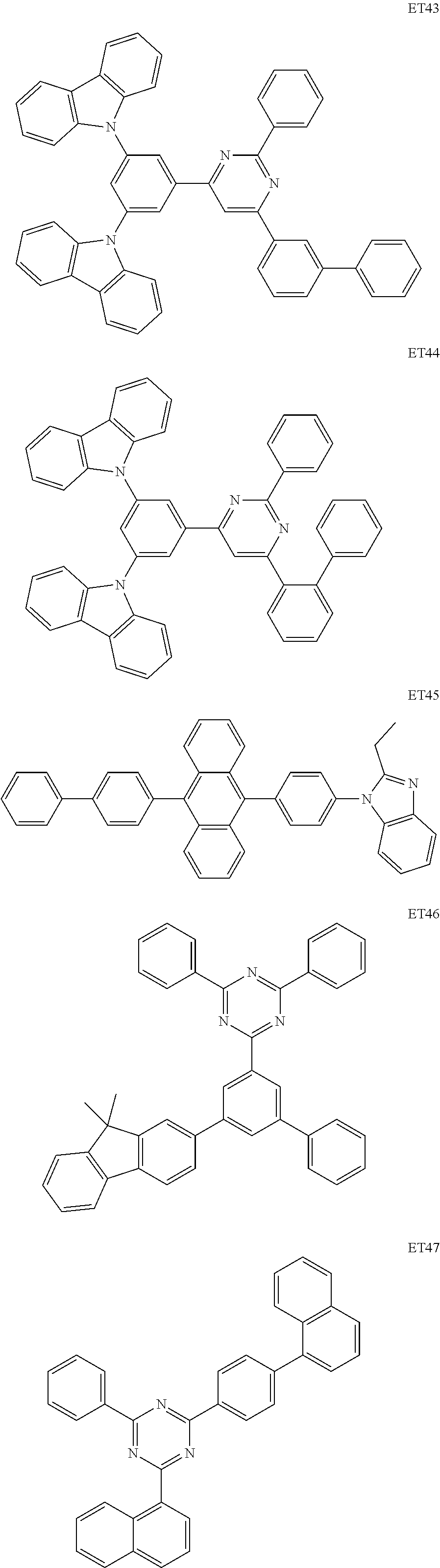

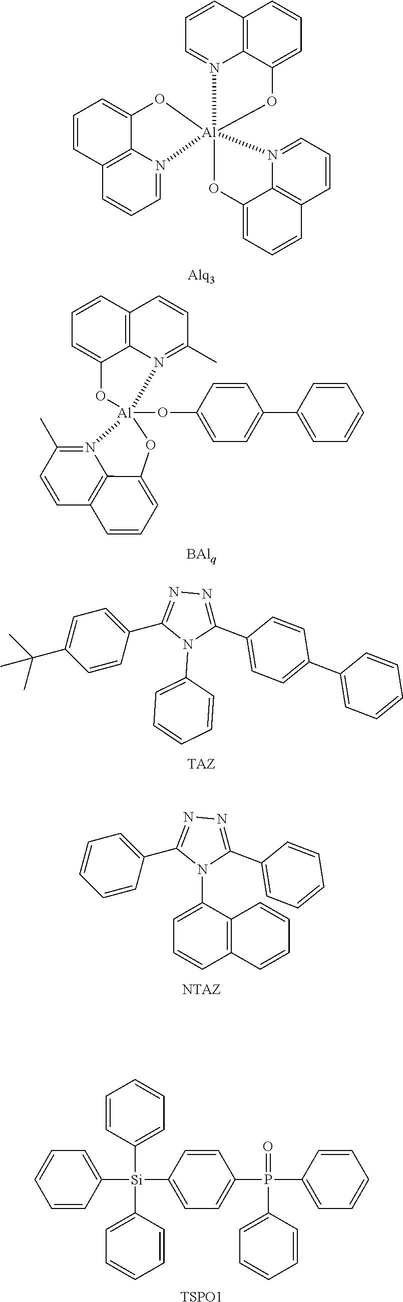

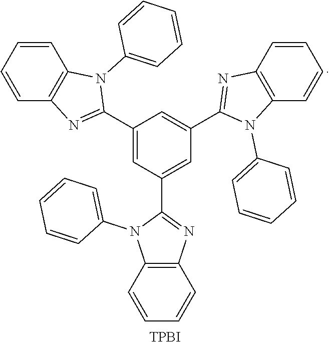

The thickness of the electron transport region may be in a range of about 100 Å to about 5,000 Å, for example, about 160 Å to about 4,000 Å. When the electron transport region includes a buffer layer, a hole-blocking layer, an electron control layer, an electron transport layer, or any combination thereof, the thickness of the buffer layer, the hole-blocking layer, and/or the electron control layer may each independently be in a range of about 20 Å to about 1,000 Å, for example, about 30 Å to about 300 Å, and the thickness of the electron transport layer may be in a range of about 100 Å to about 1,000 Å, for example, about 150 Å to about 500 Å. When the thicknesses of the buffer layer, the hole-blocking layer, the electron control layer, the electron transport layer, and/or the electron transport region are within any of their respective ranges described above, satisfactory or suitable electron-transporting characteristics may be obtained without a substantial increase in driving voltage.

The electron transport region (e.g., the electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex and/or the alkaline earth metal complex may include hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

In one or more embodiments, the metal-containing material may include a Li complex. The Li complex may include, for example, Compound ET-D1 (LiQ) and/or Compound ET-D2:

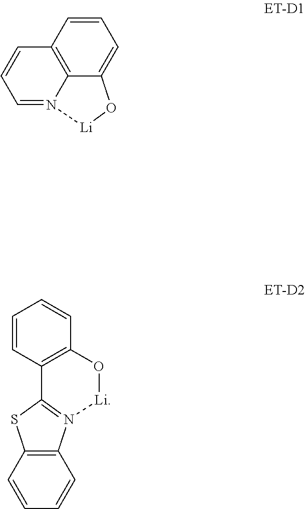

The electron transport region may include an electron injection layer that facilitates the injection of electrons from the second electrode 150. The electron injection layer may directly contact the second electrode 150.

The electron injection layer may have i) a single-layer structure including (e.g., consisting of) a single layer including (e.g., consisting of) a single material, ii) a single-layer structure including (e.g., consisting of) a single layer including multiple different materials, or iii) a multi-layer structure including multiple layers including multiple different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (e.g., fluorides, chlorides, bromides, iodides, and/or the like), and/or tellurides of the alkali metal, the alkaline earth metal, and the rare earth metal, or any combination thereof.

The alkali metal-containing compound may include: an alkali metal oxide, such as Li₂O, Cs₂O, and/or K₂O; an alkali metal halide, such as LiF, NaF, CsF, KF, LiI, NaI, CsI, and/or KI; or any combination thereof. The alkaline earth metal-containing compound may include an alkaline earth metal oxide, such as BaO, SrO, CaO, BaₓSr₁₋ₓO (wherein x is a real number satisfying 0<x<1), and/or BaₓCa₁₋ₓO (wherein x is a real number satisfying 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include a lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and/or the like.

The alkali metal complex, the alkaline earth metal complex, and the rare earth metal complex may include i) one of ions selected from among the alkali metal, the alkaline earth metal, and the rare earth metal and ii) a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (e.g., a compound represented by Formula 601).

In one or more embodiments, the electron injection layer may include (e.g., consist of) i) an alkali metal-containing compound (e.g., an alkali metal halide), or ii) a) an alkali metal-containing compound (e.g., an alkali metal halide), and b) an alkali metal, an alkaline earth metal, a rare earth metal, or any combination thereof. For example, the electron injection layer may be a KI:Yb co-deposited layer, an RbI:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth metal complex, the rare earth metal complex, or any combination thereof may be uniformly (e.g., substantially uniformly) or non-uniformly (e.g., substantially non-uniformly) dispersed in a matrix including the organic material.

The thickness of the electron injection layer may be in a range of about 1 Å to about 100 Å, for example, about 3 Å to about 90 Å. When the thickness of the electron injection layer is within any of the ranges described above, satisfactory or suitable electron injection characteristics may be obtained without a substantial increase in driving voltage.

### Second Electrode 150

The second electrode 150 is arranged on the interlayer 130. The second electrode 150 may be a cathode, which is an electron injection electrode, and as a material for forming the second electrode 150, a metal, an alloy, an electrically conductive compound, or any combination thereof, each having a suitably low-work function, may be used.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layer structure or a multi-layer structure including multiple layers.

### Capping Layer

A first capping layer may be arranged outside the first electrode 110, and/or a second capping layer may be arranged outside the second electrode 150. For example, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

Light generated in the emission layer of the interlayer 130 of the light-emitting device 10 may be extracted toward the outside through the first electrode 110, which is a transflective electrode or a transmissive electrode, and the first capping layer. Light generated in the emission layer of the interlayer 130 of the light-emitting device 10 may be extracted toward the outside through the second electrode 150, which is a transflective electrode or a transmissive electrode, and the second capping layer.

The first capping layer and the second capping layer may increase external emission efficiency according to the principle of constructive interference. Accordingly, the light extraction efficiency of the light-emitting device 10 may be increased, and thus, the luminescence efficiency of the light-emitting device 10 may be improved.

Each of the first capping layer and the second capping layer may include a material having a refractive index of 1.6 or more (at 589 nm).

The first capping layer and the second capping layer may each independently be an organic capping layer including an organic material, an inorganic capping layer including an inorganic material, or an organic-inorganic composite capping layer including an organic material and an inorganic material.

At least one selected from among the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and/or the amine group-containing compound may optionally be substituted with a substituent including O, N, S, Se, Si, F, Cl, Br, I, or any combination thereof. In one or more embodiments, at least one selected from among the first capping layer and the second capping layer may each independently include an amine group-containing compound.

In one or more embodiments, at least one selected from among the first capping layer and the second capping layer may each independently include a compound represented by Formula 201, a compound represented by Formula 202, or any combination thereof.

In one or more embodiments, at least one selected from among the first capping layer and the second capping layer may each independently include one selected from among Compounds HT28 to HT33, one selected from among Compounds CP1 to CP6, β-NPB, or any combination thereof:

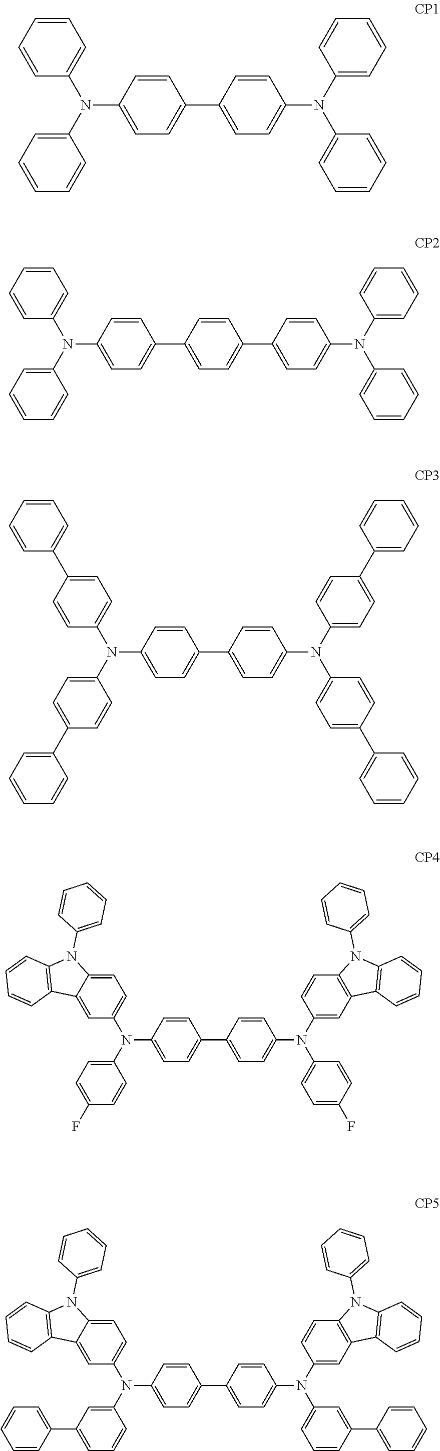 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

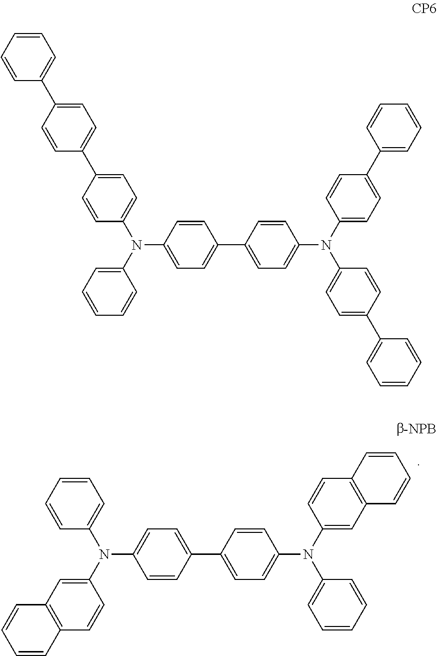 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Film

The condensed cyclic compound represented by Formula 1 may be included in one or more suitable films.

Accordingly, one or more embodiments of the present disclosure provide a film including the condensed cyclic compound represented by Formula 1. The film may be, for example, an optical member (e.g., a light control means) (e.g., a color filter, a color conversion member, a capping layer, a light extraction efficiency enhancement layer, a selective light-absorbing layer, a polarizing layer, a quantum dot-containing layer, and/or the like), a light-blocking member (e.g., a light-reflecting layer, a light-absorbing layer, and/or the like), a protective member (e.g., an insulating layer, a dielectric layer, and/or the like), and/or the like.

### Electronic Apparatus

The light-emitting device may be included in one or more suitable electronic apparatuses. For example, the electronic apparatus including the light-emitting device may be a light-emitting apparatus, an authentication apparatus, and/or the like.

The electronic apparatus (e.g., a light-emitting apparatus) may further include, in addition to the light-emitting device, i) a color filter, ii) a color conversion layer, or iii) a color filter and a color conversion layer. The color filter and/or the color conversion layer may be arranged in at least one direction in which light emitted from the light-emitting device travels. For example, the light emitted from the light-emitting device may be blue light or white light. A more detailed description of the light-emitting device is provided herein. In one or more embodiments, the color conversion layer may include quantum dots. The quantum dots may be, for example, quantum dots as described herein.

The electronic apparatus may include a first substrate. The first substrate may include a plurality of subpixel areas, the color filter may include a plurality of color filter areas respectively corresponding to the plurality of subpixel areas, and the color conversion layer may include a plurality of color conversion areas respectively corresponding to the plurality of subpixel areas.

A pixel-defining film may be arranged among the plurality of subpixel areas to define each of the plurality of subpixel areas.

The color filter may further include a plurality of color filter areas and light-shielding patterns arranged among the plurality of color filter areas, and the color conversion layer may further include a plurality of color conversion areas and light-shielding patterns arranged among the plurality of color conversion areas.

The plurality of color filter areas (and/or the plurality of color conversion areas) may include a first area to emit first color light, a second area to emit second color light, and/or a third area to emit third color light, wherein the first color light, the second color light, and/or the third color light may have different maximum emission wavelengths. For example, the first color light may be red light, the second color light may be green light, and the third color light may be blue light. For example, the plurality of color filter areas (and/or the plurality of color conversion areas) may include quantum dots. For example, the first area may include red quantum dots, the second area may include green quantum dots, and the third area may not include (e.g., may exclude) quantum dots. A more detailed description of the quantum dots is provided herein. The first area, the second area, and/or the third area may each further include a scatterer.

In one or more embodiments, the light-emitting device may be to emit first light, the first area may be to absorb the first light to emit first-1 color light, the second area may be to absorb the first light to emit second-1 color light, and the third area may be to absorb the first light to emit third-1 color light. In this regard, the first-1 color light, the second-1 color light, and the third-1 color light may have different maximum emission wavelengths. For example, the first light may be blue light, the first-1 color light may be red light, the second-1 color light may be green light, and the third-1 color light may be blue light.

The electronic apparatus may further include a thin-film transistor, in addition to the light-emitting device according to the present embodiments. The thin-film transistor may include a source electrode, a drain electrode, and an active layer, wherein one selected from among the source electrode and the drain electrode may be electrically connected (e.g., electrically coupled) to one selected from among the first electrode and the second electrode of the light-emitting device.

The thin-film transistor may further include a gate electrode, a gate insulating film, and/or the like.

The active layer may include crystalline silicon, amorphous silicon, an organic semiconductor, an oxide semiconductor, and/or the like.

The electronic apparatus may further include a sealing portion for sealing the light-emitting device. The sealing portion may be arranged between the light-emitting device and the color filter and/or the color conversion layer. The sealing portion allows light from the light-emitting device to be extracted to the outside, and concurrently (e.g., simultaneously) prevents or reduces the penetration of ambient air and/or moisture into the light-emitting device. The sealing portion may be a sealing substrate including a transparent glass substrate and/or a plastic substrate. The sealing portion may be a thin-film encapsulation layer including at least one layer of an organic layer and/or an inorganic layer. When the sealing portion is a thin-film encapsulation layer, the electronic apparatus may be suitably flexible.

One or more suitable functional layers may be additionally arranged on the sealing portion, in addition to the color filter and/or the color conversion layer, according to the use (e.g., intended and/or desired use) of the electronic apparatus. Examples of the functional layers may include a touch screen layer, a polarizing layer, and/or the like. The touch screen layer may be a pressure-sensitive touch screen layer, a capacitive touch screen layer, and/or an infrared touch screen layer. The authentication apparatus may be, for example, a biometric authentication apparatus that authenticates an individual by using biometric information of a living body (e.g., fingertips, pupils, and/or the like).

The authentication apparatus may further include, in addition to the light-emitting device as described above, a biometric information collector.

The electronic apparatus (e.g., a light-emitting apparatus) may be applied to one or more suitable electronic equipment. In one or more embodiments, the electronic apparatus may be applied to one or more suitable displays, light sources, lighting, personal computers (e.g., a mobile personal computer), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, and/or endoscope displays), fish finders, one or more suitable measuring instruments, meters (e.g., meters for a vehicle, an aircraft, and/or a vessel), projectors, and/or the like.

### Electronic Equipment

The electronic apparatus may be applied to one or more suitable electronic equipment. Accordingly, the light-emitting device may be included in one or more suitable electronic equipment.

In one or more embodiments, the light-emitting apparatus may be applied to one or more suitable electronic equipment. In one or more embodiments, electronic equipment may include the light-emitting apparatus described above, and may further include, in addition to the light-emitting apparatus, a module and/or apparatus having additional functions.

In one or more embodiments, the electronic equipment including the light-emitting device may be one selected from among a flat panel display, a curved display, a computer monitor, a medical monitor, a TV, a billboard, an indoor light, an outdoor light, a signal light, a HUD, a fully and/or partially transparent display, a flexible display, a rollable display, a foldable display, a stretchable display, a laser printer, a telephone, a mobile phone, a tablet, a phablet, a PDA, a wearable device, a laptop computer, a digital camera, a camcorder, a viewfinder, a micro display, a 3D display, a virtual reality display, an augmented reality display, a vehicle, a video wall including multiple displays tiled together, a theater screen, a stadium screen, a phototherapy device, and a signboard.

Because the light-emitting device has excellent or suitable effects in terms of luminescence efficiency and lifespan, the electronic equipment including the light-emitting device may have characteristics such as suitably high luminance, suitably high resolution, and suitably low power consumption.

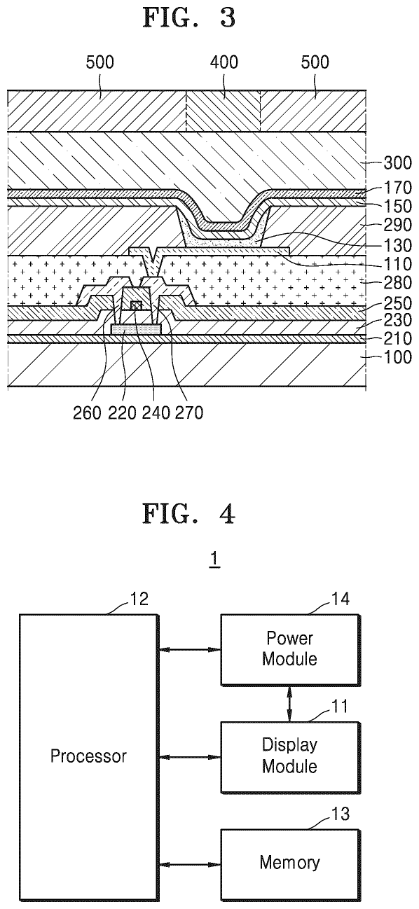

### Descriptions of FIGS. 2 and 3

FIG. 2 is a cross-sectional view of a light-emitting apparatus according to one or more embodiments.

The light-emitting apparatus of FIG. 2 includes a substrate 100, a thin-film transistor (TFT), a light-emitting device, and a sealing portion 300 that seals the light-emitting device.

The substrate 100 may be a flexible substrate, a glass substrate, and/or a metal substrate. A buffer layer 210 may be arranged on the substrate 100. The buffer layer 210 may prevent or reduce penetration of impurities through the substrate 100, and may provide a suitably flat surface on the substrate 100.

A TFT may be arranged on the buffer layer 210. The TFT may include an active layer 220, a gate electrode 240, a source electrode 260, and a drain electrode 270.

The active layer 220 may include an inorganic semiconductor, such as silicon and/or polysilicon, an organic semiconductor, and/or an oxide semiconductor, and may include a source region, a drain region, and a channel region.

A gate insulating film 230 for insulating the active layer 220 from the gate electrode 240 may be arranged on the active layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260, to insulate the gate electrode 240 from the source electrode 260, and between the gate electrode 240 and the drain electrode 270, to insulate the gate electrode 240 from the drain electrode 270.

The source electrode 260 and the drain electrode 270 may be arranged on the interlayer insulating film 250. The interlayer insulating film 250 and the gate insulating film 230 may be formed to expose the source region and the drain region of the active layer 220, and the source electrode 260 and the drain electrode 270 may be arranged in contact with the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. A light-emitting device may be provided on the passivation layer 280. The light-emitting device may include a first electrode 110, an interlayer 130, and a second electrode 150.

The first electrode 110 may be arranged on the passivation layer 280. The passivation layer 280 may be arranged to expose a portion of the drain electrode 270 without fully covering the drain electrode 270, and the first electrode 110 may be arranged to be connected to the exposed portion of the drain electrode 270.

A pixel-defining film 290 including an insulating material may be arranged on the first electrode 110. The pixel-defining film 290 may expose a certain or set region of the first electrode 110, and the interlayer 130 may be formed in the exposed region of the first electrode 110. The pixel-defining film 290 may be a polyimide-based organic film and/or a polyacrylic organic film. In some embodiments, at least some layers of the interlayer 130 may extend beyond the upper portion of the pixel-defining film 290 to be arranged in the form of a common layer.

The second electrode 150 may be arranged on the interlayer 130, and a capping layer 170 may be additionally formed on the second electrode 150. The capping layer 170 may be formed to cover the second electrode 150.

The sealing portion 300 may be arranged on the capping layer 170. The sealing portion 300 may be arranged on a light-emitting device to protect the light-emitting device from moisture and/or oxygen. The sealing portion 300 may include: an inorganic film including silicon nitride (SiNx, e.g., Si₃N₄), silicon oxide (SiOx, e.g., SiO₂), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (e.g., polymethyl methacrylate, polyacrylic acid, and/or the like), an epoxy-based resin (e.g., aliphatic glycidyl ether (AGE), and/or the like), or any combination thereof; or any combination of the inorganic film(s) and the organic film(s).

FIG. 3 is a cross-sectional view of a light-emitting apparatus according to one or more embodiments.

The light-emitting apparatus of FIG. 3 is the same as the light-emitting apparatus of FIG. 2, except that a light-shielding pattern 500 and a functional region 400 are additionally arranged on the sealing portion 300. The functional region 400 may be i) a color filter area, ii) a color conversion area, or iii) a combination of the color filter area and the color conversion area. In one or more embodiments, a light-emitting device included in the light-emitting apparatus of FIG. 3 may be a tandem light-emitting device.

### Description of FIG. 4

FIG. 4 is a block diagram of electronic equipment 1 according to one or more embodiments. Referring to FIG. 4, the electronic equipment 1 according to one or more embodiments may include an emitting module (e.g., display module) 11, a processor 12, a memory 13, and a power module 14.

The processor 12 may include at least one selected from among a central processing unit (CPU), an application processor (AP), a graphic processing unit (GPU), a communication processor (CP), an image signal processor (ISP), and a controller.

The memory 13 may store data information desired or required for operation of the processor 12 and/or the emitting module (e.g., display module) 11. When the processor 12 executes an application stored in the memory 13, an image data signal and/or an input control signal may be transmitted to the emitting module (e.g., display module) 11, and the emitting module (e.g., display module) 11 may process the received signal and output image information through a display screen.

The power module 14 may include a power supply module, such as a power adapter and/or a battery device, and a power conversion module that converts power supplied by the power supply module to generate power desired or required for operation of the electronic equipment 1.

At least one of the components of the electronic equipment 1 described above may be included in the light-emitting apparatus according to one or more embodiments described above. In one or more embodiments, some of individual modules functionally included in one module may be included in the light-emitting apparatus, and others may be provided separately from the light-emitting apparatus. For example, the light-emitting apparatus may include the emitting module (e.g., display module) 11, and the processor 12, the memory 13, and the power module 14 may be provided as apparatuses other than the light-emitting apparatus in the electronic equipment 1.

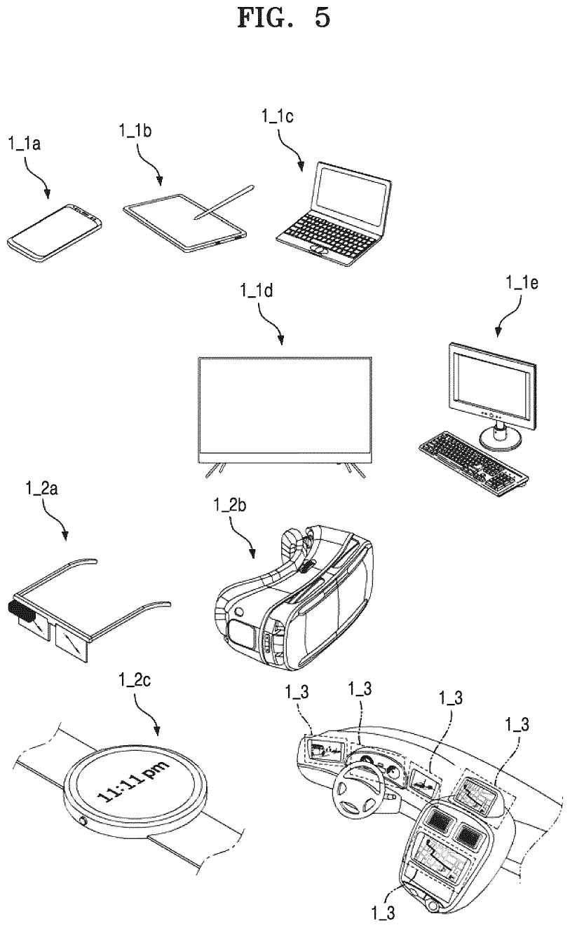

### Description of FIG. 5

FIG. 5 shows schematic views of electronic equipment according to one or more embodiments.

Referring to FIG. 5, one or more suitable electronic equipment to which the electronic apparatus (e.g., a light-emitting apparatus) is applied may include not only electronic equipment for displaying an image, such as a smartphone 1_1a, a tablet personal computer (PC) 1_1b, a laptop 1_1c, a TV 1_1d, and a desk monitor 1_1e, but also wearable electronic equipment including an emitting module, such as smart glasses 1_2a, a head-mounted display (HMD) 1_2b, and a smart watch 1_2c, and vehicle electronic equipment 1_3 including an emitting module, such as a center information display (CID) arranged on an instrument panel, a center fascia, and/or a dashboard of vehicle, and a room mirror display.

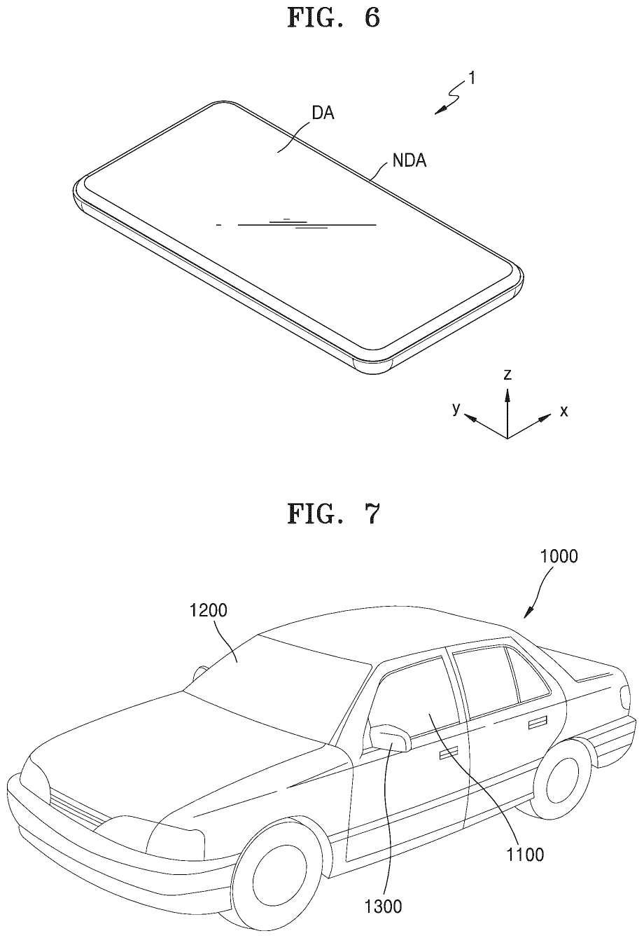

### Description of FIG. 6

FIG. 6 is a schematic perspective view of electronic equipment 1 including a light-emitting device according to one or more embodiments. The electronic equipment 1 may be, as an apparatus that displays a moving image and/or a still image, portable electronic equipment, such as a mobile phone, a smartphone, a tablet PC, a mobile communication terminal, an electronic notebook, an electronic book, a portable multimedia player (PMP), a navigation, and/or an ultra-mobile PC (UMPC), as well as one or more suitable products, such as a TV, a laptop, a monitor, a billboard, and/or an Internet of things (IoT) device. The electronic equipment 1 may be such a product above or a part thereof. In one or more embodiments, the electronic equipment 1 may be a wearable device, such as a smart watch, a watch phone, a glasses-type or kind display, and/or a HMD, or a part of the wearable device. However, embodiments are not limited thereto. For example, the electronic equipment 1 may be an instrument panel, a CID arranged on a center fascia and/or dashboard of a vehicle, a room mirror display instead of a side mirror of a vehicle, an entertainment display for a rear seat of a vehicle, a display arranged on the back of a front seat, a HUD installed in the front of a vehicle and/or projected on a front window glass, and/or a computer-generated hologram augmented reality HUD (CGH AR HUD). FIG. 6 illustrates one or more embodiments in which the electronic equipment 1 is a smartphone for convenience of explanation.

The electronic equipment 1 may include a display area DA and a non-display area NDA outside the display area DA. A display apparatus may implement an image through an array of a plurality of pixels that are two-dimensionally arranged (e.g., a two-dimensional matrix arrangement) in the display area DA.

The non-display area NDA is an area that does not display an image, and may entirely be around (e.g., may surround) the display area DA. In the non-display area NDA, a driver for providing electrical signals and/or power to display element arranged in the display area DA may be arranged. In the non-display area NDA, a pad, to which an electronic element and/or a printed circuit board may be electrically connected, may be arranged.

In the electronic equipment 1, the length in an x-axis direction and the length in a y-axis direction may be different from each other. For example, as shown in FIG. 6, the length in the x-axis direction may be less than the length in the y-axis direction. In one or more embodiments, the length in the x-axis direction may be the same as the length in the y-axis direction. In one or more embodiments, the length in the x-axis direction may be greater than the length in the y-axis direction.

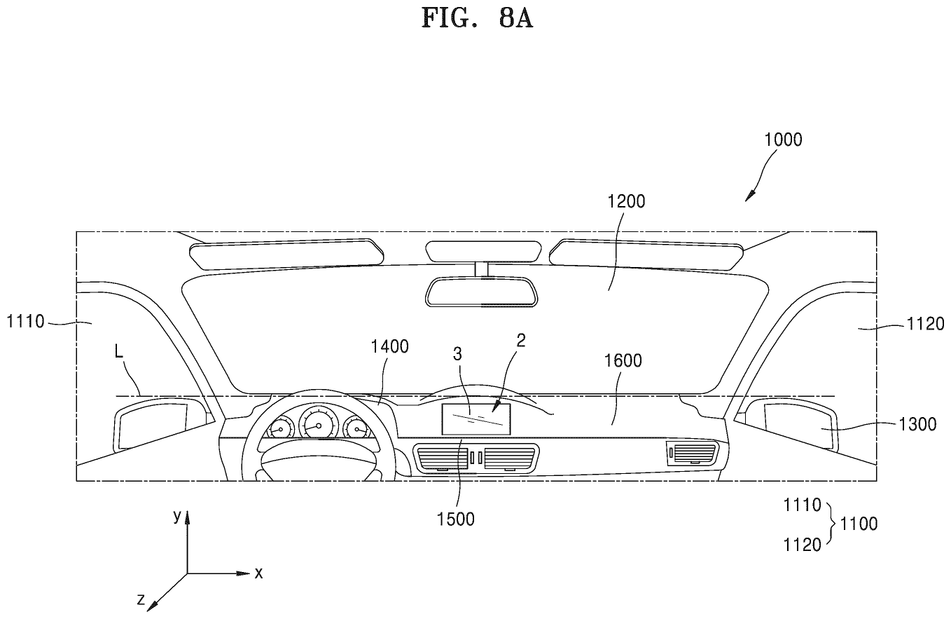

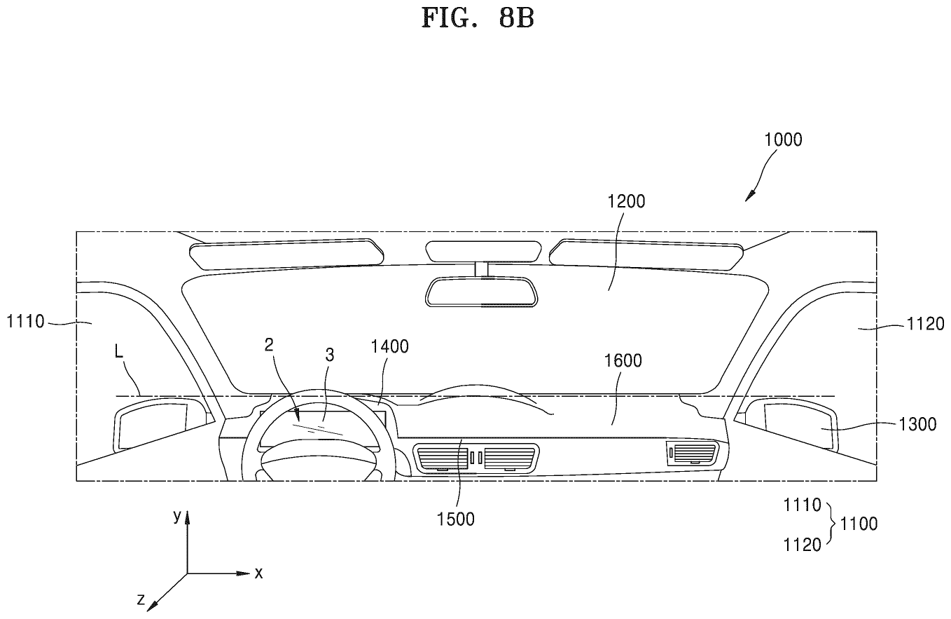

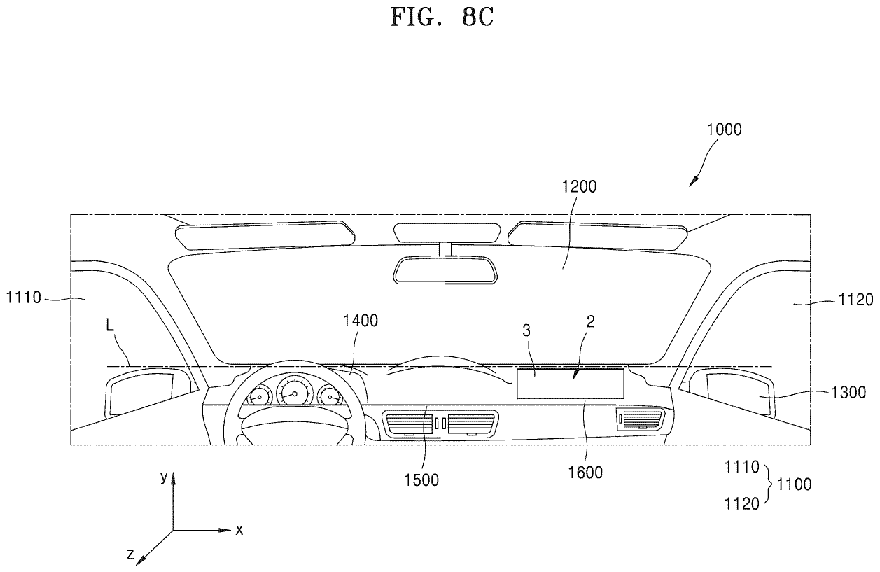

### Descriptions of FIGS. 7 and 8A to 8C

FIG. 7 is a schematic view of the exterior of a vehicle 1000 as electronic equipment including a light-emitting device according to one or more embodiments. FIGS. 8A to 8C are each a schematic view of an interior of the vehicle 1000 according to one or more embodiments.

Referring to FIGS. 7, 8A, 8B, and 8C, the vehicle 1000 may refer to one or more suitable apparatuses for moving a subject to be transported, such as a human, an object, and/or an animal, from a departure point to a destination point. The vehicle 1000 may include a vehicle traveling on a road and/or a track, a vessel moving over the sea and/or river, an airplane flying in the sky using the action of air, and/or the like.

The vehicle 1000 may travel on a road and/or a track. The vehicle 1000 may move in a certain direction according to rotation of at least one wheel. For example, the vehicle 1000 may include a three-wheeled or four-wheeled vehicle, a construction machine, a two-wheeled vehicle, a prime mover device, a bicycle, and a train running on a track.

The vehicle 1000 may include a body having an interior and an exterior, and a chassis in which mechanical apparatuses necessary for driving are installed as other parts except for the body of the vehicle 1000. The exterior of the body of the vehicle 1000 may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and right wheels, and/or the like.

The vehicle 1000 may include a side window glass 1100, a front window glass 1200, a side mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on the side of the vehicle 1000. In one or more embodiments, the side window glass 1100 may be installed on a door of the vehicle 1000. A plurality of side window glasses 1100 may be provided and may face each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced and/or apart (e.g., spaced apart or separated) from each other in an x-direction or a −x-direction. For example, the first side window glass 1110 and the second side window glass 1120 may be spaced and/or apart (e.g., spaced apart or separated) from each other in the x-direction or the −x-direction. For example, an imaginary straight line L connecting the side window glasses 1100 may extend in the x-direction or the −x-direction. For example, an imaginary straight line L connecting the first side window glass 1110 and the second side window glass 1120 to each other may extend in the x-direction or the −x-direction.

The front window glass 1200 may be installed in the front of the vehicle 1000. The front window glass 1200 may be arranged between the side window glasses 1100 facing each other.

The side mirror 1300 may provide a rear view of the vehicle 1000. The side mirror 1300 may be installed on the exterior of the body of the vehicle 1000. In one or more embodiments, a plurality of side mirrors 1300 may be provided. Any one of the plurality of side mirrors 1300 may be arranged outside the first side window glass 1110. Another of the plurality of side mirrors 1300 may be arranged outside the second side window glass 1120.

The cluster 1400 may be arranged in front of a steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which a plurality of buttons for adjusting an audio device, an air conditioning device, and/or a seat heater are arranged. The center fascia 1500 may be arranged on one side of the cluster 1400.

The passenger seat dashboard 1600 may be spaced and/or apart (e.g., spaced apart or separated) from the cluster 1400, and the center fascia 1500 may be arranged between the cluster 1400 and the passenger seat dashboard 1600. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display apparatus 2 may include a display panel 3, and the display panel 3 may display an image. The display apparatus 2 may be arranged inside the vehicle 1000. In one or more embodiments, the display apparatus 2 may be arranged between the side window glasses 1100 facing each other. The display apparatus 2 may be arranged on at least one of the cluster 1400, the center fascia 1500, and the passenger seat dashboard 1600.

The display apparatus 2 may include an organic light-emitting display apparatus, an inorganic light-emitting display apparatus, a quantum dot display apparatus, and/or the like. Hereinafter, as the display apparatus 2 according to one or more embodiments, an organic light-emitting display apparatus including the light-emitting device according to the disclosure will be described as an example, but one or more suitable types (kinds) of display apparatuses as described herein may be used in embodiments.

Referring to FIG. 8A, the display apparatus 2 may be arranged on the center fascia 1500. In one or more embodiments, the display apparatus 2 may display navigation information. In one or more embodiments, the display apparatus 2 may display information regarding audio settings, video setting, and/or vehicle settings.

Referring to FIG. 8B, the display apparatus 2 may be arranged on the cluster 1400. In this case, the cluster 1400 may display driving information and/or the like through the display apparatus 2. For example, the cluster 1400 may digitally implement driving information and/or the like. The cluster 1400 may digitally display vehicle information and driving information as images. For example, a needle and a gauge of a tachometer and various warning light icons may be displayed by digital signals.

Referring to FIG. 8C, the display apparatus 2 may be arranged on the passenger seat dashboard 1600. The display apparatus 2 may be embedded in the passenger seat dashboard 1600 or arranged on the passenger seat dashboard 1600. In one or more embodiments, the display apparatus 2 arranged on the passenger seat dashboard 1600 may display an image related to information displayed on the cluster 1400 and/or information displayed on the center fascia 1500. In one or more embodiments, the display apparatus 2 arranged on the passenger seat dashboard 1600 may display information different from information displayed on the cluster 1400 and/or information displayed on the center fascia 1500.

### Manufacturing Method

Layers constituting the hole transport region, the emission layer, and layers constituting the electron transport region may be formed in a certain or set region by using one or more suitable methods, such as vacuum deposition, spin coating, casting, Langmuir-Blodgett (LB) deposition, ink-jet printing, laser-printing, laser-induced thermal imaging, and/or the like.

When the layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/see to about 100 Å/see, depending on a material to be included in a layer to be formed and the structure of a layer to be formed.

### Definition of Terms

The term “C₃-C₆₀ carbocyclic group” as used herein may refer to a cyclic group including (e.g., consisting of) carbon atoms as the only ring-forming atoms and having 3 to 60 carbon atoms, and the term “C₁-C₆₀ heterocyclic group” as used herein refers to a cyclic group that has 1 to 60 carbon atoms and further includes, in addition to carbon atoms, at least one heteroatom as a ring-forming atom. The C₃-C₆₀ carbocyclic group and the C₁-C₆₀ heterocyclic group may each independently be a monocyclic group including (e.g., consisting of) one ring or a polycyclic group in which two or more rings are condensed with each other. For example, the number of ring-forming atoms of the C₁-C₆₀ heterocyclic group may be from 3 to 61.

The term “cyclic group” as used herein may include both (e.g., simultaneously) the C₃-C₆₀ carbocyclic group and the C₁-C₆₀ heterocyclic group.

The term “π electron-rich C₃-C₆₀ cyclic group” as used herein may refer to a cyclic group that has 3 to 60 carbon atoms and does not include *—N═*′ as a ring-forming moiety, and the term “π electron-deficient nitrogen-containing C₁-C₆₀ cyclic group” as used herein may refer to a heterocyclic group that has 1 to 60 carbon atoms and includes *—N═*′ as a ring-forming moiety.

For example,
the C₃-C₆₀ carbocyclic group may be i) Group T1 or ii) a condensed cyclic group in which two or more of Group T1 are condensed with each other (e.g., the C₃-C₆₀ carbocyclic group may be a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (e.g., the C₁-C₆₀ heterocyclic group may be a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T₃ and at least one Group T1 are condensed with each other (e.g., the π electron-rich C₃-C₆₀ cyclic group may be the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),
the π electron-deficient nitrogen-containing C₁-C₆₀ cyclic group may be i) Group T4, ii) a condensed cyclic group in which two or more of Group T4 are condensed with each other, iii) a condensed cyclic group in which at least one Group T₄ and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (e.g., the π electron-deficient nitrogen-containing C₁-C₆₀ cyclic group may be a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
Group T3 may be a furan group, a thiophene group, a 1H-pyrrole group, a silole group, or a borole group, and
Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group,” “C₃-C₆₀ carbocyclic group,” “C₁-C₆₀ heterocyclic group,” “π electron-rich C₃-C₆₀ cyclic group,” and “π electron-deficient nitrogen-containing C₁-C₆₀ cyclic group” as used herein each may refer to a group condensed to any suitable cyclic group, a monovalent group, or a polyvalent group (e.g., a divalent group, a trivalent group, a tetravalent group, and/or the like) according to the structure of a formula for which the corresponding term is used. For example, the “benzene group” may be a benzo group, a phenyl group, a phenylene group, and/or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may refer to a linear or branched aliphatic hydrocarbon monovalent group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and/or the like. The term “C₁-C₆₀ alkylene group” as used herein refers to a divalent group having the same structure as the C₁-C₆₀ alkyl group.

The term “C₂-C₆₀ alkenyl group” as used herein may refer to a monovalent hydrocarbon group having at least one carbon-carbon double bond in the middle and/or at the terminus of the C₂-C₆₀ alkyl group, and examples thereof may include an ethenyl group, a propenyl group, a butenyl group, and/or the like. The term “C₂-C₆₀ alkenylene group” as used herein refers to a divalent group having the same structure as the C₂-C₆₀ alkenyl group.

The term “C₂-C₆₀ alkynyl group” as used herein may refer to a monovalent hydrocarbon group having at least one carbon-carbon triple bond in the middle and/or at the terminus of the C₂-C₆₀ alkyl group, and examples thereof may include an ethynyl group, a propynyl group, and/or the like. The term “C₂-C₆₀ alkynylene group” as used herein refers to a divalent group having the same structure as the C₂-C₆₀ alkynyl group.

The term “C₁-C₆₀ alkoxy group” as used herein may refer to a monovalent group represented by —OA₁₀₁ (wherein A₁₀₁ is the C₁-C₆₀ alkyl group), and examples thereof may include a methoxy group, an ethoxy group, an isopropyloxy (e.g., isopropoxy) group, and/or the like.

The term “C₃-C₁₀ cycloalkyl group” as used herein may refer to a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and/or the like. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein may refer to a monovalent cyclic group of 1 to 10 carbon atoms, further including, in addition to carbon atoms, at least one heteroatom as ring-forming atoms, and examples thereof may include a 1,2,3,4-oxatriazolidinyl group, a tetrahydrofuranyl group, a tetrahydrothiophenyl group, and/or the like. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein may refer to a monovalent cyclic group that has 3 to 10 carbon atoms, at least one carbon-carbon double bond in the ring thereof, and no aromaticity, and examples thereof may include a cyclopentenyl group, a cyclohexenyl group, a cycloheptenyl group, and/or the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein may refer to a monovalent cyclic group of 1 to 10 carbon atoms, further including, in addition to carbon atoms, at least one heteroatom as ring-forming atoms and at least one double bond in the ring thereof. Examples of the C₁-C₁₀ heterocycloalkenyl group may include a 4,5-dihydro-1,2,3,4-oxatriazolyl group, a 2,3-dihydrofuranyl group, a 2,3-dihydrothiophenyl group, and/or the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein may refer to a monovalent group having a carbocyclic aromatic system of 6 to 60 carbon atoms, and the term “C₆-C₆₀ arylene group” as used herein refers to a divalent group having the same structure as the C₆-C₆₀ aryl group. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and/or the like. When the C₆-C₆₀ aryl group and/or the C₆-C₆₀ arylene group each independently include two or more rings, the two or more rings may be condensed with each other.

The term “C₁-C₆₀ heteroaryl group” as used herein may refer to a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein refers to a divalent group having the same structure as the C₁-C₆₀ heteroaryl group. Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and/or the like. When the C₁-C₆₀ heteroaryl group and/or the C₁-C₆₀ heteroarylene group each independently include two or more rings, the two or more rings may be condensed with each other.

The term “monovalent non-aromatic condensed polycyclic group” as used herein refers to a monovalent group (e.g., having 8 to 60 carbon atoms) having two or more rings condensed to each other, only carbon atoms as ring-forming atoms, and no aromaticity in its entire molecular structure. Examples of the monovalent non-aromatic condensed polycyclic group may include an indenyl group, a fluorenyl group, a spiro-bifluorenyl group, a benzofluorenyl group, an indenophenanthrenyl group, an indenoanthracenyl group, and/or the like. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (e.g., having 1 to 60 carbon atoms) having two or more rings condensed to each other, further including, in addition to carbon atoms, at least one heteroatom as ring-forming atoms, and having no aromaticity in its entire molecular structure. Examples of the monovalent non-aromatic condensed heteropolycyclic group may include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and/or the like. The term “divalent non-aromatic condensed heteropolycyclic group” as used herein refers to a divalent group having the same structure as the monovalent non-aromatic condensed heteropolycyclic group.

The term “C₆-C₆₀ aryloxy group” as used herein refers to a group represented by —OA₁₀₂ (wherein A₁₀₂ is the C₆-C₆₀ aryl group), and the term “C₆-C₆₀ arylthio group” as used herein refers to a group represented by —SA₁₀₃ (wherein A₁₀₃ is the C₆-C₆₀ aryl group).

The term “C₇-C₆₀ arylalkyl group” as used herein refers to a group represented by -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as used herein refers to a group represented by -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein may be:

deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ as used herein may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

The term “heteroatom” as used herein may refer to any atom other than a carbon atom and a hydrogen atom. Examples of the heteroatom may include O, S, N, P, Si, B, Ge, Se, or any combination thereof.

The term “transition metal” used herein may include hafnium (Hf), tantalum (Ta), tungsten (W), rhenium (Re), osmium (Os), iridium (Ir), platinum (Pt), gold (Au), and/or the like.

“Ph” as used herein refers to a phenyl group, “Me” as used herein refers to a methyl group, “Et” as used herein refers to an ethyl group, “tert-Bu” or “Bu^{t}” as used herein refers to a tert-butyl group, and “OMe” as used herein refers to a methoxy group.

The term “biphenyl group” as used herein may refer to “a phenyl group substituted with a phenyl group.” For example, the “biphenyl group” may be a substituted phenyl group having a C₆-C₆₀ aryl group as a substituent.

The term “terphenyl group” as used herein may refer to “a phenyl group substituted with a biphenyl group.” For example, the “terphenyl group” may be a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula or moiety.

The terms “x-axis,” “y-axis,” and “z-axis” as used herein are not limited to three axes in an orthogonal coordinate system, and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, condensed cyclic compounds according to one or more embodiments and light-emitting devices according to one or more embodiments will be described in more detail with reference to Synthesis Examples and Examples. The wording “B was used instead of A” used in describing Synthesis Examples refers to that an substantially identical molar equivalent of B being used in place of A.

### EXAMPLES

### Synthesis Example 1: Synthesis of Compound 2

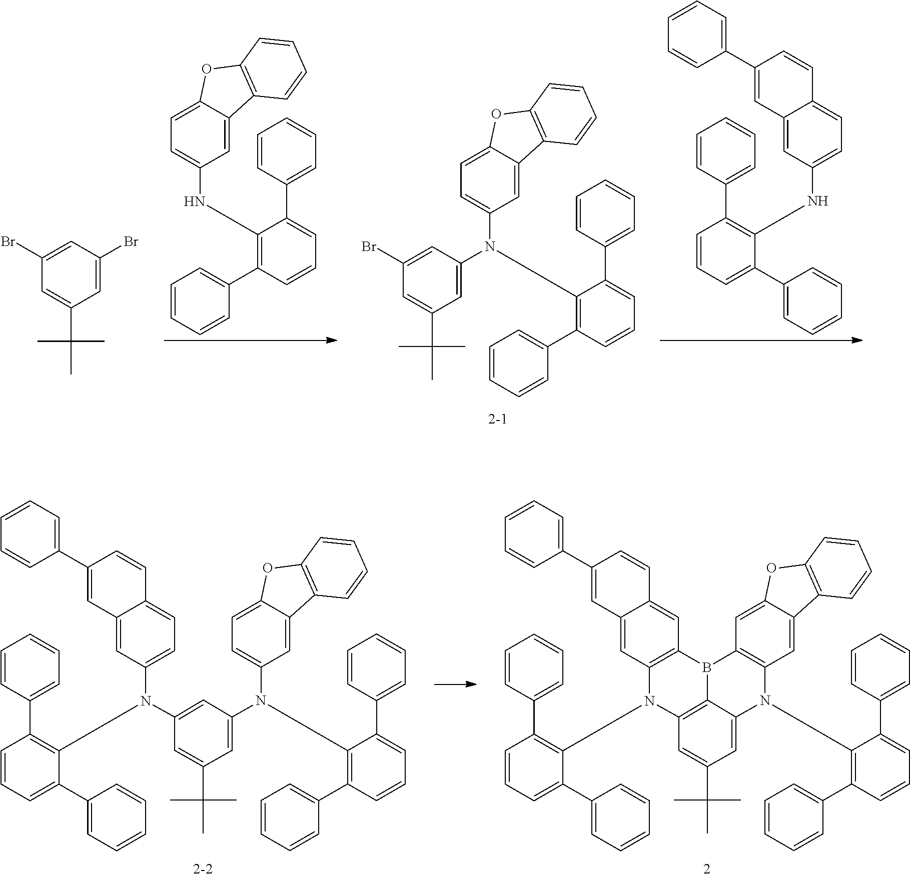 [SMILES: CC(C)(C)c1cc(Br)cc(Br)c1 ; c1ccc(-c2cccc(-c3ccccc3)c2Nc2ccc3oc4ccccc4c3c2)cc1 ; CC(C)(C)c1cc(Br)cc(N(c2ccc3oc4ccccc4c3c2)c2c(-c3ccccc3)cccc2-c2ccccc2)c1 ; c1ccc(-c2ccc3ccc(Nc4c(-c5ccccc5)cccc4-c4ccccc4)cc3c2)cc1 ; CC(C)(C)c1cc(N(c2ccc3ccc(-c4ccccc4)cc3c2)c2c(-c3ccccc3)cccc2-c2ccccc2)cc(N(c2ccc3oc4ccccc4c3c2)c2c(-c3ccccc3)cccc2-c2ccccc2)c1 ; CC(C)(C)c1cc2c3c(c1)N(c1c(-c4ccccc4)cccc1-c1ccccc1)c1cc4c(cc1B3c1cc3ccc(-c5ccccc5)cc3cc1N2c1c(-c2ccccc2)cccc1-c1ccccc1)oc1ccccc14]

### (Synthesis of Intermediate 2-1)

1,3-dibromo-5-(tert-butyl)benzene (1 eq), N-([1,1′:3′,1″-terphenyl]-2′-yl)dibenzo[b,d]furan-2-amine (1 eq), tris(dibenzylideneacetone)dipalladium(0) (0.05 eq), tri-tert-butylphosphine (0.1 eq), and sodium tert-butoxide (3 eq) were dissolved in toluene, and stirred at 110° C. for 24 hours. After cooling, the mixed solution was washed with ethyl acetate and water each for three times and separated, and the resulting organic layer was dried with MgSO₄ first and then dried again under reduced pressure. The resulting product was purified by column chromatography using methylene chloride (MC) and n-hexane to thereby obtain Intermediate 2-1. (Yield: 34%)

### (Synthesis of Intermediate 2-2)

Intermediate 2-1 (1 eq), N-([1,1′: 3′,1″-terphenyl]-2′-yl)-7-phenylnaphthalen-2-amine (1.2 eq), tris(dibenzylideneacetone)dipalladium(0) (0.15 eq), tri-tert-butylphosphine (0.3 eq), and sodium tert-butoxide (5 eq) were dissolved in o-xylene, and stirred at 150° C. for 72 hours. After cooling, the mixed solution was washed with ethyl acetate and water each for three times and separated, and the resulting organic layer was dried with MgSO₄ first and then dried again under reduced pressure. The resulting product was purified by column chromatography using MC and n-hexane to thereby obtain Intermediate 2-2. (Yield: 41%)

### (Synthesis of Compound 2)

After dissolving Intermediate 2-2 (1 eq) in ortho dichlorobenzene, the mixed solution was cooled to 0° C., and BBr₃ (3 eq) was slowly added dropwise thereto in a nitrogen atmosphere. After completion of the dropwise addition, the temperature was raised to 180° C., and the resulting solution was stirred for 72 hours. After cooling, triethylamine was slowly added dropwise into the flask containing the reactant to terminate the reaction, and ethyl alcohol was added to the reactant, followed by precipitation and filtration to thereby obtain a reaction product. The resulting solid was purified by column chromatography using MC and n-hexane, and recrystallized with toluene and acetone to thereby obtain Compound 2. (Yield: 13%)

### Synthesis Example 2: Synthesis of Compound 6

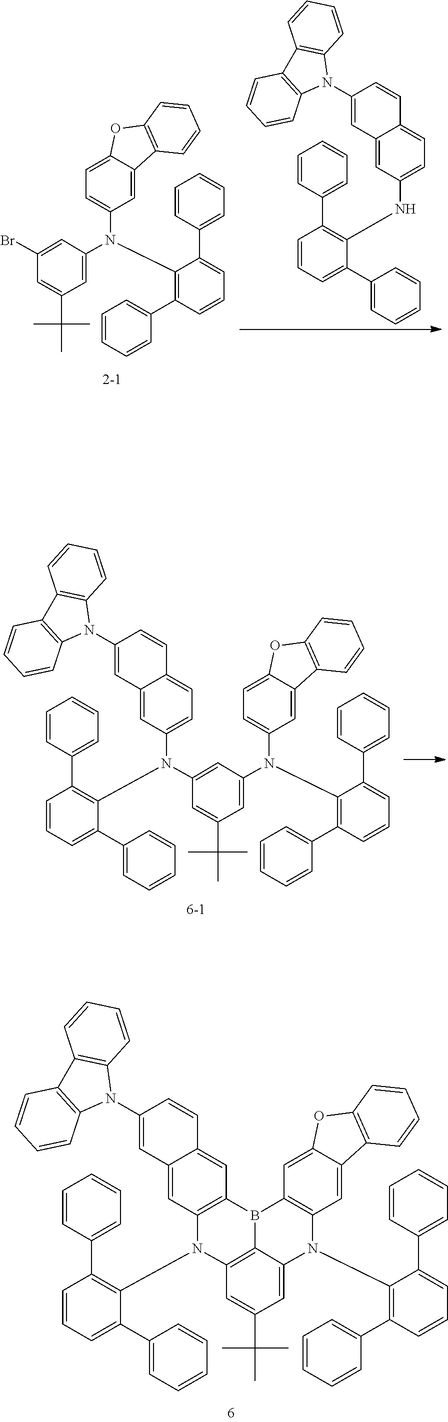 [SMILES: CC(C)(C)c1cc(Br)cc(N(c2ccc3oc4ccccc4c3c2)c2c(-c3ccccc3)cccc2-c2ccccc2)c1 ; c1ccc(-c2cccc(-c3ccccc3)c2Nc2ccc3ccc(-n4c5ccccc5c5ccccc54)cc3c2)cc1 ; CC(C)(C)c1cc(N(c2ccc3ccc(-n4c5ccccc5c5ccccc54)cc3c2)c2c(-c3ccccc3)cccc2-c2ccccc2)cc(N(c2ccc3oc4ccccc4c3c2)c2c(-c3ccccc3)cccc2-c2ccccc2)c1 ; CC(C)(C)c1cc2c3c(c1)N(c1c(-c4ccccc4)cccc1-c1ccccc1)c1cc4c(cc1B3c1cc3ccc(-n5c6ccccc6c6ccccc65)cc3cc1N2c1c(-c2ccccc2)cccc1-c1ccccc1)oc1ccccc14]

### (Synthesis of Intermediate 6-1)

Intermediate 2-1 (1 eq), N-([1,1′: 3′,1″-terphenyl]-2′-yl)-7-(9H-carbazol-9-yl)naphthalen-2-amine (1.5 eq), tris(dibenzylideneacetone)dipalladium(0) (0.15 eq), tri-tert-butylphosphine (0.3 eq), and sodium tert-butoxide (5 eq) were dissolved in o-xylene, and stirred at 150° C. for 72 hours. After cooling, the mixed solution was washed with ethyl acetate and water each for three times and separated, and the resulting organic layer was dried with MgSO₄ first and then dried again under reduced pressure. The resulting product was purified by column chromatography using MC and n-hexane to thereby obtain Intermediate 6-1. (Yield: 36%)

### (Synthesis of Compound 6)

After dissolving Intermediate 6-1 (1 eq) in ortho dichlorobenzene, the mixed solution was cooled to 0° C., and BBr₃ (3 eq) was slowly added dropwise thereto in a nitrogen atmosphere. After completion of the dropwise addition, the temperature was raised to 180° C., and the resulting solution was stirred for 72 hours. After cooling, triethylamine was slowly added dropwise into the flask containing the reactant to terminate the reaction, and ethyl alcohol was added to the reactant, followed by precipitation and filtration to thereby obtain a reaction product. The resulting solid was purified by column chromatography using MC and n-hexane, and recrystallized with toluene and acetone to thereby obtain Compound 6. (Yield: 16%)

### Synthesis Example 3: Synthesis of Compound 12

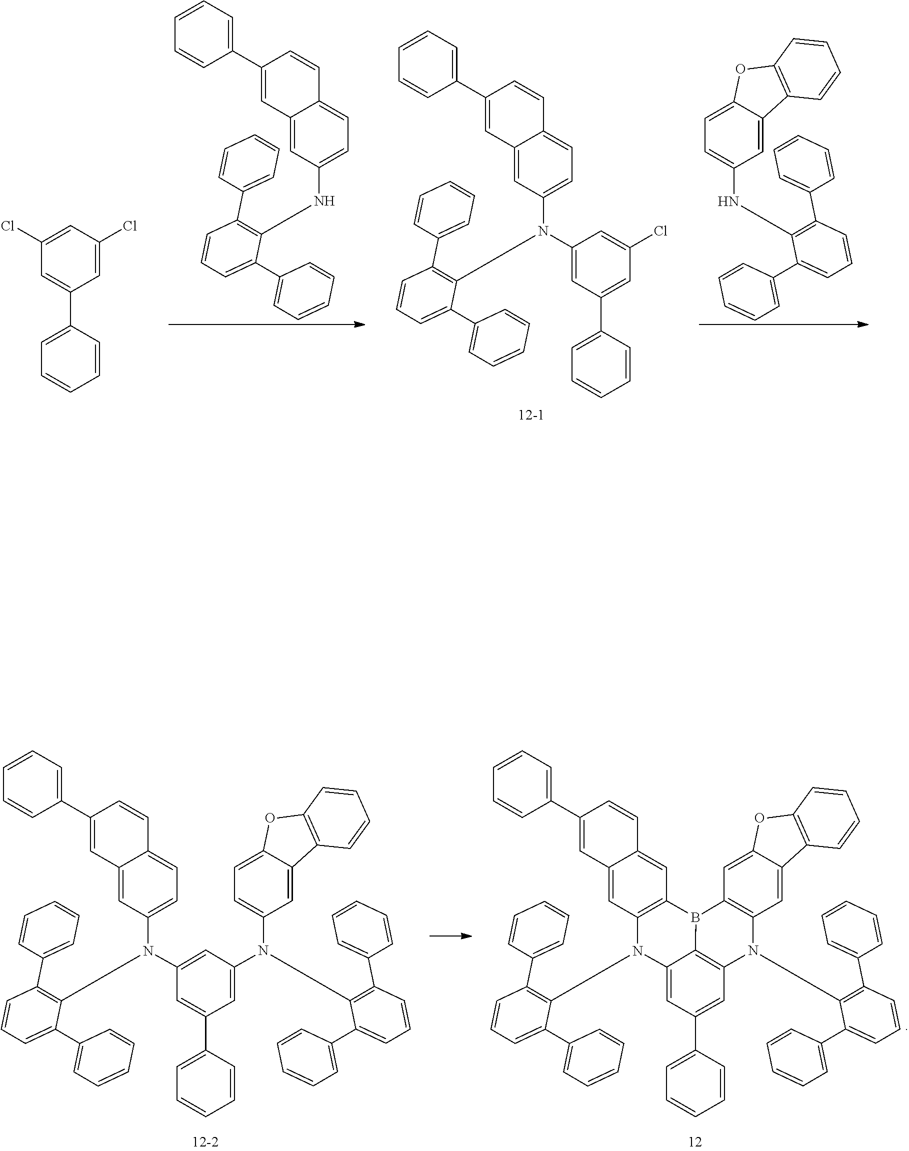 [SMILES: Clc1cc(Cl)cc(-c2ccccc2)c1 ; c1ccc(-c2ccc3ccc(Nc4c(-c5ccccc5)cccc4-c4ccccc4)cc3c2)cc1 ; Clc1cc(-c2ccccc2)cc(N(c2ccc3ccc(-c4ccccc4)cc3c2)c2c(-c3ccccc3)cccc2-c2ccccc2)c1 ; c1ccc(-c2cccc(-c3ccccc3)c2Nc2ccc3oc4ccccc4c3c2)cc1 ; c1ccc(-c2cc(N(c3ccc4ccc(-c5ccccc5)cc4c3)c3c(-c4ccccc4)cccc3-c3ccccc3)cc(N(c3ccc4oc5ccccc5c4c3)c3c(-c4ccccc4)cccc3-c3ccccc3)c2)cc1 ; c1ccc(-c2cc3c4c(c2)N(c2c(-c5ccccc5)cccc2-c2ccccc2)c2cc5c(cc2B4c2cc4ccc(-c6ccccc6)cc4cc2N3c2c(-c3ccccc3)cccc2-c2ccccc2)oc2ccccc25)cc1]

### (Synthesis of Intermediate 12-1)

3,5-dichloro-1,1′-biphenyl (1 eq), N-([1,1′:3′,1″-terphenyl]-2′-yl)-7-phenylnaphthalen-2-amine (1 eq), tris(dibenzylideneacetone)dipalladium(0) (0.05 eq), tri-tert-butylphosphine (0.1 eq), and sodium tert-butoxide (3 eq) were dissolved in toluene, and stirred at 110° C. for 24 hours. After cooling, the mixed solution was washed with ethyl acetate and water and separated, and the resulting organic layer was dried with MgSO₄ first and then dried again under reduced pressure. The resulting product was purified by column chromatography using MC and n-hexane to thereby obtain Intermediate 12-1. (Yield: 44%)

### (Synthesis of Intermediate 12-2)

Intermediate 12-1 (1 eq), N-([1,1′:3′,1″-terphenyl]-2′-yl)dibenzo[b,d]furan-2-amine (1 eq), tris(dibenzylideneacetone)dipalladium(0) (0.15 eq), tri-tert-butylphosphine (0.3 eq), and sodium tert-butoxide (5 eq) were dissolved in o-xylene, and stirred at 150° C. for 12 hours. After cooling, the mixed solution was washed with ethyl acetate and water and separated, and the resulting organic layer was dried with MgSO₄ first and then dried again under reduced pressure. The resulting product was purified by column chromatography using MC and n-hexane to thereby obtain Intermediate 12-2. (Yield: 43%)

### (Synthesis of Compound 12)

After dissolving Intermediate 12-2 (1 eq) in ortho dichlorobenzene, the mixed solution was cooled to 0° C., and BBr₃ (3 eq) was slowly added dropwise thereto in a nitrogen atmosphere. After completion of the dropwise addition, the temperature was raised to 180° C., and the resulting solution was stirred for 24 hours. After cooling, triethylamine was slowly added dropwise into the flask containing the reactant to terminate the reaction, and ethyl alcohol was added to the reactant, followed by precipitation and filtration to thereby obtain a reaction product. The resulting solid was purified by column chromatography using MC and n-hexane, and recrystallized with toluene and acetone to thereby obtain Compound 12. (Yield: 17%)

### Synthesis Example 4: Synthesis of Compound 61

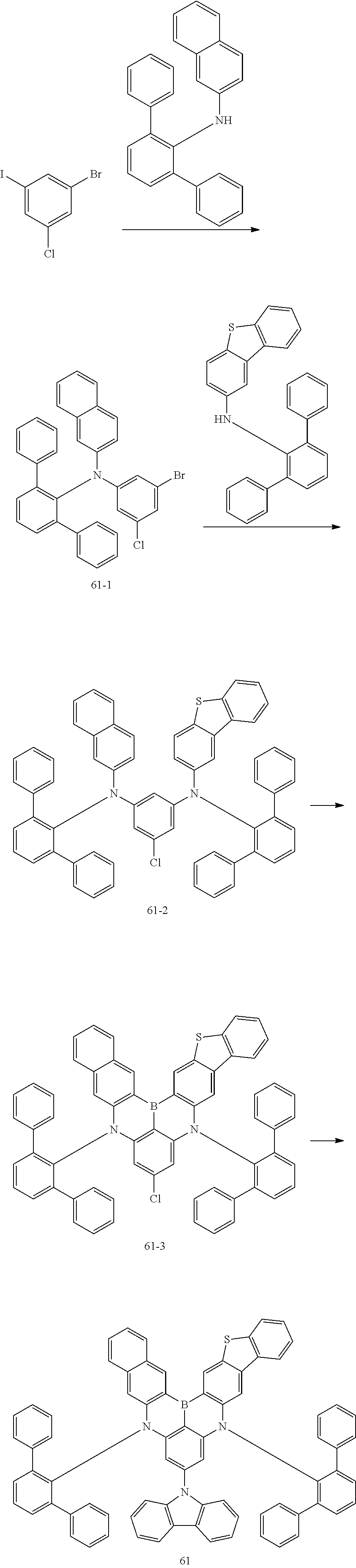

### (Synthesis of Intermediate 61-1)

1-bromo-3-chloro-5-iodobenzene (1 eq), N-([1,1′:3′,1″-terphenyl]-2′-yl)naphthalen-2-amine (0.9 eq), tris(dibenzylideneacetone)dipalladium(0) (0.05 eq), tri-tert-butylphosphine (0.1 eq), and sodium tert-butoxide (3 eq) were dissolved in toluene, and stirred at 90° C. for 8 hours. After cooling, the mixed solution was washed with ethyl acetate and water and separated, and the resulting organic layer was dried with MgSO₄ first and then dried again under reduced pressure. The resulting product was purified by column chromatography using MC and n-hexane to thereby obtain Intermediate 61-1. (Yield: 47%)

### (Synthesis of Intermediate 61-2)

Intermediate 61-1 (1 eq), N-([1,1′:3′,1″-terphenyl]-2′-yl)dibenzo[b,d]thiophen-2-amine (1 eq), tris(dibenzylideneacetone)dipalladium(0) (0.05 eq), tri-tert-butylphosphine (0.1 eq), and sodium tert-butoxide (3 eq) were dissolved in toluene, and stirred at 90° C. for 6 hours. After cooling, the mixed solution was washed with ethyl acetate and water and separated, and the resulting organic layer was dried with MgSO₄ first and then dried again under reduced pressure. The resulting product was purified by column chromatography using MC and n-hexane to thereby obtain Intermediate 61-2. (Yield: 36%)

### (Synthesis of Intermediate 61-3)

After dissolving Intermediate 61-2 (1 eq) in ortho dichlorobenzene, the mixed solution was cooled to 0° C., and BBr₃ (3 eq) was slowly added dropwise thereto in a nitrogen atmosphere. After completion of the dropwise addition, the temperature was raised to 180° C., and the resulting solution was stirred for 24 hours. After cooling, triethylamine was slowly added dropwise into the flask containing the reactant to terminate the reaction, and ethyl alcohol was added to the reactant, followed by precipitation and filtration to thereby obtain a reaction product. The resulting solid was purified by column chromatography using MC and n-hexane, and recrystallized with toluene and acetone to thereby obtain Intermediate 61-3. (Yield: 12%)

### (Synthesis of Compound 61)

Intermediate 61-3 (1 eq), carbazole (1.5 eq), tris(dibenzylideneacetone)dipalladium(0) (0.05 eq), tri-tert-butylphosphine (0.1 eq), and sodium tert-butoxide (3 eq) were dissolved in toluene, and stirred at 110° C. for 12 hours. After cooling, the mixed solution was washed with ethyl acetate and water and separated, and the resulting organic layer was dried with MgSO₄ first and then dried again under reduced pressure. The resulting product was purified by column chromatography using MC and n-hexane to thereby obtain Compound 61. (Yield: 67%)

### Synthesis Example 5: Synthesis of Compound 92

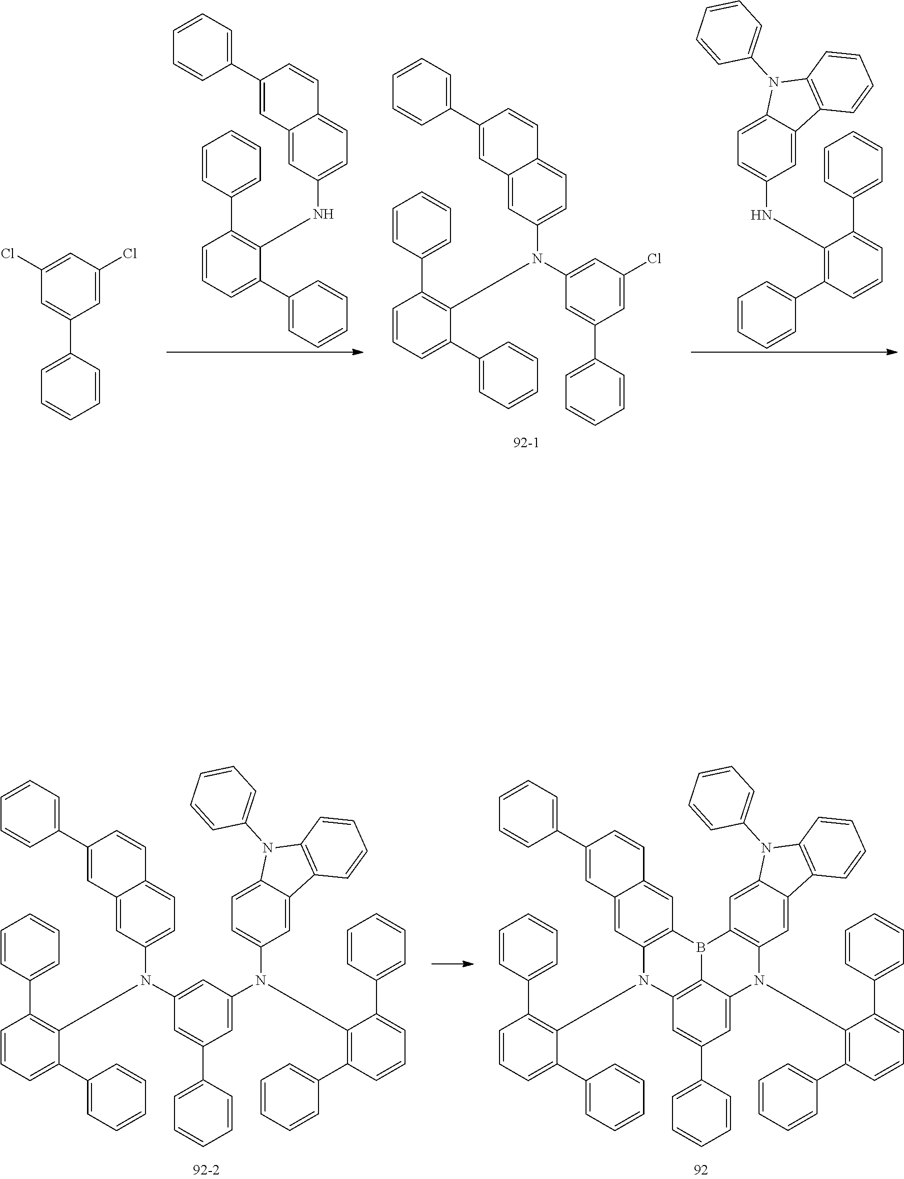

### (Synthesis of Intermediate 92-1)

3,5-dichloro-1,1′-biphenyl (1 eq), N-([1,1′: 3′,1″-terphenyl]-2′-yl)-7-phenylnaphthalen-2-amine (0.9 eq), tris(dibenzylideneacetone)dipalladium(0) (0.05 eq), tri-tert-butylphosphine (0.1 eq), and sodium tert-butoxide (3 eq) were dissolved in toluene, and stirred at 90° C. for 8 hours. After cooling, the mixed solution was washed with ethyl acetate and water and separated, and the resulting organic layer was dried with MgSO₄ first and then dried again under reduced pressure. The resulting product was purified by column chromatography using MC and n-hexane to thereby obtain Intermediate 92-1. (Yield: 45%)

### (Synthesis of Intermediate 92-2)

Intermediate 92-1 (1 eq), N-([1,1′: 3′,1″-terphenyl]-2′-yl)-9-phenyl-9H-carbazol-3-amine (1 eq), tris(dibenzylideneacetone)dipalladium(0) (0.05 eq), tri-tert-butylphosphine (0.1 eq), and sodium tert-butoxide (3 eq) were dissolved in toluene, and stirred at 110° C. for 24 hours. After cooling, the mixed solution was washed with ethyl acetate and water and separated, and the resulting organic layer was dried with MgSO₄ first and then dried again under reduced pressure. The resulting product was purified by column chromatography using MC and n-hexane to thereby obtain Intermediate 92-2. (Yield: 42%)

### (Synthesis of Compound 92)

After dissolving Intermediate 92-2 (1 eq) in ortho dichlorobenzene, the mixed solution was cooled to 0° C., and BBr₃ (3 eq) was slowly added dropwise thereto in a nitrogen atmosphere. After completion of the dropwise addition, the temperature was raised to 180° C., and the resulting solution was stirred for 24 hours. After cooling, triethylamine was slowly added dropwise into the flask containing the reactant to terminate the reaction, and ethyl alcohol was added to the reactant, followed by precipitation and filtration to thereby obtain a reaction product. The resulting solid was purified by column chromatography using MC and n-hexane, and recrystallized with toluene and acetone to thereby obtain Compound 92. (Yield: 14%)

### Synthesis Example 6: Synthesis of Compound 113

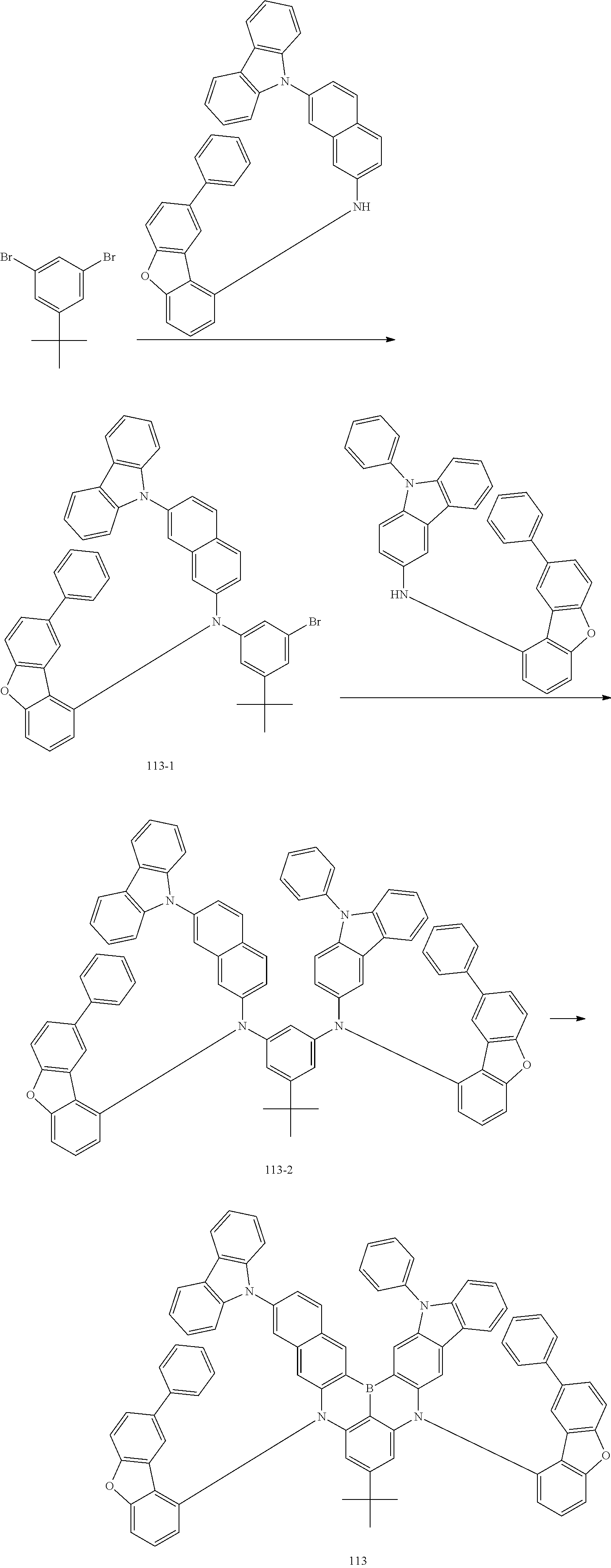

### (Synthesis of Intermediate 113-1)

1,3-dibromo-5-(tert-butyl)benzene (1 eq), N-(7-(9H-carbazol-9-yl)naphthalen-2-yl)-8-phenyldibenzo[b,d]furan-1-amine (1 eq), tris(dibenzylideneacetone)dipalladium(0) (0.05 eq), tri-tert-butylphosphine (0.1 eq), and sodium tert-butoxide (3 eq) were dissolved in toluene, and stirred at 100° C. for 12 hours. After cooling, the mixed solution was washed with ethyl acetate and water and separated, and the resulting organic layer was dried with MgSO₄ first and then dried again under reduced pressure. The resulting product was purified by column chromatography using MC and n-hexane to thereby obtain Intermediate 113-1. (Yield: 59%)

### (Synthesis of Intermediate 113-2)

Intermediate 113-1 (1 eq), 9-phenyl-N-(8-phenyldibenzo[b,d]furan-1-yl)-9H-carbazol-3-amine (1 eq), tris(dibenzylideneacetone)dipalladium(0) (0.15 eq), tri-tert-butylphosphine (0.3 eq), and sodium tert-butoxide (5 eq) were dissolved in o-xylene, and stirred at 150° C. for 48 hours. After cooling, the mixed solution was washed with ethyl acetate and water and separated, and the resulting organic layer was dried with MgSO₄ first and then dried again under reduced pressure. The resulting product was purified by column chromatography using MC and n-hexane to thereby obtain Intermediate 113-2. (Yield: 67%)

### (Synthesis of Compound 113)

After dissolving Intermediate 113-2 (1 eq) in ortho dichlorobenzene, the mixed solution was cooled to 0° C., and BBr₃ (3 eq) was slowly added dropwise thereto in a nitrogen atmosphere. After completion of the dropwise addition, the temperature was raised to 180° C., and the resulting solution was stirred for 24 hours. After cooling, triethylamine was slowly added dropwise into the flask containing the reactant to terminate the reaction, and ethyl alcohol was added to the reactant, followed by precipitation and filtration to thereby obtain a reaction product. The resulting solid was purified by column chromatography using MC and n-hexane, and recrystallized with toluene and acetone to thereby obtain Compound 113. (Yield: 12%)

Synthesis methods of compounds other than the compounds synthesized in Synthesis Examples 1 to 6 may be easily recognized by those skilled in the art by referring to the synthesis paths and source materials.

### Evaluation Example 1: Evaluation of Characteristics of Condensed Cyclic Compounds

The HOMO energy level (E_{HOMO}), LUMO energy level (E_{LUMO}), oscillator strength coefficient (OSC), singlet excitation energy (S1), and triplet excitation energy (T1) of each of the compounds were evaluated using the Density Functional Theory (DFT) method of the Gaussian program which is structurally optimized at the level of B3LYP/6-31G(d,p) (e.g., at a level of theory utilizing a B3LYP hybrid functional and 6-31G(d,p) basis set), and the results are shown in Table 1.

TABLE 1

| Compound | E_{HOMO} | E_{LUMO} | OSC | S1 | S1 | T1 |
|---|---|---|---|---|---|---|
| No. | [eV] | [eV] | [no unit] | [eV] | [nm] | [eV] |
| Compound | −4.98 | −1.9 | 0.211 | 2.5887 | 479 | 2.1716 |
| 2 | | | | | | |
| Compound | −5.08 | −1.99 | 0.249 | 2.5941 | 478 | 2.1869 |
| 6 | | | | | | |
| Compound | −5.03 | −1.97 | 0.226 | 2.5780 | 481 | 2.1490 |
| 12 | | | | | | |
| Compound | −5.16 | −2.01 | 0.198 | 2.6552 | 467 | 2.2103 |
| 61 | | | | | | |
| Compound | −4.87 | −1.88 | 0.214 | 2.5152 | 493 | 2.1269 |
| 92 | | | | | | |
| Compound | −4.97 | −1.97 | 0.231 | 2.5203 | 492 | 2.1416 |
| 113 | | | | | | |
| Compound | −4.85 | −1.76 | 0.221 | 2.6050 | 476 | 2.1678 |
| 143 | | | | | | |
| Compound | −4.94 | −1.89 | 0.238 | 2.5726 | 482 | 2.1379 |
| 144 | | | | | | |
| Compound | −5.02 | −1.96 | 0.308 | 2.5615 | 484.1 | 2.2135 |
| C1 | | | | | | |
| Compound | −4.81 | −1.56 | 0.24 | 2.7616 | 449 | 2.3709 |
| C2 | | | | | | |
| Compound | −4.96 | −1.95 | 0.201 | 2.5306 | 490 | 2.0946 |
| C3 | | | | | | |

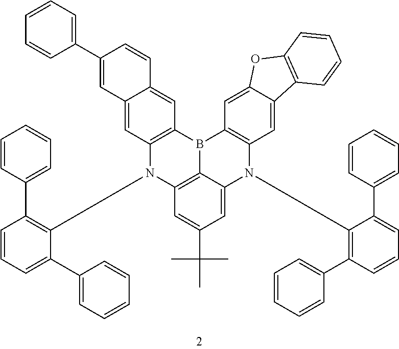 [SMILES: CC(C)(C)c1cc2c3c(c1)N(c1c(-c4ccccc4)cccc1-c1ccccc1)c1cc4c(cc1B3c1cc3ccc(-c5ccccc5)cc3cc1N2c1c(-c2ccccc2)cccc1-c1ccccc1)oc1ccccc14]

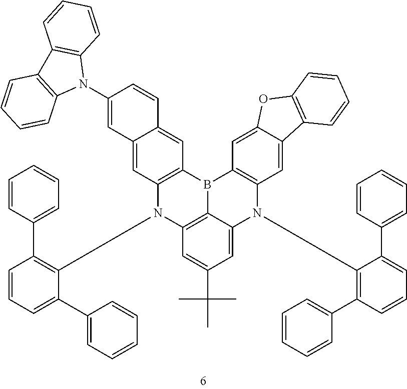 [SMILES: CC(C)(C)c1cc2c3c(c1)N(c1c(-c4ccccc4)cccc1-c1ccccc1)c1cc4c(cc1B3c1cc3ccc(-n5c6ccccc6c6ccccc65)cc3cc1N2c1c(-c2ccccc2)cccc1-c1ccccc1)oc1ccccc14]

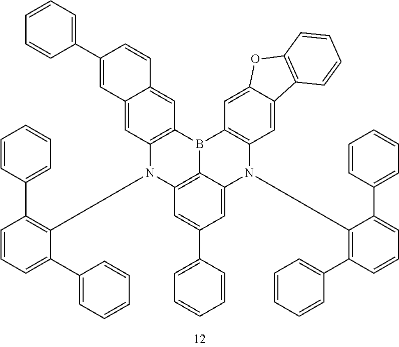 [SMILES: c1ccc(-c2cc3c4c(c2)N(c2c(-c5ccccc5)cccc2-c2ccccc2)c2cc5c(cc2B4c2cc4ccc(-c6ccccc6)cc4cc2N3c2c(-c3ccccc3)cccc2-c2ccccc2)oc2ccccc25)cc1]

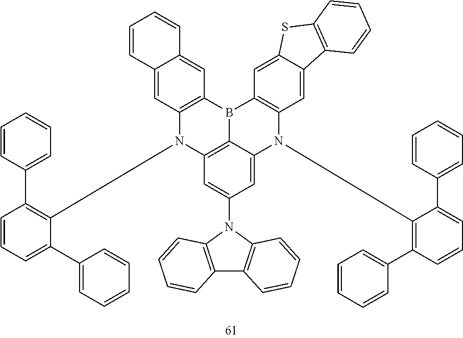 [SMILES: c1ccc(-c2cccc(-c3ccccc3)c2N2c3cc4ccccc4cc3B3c4cc5sc6ccccc6c5cc4N(c4c(-c5ccccc5)cccc4-c4ccccc4)c4cc(-n5c6ccccc6c6ccccc65)cc2c43)cc1]

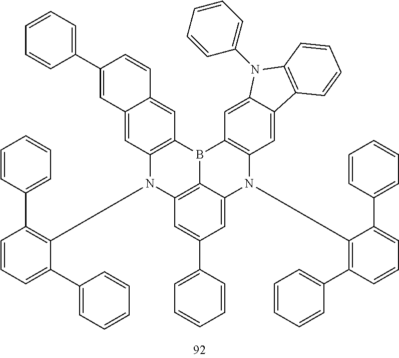 [SMILES: c1ccc(-c2cc3c4c(c2)N(c2c(-c5ccccc5)cccc2-c2ccccc2)c2cc5c6ccccc6n(-c6ccccc6)c5cc2B4c2cc4ccc(-c5ccccc5)cc4cc2N3c2c(-c3ccccc3)cccc2-c2ccccc2)cc1]

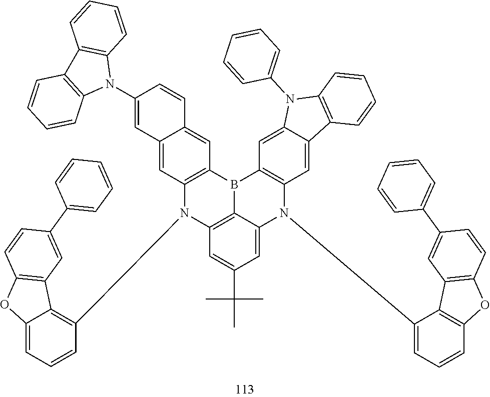 [SMILES: CC(C)(C)c1cc2c3c(c1)N(c1cccc4oc5ccc(-c6ccccc6)cc5c14)c1cc4c5ccccc5n(-c5ccccc5)c4cc1B3c1cc3ccc(-n4c5ccccc5c5ccccc54)cc3cc1N2c1cccc2oc3ccc(-c4ccccc4)cc3c12]

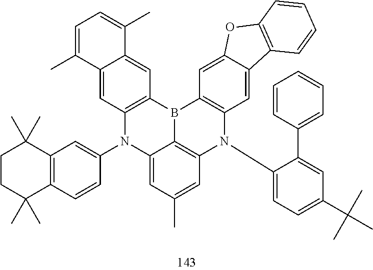 [SMILES: Cc1cc2c3c(c1)N(c1ccc(C(C)(C)C)cc1-c1ccccc1)c1cc4c(cc1B3c1cc3c(C)ccc(C)c3cc1N2c1ccc2c(c1)C(C)(C)CCC2(C)C)oc1ccccc14]

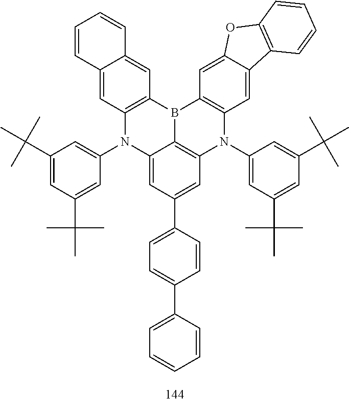 [SMILES: CC(C)(C)c1cc(N2c3cc4ccccc4cc3B3c4cc5oc6ccccc6c5cc4N(c4cc(C(C)(C)C)cc(C(C)(C)C)c4)c4cc(-c5ccc(-c6ccccc6)cc5)cc2c43)cc(C(C)(C)C)c1]

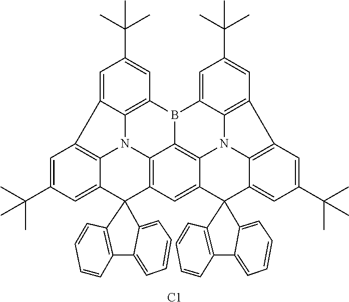

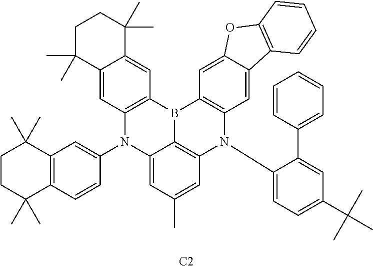

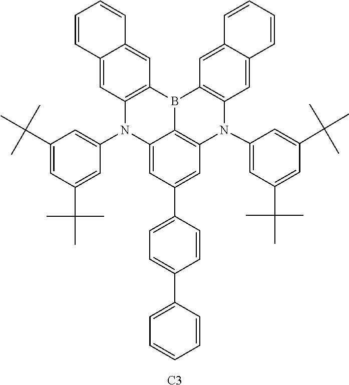

Referring to Table 1, it can be confirmed that, in the condensed cyclic compounds according to the disclosure, green light may be realized by partially adjusting the multiple resonance rule according to the HOMO and LUMO that are alternately arranged in the core, without further fusing rings in the condensed cyclic compound together to broaden conjugation, as in comparative Compound C1. Moreover, because the rings in the condensed cyclic compound are not further fused together, a substituent for protecting the core may be introduced to a nitrogen atom, and thus, the condensed compound may have an improved degree of freedom in structural improvement.

In one or more embodiments, it can be confirmed that, in the condensed cyclic compounds according to the disclosure, compared to Compounds C₂ and C₃, by increasing the intermolecular distance, side effects due to concentration quenching and/or intermolecular interactions (formation of an excimer, an exciplex, and/or the like) may be prevented or reduced, and the triplet exciton density, which is of a great importance in a device using triplet excitons, may be lowered.

Accordingly, it is expected (or believed) that the condensed cyclic compound represented by Formula 1 may be used to manufacture an excellent or suitable green light-emitting device.

### Example 1

A Corning 15 Ω/cm² (1,200 Å) ITO glass substrate (anode) was cut to a size of 50 mm×50 mm×0.7 mm, sonicated with isopropyl alcohol and pure water each for 5 minutes, and then cleaned by exposure to ultraviolet rays and ozone for 30 minutes. Then, the ITO glass substrate was mounted on a vacuum deposition apparatus.

HT3 was vacuum-deposited on the glass substrate to form a hole transport layer having a thickness of 600 Å. HT47 was vacuum-deposited on the hole transport layer to form an electron-blocking layer having a thickness of 100 Å.

On the electron-blocking layer, a host compound in which a first host (HTH1) and a second host (ETH26) were mixed at a weight ratio of 1:1, a phosphorescent sensitizer (PD40), and a green light emitter (Compound 2) were co-deposited at a weight ratio of 85:14:1 to form an emission layer having a thickness of 300 Å.

ET46 was vacuum-deposited on the emission layer to form a hole-blocking layer having a thickness of 50 Å, and ET47 and LiQ (a weight ratio of 5:5) were deposited thereon to form an electron transport layer having a thickness of 300 Å. LiQ was deposited on the electron transport layer to form an electron injection layer having a thickness of 10 Å.

Al was vacuum-deposited on the electron injection layer to form a cathode having a thickness of a 1,000 Å, thereby completing the manufacture of a light-emitting device.

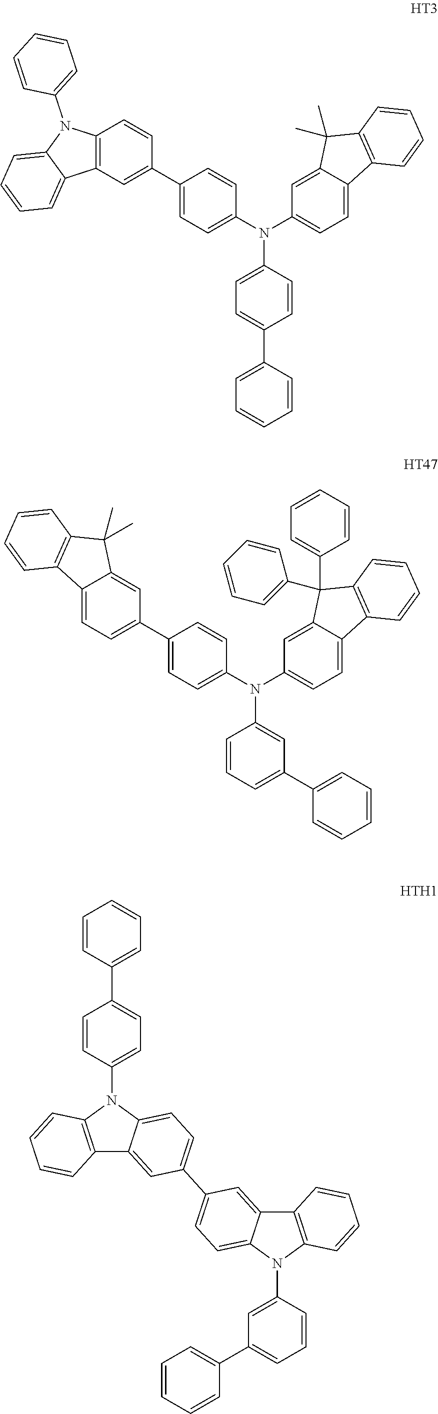 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(-c3ccc(N(c4cccc(-c5ccccc5)c4)c4ccc5c(c4)C(c4ccccc4)(c4ccccc4)c4ccccc4-5)cc3)cc21 ; c1ccc(-c2ccc(-n3c4ccccc4c4cc(-c5ccc6c(c5)c5ccccc5n6-c5cccc(-c6ccccc6)c5)ccc43)cc2)cc1]

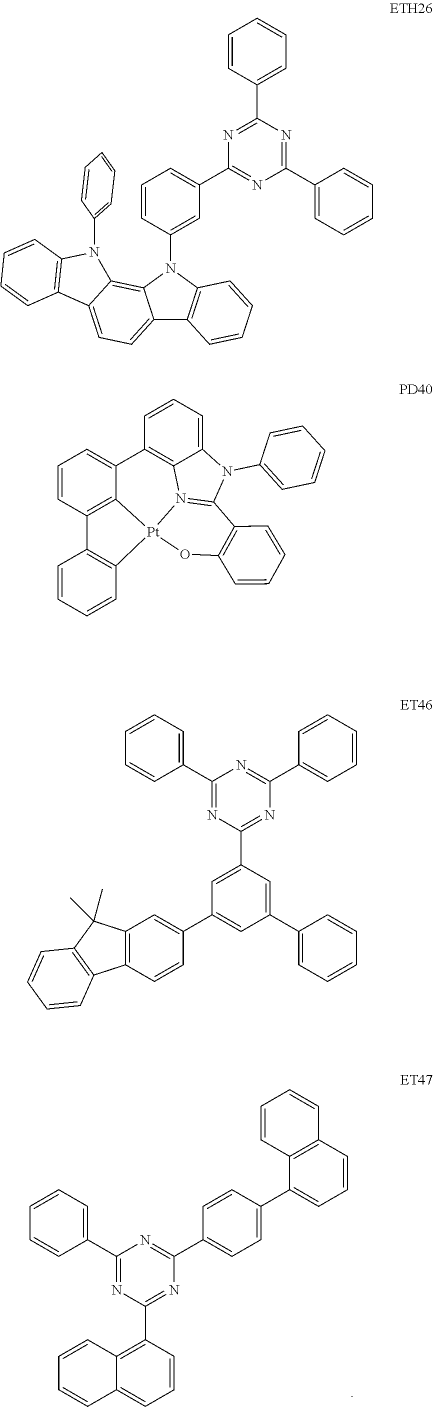

### Examples 2 to 8 and Comparative Examples 1 to 3

Light-emitting devices were manufactured in substantially the same manner as in Example 1, except that, in forming an emission layer, compounds as shown in Table 2 were each used as a green light emitter.

### Evaluation Example 2: Evaluation of Characteristics of Light-Emitting Devices

To evaluate the characteristics of the light-emitting devices manufactured in Examples 1 to 8 and Comparative Examples 1 to 3, the driving voltage (V), luminescence efficiency (cd/A), maximum emission wavelength (nm), and device lifespan (h) of each of the manufactured light-emitting devices at the luminance of 1,000 cd/m2 were measured using Keithley SMU 236 and luminance meter PR650, and the results are shown in Table 2. In Table 2, the lifespan ratio (T₉₅) is a measure of the time (h) taken for the luminance to reach 95% of the initial luminance of the light-emitting devices, and is expressed as a relative value evaluated based on the value of Comparative Example 1. In Table 2, the driving voltage is expressed as a relative value evaluated based on the value of Comparative Example 1.

TABLE 2

| | | | | Relative | | Maximum | Lifespan |
|---|---|---|---|---|---|---|---|
| | | Phosphore | | Driving | | emission | ratio |
| | | scent | Green light | voltage | Efficiency | wavelength | (T₉₅) |
| | Host | sensitizer | emitter | [%] | [cd/A] | [nm] | [%] |
| Example 1 | HTH1/ETH26 | PD40 | Compound 2 | 96 | 129 | 524 | 147 |
| Example 2 | HTH1/ETH26 | PD40 | Compound 6 | 97 | 135 | 526 | 136 |
| Example 3 | HTH1/ETH26 | PD40 | Compound 12 | 95 | 141 | 525 | 146 |
| Example 4 | HTH1/ETH26 | PD40 | Compound 61 | 99 | 118 | 516 | 131 |
| Example 5 | HTH1/ETH26 | PD40 | Compound 92 | 94 | 132 | 533 | 128 |
| Example 6 | HTH1/ETH26 | PD40 | Compound 113 | 98 | 123 | 531 | 134 |
| Example 7 | HTH1/ETH26 | PD40 | Compound 143 | 100 | 101 | 519 | 111 |
| Example 8 | HTH1/ETH26 | PD40 | Compound 144 | 99 | 104 | 526 | 105 |
| Comparative | HTH1/ETH26 | PD40 | Compound C1 | 100 | 98 | 531 | 100 |
| Example 1 | | | | | | | |
| Comparative | HTH1/ETH26 | PD40 | Compound C2 | 177 | 76 | 529 | 33 |
| Example 2 | | | | | | | |
| Comparative | HTH1/ETH26 | PD40 | Compound C3 | 123 | 91 | 539 | 42 |
| Example 3 | | | | | | | |

Referring to Table 2, it can be confirmed that the light-emitting devices of Examples 1 to 8 exhibit higher efficiency and longer lifespan than the light-emitting devices of Comparative Examples 1 to 3, thereby exhibiting significantly superior characteristics as green light-emitting devices. It can be confirmed that the light-emitting devices of Examples 1 to 8 also have excellent driving voltage characteristics that are equal to or lower than those of the light-emitting devices of Comparative Examples 1 to 3.

It is assumed (or believed), without being bound by any particular theory, that Compound C1 used in Comparative Example 1, in which green light is realized by further fusing rings in the condensed cyclic compound to broaden conjugation, has increased molecular planarity that causes side effects due to intermolecular interactions, resulting in poor efficiency and lifespan characteristics.

It is assumed (or believed), without being bound by any particular theory, that Compound C2 used in Comparative Example 2, which has a short-conjugated structure in which an alkyl group is condensed, has emission characteristics of a relatively short wavelength region that are not suitable in terms of energy transfer, and thus, light is emitted by a phosphorescent dopant. Accordingly, it is assumed that Compound C2 used in Comparative Example 2, which has relatively high energy, is used as a sensitizer contrary to the intended use thereof, resulting in poor efficiency and lifespan characteristics.

It is assumed (or believed), without being bound by any particular theory, that Compound C3 used in Comparative Example 3, which does not include a dibenzofuran group in the core thereof, has low (e.g., unsuitably low) absorbance (e.g., unsuitably low oscillator strength) and reduced efficiency, such that more current is desired or required to achieve the same luminance, resulting in poor lifespan characteristics.

According to the one or more embodiments, the use of a condensed cyclic compound represented by Formula 1 may enable the manufacture of a green light-emitting device having suitably high efficiency and a long lifespan and a high-quality electronic apparatus including the green light-emitting device.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A light-emitting device comprising:
a first electrode;
a second electrode facing the first electrode;
an interlayer between the first electrode and the second electrode and comprising an emission layer; and
a condensed cyclic compound represented by Formula 1: 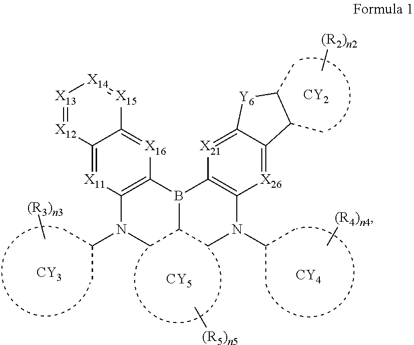
wherein, in Formula 1,
CY₂ to CY₅ are each independently a C₃-C₆₀ carbocyclic group or a C₁-C₆₀ heterocyclic group,
Y₆ is C(R₆₁)(R₆₂), N(R₆₁), O, Si(R₆₁)(R₆₂), P(R₆₁), or S,
X₁₁ is N or C(R₁₁), X₁₂ is N or C(R₁₂), X₁₃ is N or C(R₁₃), X₁₄ is N or C(R₁₄), X₁₅ is N or C(R₁₅), and X₁₆ is N or C(R₁₆),
X₂₁ is N or C(R₂₁), and X₂₆ is N or C(R₂₆),
n2 to n5 are each independently an integer from 0 to 10,
when n2 is 2 or more, R₂ in the number of n2 are identical to or different from each other,
when n3 is 2 or more, R₃ in the number of n3 are identical to or different from each other,
when n4 is 2 or more, R₄ in the number of n4 are identical to or different from each other,
when n5 is 2 or more, R₅ in the number of n5 are identical to or different from each other,
R₁₁ to R₁₆, R₂, R₂₁, R₂₆, R₃, R₄, R₅, R₆₁, and R₆₂ are each independently hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂),
neighboring two or more selected from among R₁₁ to R₁₆, R₂, R₂₁, R₂₆, R₃, R₄, R₅, R₆₁, R₆₂, and Q₁ to Q₃ are optionally bonded to each other to form a C₅-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

2. The light-emitting device of claim 1, wherein the first electrode is an anode,
the second electrode is a cathode,
the interlayer further comprises a hole transport region between the first electrode and the emission layer, and an electron transport region between the emission layer and the second electrode,
the hole transport region comprises a hole injection layer, a hole transport layer, an emission auxiliary layer, an electron-blocking layer, or any combination thereof, and
the electron transport region comprises a buffer layer, a hole-blocking layer, an electron control layer, an electron transport layer, an electron injection layer, or any combination thereof.

3. The light-emitting device of claim 1, wherein the condensed cyclic compound represented by Formula 1 is in the emission layer.

4. The light-emitting device of claim 1, wherein the emission layer is to emit green light.

5. The light-emitting device of claim 1, wherein the emission layer comprises a host and a dopant, and
the dopant comprises the condensed cyclic compound represented by Formula 1.

6. The light-emitting device of claim 5, wherein the dopant further comprises a phosphorescent dopant.

7. An electronic apparatus comprising the light-emitting device of claim 1.

8. The electronic apparatus of claim 7, further comprising a thin-film transistor,
wherein the thin-film transistor comprises a source electrode and a drain electrode, and
the first electrode of the light-emitting device is electrically connected to at least one selected from among the source electrode and the drain electrode of the thin-film transistor.

9. The electronic apparatus of claim 7, further comprising a color filter, a color conversion layer, a touch screen layer, a polarizing layer, or any combination thereof.

10. Electronic equipment comprising the light-emitting device of claim 1.

11. The electronic equipment of claim 10, wherein the electronic equipment is one selected from among a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall comprising multiple displays tiled together, a theater screen, a stadium screen, a phototherapy device, and a signboard.

12. A condensed cyclic compound represented by Formula 1: 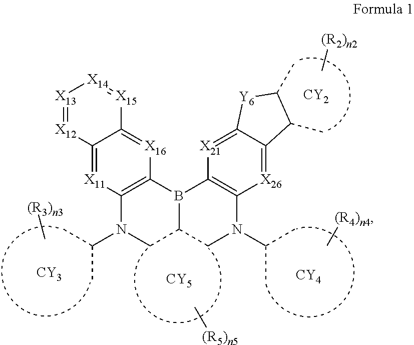
wherein, in Formula 1,
CY₂ to CY₅ are each independently a C₃-C₆₀ carbocyclic group or a C₁-C₆₀ heterocyclic group,
Y₆ is C(R₆₁)(R₆₂), N(R₆₁), O, Si(R₆₁)(R₆₂), P(R₆₁), or S,
X₁₁ is N or C(R₁₁), X₁₂ is N or C(R₁₂), X₁₃ is N or C(R₁₃), X₁₄ is N or C(R₁₄), X₁₅ is N or C(R₁₅), and X₁₆ is N or C(R₁₆),
X₂₁ is N or C(R₂₁), and X₂₆ is N or C(R₂₆),
n2 to n5 are each independently an integer from 0 to 10,
when n2 is 2 or more, R₂ in the number of n2 are identical to or different from each other,
when n3 is 2 or more, R₃ in the number of n3 are identical to or different from each other,
when n4 is 2 or more, R₄ in the number of n4 are identical to or different from each other,
when n5 is 2 or more, R₅ in the number of n5 are identical to or different from each other,
R₁₁ to R₁₆, R₂, R₂₁, R₂₆, R₃, R₄, R₅, R₆₁, and R₆₂ are each independently hydrogen, deuterium, —F, —Cl, —Br, —I, a hydroxyl group, a cyano group, a nitro group, an amidino group, a hydrazino group, a hydrazono group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₁₀ cycloalkyl group unsubstituted or substituted with at least one R₁₀ₐ, a C₁-C₁₀ heterocycloalkyl group unsubstituted or substituted with at least one R₁₀ₐ, a C₃-C₁₀ cycloalkenyl group unsubstituted or substituted with at least one R₁₀ₐ, a C₁-C₁₀ heterocycloalkenyl group unsubstituted or substituted with at least one R₁₀ₐ, a C₆-C₆₀ aryl group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₁-C₆₀ heteroaryl group unsubstituted or substituted with at least one R₁₀ₐ, a C₁-C₆₀ heteroaryloxy group unsubstituted or substituted with at least one R₁₀ₐ, a C₁-C₆₀ heteroarylthio group unsubstituted or substituted with at least one R₁₀ₐ, a C₇-C₆₀ arylalkyl group unsubstituted or substituted with at least one R₁₀ₐ, a C₂-C₆₀ heteroarylalkyl group unsubstituted or substituted with at least one R₁₀ₐ, a monovalent non-aromatic condensed polycyclic group unsubstituted or substituted with at least one R₁₀ₐ, a monovalent non-aromatic condensed heteropolycyclic group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂),
neighboring two or more selected from among R₁₁ to R₁₆, R₂, R₂₁, R₂₆, R₃, R₄, R₅, R₆₁, R₆₂, and Q₁ to Q₃ are optionally bonded to each other to form a C₅-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

13. The condensed cyclic compound of claim 12, wherein CY₂ to CY₅ are each independently a benzene group, a naphthalene group, an anthracene group a phenanthrene group, a fluoranthene group, a triphenylene group, a pyrene group, a chrysene group, an indene group, a fluorene group, a spiro-bifluorene group, a benzofluorene group, a dibenzofluorene group, an indole group, a pyridine group, a pyrimidine group, a carbazole group, a benzocarbazole group, a dibenzocarbazole group, a furan group, a benzofuran group, a dibenzofuran group, a naphthofuran group, a benzonaphthofuran group, a dinaphthofuran group, a thiophene group, a benzothiophene group, a dibenzothiophene group, a naphthothiophene group, a benzonaphthothiophene group, or a dinaphthothiophene group.

14. The condensed cyclic compound of claim 12, wherein the condensed cyclic compound represented by Formula 1 is a compound represented by Formula 1-1: 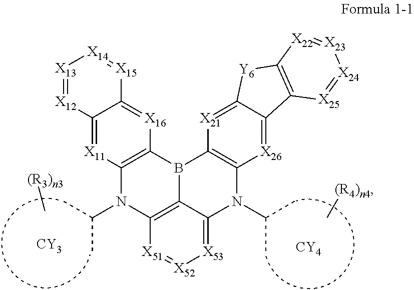
wherein, in Formula 1-1,
CY₃, CY₄, Y₆, X₁₁ to X₁₆, X₂₁, X₂₆, n3, n4, R₃, and R₄ are each as respectively described in Formula 1,
X₂₂ is N or C(R₂₂), X₂₃ is N or C(R₂₃), X₂₄ is N or C(R₂₄), and X₂₅ is N or C(R₂₅),
X₅₁ is N or C(R₅₁), X₅₂ is N or C(R₅₂), and X₅₃ is N or C(R₅₃),
R₂₂ to R₂₅ are each independently as described in connection with R₂ in Formula 1, and
R₅₁ to R₅₃ are each independently as described in connection with R₅ in Formula 1.

15. The condensed cyclic compound of claim 12, wherein the condensed cyclic compound represented by Formula 1 is a compound represented by Formula 1-2: 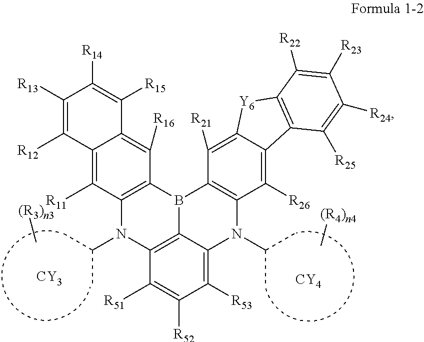
wherein, in Formula 1-2,
CY₃, CY₄, Y₆, n3, n4, R₁₁ to R₁₆, R₂₁, R₂₆, R₃, and R₄ are each as respectively described in Formula 1,
R₂₂ to R₂₅ are each independently as described in connection with R₂ in Formula 1, and
R₅₁ to R₅₃ are each independently as described in connection with R₅ in Formula 1.

16. The condensed cyclic compound of claim 12, wherein a group represented by 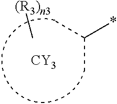
is a group represented by Formula 3: 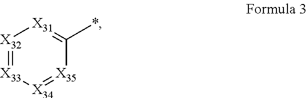
wherein, in Formula 3,
X₃₁ is N or C(R₃₁), X₃₂ is N or C(R₃₂), X₃₃ is N or C(R₃₃), X₃₄ is N or C(R₃₄), and X₃₅ is N or C(R₃₅),
R₃₁ to R₃₅ are each independently as described in connection with R₃ in Formula 1, and
* indicates a binding site to a neighboring nitrogen atom.

17. The condensed cyclic compound of claim 12, wherein a group represented by 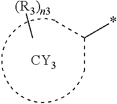
is a group represented by one selected from among Formulae 3A to 3E: 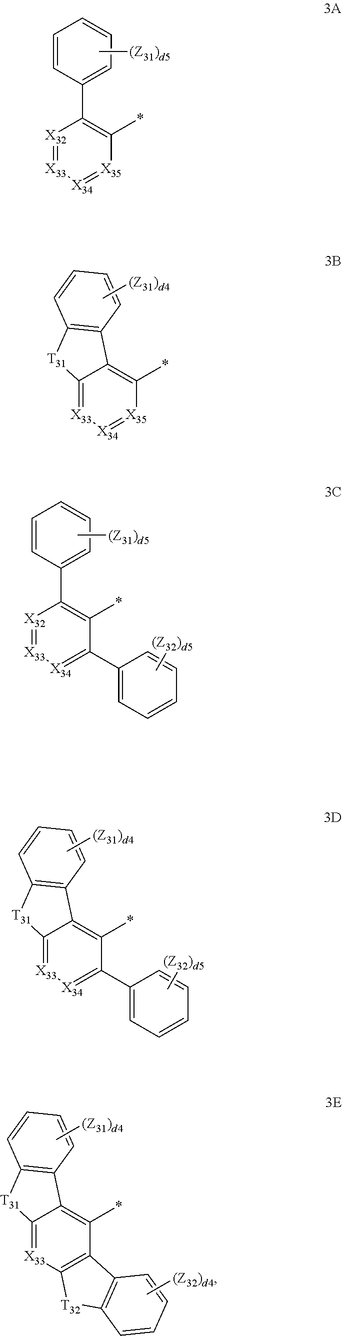
wherein, in Formulae 3A to 3E,
T₃₁ and T₃₂ are each independently C(Z₃₃)(Z₃₄), N(Z₃₃), O, Si(Z₃₃)(Z₃₄), P(Z₃₃), or S,
X₃₂ is N or C(R₃₂), X₃₃ is N or C(R₃₃), X₃₄ is N or C(R₃₄), and X₃₅ is N or C(R₃₅),
R₃₂ to R₃₅ are each independently as described in connection with R₃ in Formula 1,
Z₃₁ to Z₃₄ are each independently as described in connection with R₁₀ₐ in Formula 1,
d4 is an integer from 0 to 4,
d5 is an integer from 0 to 5, and
* indicates a binding site to a neighboring nitrogen atom.

18. The condensed cyclic compound of claim 12, wherein a group represented by 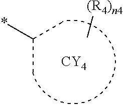
is a group represented by Formula 4: 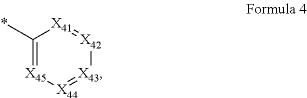
wherein, in Formula 4,
X₄₁ is N or C(R₄₁), X₄₂ is N or C(R₄₂), X₄₃ is N or C(R₄₃), X₄₄ is N or C(R₄₄), and X₄₅ is N or C(R₄₅),
R₄₁ to R₄₅ are each independently as described in connection with R₄ in Formula 1, and
* indicates a binding site to a neighboring nitrogen atom.

19. The condensed cyclic compound of claim 12, wherein a group represented by 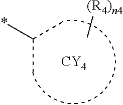
is a group represented by one selected from among Formulae 4A to 4E: 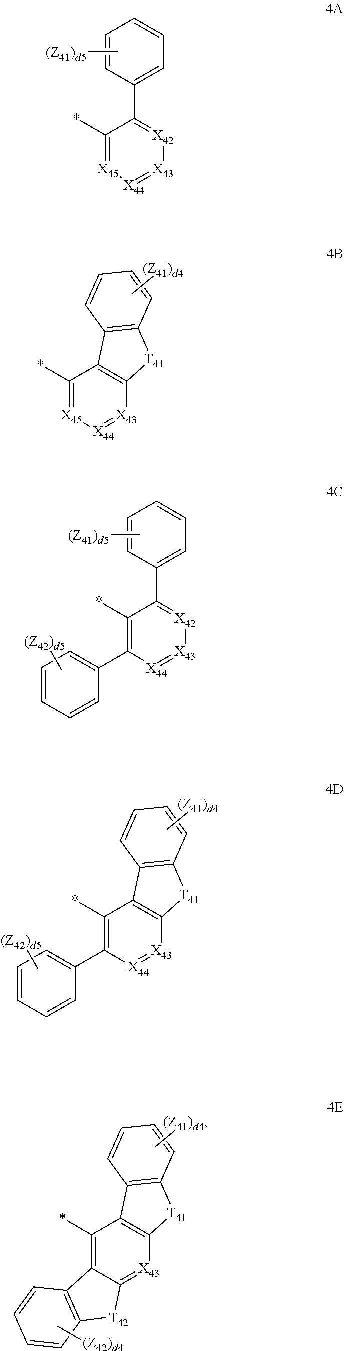
wherein, in Formulae 4A to 4E,
T₄₁ and T₄₂ are each independently C(Z₄₃)(Z₄₄), N(Z₄₃), O, Si(Z₄₃)(Z₄₄), P(Z₄₃), or S,
X₄₂ is N or C(R₄₂), X₄₃ is N or C(R₄₃), X₄₄ is N or C(R₄₄), and X₄₅ is N or C(R₄₅),
R₄₂ to R₄₅ are each independently as described in connection with R₄ in Formula 1,
Z₄₁ to Z₄₄ are each independently as described in connection with R₁₀ₐ in Formula 1,
d4 is an integer from 0 to 4,
d5 is an integer from 0 to 5, and
* indicates a binding site to a neighboring nitrogen atom.

20. The condensed cyclic compound of claim 12, wherein the condensed cyclic compound represented by Formula 1 is one selected from among Compounds 1 to 144: 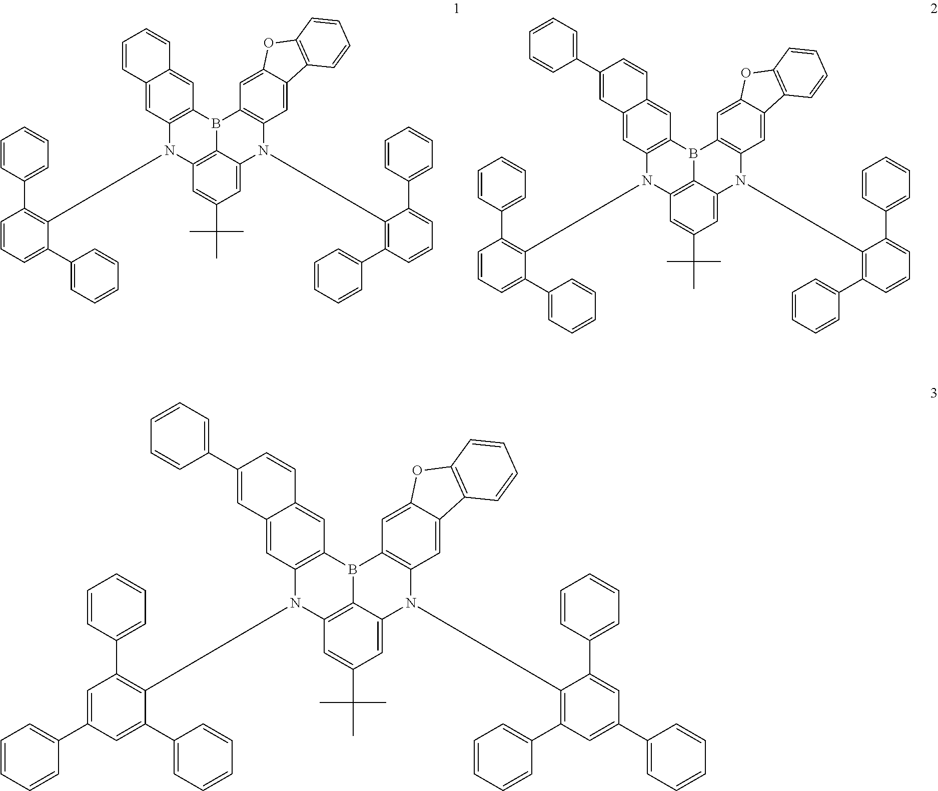 [SMILES: CC(C)(C)c1cc2c3c(c1)N(c1c(-c4ccccc4)cccc1-c1ccccc1)c1cc4c(cc1B3c1cc3ccccc3cc1N2c1c(-c2ccccc2)cccc1-c1ccccc1)oc1ccccc14 ; CC(C)(C)c1cc2c3c(c1)N(c1c(-c4ccccc4)cccc1-c1ccccc1)c1cc4c(cc1B3c1cc3ccc(-c5ccccc5)cc3cc1N2c1c(-c2ccccc2)cccc1-c1ccccc1)oc1ccccc14 ; CC(C)(C)c1cc2c3c(c1)N(c1c(-c4ccccc4)cc(-c4ccccc4)cc1-c1ccccc1)c1cc4c(cc1B3c1cc3ccc(-c5ccccc5)cc3cc1N2c1c(-c2ccccc2)cc(-c2ccccc2)cc1-c1ccccc1)oc1ccccc14] 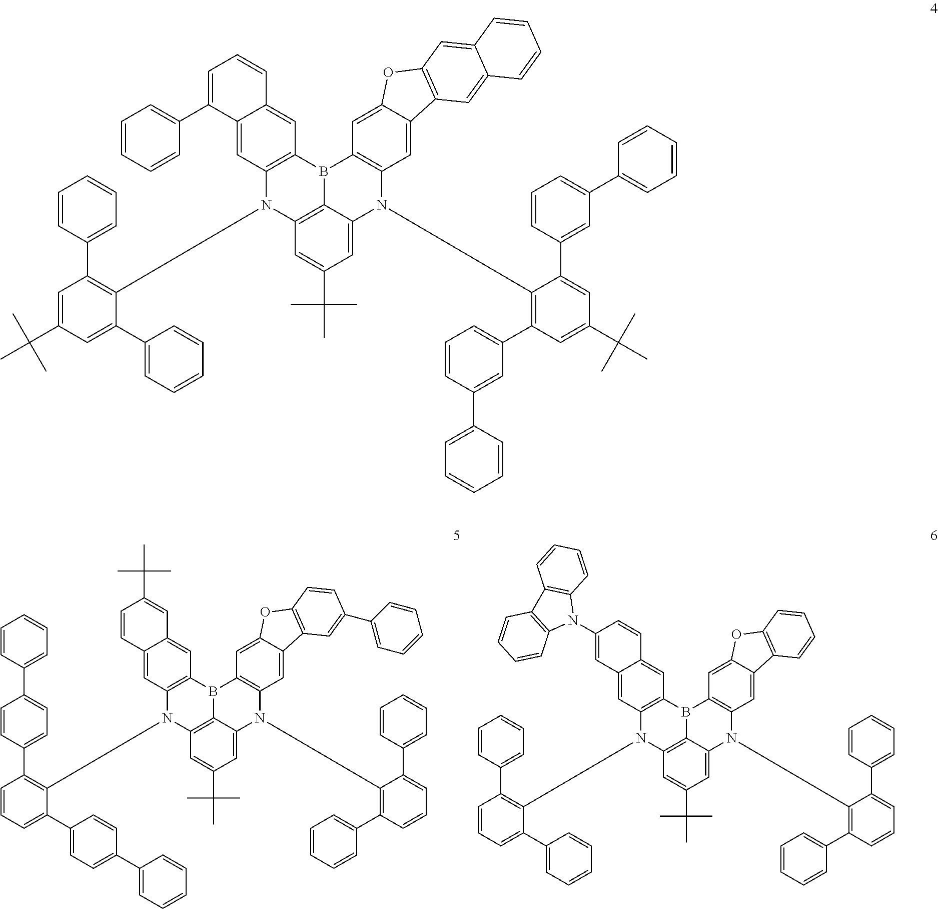 [SMILES: CC(C)(C)c1cc(-c2ccccc2)c(N2c3cc4c(-c5ccccc5)cccc4cc3B3c4cc5oc6cc7ccccc7cc6c5cc4N(c4c(-c5cccc(-c6ccccc6)c5)cc(C(C)(C)C)cc4-c4cccc(-c5ccccc5)c4)c4cc(C(C)(C)C)cc2c43)c(-c2ccccc2)c1 ; CC(C)(C)c1cc2c3c(c1)N(c1c(-c4ccccc4)cccc1-c1ccccc1)c1cc4c(cc1B3c1cc3cc(C(C)(C)C)ccc3cc1N2c1c(-c2ccc(-c3ccccc3)cc2)cccc1-c1ccc(-c2ccccc2)cc1)oc1ccc(-c2ccccc2)cc14 ; CC(C)(C)c1cc2c3c(c1)N(c1c(-c4ccccc4)cccc1-c1ccccc1)c1cc4c(cc1B3c1cc3ccc(-n5c6ccccc6c6ccccc65)cc3cc1N2c1c(-c2ccccc2)cccc1-c1ccccc1)oc1ccccc14] 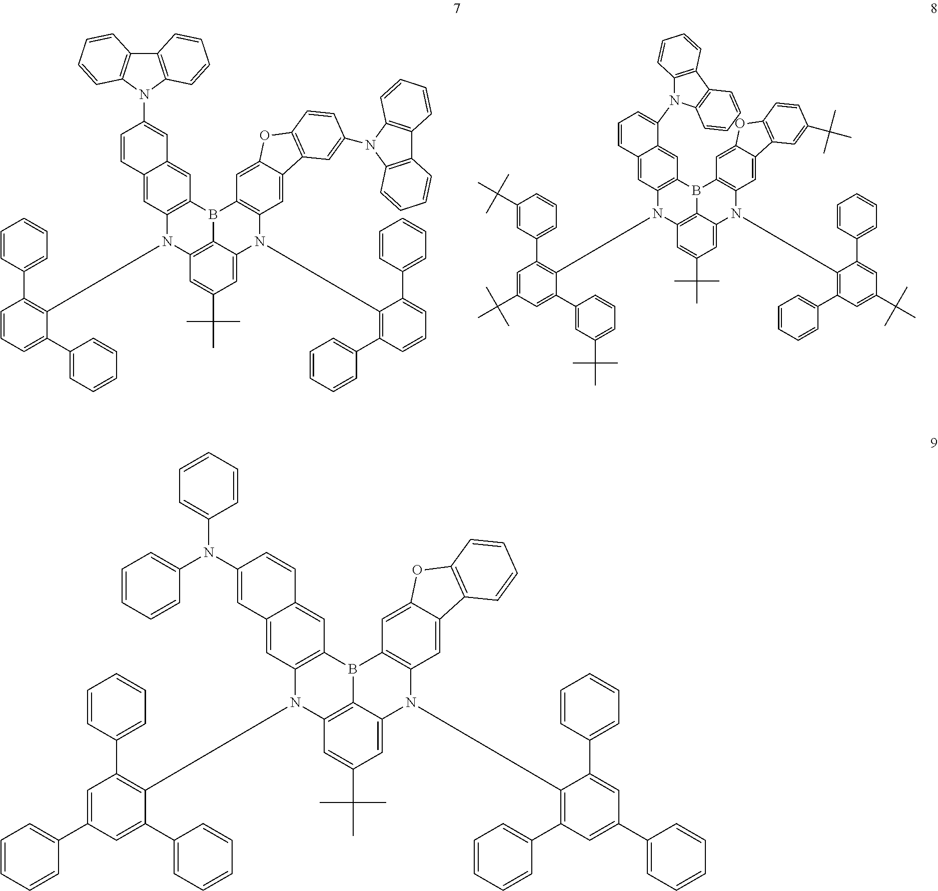 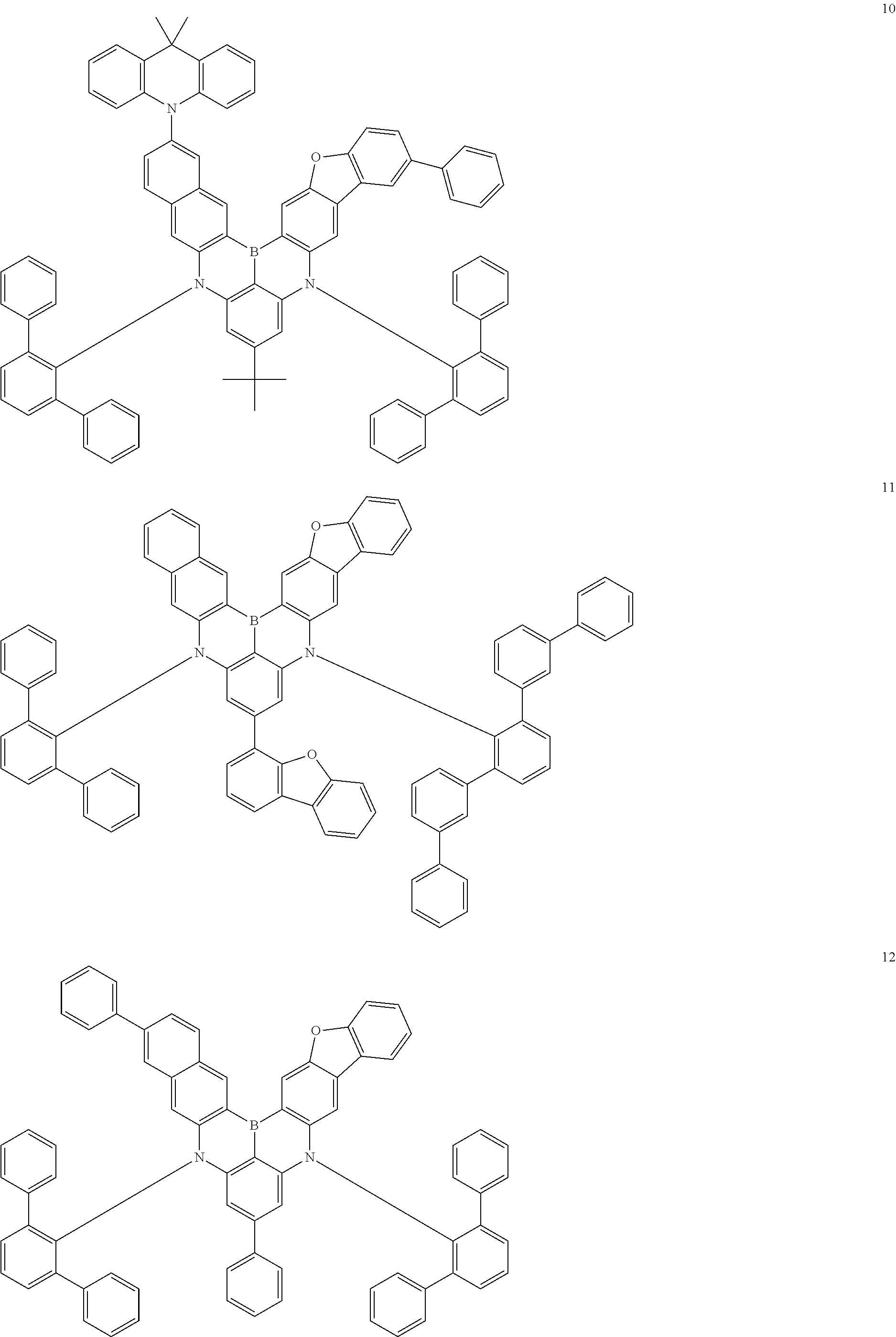 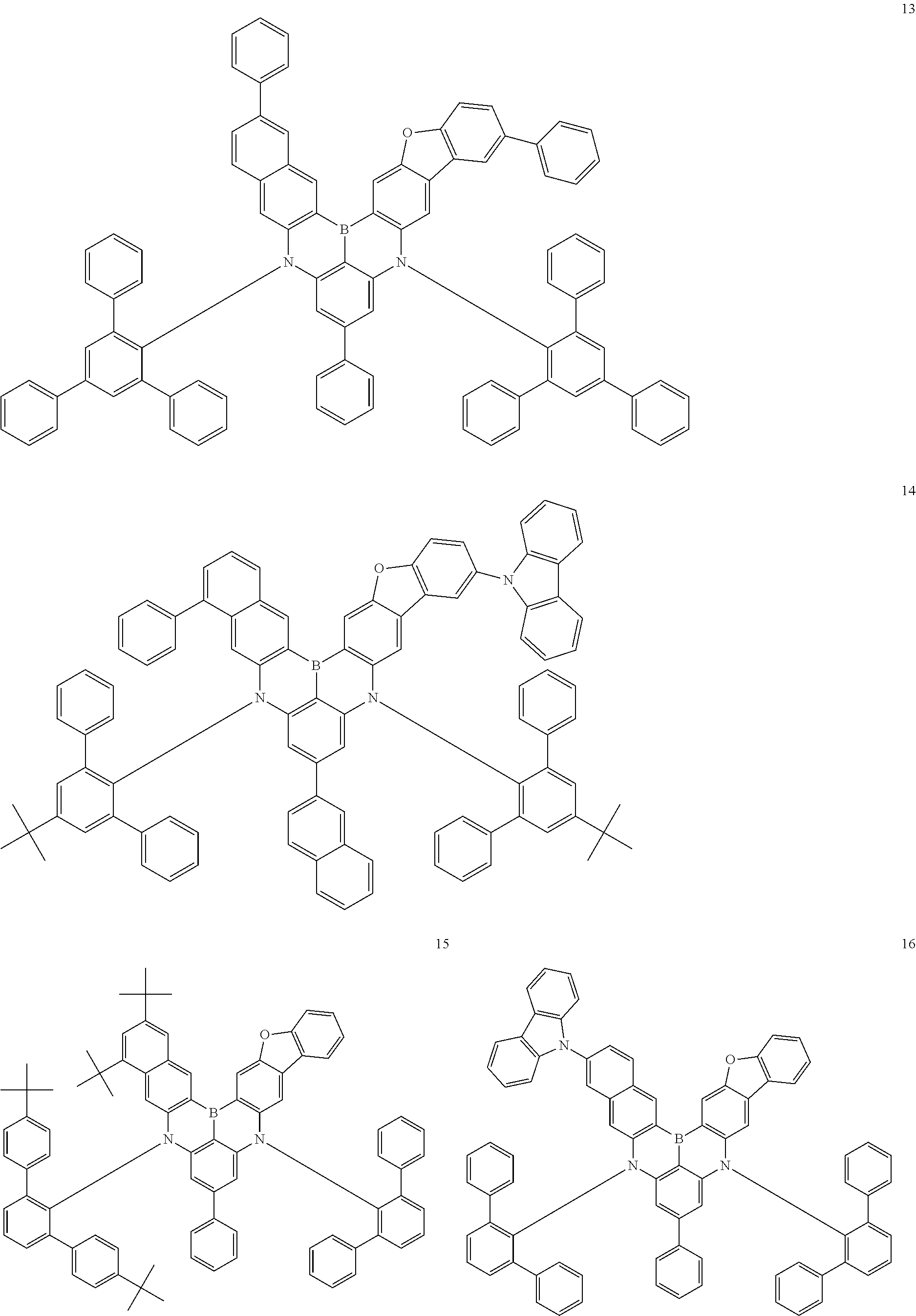 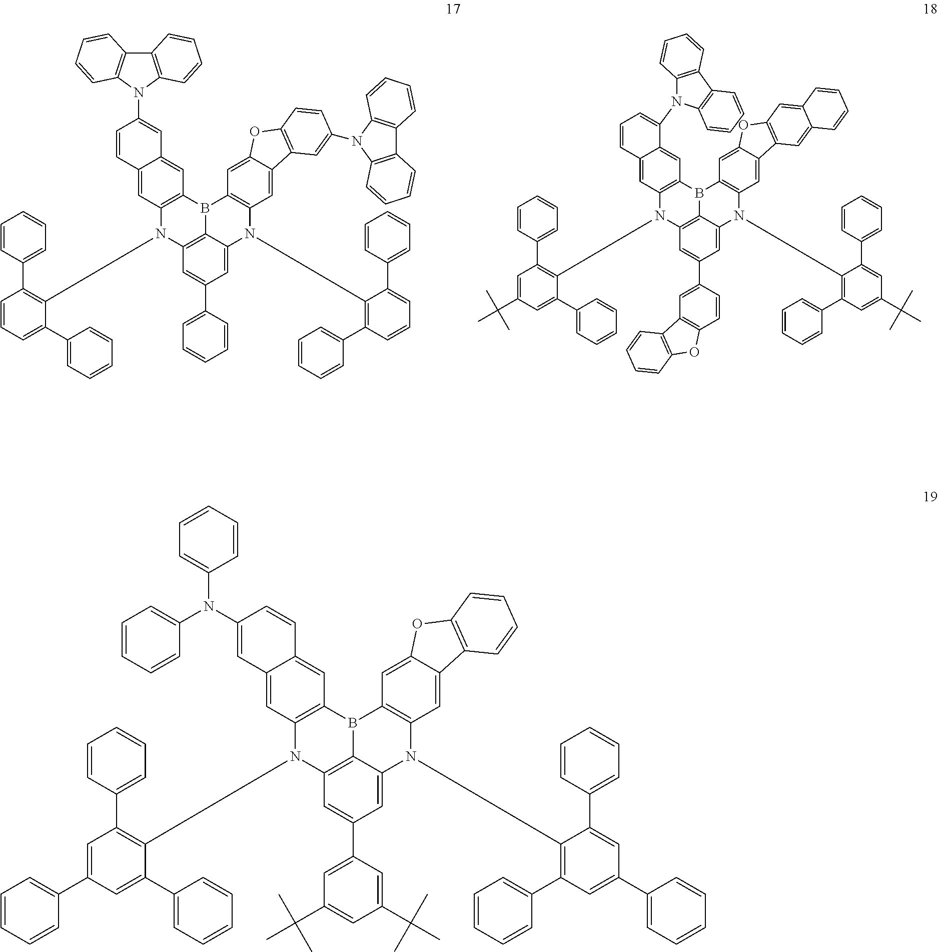 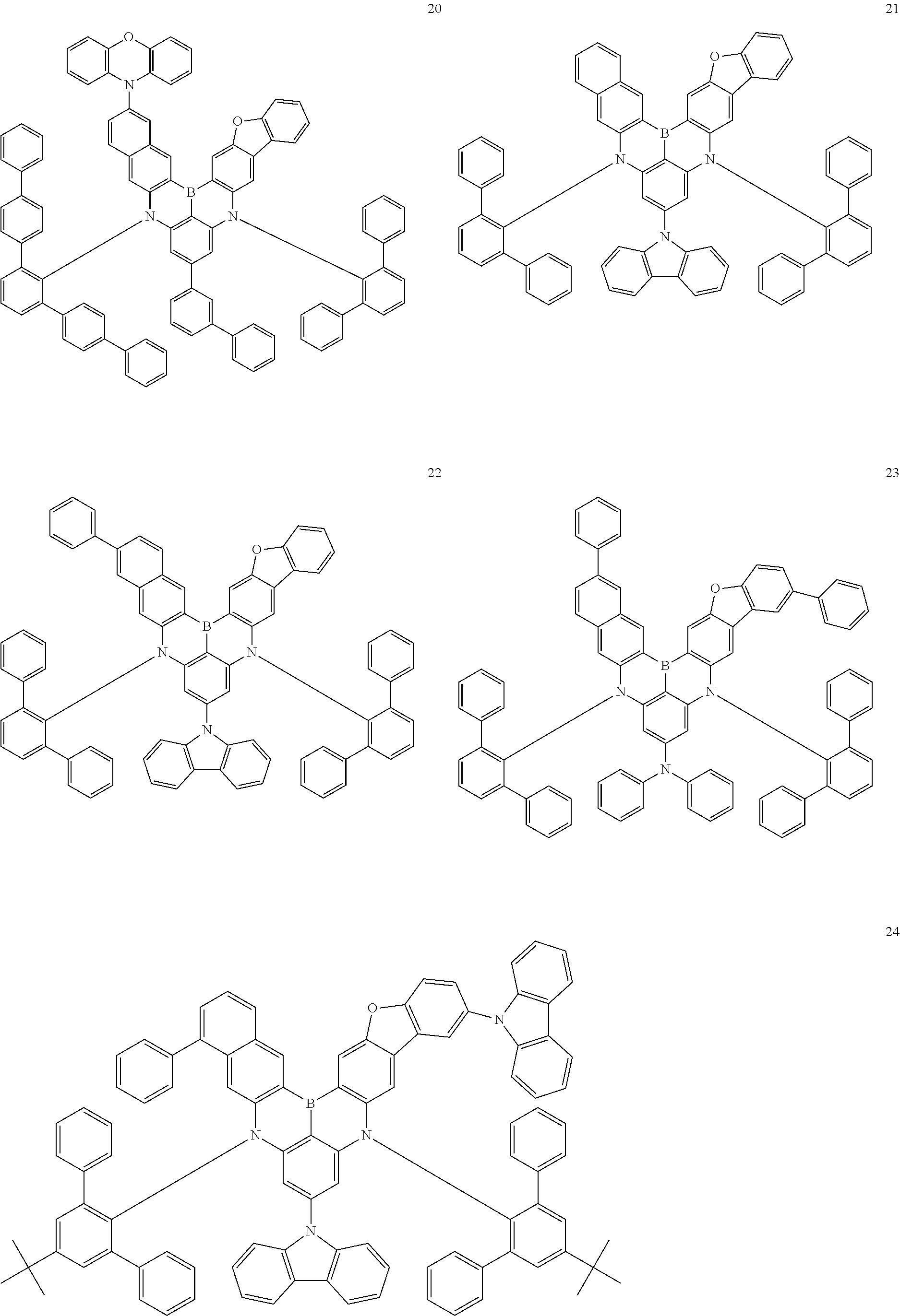 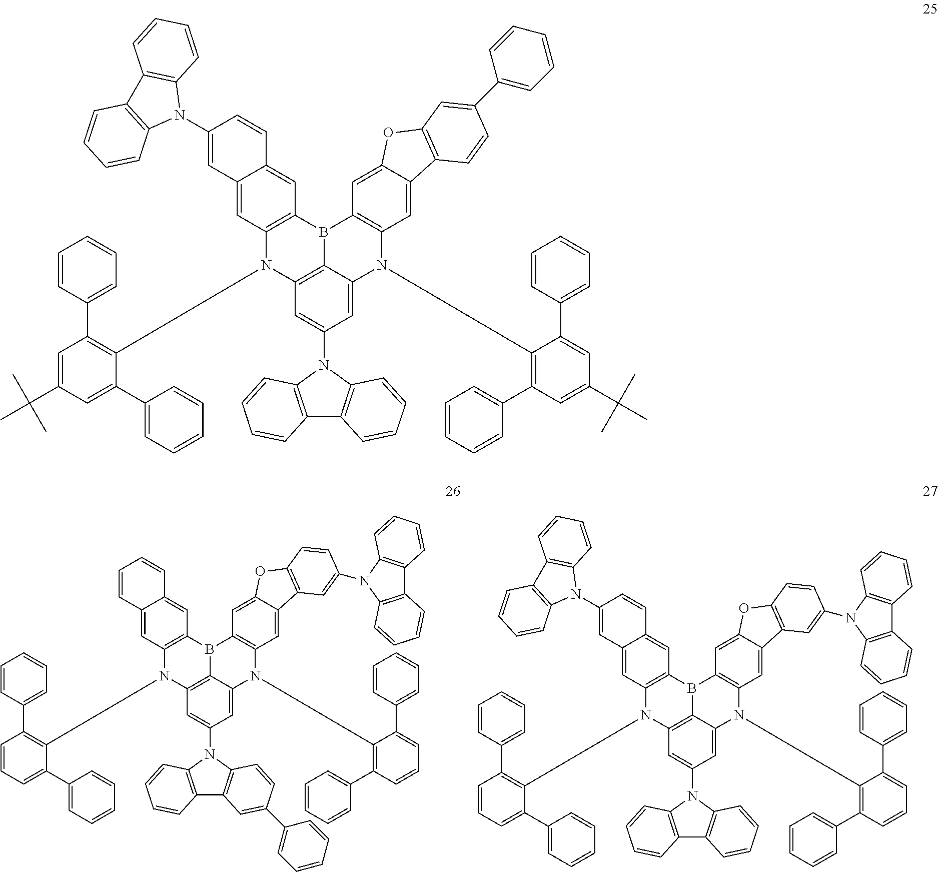 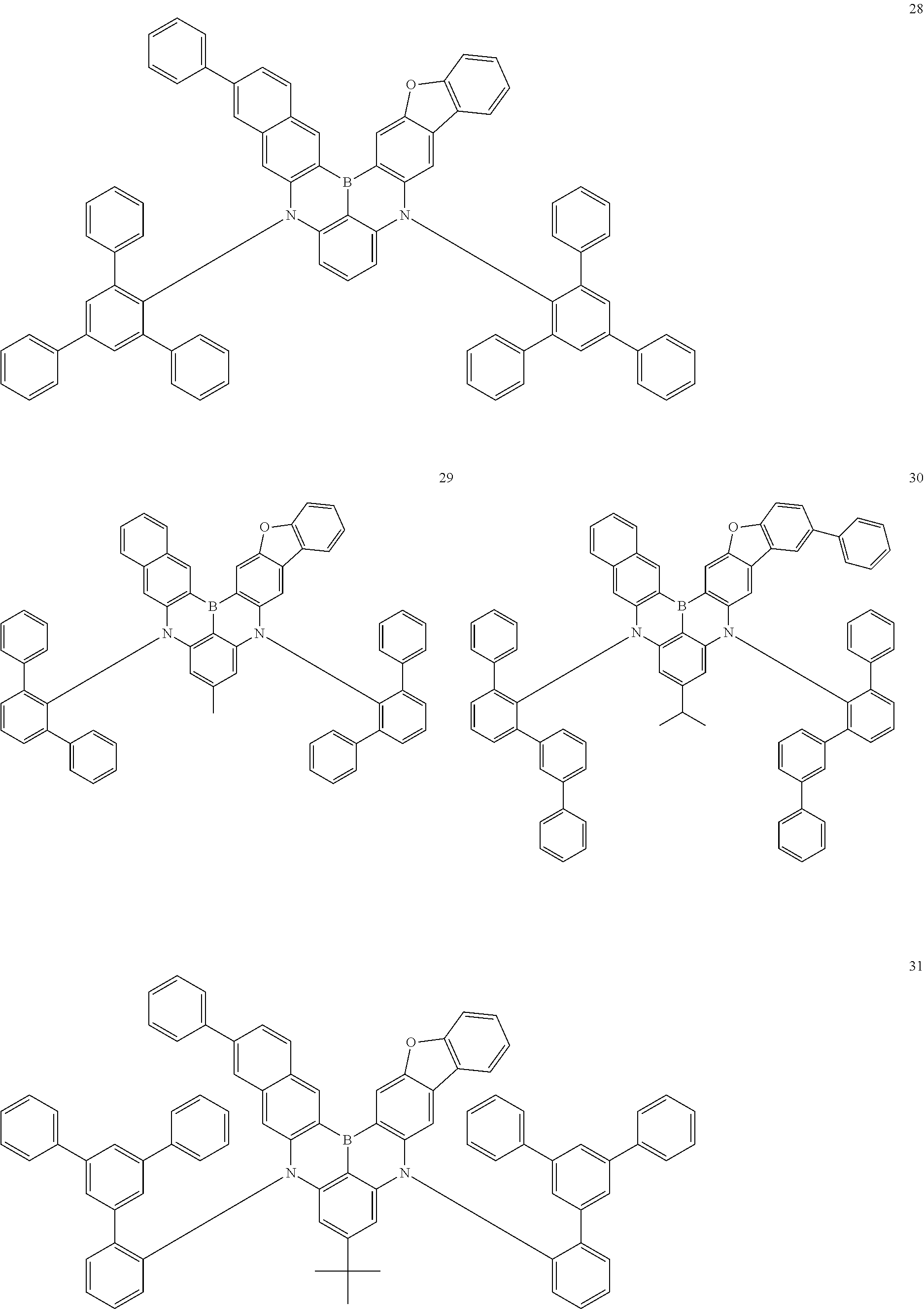 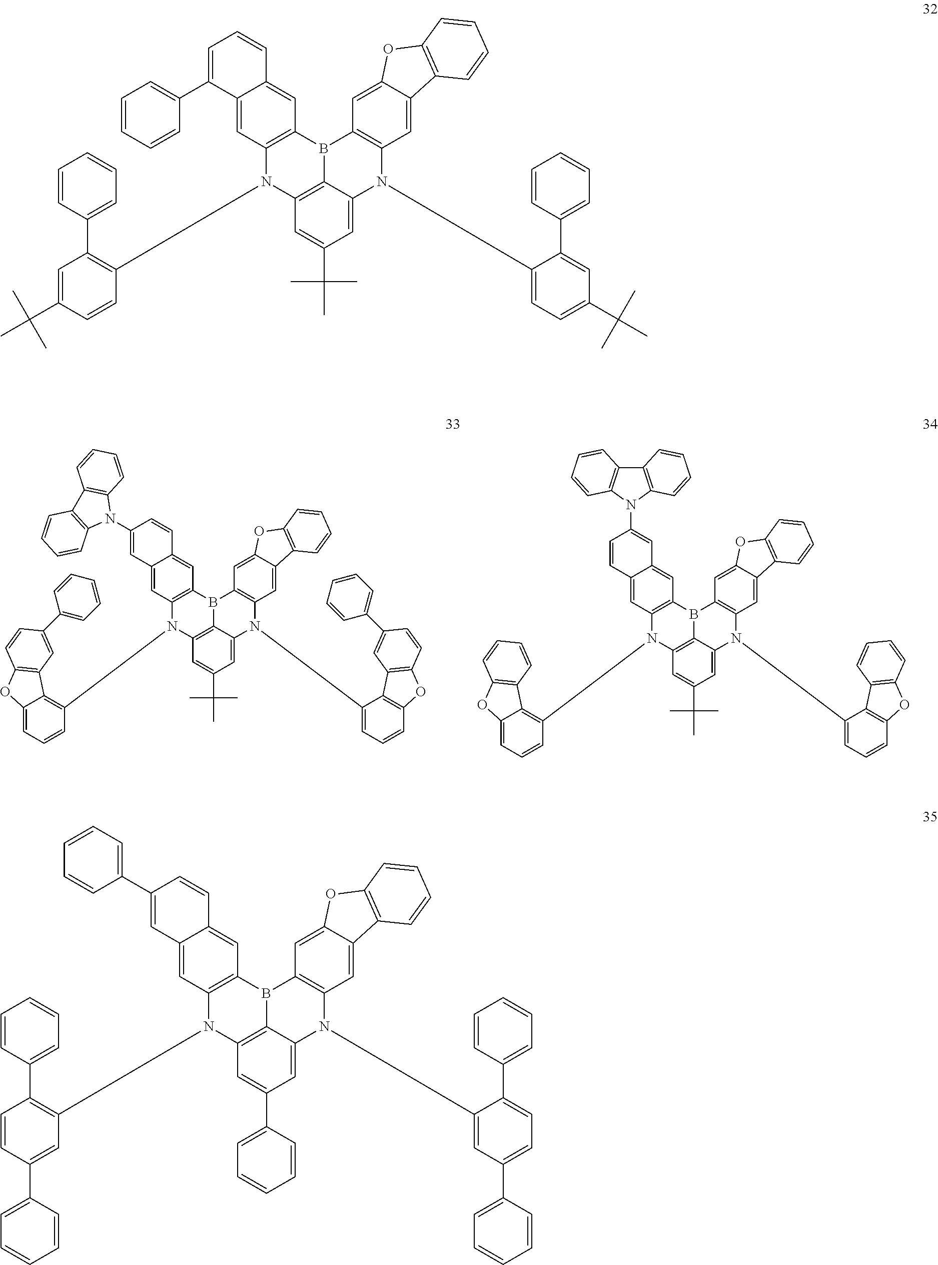 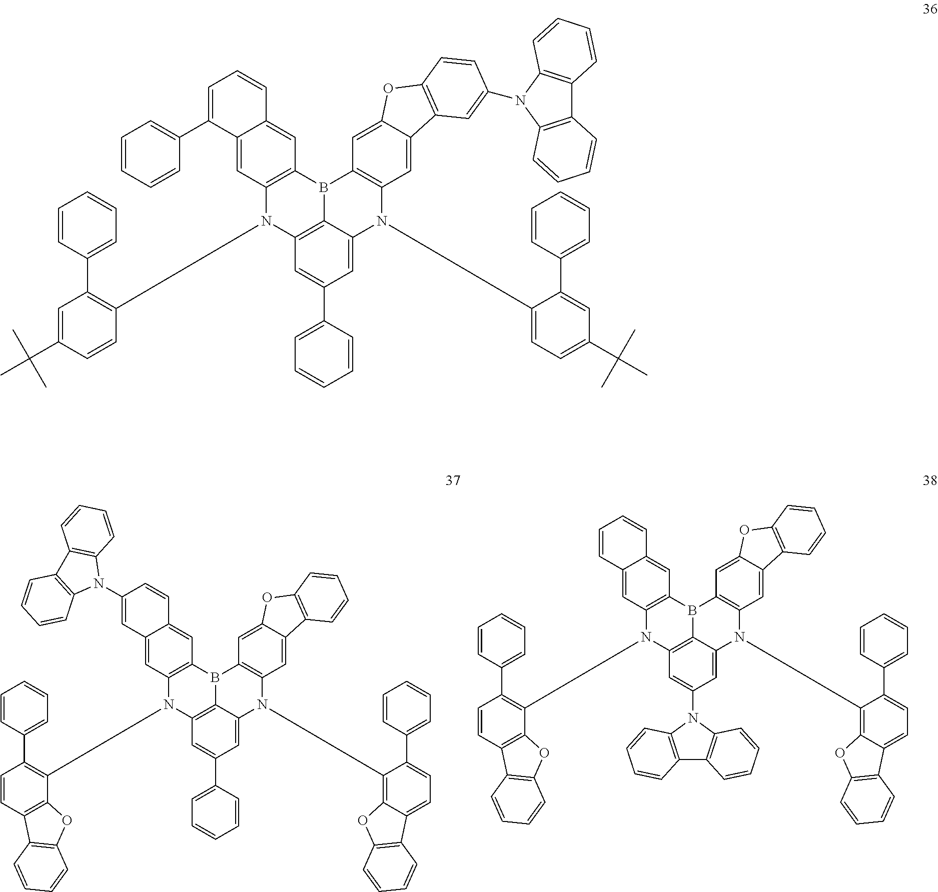 [SMILES: CC(C)(C)c1ccc(N2c3cc4c(-c5ccccc5)cccc4cc3B3c4cc5oc6ccc(-n7c8ccccc8c8ccccc87)cc6c5cc4N(c4ccc(C(C)(C)C)cc4-c4ccccc4)c4cc(-c5ccccc5)cc2c43)c(-c2ccccc2)c1 ; c1ccc(-c2cc3c4c(c2)N(c2c(-c5ccccc5)ccc5c2oc2ccccc25)c2cc5c(cc2B4c2cc4ccc(-n6c7ccccc7c7ccccc76)cc4cc2N3c2c(-c3ccccc3)ccc3c2oc2ccccc23)oc2ccccc25)cc1 ; c1ccc(-c2ccc3c(oc4ccccc43)c2N2c3cc4ccccc4cc3B3c4cc5oc6ccccc6c5cc4N(c4c(-c5ccccc5)ccc5c4oc4ccccc45)c4cc(-n5c6ccccc6c6ccccc65)cc2c43)cc1] 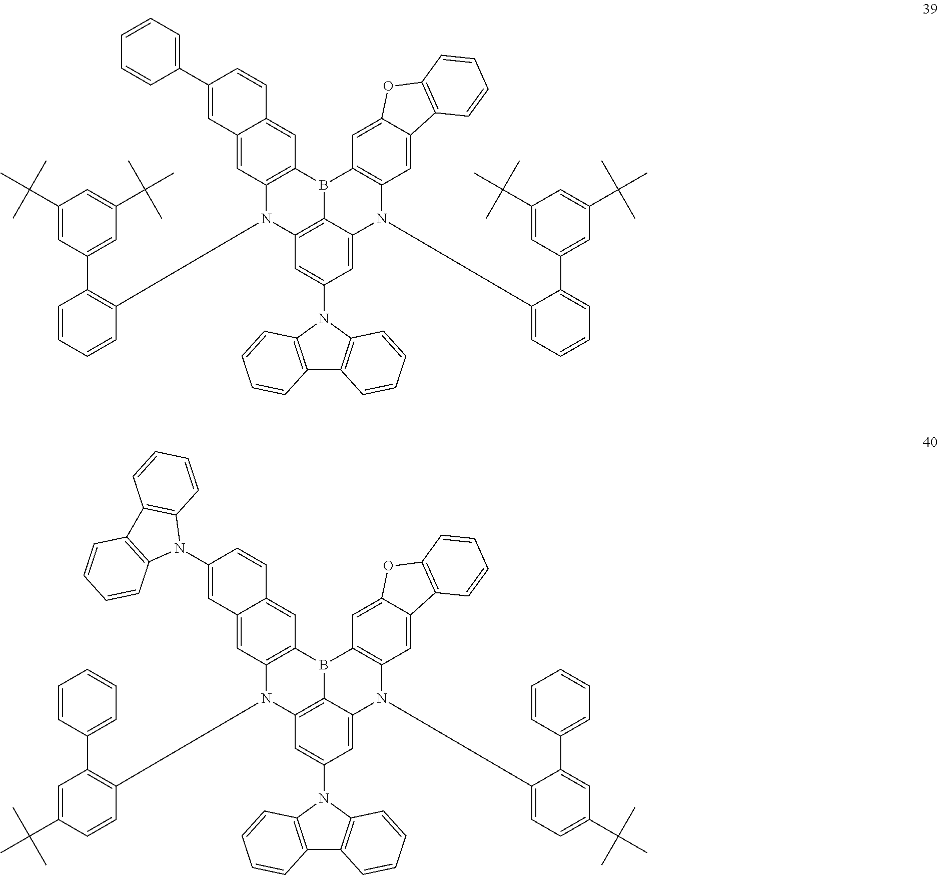 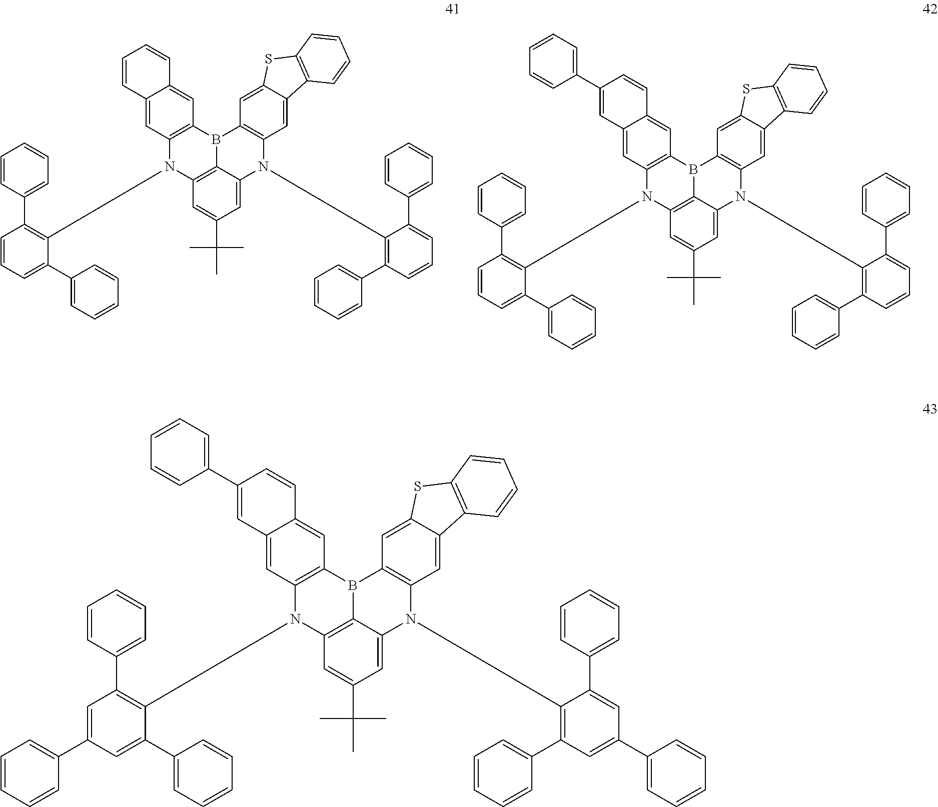 [SMILES: CC(C)(C)c1cc2c3c(c1)N(c1c(-c4ccccc4)cccc1-c1ccccc1)c1cc4c(cc1B3c1cc3ccccc3cc1N2c1c(-c2ccccc2)cccc1-c1ccccc1)sc1ccccc14 ; CC(C)(C)c1cc2c3c(c1)N(c1c(-c4ccccc4)cccc1-c1ccccc1)c1cc4c(cc1B3c1cc3ccc(-c5ccccc5)cc3cc1N2c1c(-c2ccccc2)cccc1-c1ccccc1)sc1ccccc14 ; CC(C)(C)c1cc2c3c(c1)N(c1c(-c4ccccc4)cc(-c4ccccc4)cc1-c1ccccc1)c1cc4c(cc1B3c1cc3ccc(-c5ccccc5)cc3cc1N2c1c(-c2ccccc2)cc(-c2ccccc2)cc1-c1ccccc1)sc1ccccc14] 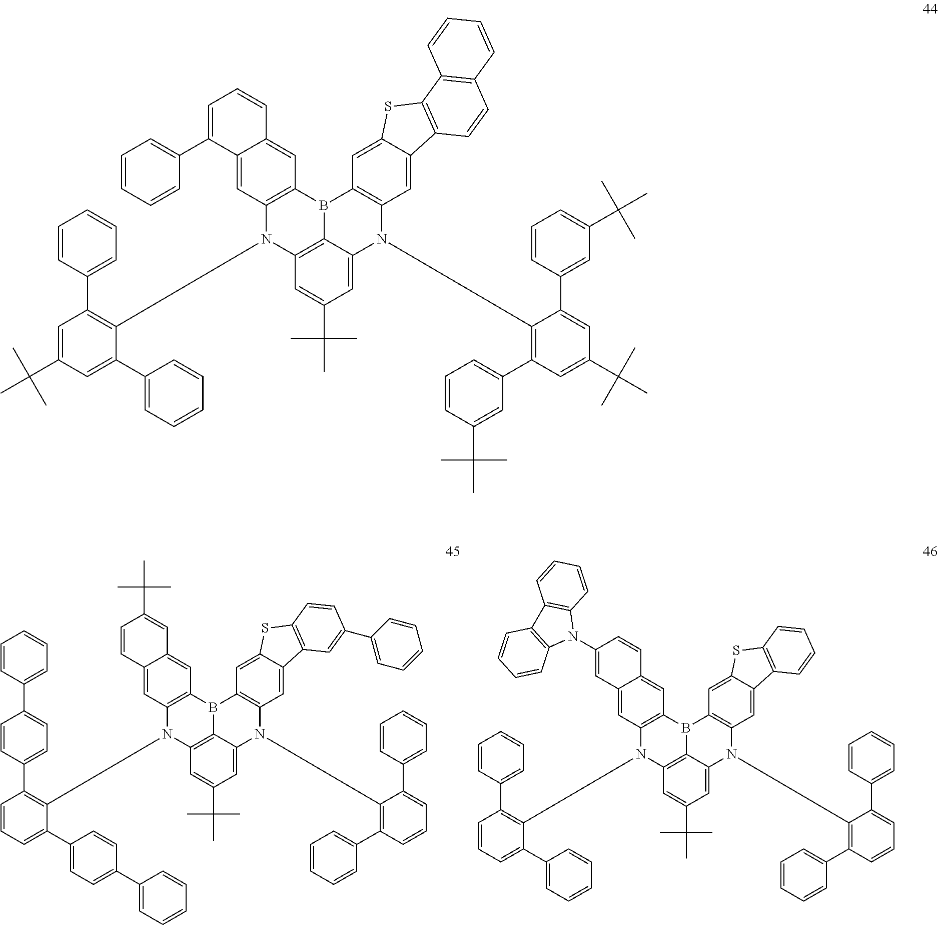 [SMILES: CC(C)(C)c1cccc(-c2cc(C(C)(C)C)cc(-c3cccc(C(C)(C)C)c3)c2N2c3cc4c(cc3B3c5cc6cccc(-c7ccccc7)c6cc5N(c5c(-c6ccccc6)cc(C(C)(C)C)cc5-c5ccccc5)c5cc(C(C)(C)C)cc2c53)sc2c3ccccc3ccc42)c1 ; CC(C)(C)c1cc2c3c(c1)N(c1c(-c4ccccc4)cccc1-c1ccccc1)c1cc4c(cc1B3c1cc3cc(C(C)(C)C)ccc3cc1N2c1c(-c2ccc(-c3ccccc3)cc2)cccc1-c1ccc(-c2ccccc2)cc1)sc1ccc(-c2ccccc2)cc14 ; CC(C)(C)c1cc2c3c(c1)N(c1c(-c4ccccc4)cccc1-c1ccccc1)c1cc4c(cc1B3c1cc3ccc(-n5c6ccccc6c6ccccc65)cc3cc1N2c1c(-c2ccccc2)cccc1-c1ccccc1)sc1ccccc14] 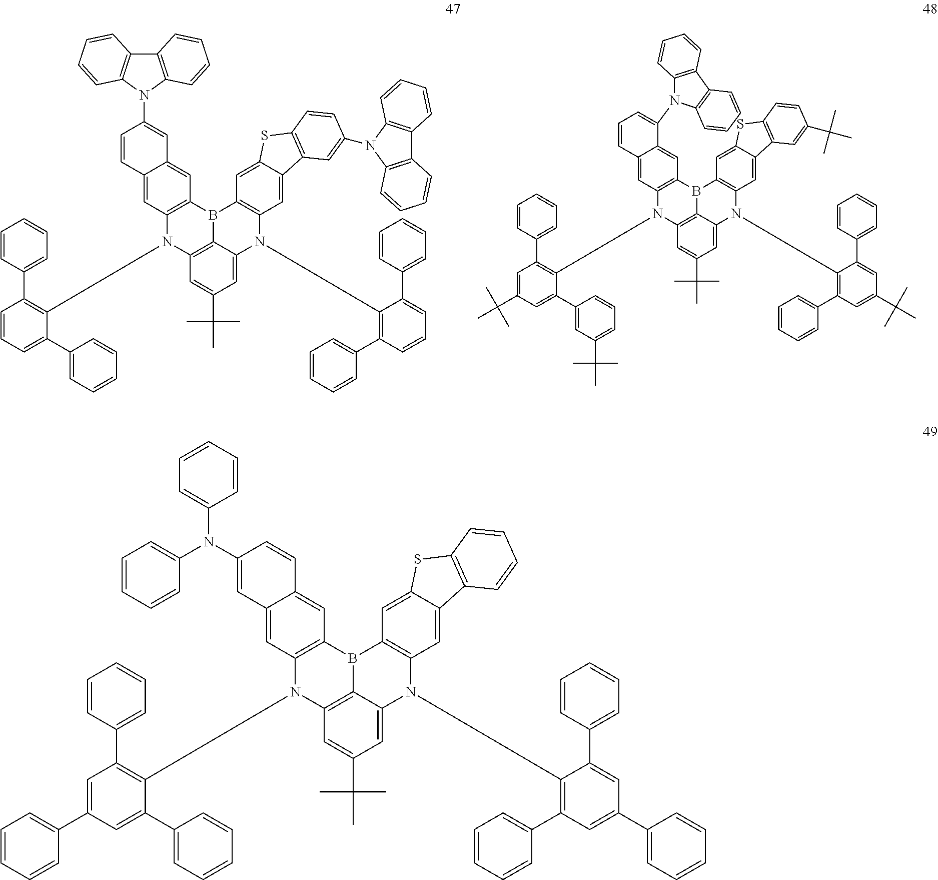 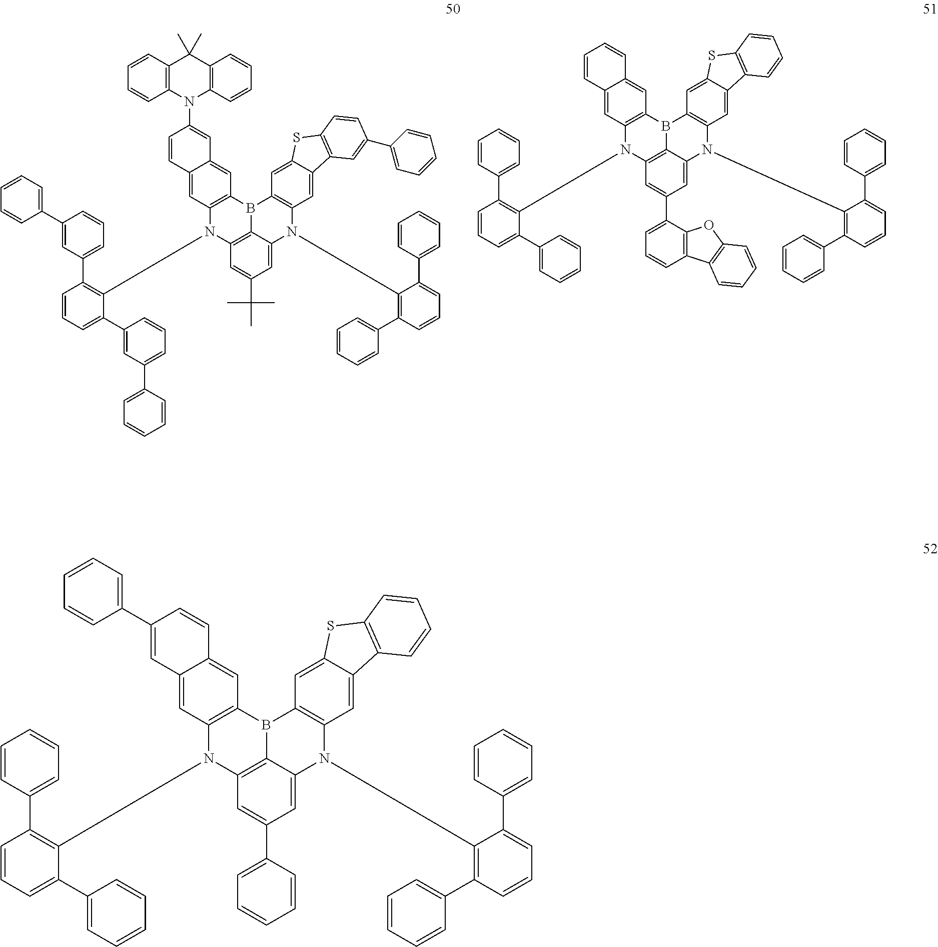 [SMILES: CC(C)(C)c1cc2c3c(c1)N(c1c(-c4ccccc4)cccc1-c1ccccc1)c1cc4c(cc1B3c1cc3cc(N5c6ccccc6C(C)(C)c6ccccc65)ccc3cc1N2c1c(-c2cccc(-c3ccccc3)c2)cccc1-c1cccc(-c2ccccc2)c1)sc1ccc(-c2ccccc2)cc14 ; c1ccc(-c2cccc(-c3ccccc3)c2N2c3cc4ccccc4cc3B3c4cc5sc6ccccc6c5cc4N(c4c(-c5ccccc5)cccc4-c4ccccc4)c4cc(-c5cccc6c5oc5ccccc56)cc2c43)cc1 ; c1ccc(-c2cc3c4c(c2)N(c2c(-c5ccccc5)cccc2-c2ccccc2)c2cc5c(cc2B4c2cc4ccc(-c6ccccc6)cc4cc2N3c2c(-c3ccccc3)cccc2-c2ccccc2)sc2ccccc25)cc1] 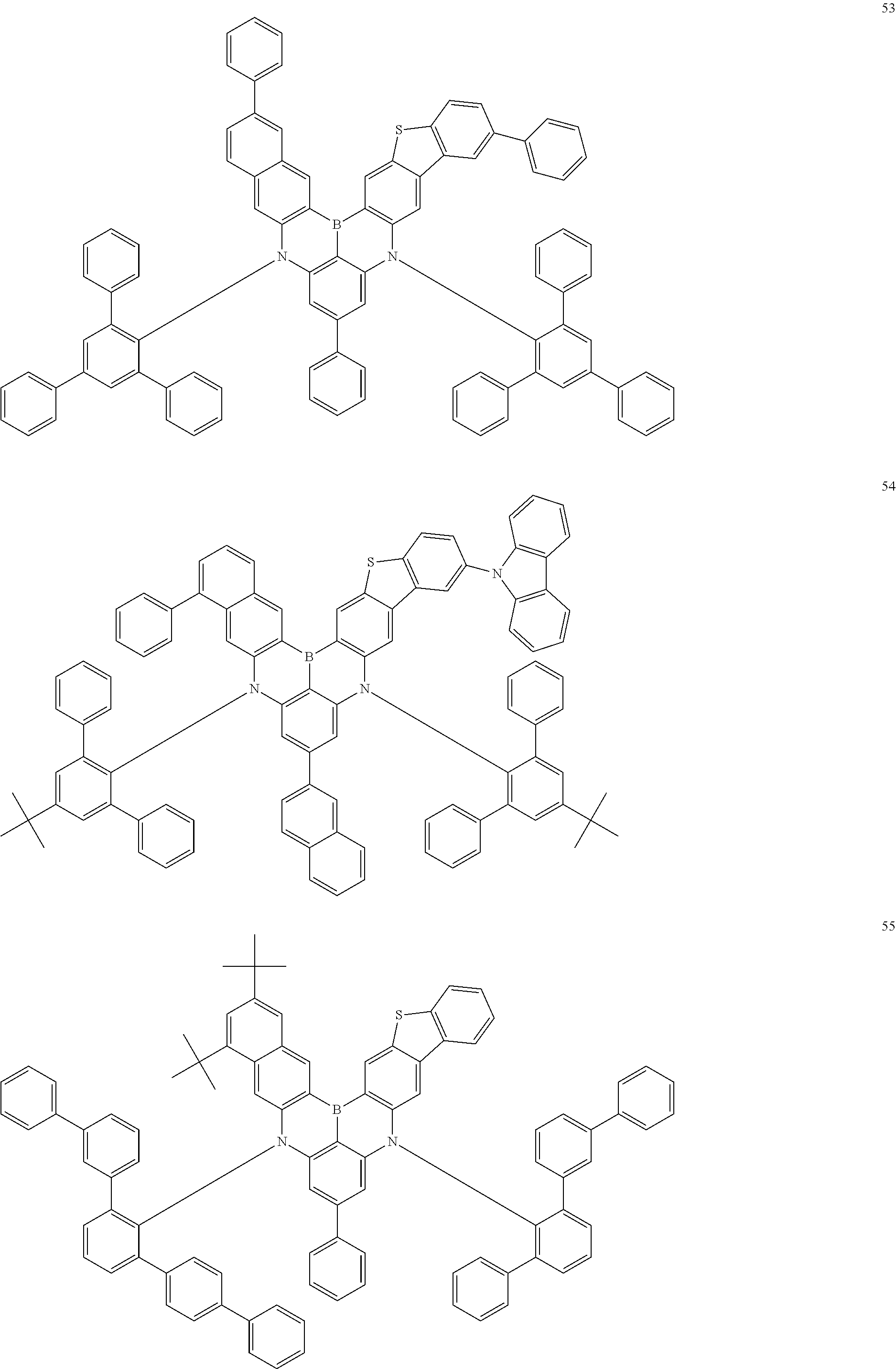 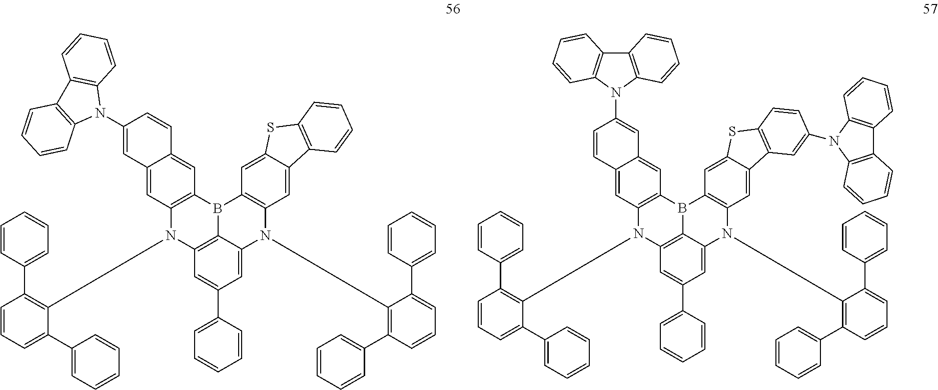 [SMILES: c1ccc(-c2cc3c4c(c2)N(c2c(-c5ccccc5)cccc2-c2ccccc2)c2cc5c(cc2B4c2cc4ccc(-n6c7ccccc7c7ccccc76)cc4cc2N3c2c(-c3ccccc3)cccc2-c2ccccc2)sc2ccccc25)cc1 ; c1ccc(-c2cc3c4c(c2)N(c2c(-c5ccccc5)cccc2-c2ccccc2)c2cc5c(cc2B4c2cc4cc(-n6c7ccccc7c7ccccc76)ccc4cc2N3c2c(-c3ccccc3)cccc2-c2ccccc2)sc2ccc(-n3c4ccccc4c4ccccc43)cc25)cc1] 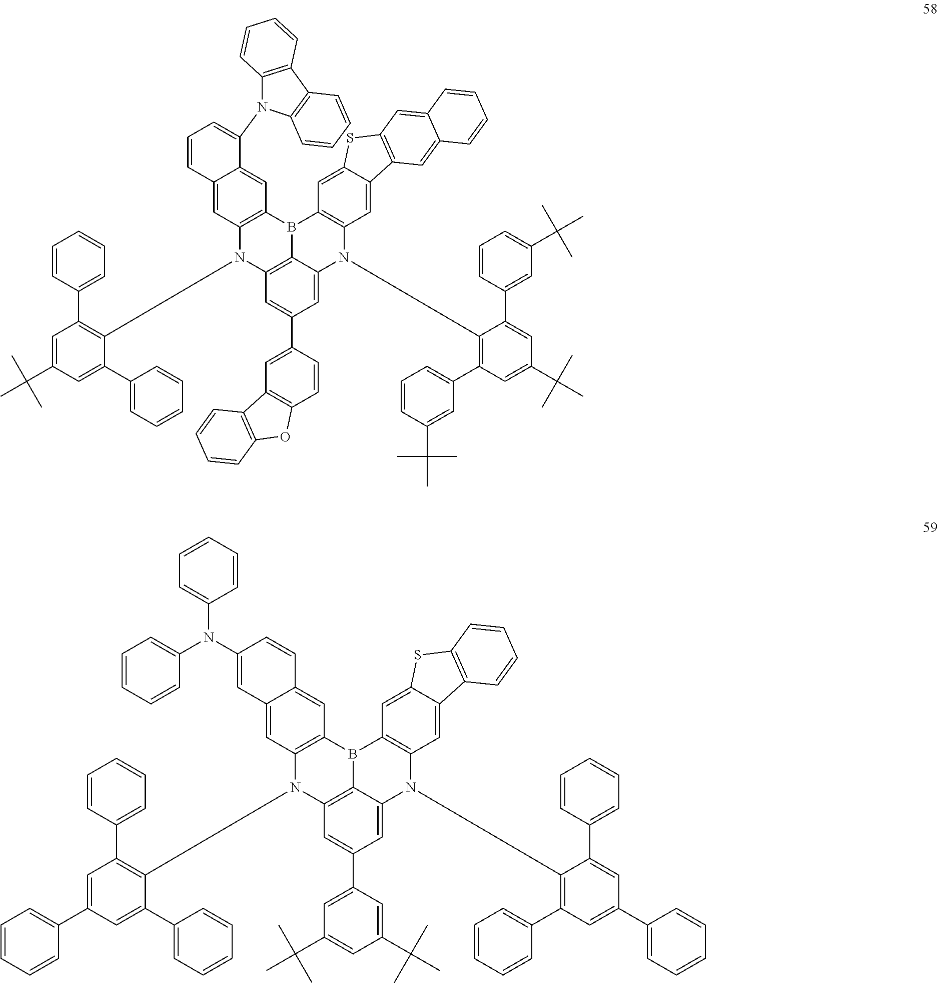 [SMILES: CC(C)(C)c1cccc(-c2cc(C(C)(C)C)cc(-c3cccc(C(C)(C)C)c3)c2N2c3cc4c(cc3B3c5cc6c(-n7c8ccccc8c8ccccc87)cccc6cc5N(c5c(-c6ccccc6)cc(C(C)(C)C)cc5-c5ccccc5)c5cc(-c6ccc7oc8ccccc8c7c6)cc2c53)sc2cc3ccccc3cc24)c1 ; CC(C)(C)c1cc(-c2cc3c4c(c2)N(c2c(-c5ccccc5)cc(-c5ccccc5)cc2-c2ccccc2)c2cc5c(cc2B4c2cc4ccc(N(c6ccccc6)c6ccccc6)cc4cc2N3c2c(-c3ccccc3)cc(-c3ccccc3)cc2-c2ccccc2)sc2ccccc25)cc(C(C)(C)C)c1] 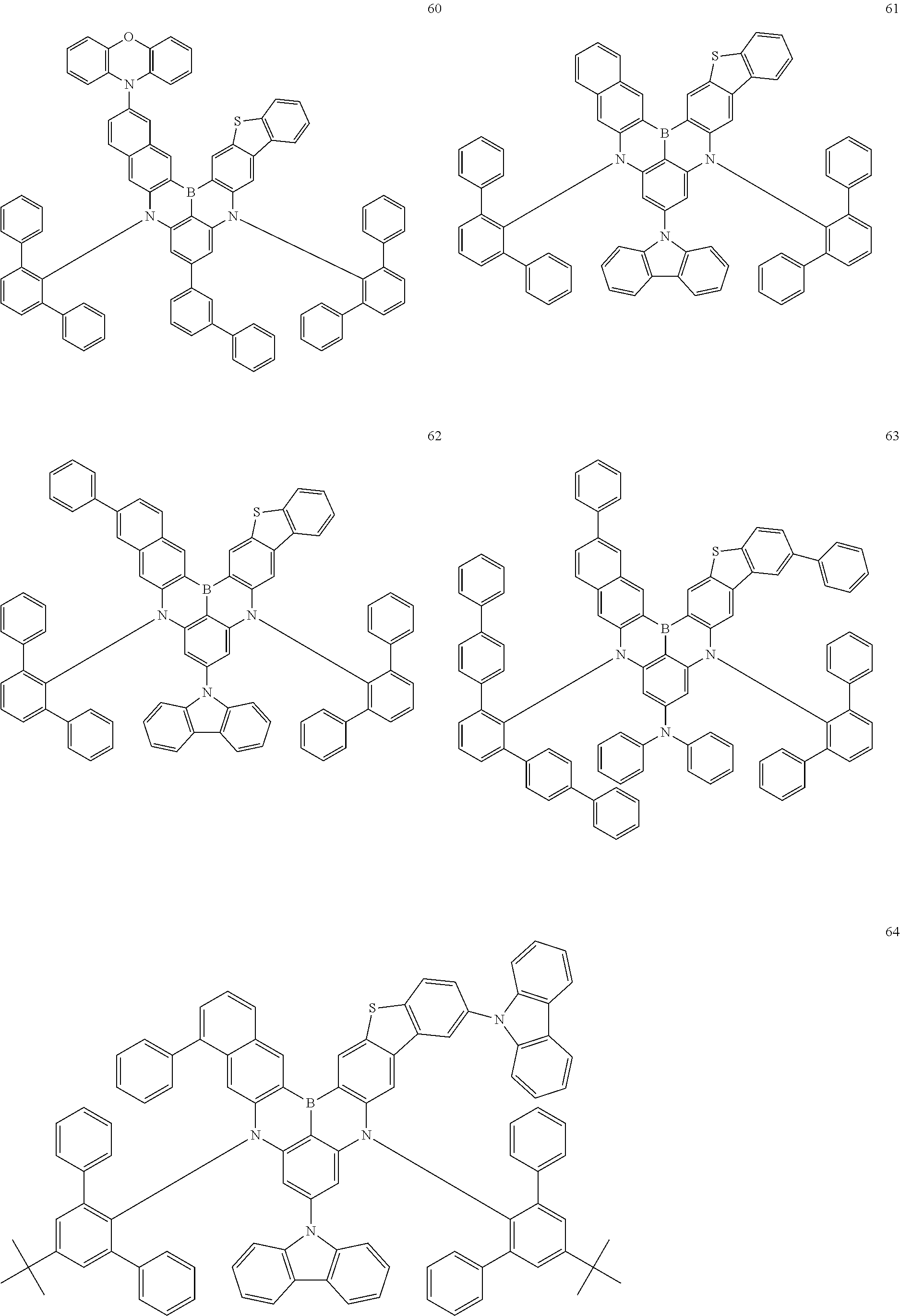 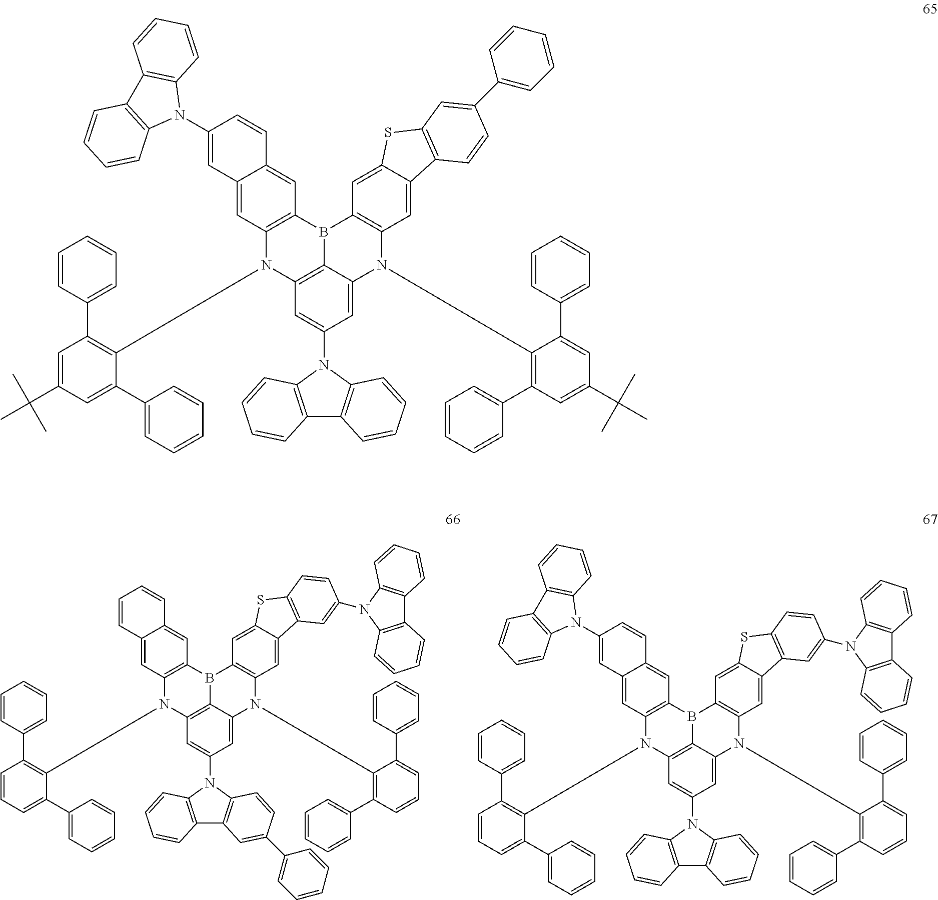 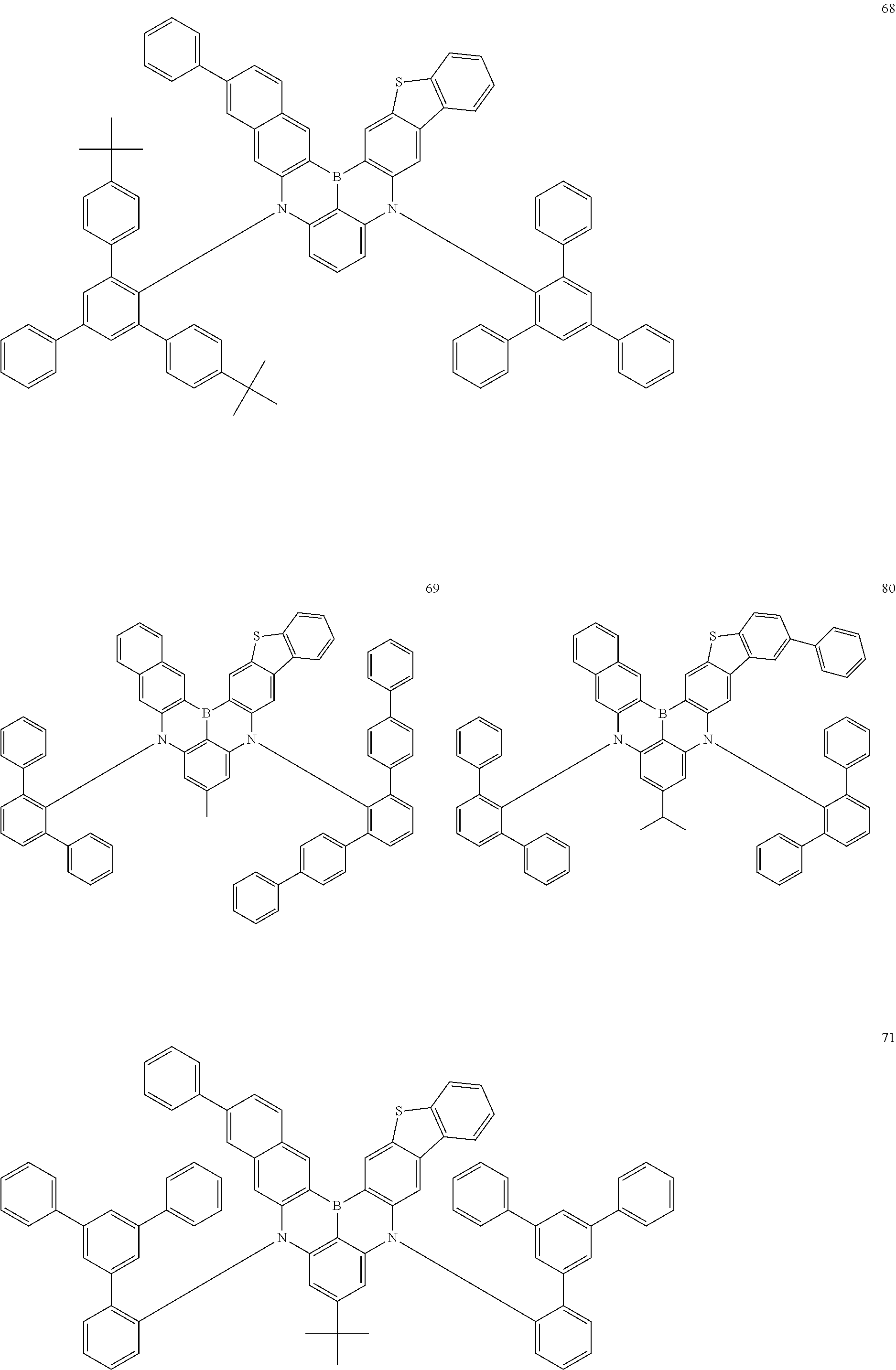 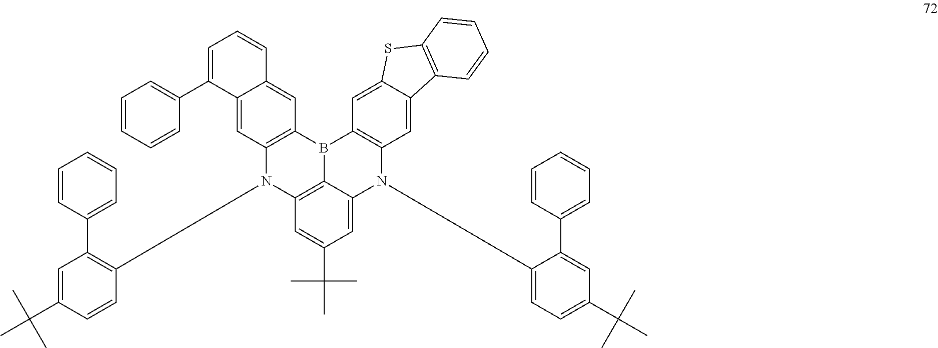 [SMILES: CC(C)(C)c1ccc(N2c3cc4c(-c5ccccc5)cccc4cc3B3c4cc5sc6ccccc6c5cc4N(c4ccc(C(C)(C)C)cc4-c4ccccc4)c4cc(C(C)(C)C)cc2c43)c(-c2ccccc2)c1] 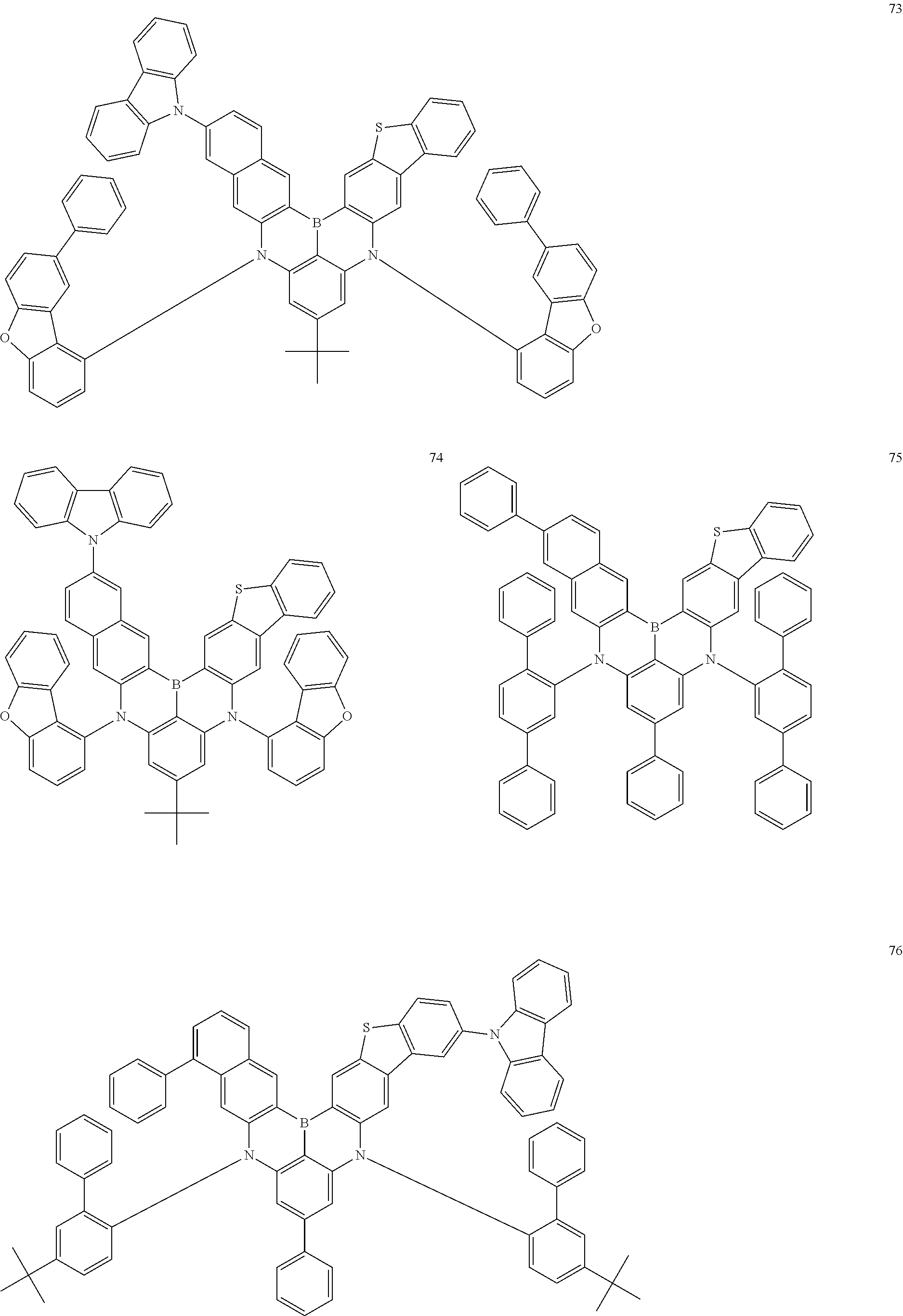 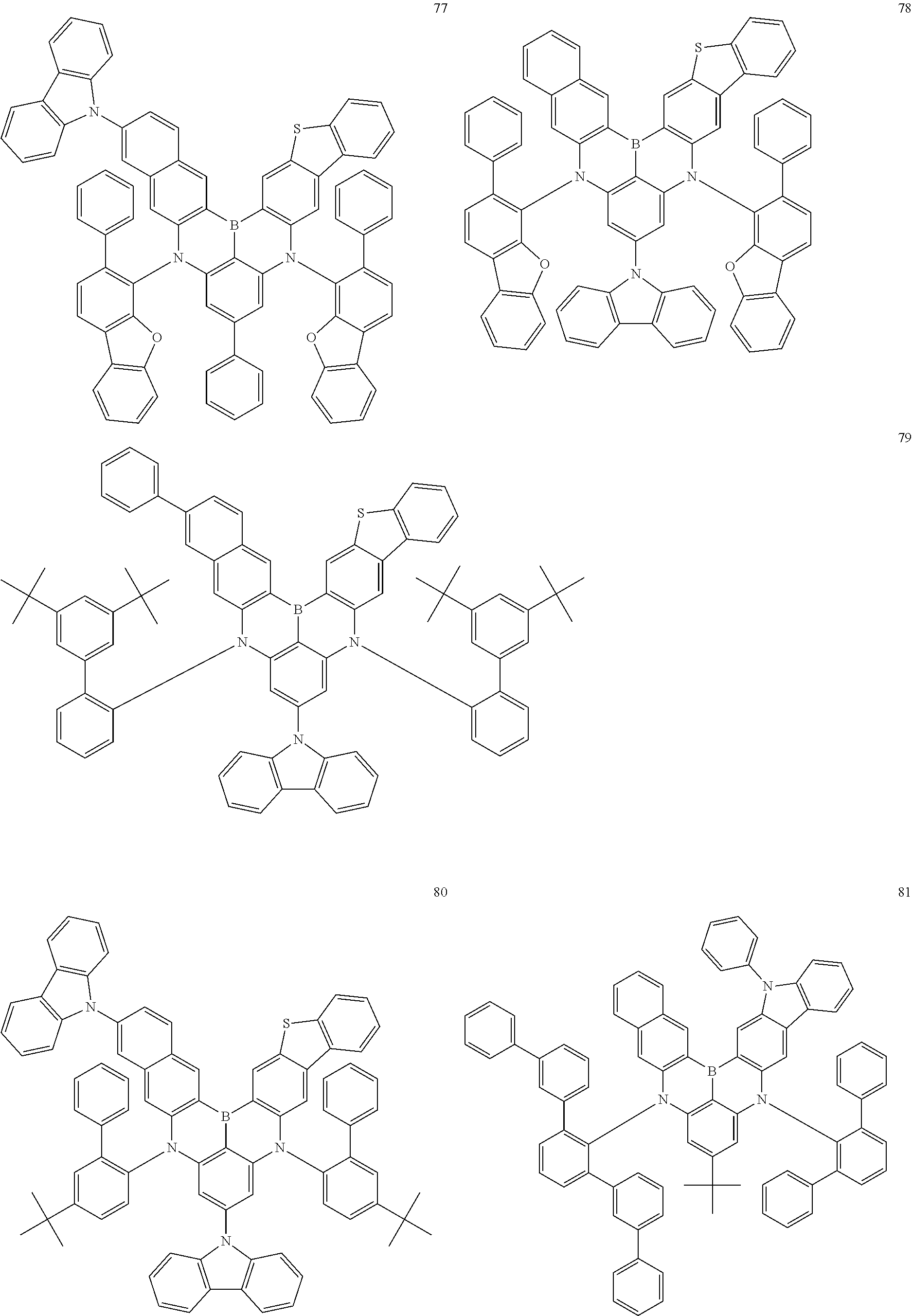 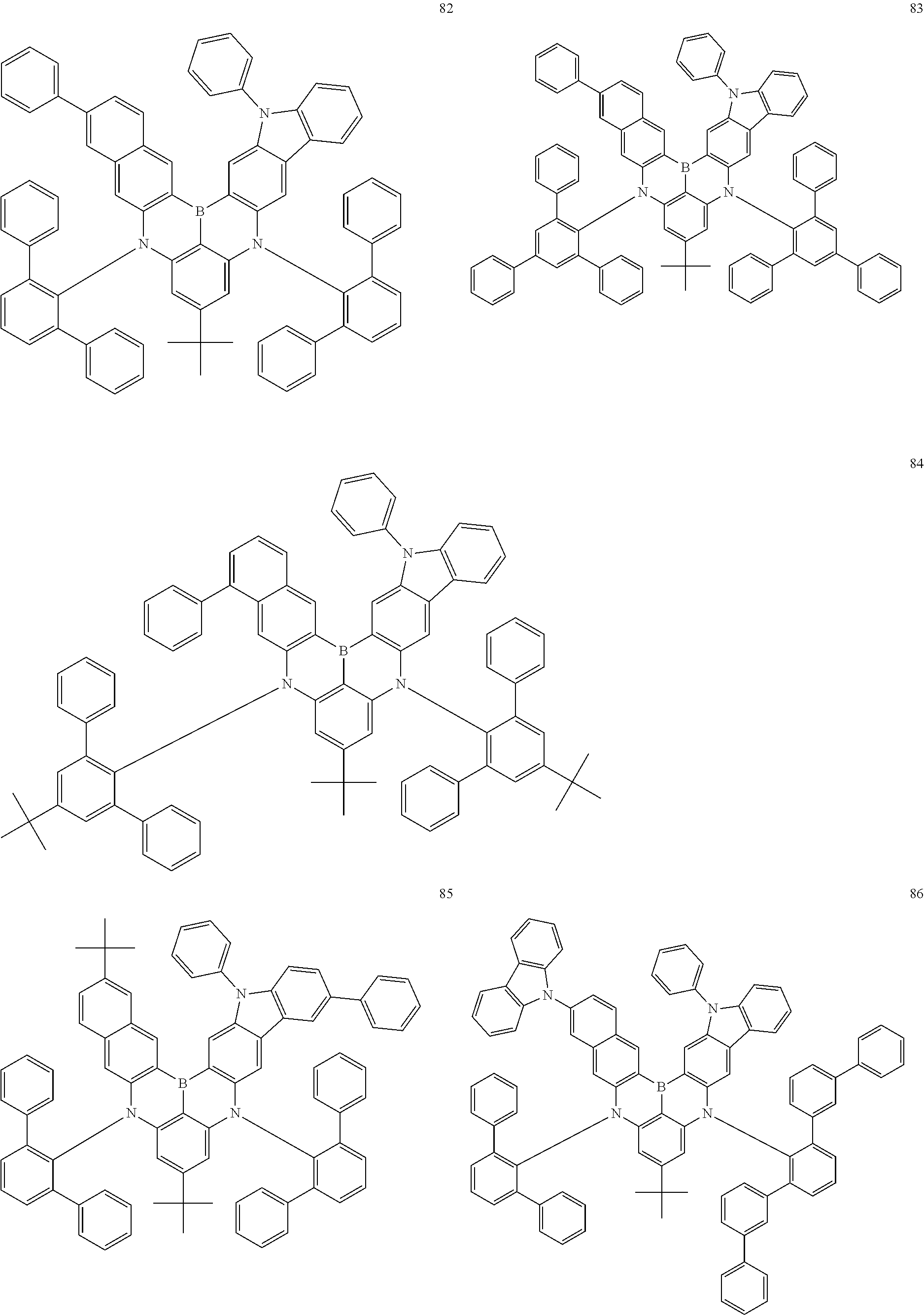 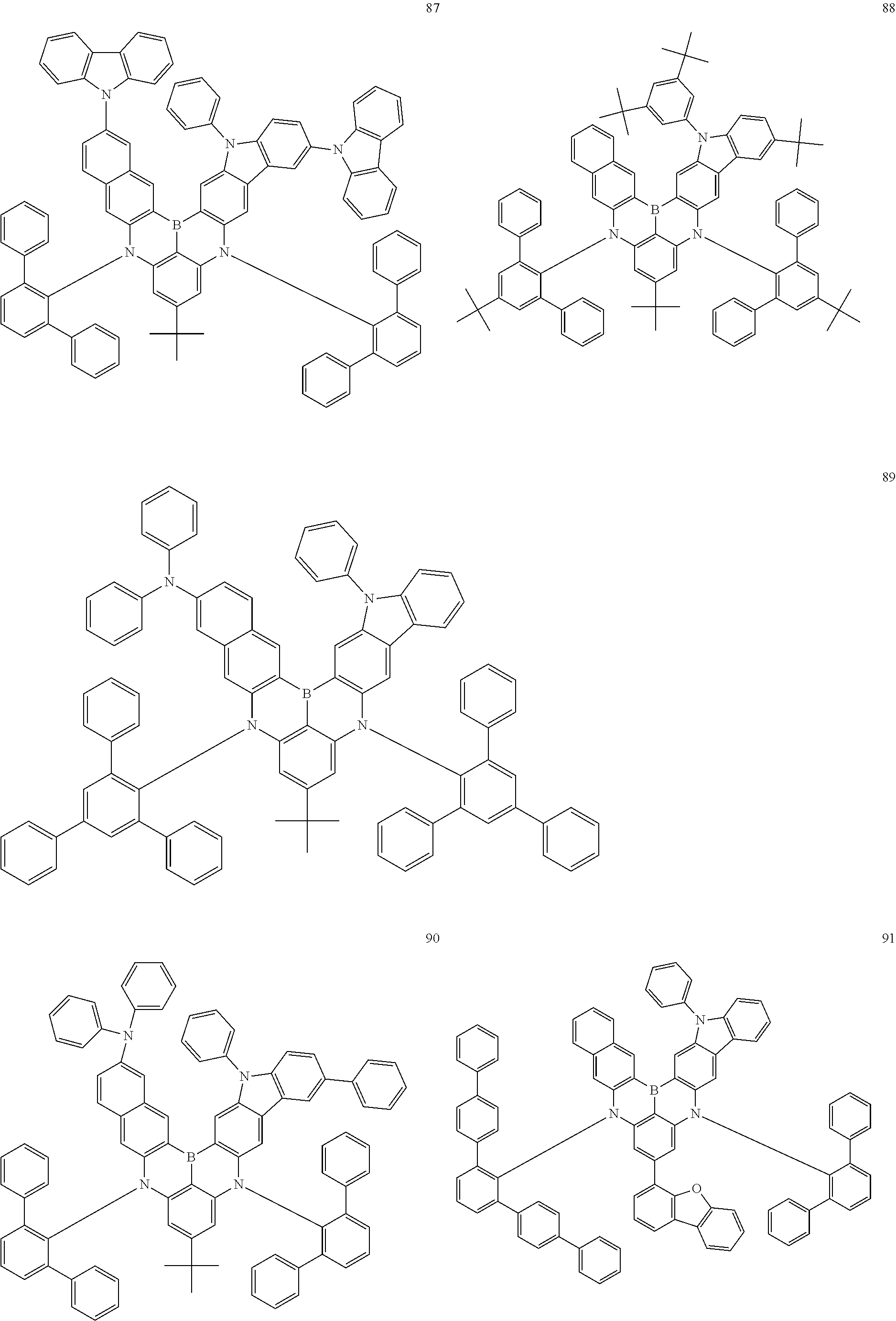 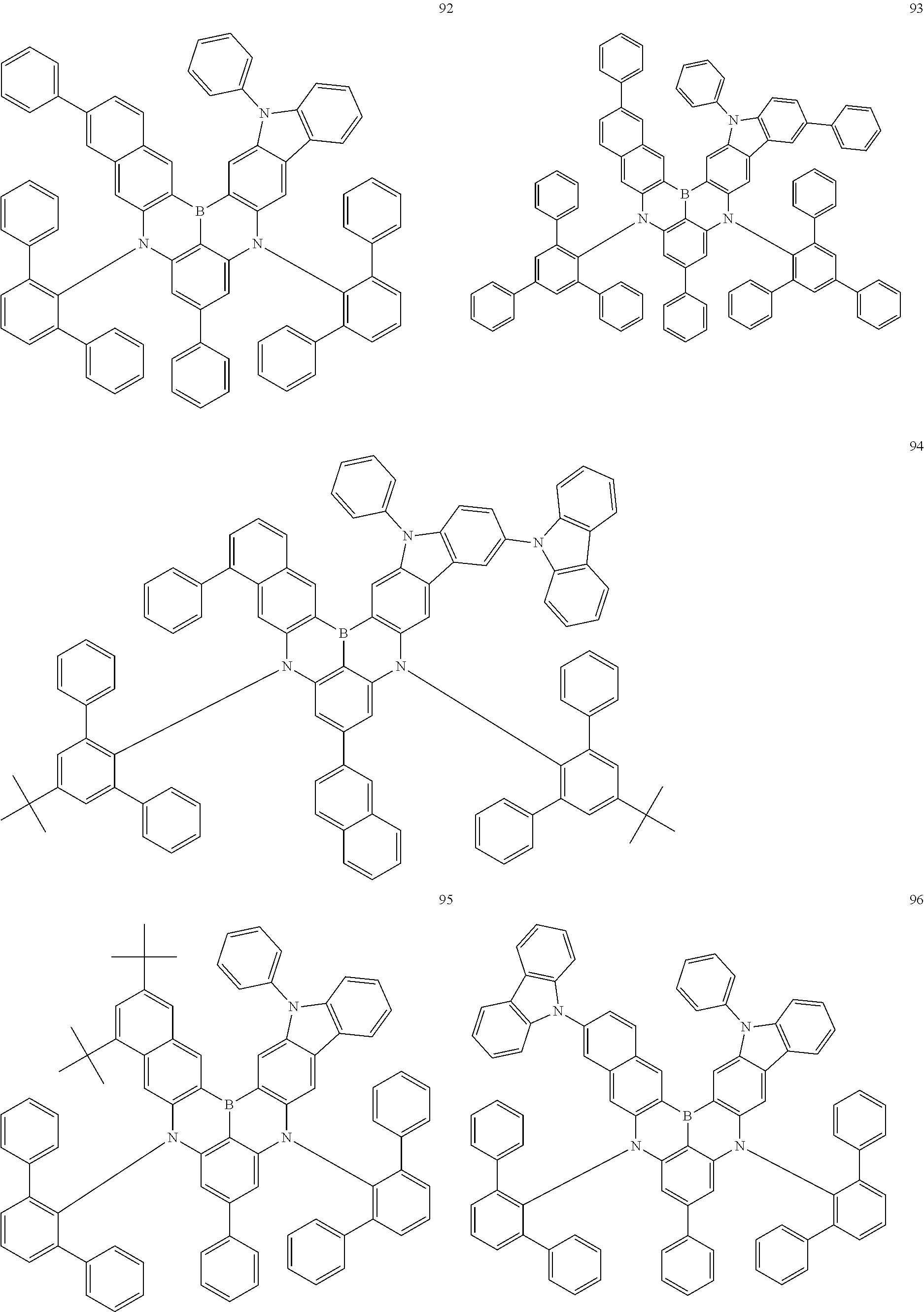 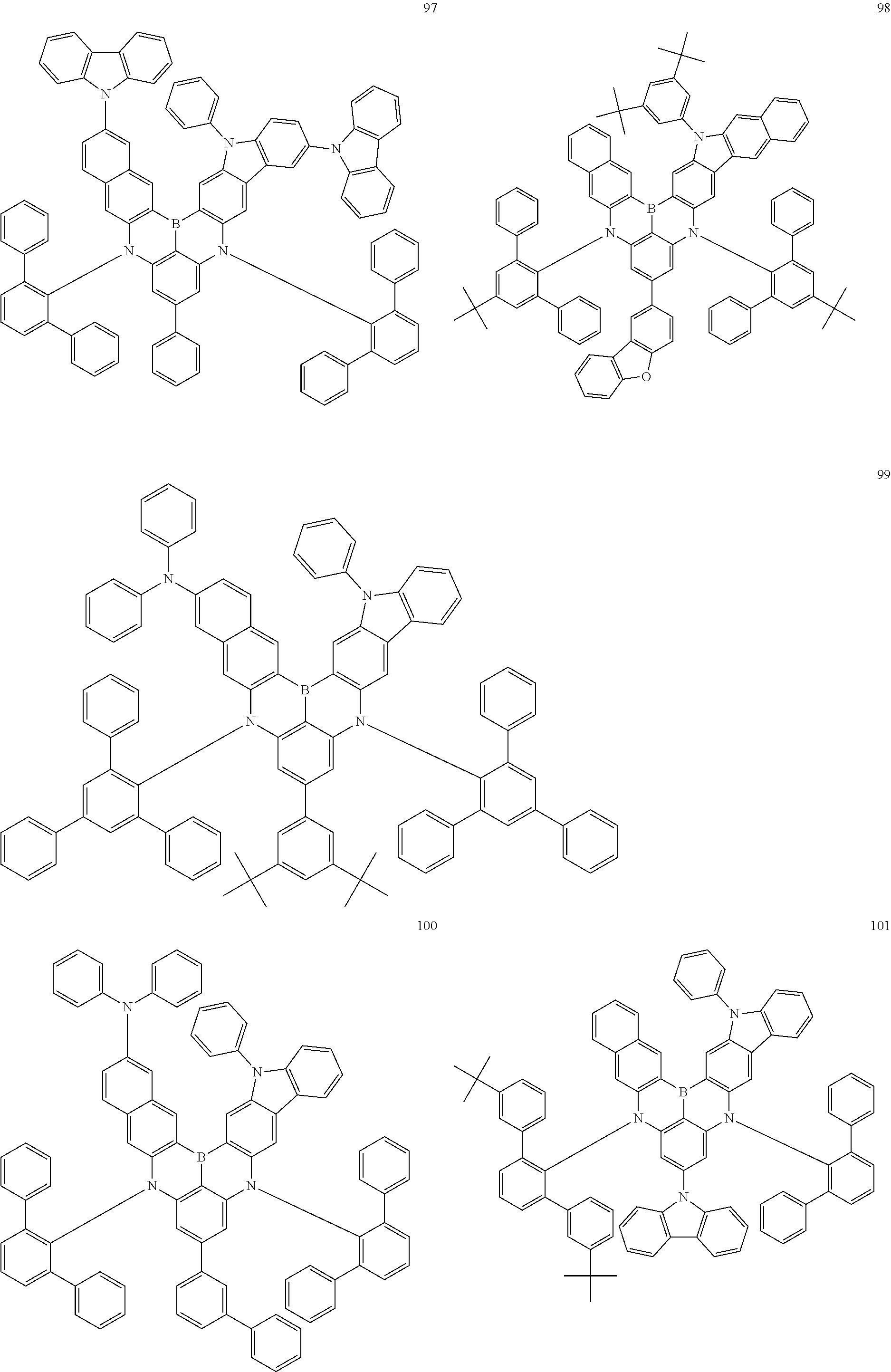 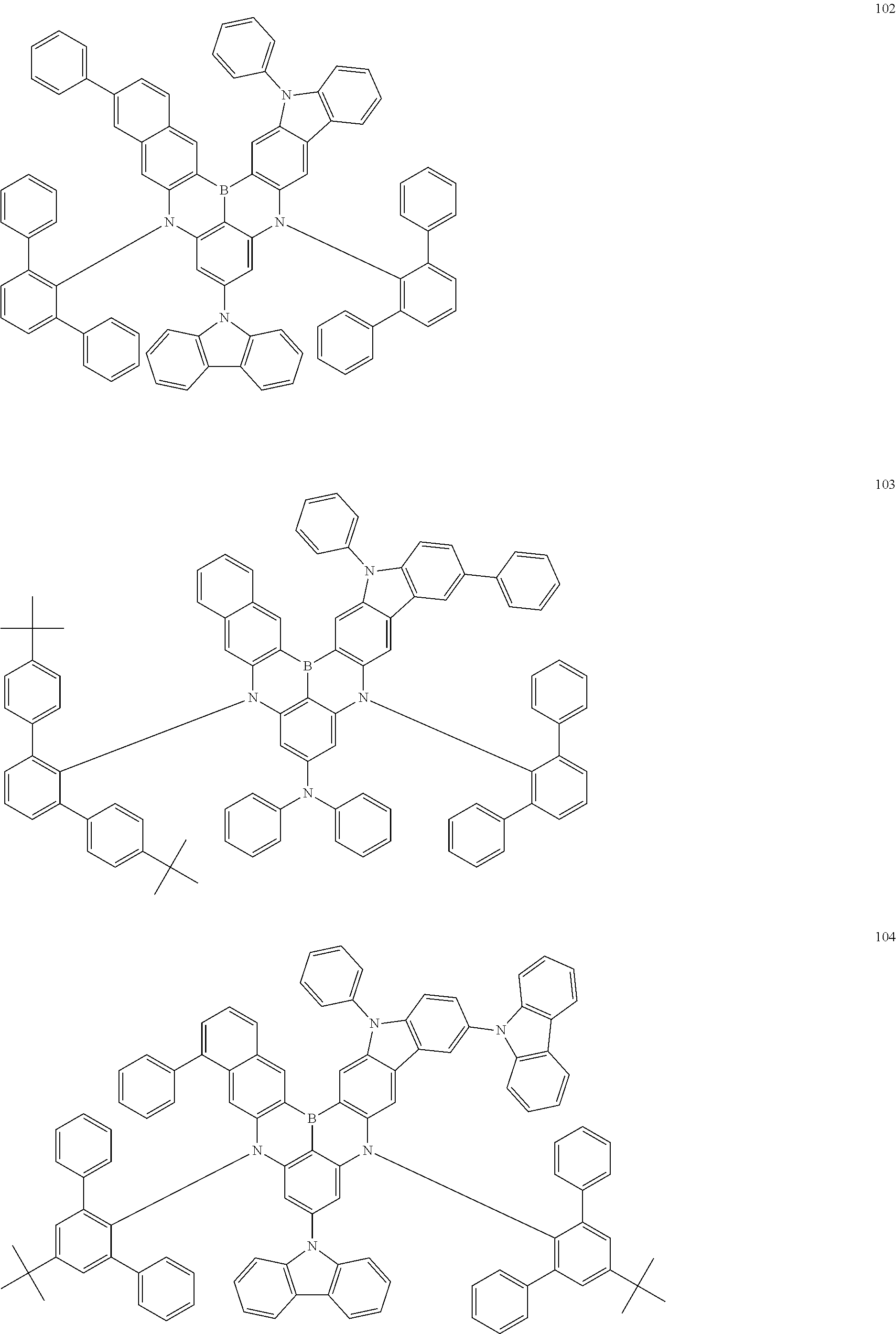 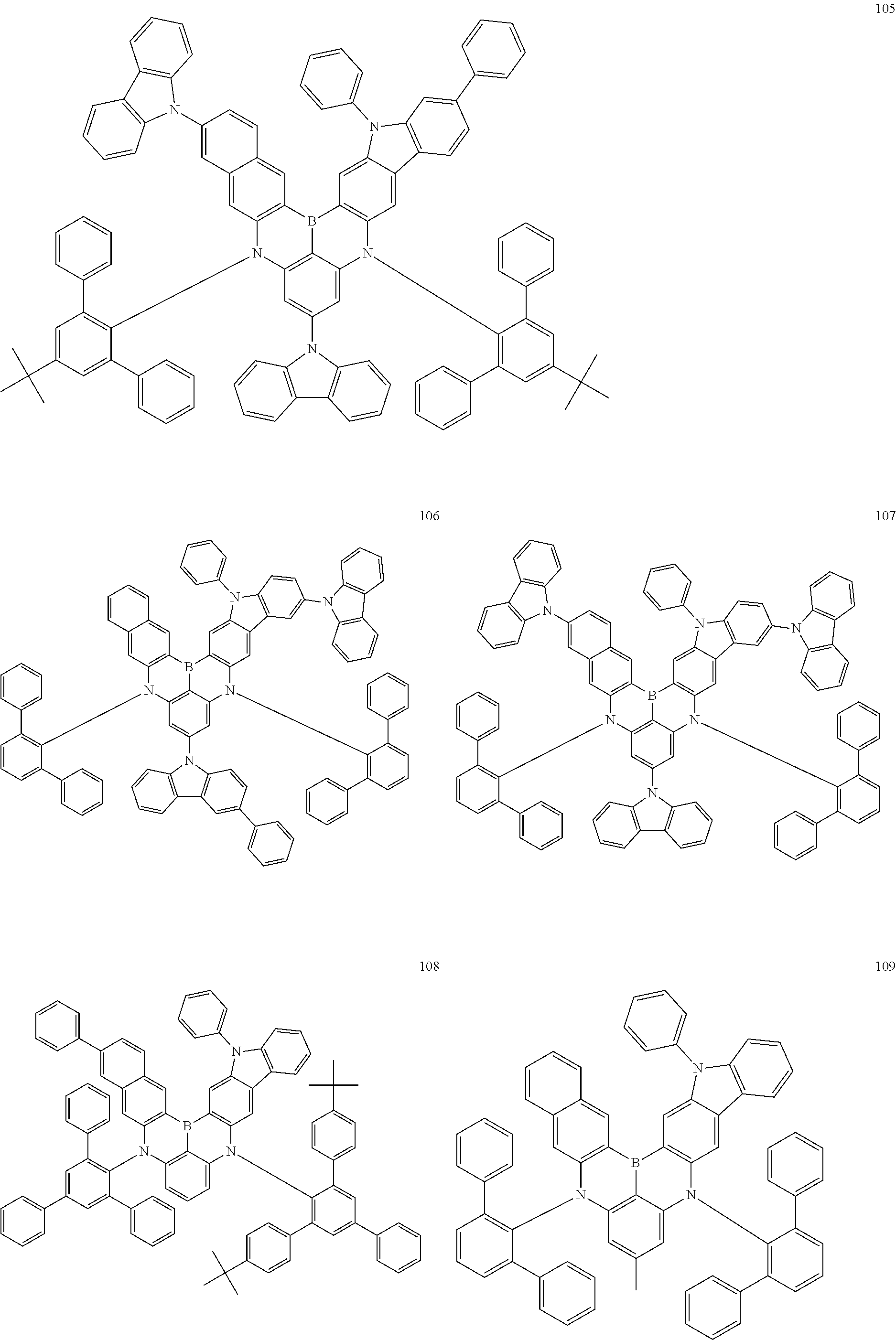 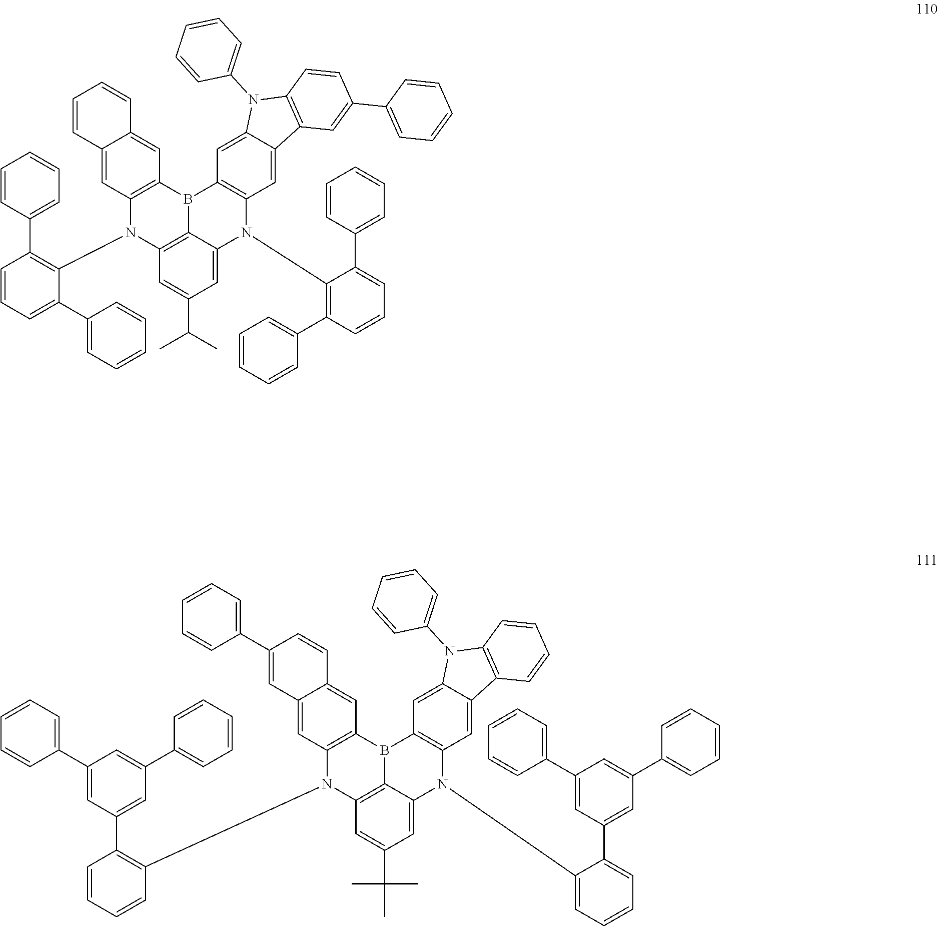 [SMILES: CC(C)c1cc2c3c(c1)N(c1c(-c4ccccc4)cccc1-c1ccccc1)c1cc4c5cc(-c6ccccc6)ccc5n(-c5ccccc5)c4cc1B3c1cc3ccccc3cc1N2c1c(-c2ccccc2)cccc1-c1ccccc1 ; CC(C)(C)c1cc2c3c(c1)N(c1ccccc1-c1cc(-c4ccccc4)cc(-c4ccccc4)c1)c1cc4c5ccccc5n(-c5ccccc5)c4cc1B3c1cc3ccc(-c4ccccc4)cc3cc1N2c1ccccc1-c1cc(-c2ccccc2)cc(-c2ccccc2)c1] 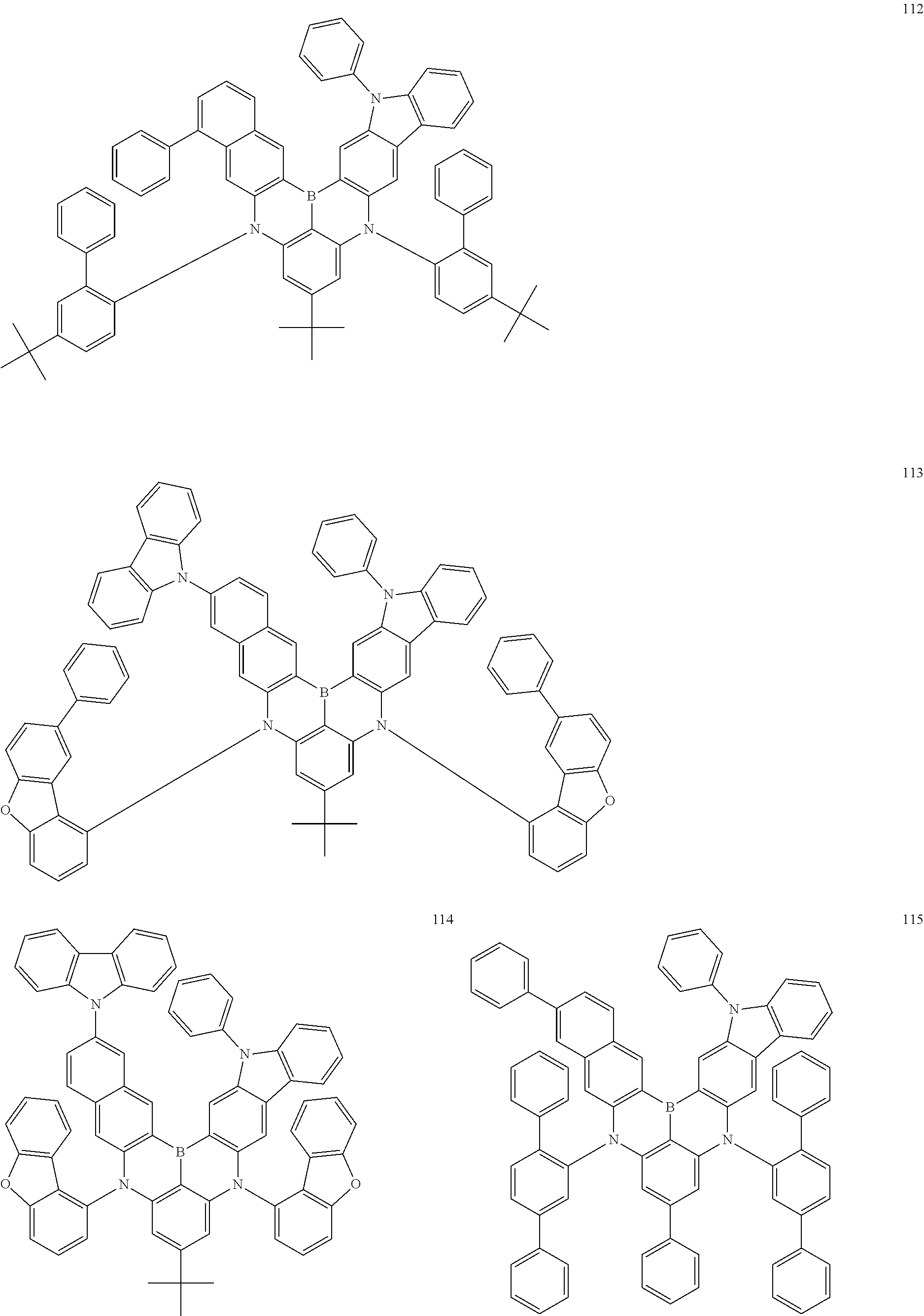 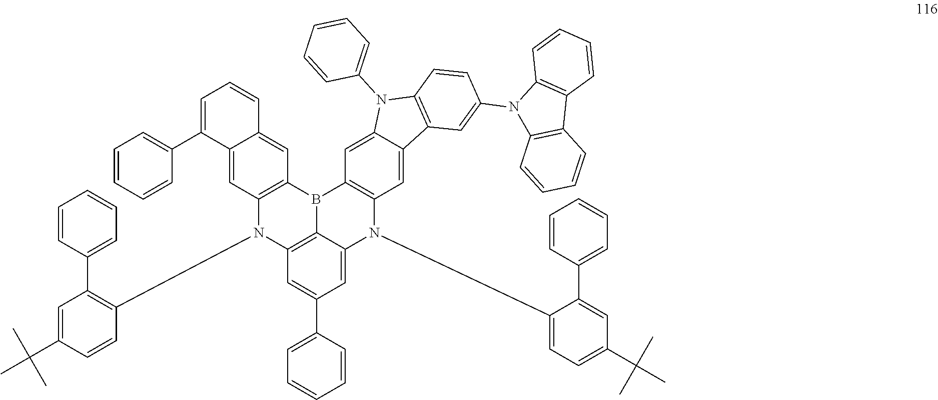 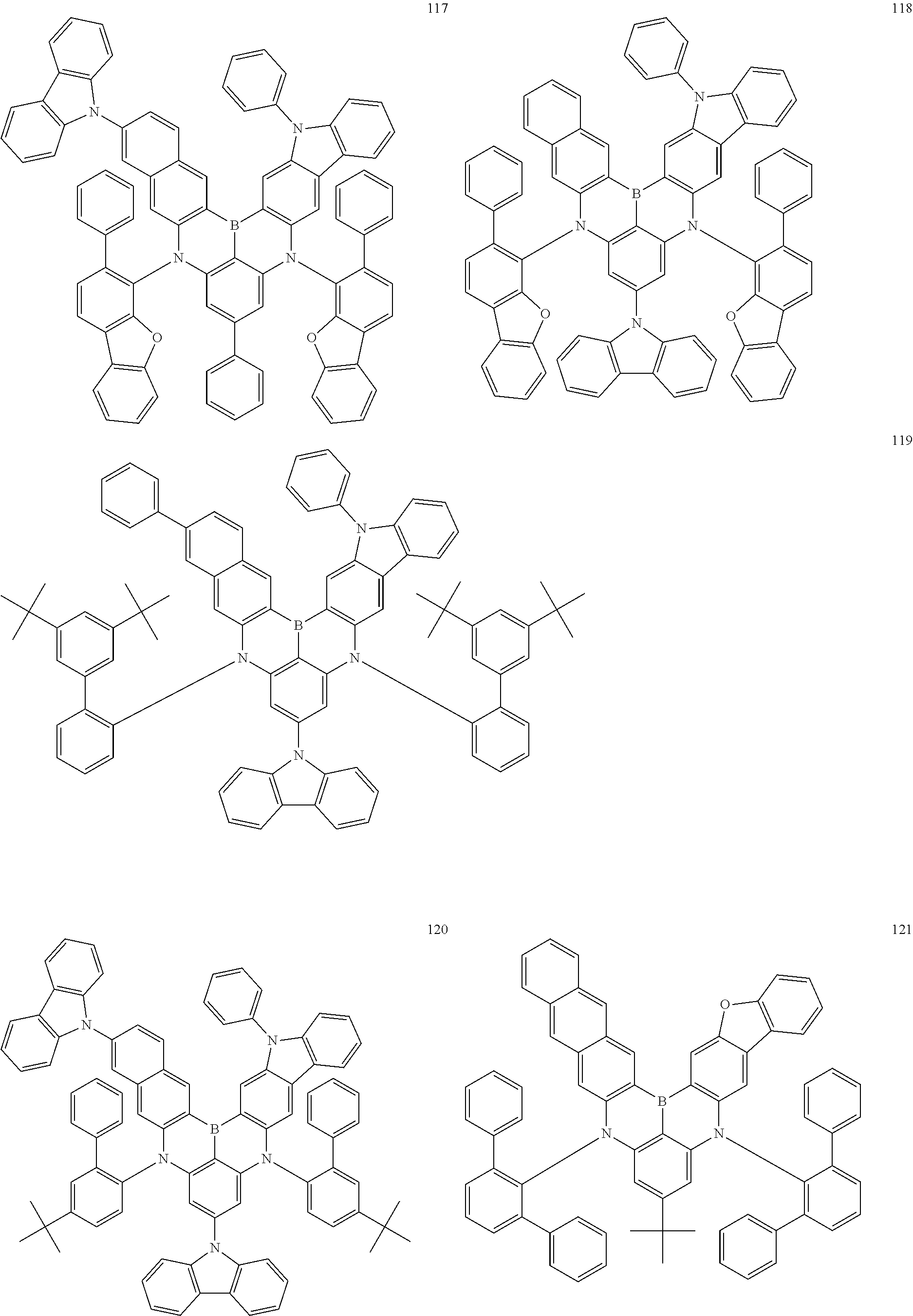 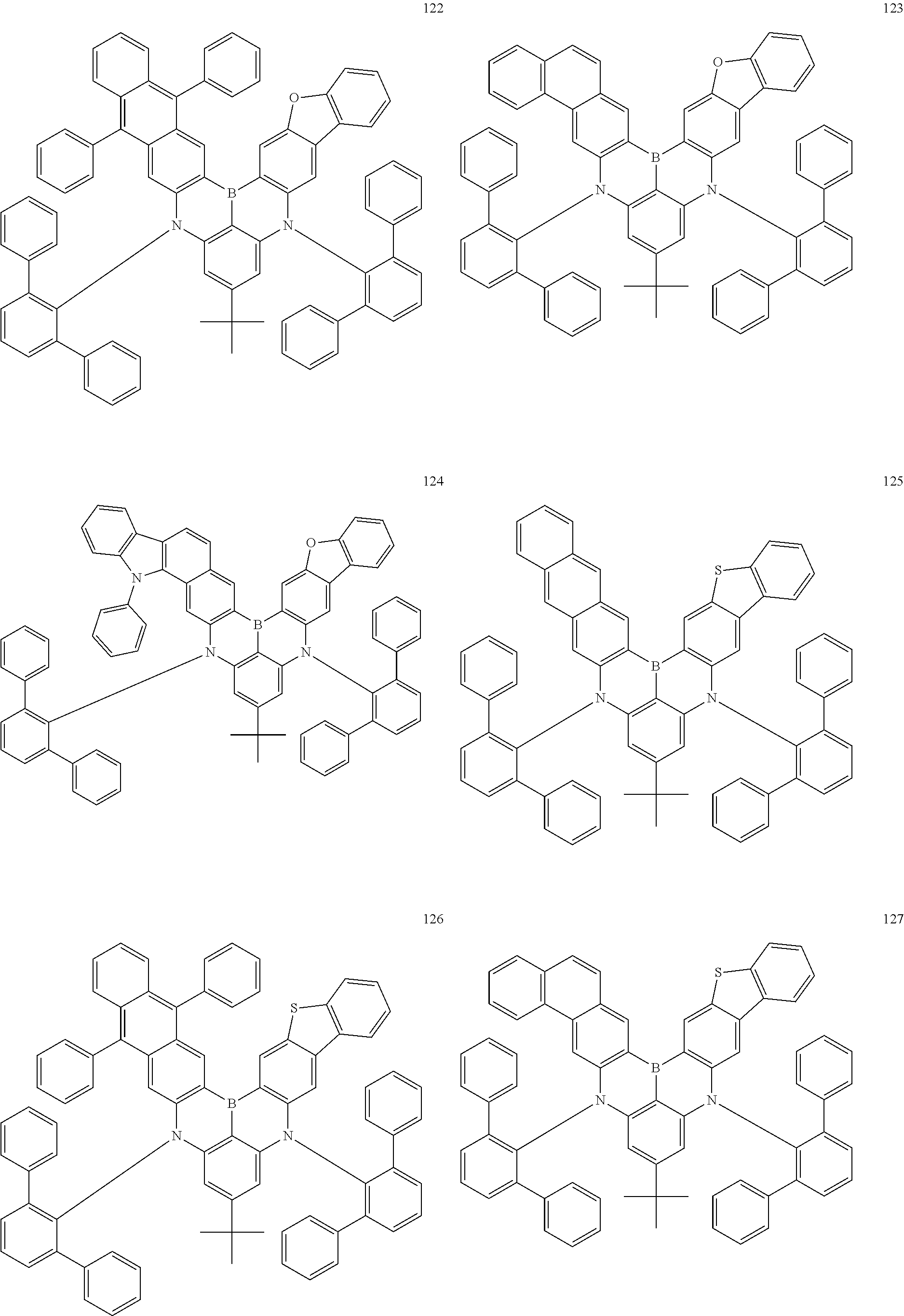 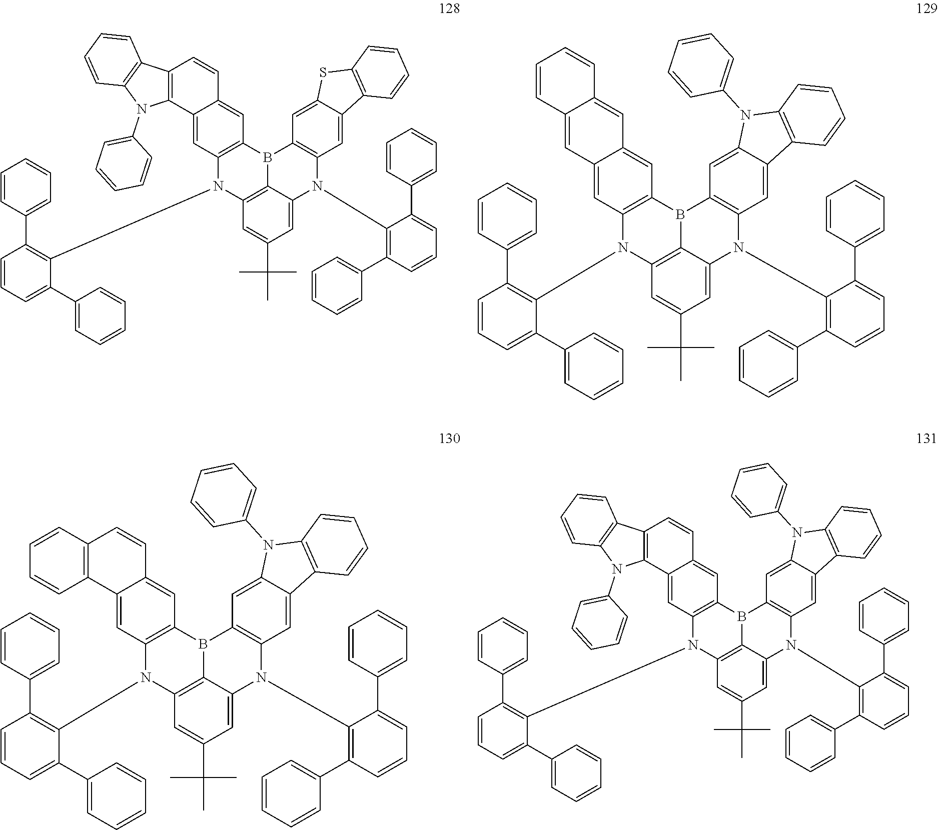 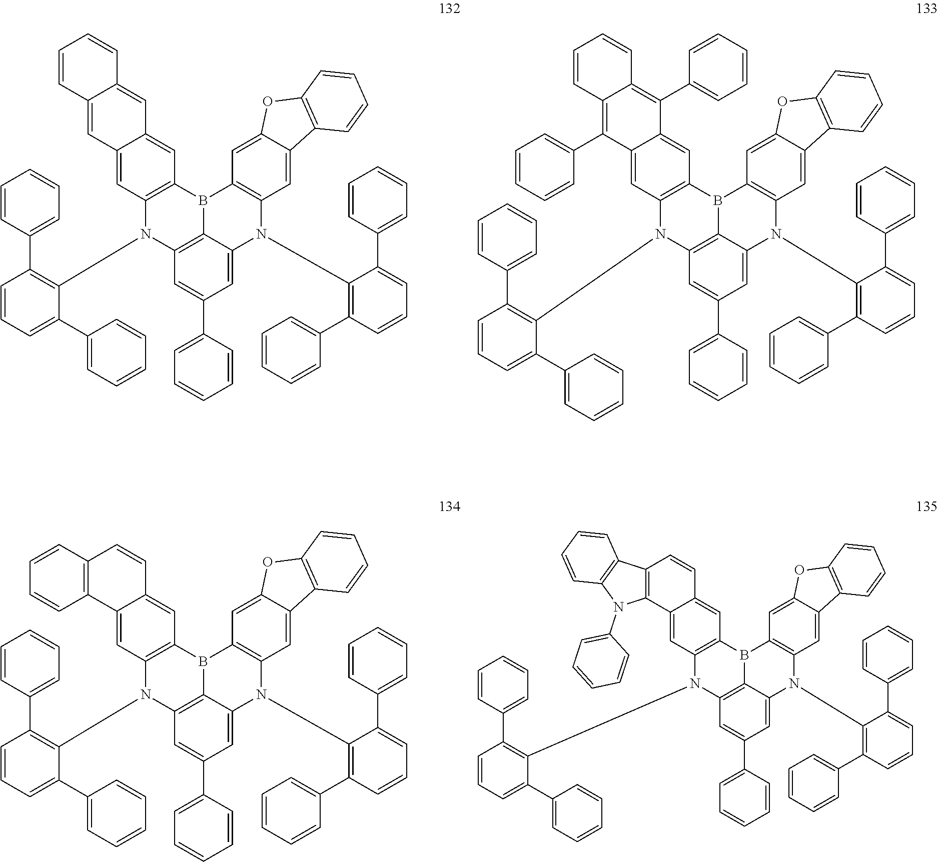 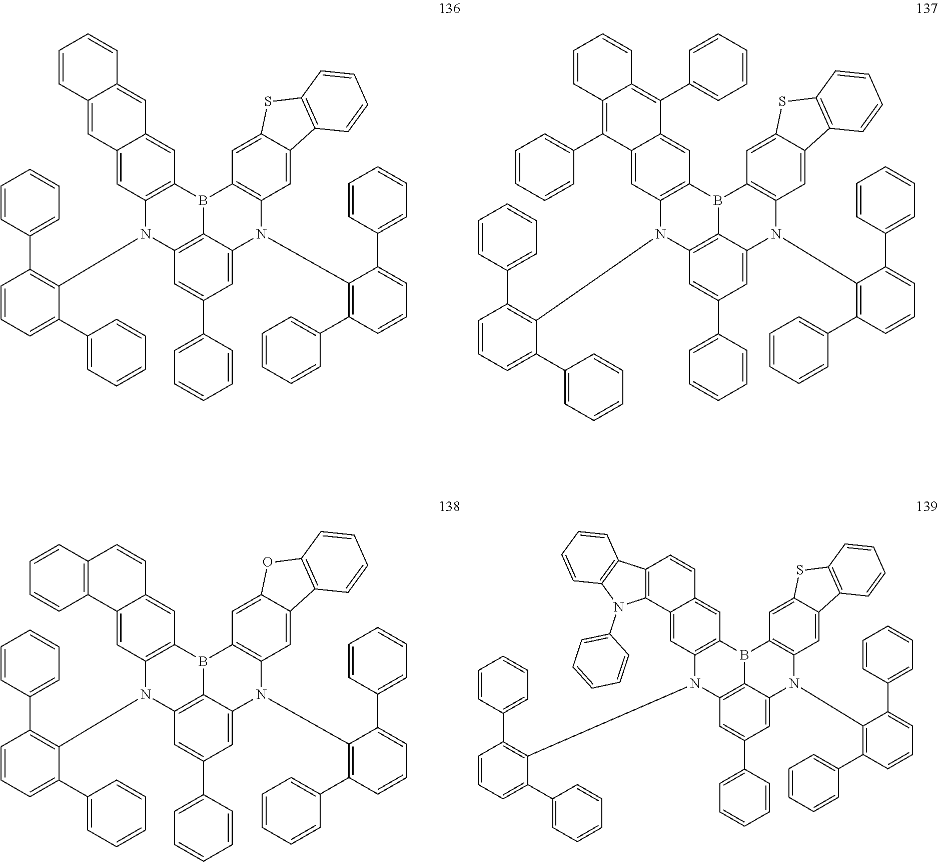 [chemical structure]
